(19) United States
(12) Patent Application Publication
(10) Pub. No.: US 2025/0120317 A1
(43) Pub. Date: Apr. 10, 2025

(54) LIGHT EMITTING ELEMENT, FUSED POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: Taeil KIM, Yongin-si (KR); Sun Young PAK, Yongin-si (KR); Junha PARK, Yongin-si (KR); MinJae SUNG, Yongin-si (KR); Mun-Ki SIM, Yongin-si (KR); Chihyun RYOO, Yongin-si (KR); Minjung JUNG, Yongin-si (KR); Giwoong HAN, Yongin-si (KR); Seonhyoung HUR, Yongin-si (KR)

(73) Assignee: Samsung Display Co., Ltd., Yongin-si (KR)

(21) Appl. No.: 18/670,851

(22) Filed: May 22, 2024

(30) Foreign Application Priority Data
Sep. 27, 2023 (KR) 10-2023-0129979

(51) Int. Cl. H10K 85/60; C07F 5/02; C09K 11/06; H10K 50/12

(52) U.S. Cl. CPC H10K 85/658; C07F 5/027; C09K 11/06; C07B 2200/05; C09K 2211/1018; H10K 50/12

(57) ABSTRACT

Embodiments provide a fused polycyclic compound, a light emitting element that includes the fused polycyclic compound, and a display device that includes the light emitting element. The light emitting element includes a first electrode, a second electrode disposed on the first electrode, and an emission layer disposed between the first electrode and the second electrode and including a first compound represented by Formula 1, which is explained in the specification:

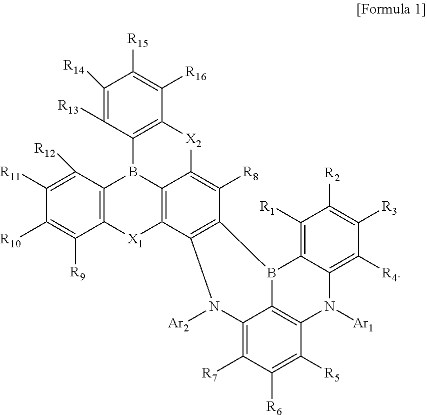

### CROSS-REFERENCE TO RELATED APPLICATION(S)

This application claims priority to and benefits of Korean Patent Application No. 10-2023-0129979 under 35 U.S.C. § 119, filed on Sep. 27, 2023 in the Korean Intellectual Property Office, the entire contents of which are incorporated herein by reference.

### BACKGROUND

### 1. Technical Field

The disclosure herein relates to a light emitting element, a fused polycyclic compound used in the light emitting element, and a display device including the light emitting element.

### 2. Description of the Related Art

Active development continues for an organic electroluminescence display device as an image display device. An organic electroluminescence display device is different from a liquid crystal display in that it is a so-called self-luminescent display device in which holes and electrons respectively injected from a first electrode and a second electrode recombine in an emission layer, so that a luminescent material including an organic compound in the emission layer emits light to implement display.

In the application of an organic electroluminescence element to a display device, there is a demand for an organic electroluminescence element having a low driving voltage, high luminous efficiency, and a long service life, and continuous development is required on materials for an organic electroluminescence element that are capable of stably achieving such characteristics.

In order to implement a highly efficient organic electroluminescence element, technologies pertaining to phosphorescence emission, which uses triplet state energy, or to fluorescence, which uses triplet-triplet annihilation (TTA) where singlet excitons are generated by collision of triplet excitons, are being developed. Development is currently directed to thermally activated delayed fluorescence (TADF) materials which use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminous efficiency and an element service life may be improved.

The disclosure also provides a fused polycyclic compound capable of improving luminous efficiency and an element service life of a light emitting element.

The disclosure also provides a display device including the light emitting element in which the luminous efficiency and service life may be improved, thereby having excellent display quality.

An embodiment provides a light emitting element that may include a first electrode, a second electrode disposed on the first electrode, and an emission layer disposed between the first electrode and the second electrode and including a first compound represented by Formula 1:

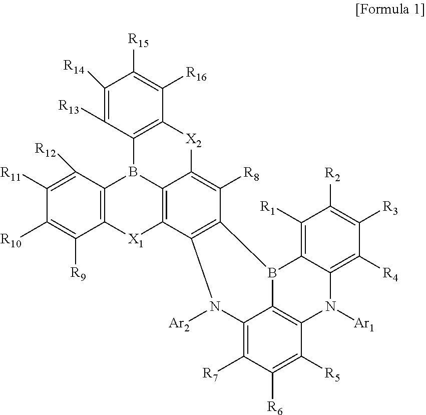

In Formula 1, X₁ and X₂ may each independently be S, O, Se, Te, or N(R₁₇); R₁ to R₁₆ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted amine group, a substituted or unsubstituted thio group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula 1, R₁₇ may be a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula 1, Ar₁ and Ar₂ may each independently be a substituted or unsubstituted aryl group having 6 to 60 ring-forming carbon atoms, a substituted or unsubstituted heteroaryl group having 2 to 60 ring-forming carbon atoms, or bonded to an adjacent group to form a ring; and at least one of Ar₁ and Ar₂ may each independently be a group represented by Formula 2:

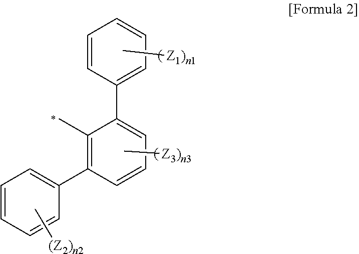

In Formula 2, Z₁ to Z₃ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula 2, n1 and n2 may each independently be an integer from 0 to 5; n3 may be an integer from 0 to 3; and

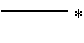

may be a position linked to Formula 1.

In an embodiment, at least one of Ar₁ and Ar₂ may each independently be a group represented by Formula 2; and the remainder of Ar₁ and Ar₂ may be a group represented by any one of Formula A-1 to Formula A-3:

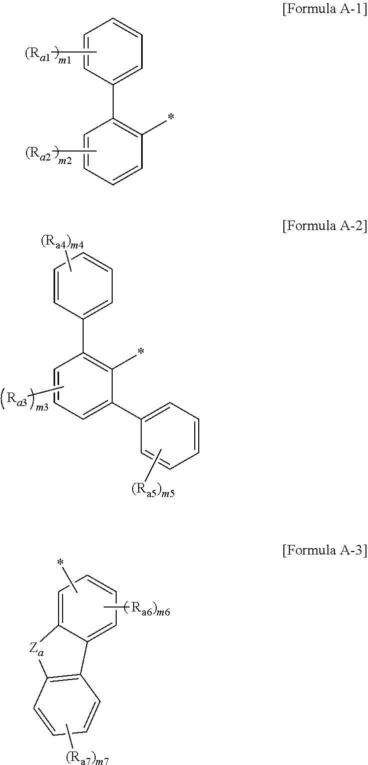

In Formula A-1 to Formula A-3, Zₐ may be C(Rₐ₈)(Rₐ₉), N(Rₐ₁₀), O, S, or Se.

In Formula A-1 to Formula A-3, Rₐ₁ to Rₐ₁₀ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula A-1 to Formula A-3, m1, m4, and m5 may each independently be an integer from 0 to 5; m2 and m7 may each independently be an integer from 0 to 4; m3 and m6 may each independently be an integer from 0 to 3; and

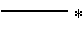

may be a position linked to Formula 1.

In an embodiment, the first compound may be represented by Formula 3:

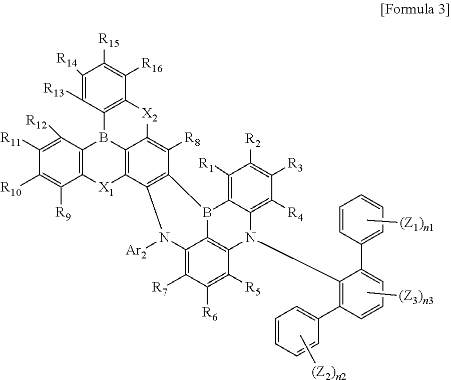

In Formula 3, X₁, X₂, R₁ to R₁₆, Ar₂, Z₁ to Z₃, and n1 to n3 may be the same as defined in Formula 1 and Formula 2.

In an embodiment, the first compound may be represented by Formula 4-1 or Formula 4-2:

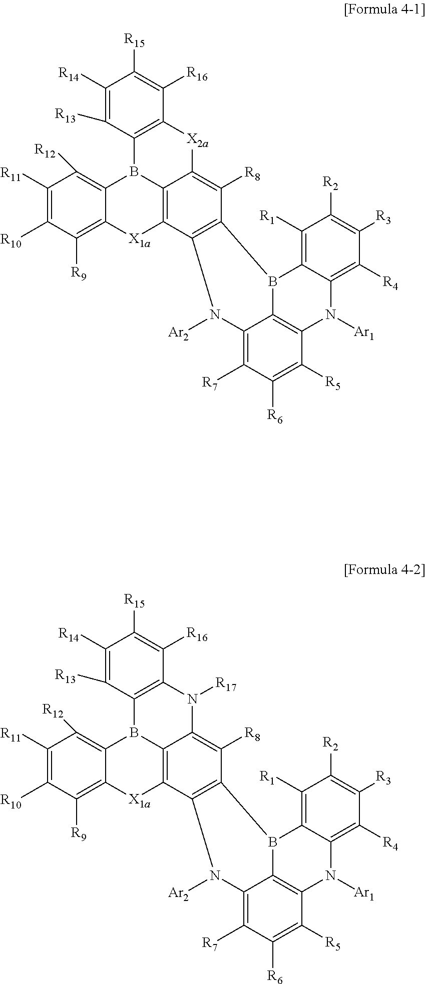

In Formula 4-1 and Formula 4-2, X₁ₐ and X₂ₐ may each independently be S, O, Se, or Te.

In Formula 4-1 and Formula 4-2, R₁ to R₁₇, Ar₁, and Ar₂ may be the same as defined in Formula 1.

In an embodiment, the first compound may be represented by Formula 5-1 or Formula 5-2:

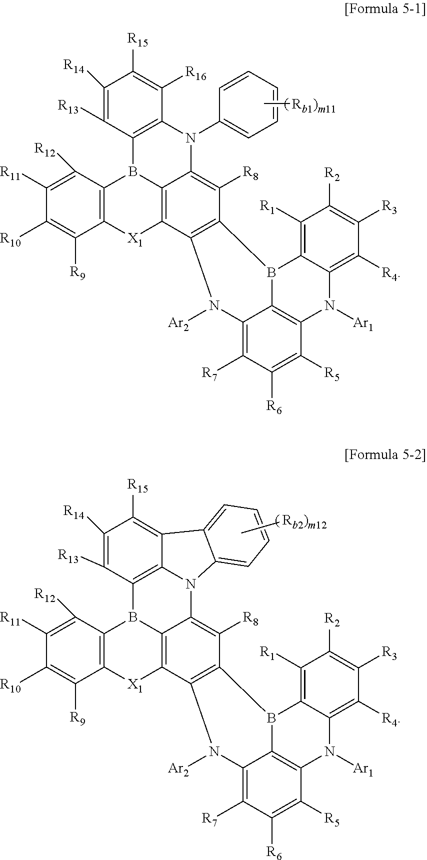

In Formula 5-1 and Formula 5-2, R_{b1} and R_{b2} may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms.

In Formula 5-1 and Formula 5-2, m11 may be an integer from 0 to 5; and m12 may be an integer from 0 to 4.

In Formula 5-1 to Formula 5-2, X₁, R₁ to R₁₆, Ar₁, and Ar₂ may be the same as defined in Formula 1.

In an embodiment, the first compound may be represented by Formula 6-1 or Formula 6-2:

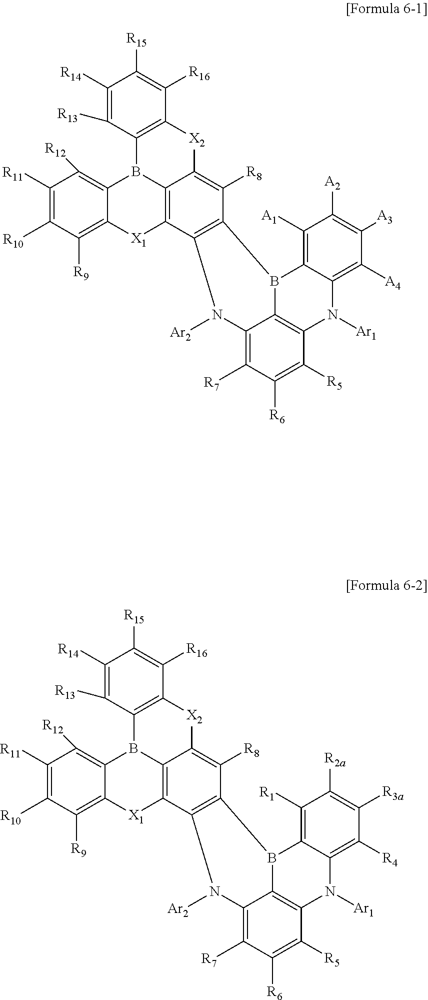

In Formula 6-1 and Formula 6-2, X₁, X₂, R₁, R₄ to R₁₆, Ar₁, and Ar₂ may be the same as defined in Formula 1.

In Formula 6-1 and Formula 6-2, A₁ to A₄ may each independently be a hydrogen atom or a deuterium atom; and R₂ₐ and R₃ₐ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula 6-1 and Formula 6-2, at least one of R₂ₐ and R₃ₐ may each independently be a group represented by any one of Formula B-1 to Formula B-6, or R₂ₐ and R₃ₐ may be positions at which a substituent represented by Formula C-1 is fused:

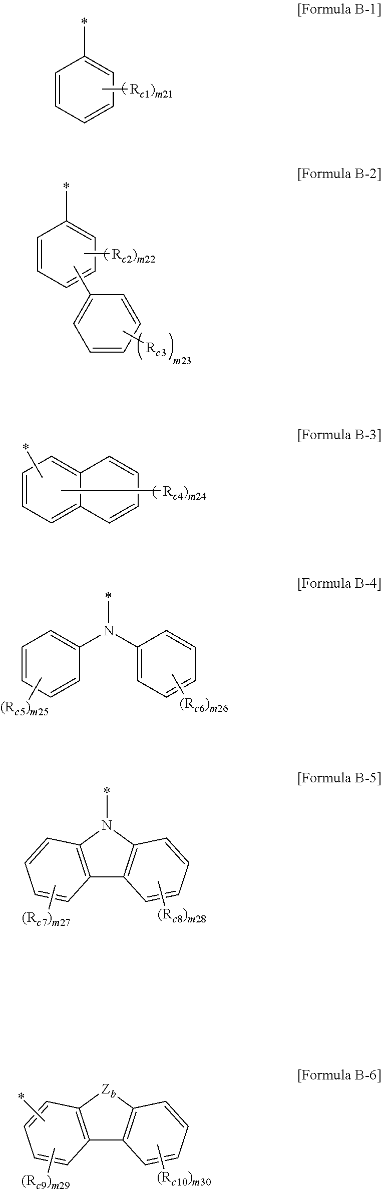

In Formula B-1 to Formula B-6, Z_{b} may be O, S, Se, or N(R_{c11}); and R_{c1} to R_{c11} may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula B-1 to Formula B-6, m21, m23, m25, and m26 may each independently be an integer from 0 to 5; m22, m27, m28, and m30 may each independently be an integer from 0 to 4; m24 may be an integer from 0 to 7; and m29 may be an integer from 0 to 3.

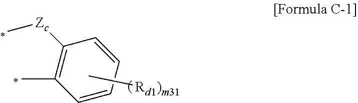

In Formula C-1, Z_{c} may be O, S, or N(R_{d2}).

In Formula C-1, R_{d1} and Rd₂ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula C-1, m31 may be an integer from 0 to 4; and

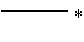

may be a position fused at R₂ₐ and R₃ₐ in Formula 6-2.

In an embodiment, in Formula 1, at least one of R₅ to R₇ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the first compound may be represented by Formula 7:

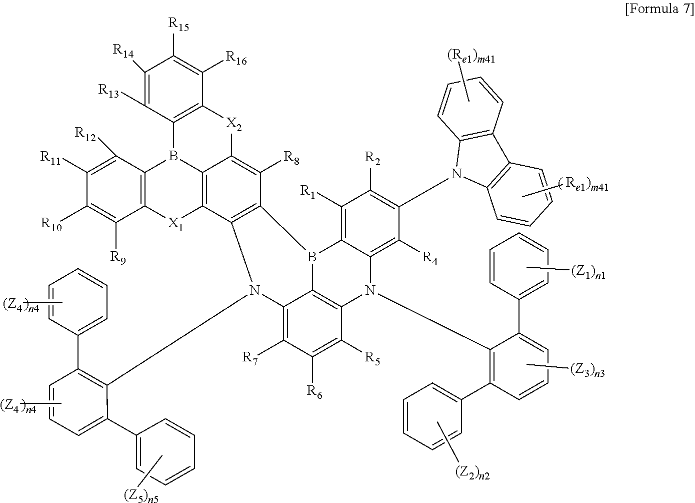

In Formula 7, Z₄ to Z₆, Rₑ₁, and Rₑ₂ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

In Formula 7, m41 and m42 may each independently be an integer from 0 to 4; n4 and n5 may each independently be an integer from 0 to 5; and n6 may be an integer from 0 to 3.

In Formula 7, X₁, X₂, R₁, R₂, R₄ to R₁₆, Z₁ to Z₃, and n1 to n3 may be the same as defined in Formula 1 and Formula 2.

In an embodiment, the emission layer may emit green light.

In an embodiment, the emission layer may further include at least one of a second compound represented by Formula HT-1, a third compound represented by Formula ET-1, and a fourth compound represented by Formula M-a:

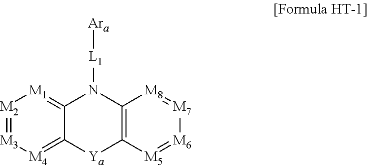

In Formula HT-1,
M₁ to M₈ may each independently be N or C(R₅₁),
L₁ may be a direct linkage, a substituted or unsubstituted arylene group having 6 to 30 ring-forming carbon atoms, or a substituted or unsubstituted heteroarylene group having 2 to 30 ring-forming carbon atoms,
Yₐ may be a direct linkage, C(R₅₂)(R₅₃), or Si(R₅₄)(R₅₅),
Arₐ may be a substituted or unsubstituted aryl group having 6 to 30 ring-forming carbon atoms or a substituted or unsubstituted heteroaryl group having 2 to 30 ring-forming carbon atoms, and
R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring.

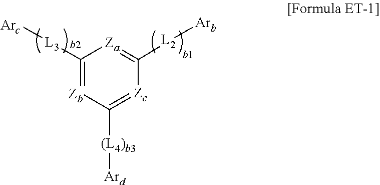

In Formula ET-1,
at least one of Zₐ to Z_{c} may each be N,
the remainder of Zₐ to Z_{c} may each independently be C(R₅₆),

R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,

b1 to b3 may each independently be an integer from 0 to 10,

Ar_{b} to Ar_{d} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and

L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

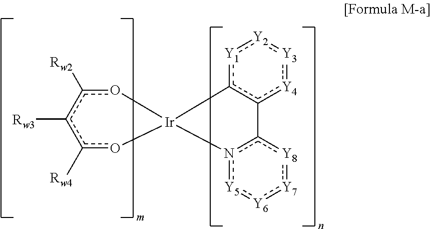

In Formula M-a,

Y₁ to Y₈ may each independently be C(R_{w1}) or N,

R_{w1} to R_{w4} may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,

m may be 0 or 1,

n may be 2 or 3, and

when m is 0, n may be 3, and when m is 1, n may be 2.

An embodiment provides a display device that may include a circuit layer disposed on a base layer, and a display element layer disposed on the circuit layer and including a light emitting element, wherein

the light emitting element may include a first electrode, a second electrode disposed on the first electrode, and an emission layer disposed between the first electrode and the second electrode and including a first compound represented by Formula 1, which is explained herein.

In an embodiment, the light emitting element may further include a capping layer disposed on the second electrode, and the capping layer may have a refractive index equal to or greater than about 1.6 with respect to light in a wavelength range of about 550 nm to about 660 nm.

In an embodiment, the display device may further include a light control layer disposed on the display element layer and including a quantum dot, wherein
the light emitting element may emit a first color light, and
the light control layer may include a first light control part including a first quantum dot that converts the first color light into a second color light in a longer wavelength region than the first color light, a second light control part including a second quantum dot that converts the second color light into a third color light in a longer wavelength region than the second color light, and a third light control part that transmits the first color light.

In an embodiment, the display device may further include a color filter layer disposed on the light control part, wherein

the color filter layer may include a first filter that transmits the second color light, a second filter that transmits the third color light, and a third filter that transmits the first color light.

An embodiment provides a fused polycyclic compound that may be represented by Formula 1, which is explained herein.

In an embodiment, a Stokes-shift of the fused polycyclic compound may be equal to or less than about 25 nm; and a full width at half maximum (FWHM) of the fused polycyclic compound may be equal to or less than about 25 nm.

In an embodiment, the fused polycyclic compound may be represented by Formula 3, which is explained herein.

In an embodiment, the fused polycyclic compound may be represented by Formula 5-1 or Formula 5-2, which are explained herein.

In an embodiment, the fused polycyclic compound may be represented by Formula 6-1 or Formula 6-2, which are explained herein.

In an embodiment, the fused polycyclic compound may be selected from Compound Group 1, which is explained herein.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of embodiments, and are incorporated in and constitute a part of this specification. The drawings illustrate exemplary embodiments of the disclosure and principles thereof. The above and other aspects and features of the disclosure will be more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is schematic a cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic diagram of a vehicle in which display devices are disposed according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent substituted that is for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, the hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in the aryl group may be 6 to 60, 6 to 50, 6 to 40, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

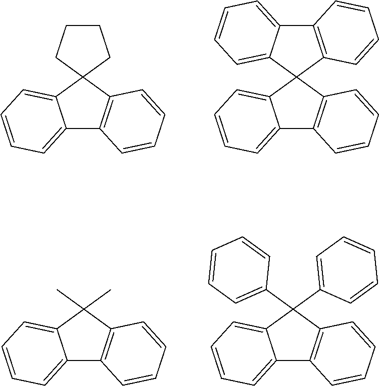

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 60, 2 to 50, 2 to 40, 2 to 30, 2 to 20, or 2 to 10.

In the specification, an aliphatic heterocyclic group may include at least one of B, O, N, P, Si, S, and Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, and Se as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 50, 2 to 40, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the description of an aryl group may be applied to an arylene group, except that an arylene group is a divalent group. The description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

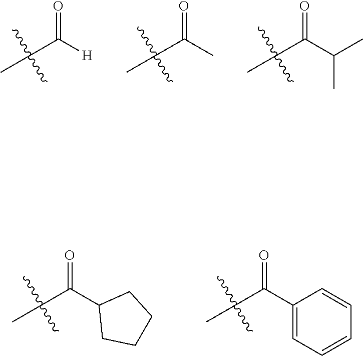

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, or a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, a n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

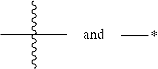

each represent a bond to a neighboring atom in a corresponding formula or moiety.

Hereinafter, embodiments will be described with reference to the accompanying drawings.

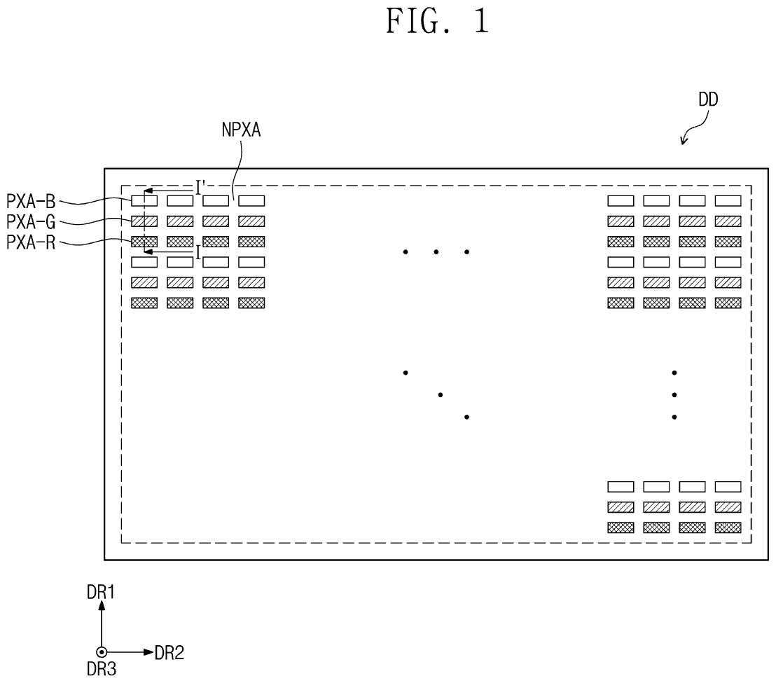

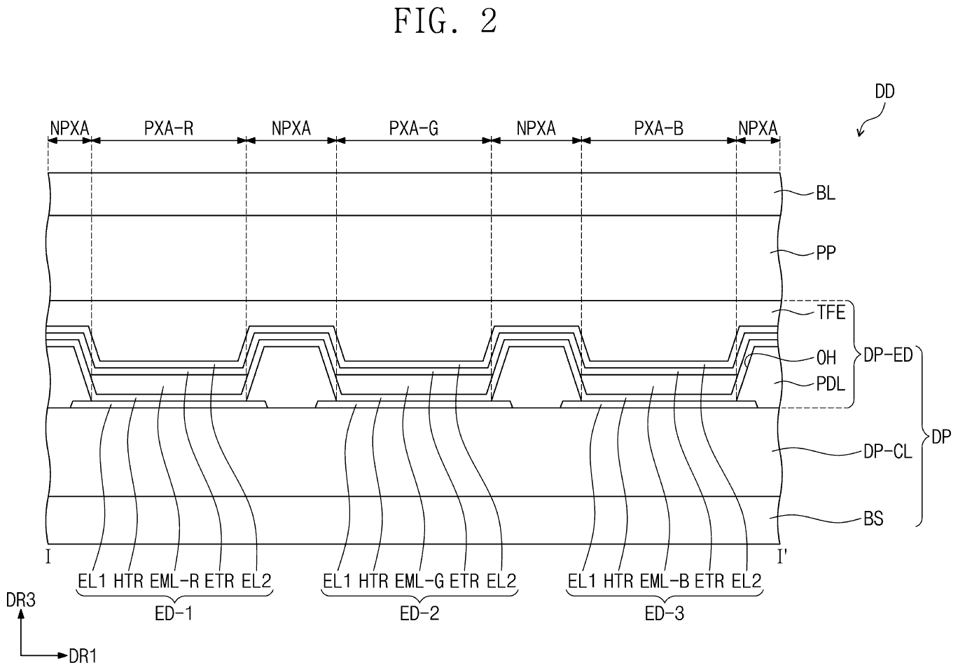

FIG. 1 is a schematic plan view of a display device DD according to an embodiment. FIG. 2 is a schematic cross-sectional view of a display device DD according to an embodiment. FIG. 2 is a schematic cross-sectional view illustrating a part taken along line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

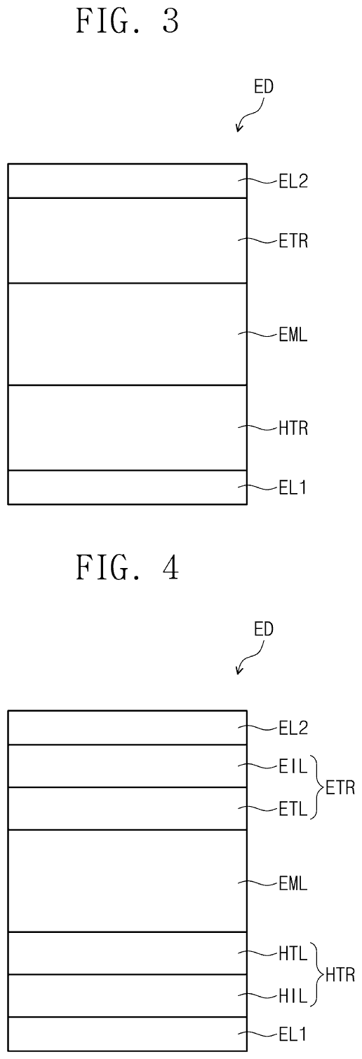

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, embodiments are not limited thereto.

Although not shown in in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 in an embodiment may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not particularly limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between the adjacent light emitting regions PXA-R, PXA-G, and PXA-B, and which correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined by the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment shown in FIGS. 1 and 2, three light emitting regions PXA-R, PXA-G, and PXA-B, which respectively emit red light, green light, and blue light, are shown as an example. For example, the display device DD may include a red light emitting region PXA-R, a green light emitting region PXA-G, and a blue light emitting region PXA-B, which are distinct from one another.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting elements may emit a light in a wavelength range different from the remainder. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B each may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 show that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration shown in FIG. 1, and the order in which the red light emitting region PXA-R, the green light emitting region PXA-G, and the blue light emitting region PXA-B are arranged may be provided in various combinations according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. The light emitting element ED according to an embodiment may include a first electrode EL1, a second electrode EL2 oppositely disposed to the first electrode EL1, and at least one functional layer disposed between the first electrode EL1 and the second electrode EL2. The light emitting element ED according to an embodiment may include a fused polycyclic compound according to an embodiment, which will be explained later, in the at least one functional layer.

The light emitting element ED may include a hole transport region HTR, an emission layer EML, an electron transport region ETR, or the like, as the at least one functional layer.

Referring to FIG. 3, the light emitting element ED according to an embodiment may include a first electrode EL1, a hole transport region HTR, an emission layer EML, an electron transport region ETR, and a second electrode EL2.

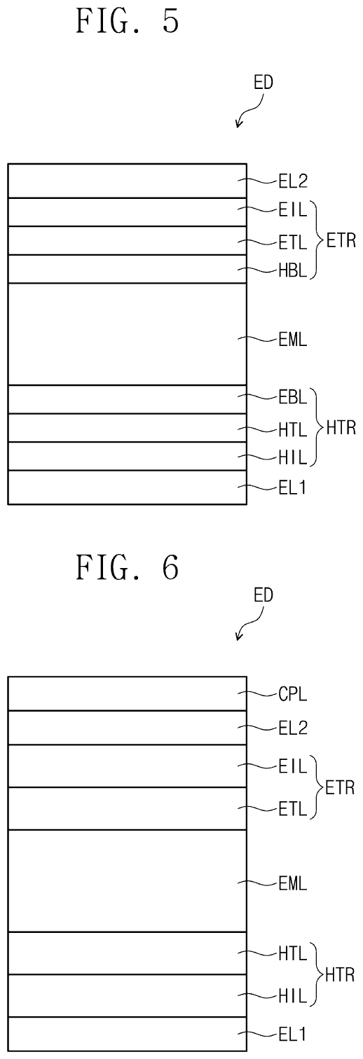

In comparison with FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison with FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison with FIG. 4, FIG. 6 is a schematic cross-sectional view of a light emitting element ED according to an embodiment which includes a capping layer CPL disposed on a second electrode EL2.

In an embodiment, the light emitting element ED may include a fused polycyclic compound according to an embodiment, which will be explained later, in the at least one functional layer. In the light emitting element ED, at least one of the hole transport region HTR, the emission layer EML, and the electron transport region ETR may include the fused polycyclic compound according to an embodiment. For example, in the light emitting element ED, the emission layer EML may include the fused polycyclic compound according to an embodiment.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the metal materials, combinations of at least two metal materials, oxides of the metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL may stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

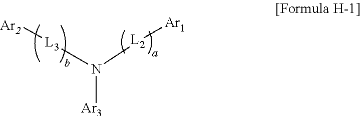

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms.

In Formula H-1, a and b may each independently be an integer from 0 to 10. When a or b is equal to or greater than 2, groups of each L₁ and L₂ may independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, a compound represented by Formula H-1 may be a monoamine compound. In an embodiment, the compound represented by Formula H-1 may be a diamine compound in which at least one of Ar₁ to Ar₃ includes an amine group as a substituent. In another embodiment, a compound represented by Formula H-1 may be a carbazole-based compound in which at least one of Ar₁ and Ar₂ includes a substituted or unsubstituted carbazole group, or may be a fluorene-based compound in which at least one of A₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

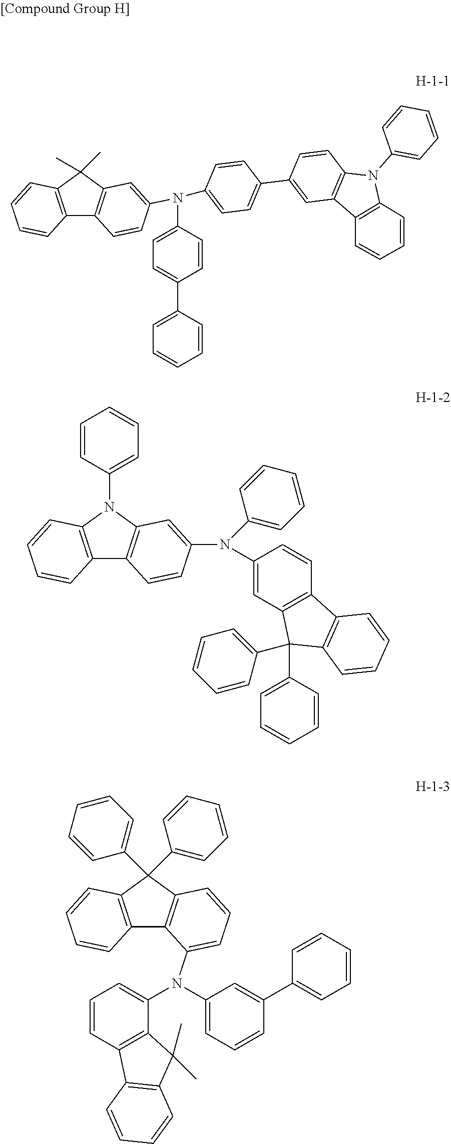 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

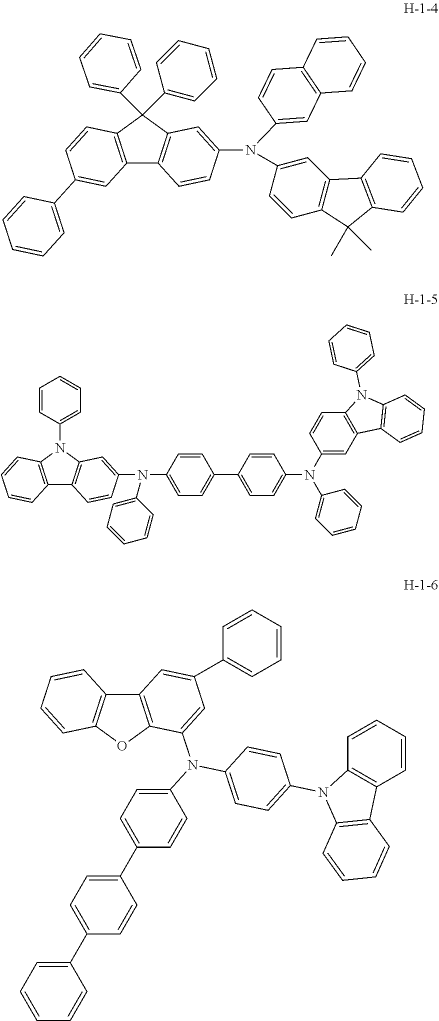 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

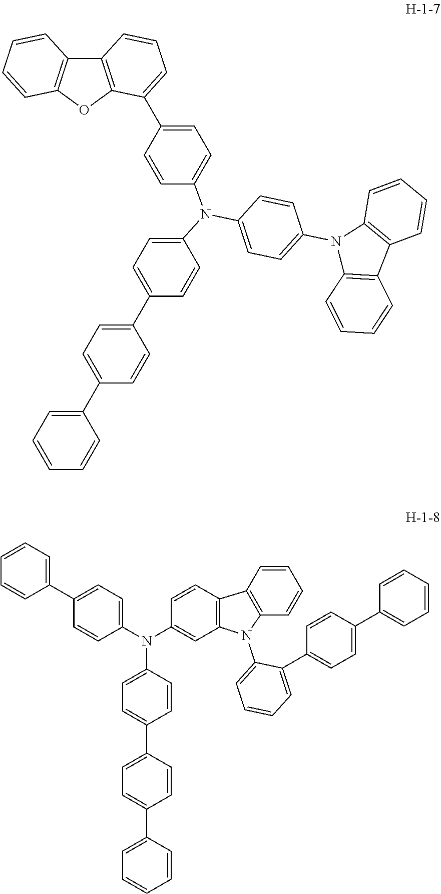 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1]

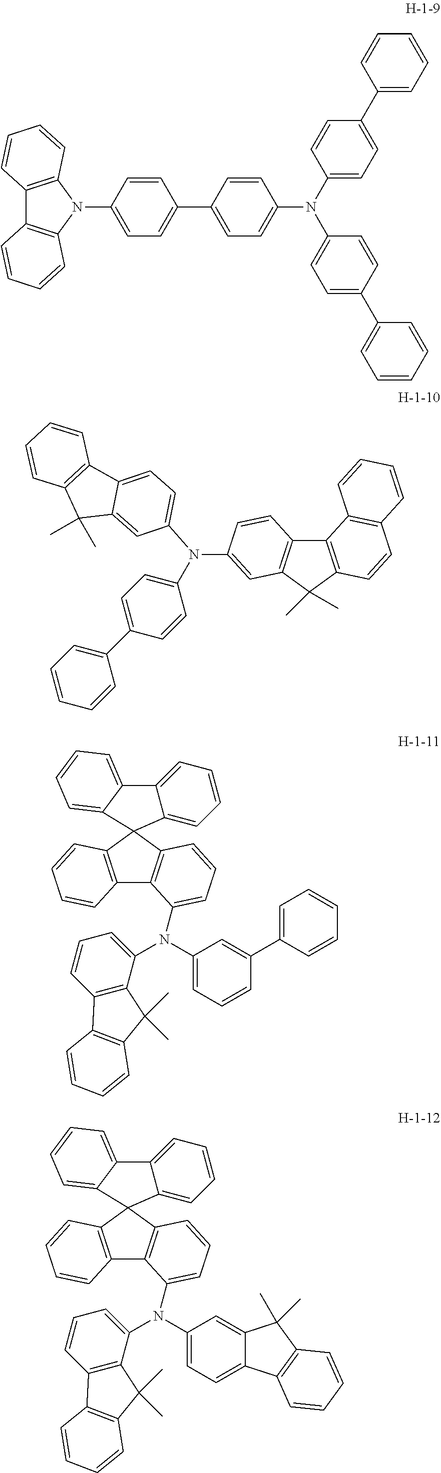

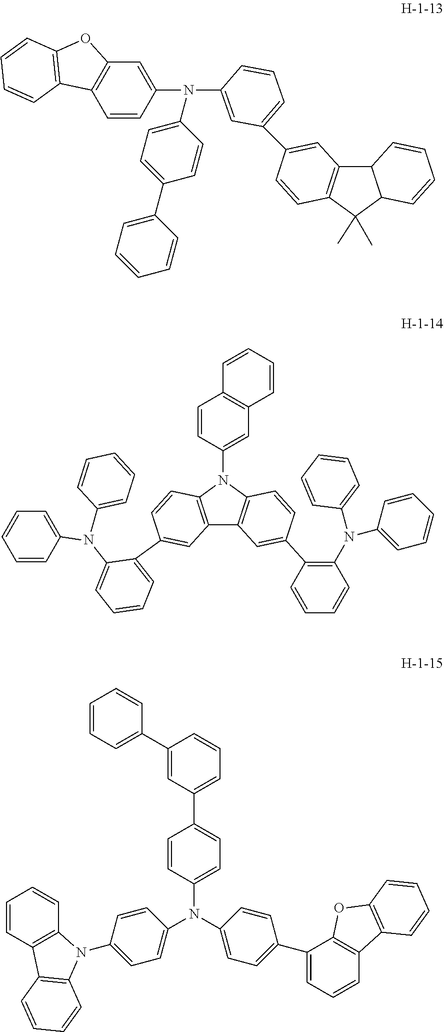 [SMILES: CC1(C)c2ccc(-c3cccc(N(c4ccc(-c5ccccc5)cc4)c4ccc5c(c4)oc4ccccc45)c3)cc2C2C=CC=CC21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

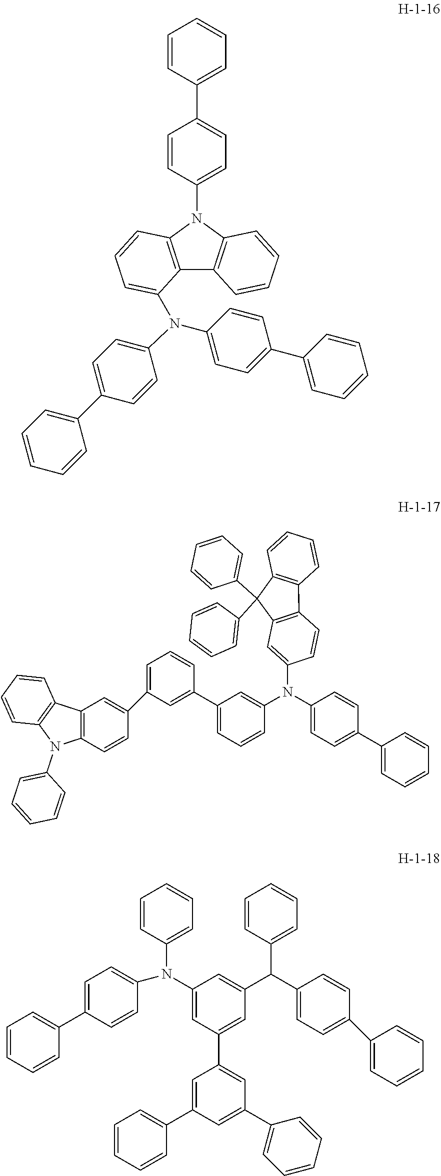 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(C(c3ccccc3)c3cc(-c4cc(-c5ccccc5)cc(-c5ccccc5)c4)cc(N(c4ccccc4)c4ccc(-c5ccccc5)cc4)c3)cc2)cc1]

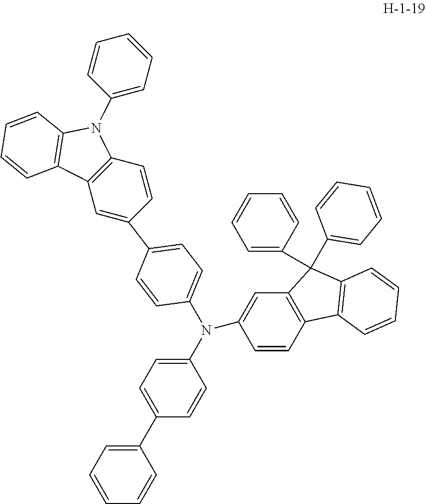 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, and a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The light emitting element ED may include a fused polycyclic compound represented by Formula 1 in at least one functional layer disposed between the first electrode EL1 and the second electrode EL2. In an embodiment, the emission layer EML in the light emitting element ED may include a fused polycyclic compound according to an embodiment. In an embodiment, the emission layer EML may include the fused polycyclic compound as a dopant. The fused polycyclic compound may be a dopant material in the emission layer EML. In the specification, the fused polycyclic compound according to an embodiment may be referred to as a first compound.

The fused polycyclic compound may include a fused ring core in which five rings are fused and which contains a first boron atom, a first nitrogen atom, and a second nitrogen atom. The fused polycyclic compound may have a structure in which two aromatic hydrocarbon rings are linked to the fused ring core. A second boron atom, a first heteroatom, and a second heteroatom may be included in a linking group between the fused polycyclic heterocycle and the two aromatic hydrocarbon rings. The two aromatic hydrocarbon rings may be linked to the fused polycyclic heterocycle via the second boron atom, the first heteroatom, and the second heteroatom to form an additional fused structure.

In an embodiment, in the fused ring core in the fused polycyclic compound, three substituted or unsubstituted benzene rings may be linked via the first boron atom, the first nitrogen atom, and the second nitrogen atom, thereby forming five rings. For example, in the three benzene rings in the fused ring core, the three benzene rings may be linked around the first boron atom, a first benzene ring and a second benzene ring among the three benzene rings may be linked via the first nitrogen atom, and a third benzene ring may be linked to the second benzene ring via the second nitrogen atom. The first boron atom and the first and second nitrogen atoms may each be linked to the second benzene ring.

In an embodiment, the two aromatic hydrocarbon rings in the fused polycyclic compound may be linked to the fused ring core via a second boron atom, the first heteroatom, and the second heteroatom to form an additional fused structure. For example, the fused polycyclic compound according to an embodiment may have a structure in which a fourth benzene ring and a fifth benzene ring, which are two aromatic hydrocarbon rings, are linked to the fused polycyclic heterocycle, and the second boron atom, the first heteroatom, and the second heteroatom may form part of a linking group between the fused ring core and the fourth and fifth benzene rings. The fourth and fifth benzene rings may be linked to the fused ring core via the second boron atom, the first heteroatom, and the second heteroatom to form four additional fused rings.

The fourth benzene ring and the fifth benzene ring may be linked to the third benzene ring of the fused ring core. For example, the second boron atom, the first heteroatom, and the second heteroatom may be linked to the third benzene ring, the fourth benzene ring and the third benzene ring may be linked via the second boron atom and the first heteroatom, and the fifth benzene ring and the third benzene ring may be linked via the second boron atom and the second heteroatom. The second boron atom may be linked to a carbon atom of the third benzene ring, which is at a para position to the first boron atom. The first and second heteroatom may each be linked to a carbon atom of the third benzene ring, which are each at a meta position to the first boron atom. The first heteroatom may be linked at an ortho position to the second nitrogen atom, and the second heteroatom may be linked at a para position to the second nitrogen atom. In an embodiment, the third benzene ring, to which the fourth benzene ring and the fifth benzene ring are linked, may be referred to as a fused benzene ring.

In an embodiment, the first and second heteroatoms may each independently be a nitrogen (N) atom, an oxygen (O) atom, a sulfur (S) atom, a selenium (Se) atom, or a tellurium (Te) atom.

The fused polycyclic compound may include a first substituent linked to the fused ring core. The first substituent may be linked to at least one of the first nitrogen atom and the second nitrogen atom constituting the fused ring core in the fused polycyclic compound according to an embodiment. The first substituent may include a benzene moiety, and may include a first sub-substituent and a second sub-substituent which may be substituted at a specific position of the benzene moiety. For example, the first substituent may include a benzene moiety linked to the nitrogen atom of the fused ring core, and a structure in which the first sub-substituent and the second sub-substituent are each linked at an ortho position with respect to the nitrogen atom.

The first sub-substituent and the second sub-substituent may each be a substituted or unsubstituted aryl group having 6 to 30 ring-forming carbon atoms. For example, the first sub-substituent and the second sub-substituent may each be a substituted or unsubstituted phenyl group.

The fused polycyclic compound according to an embodiment may be represented by Formula 1:

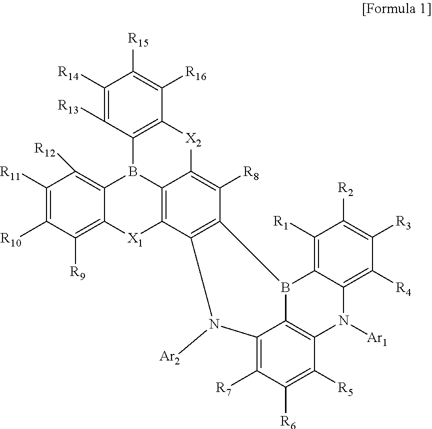

The fused polycyclic compound represented by Formula 1 according to an embodiment may have a fused ring core in which five rings are fused together with a first boron atom, a first nitrogen atom, and a second nitrogen atom, and wherein two aromatic hydrocarbon rings are linked to the fused ring core. A second boron atom, a first heteroatom, and a second heteroatom may form a linking group between the fused ring core and the two aromatic hydrocarbon rings. The two aromatic hydrocarbon rings may be linked to the fused ring core via the second boron atom, the first heteroatom, and the second heteroatom to form an additional fused structure. In the specification, in Formula 1, the benzene ring that includes R₁ to R₄ may correspond to the aforementioned first benzene ring, the benzene ring that includes R₅ to R₇ may correspond to the aforementioned second benzene ring, and the benzene ring that includes R₈ may correspond to the aforementioned third benzene ring.

In Formula 1, X₁ and X₂ may each independently be S, O, Se, Te, or N(R₁₇). In an embodiment, X₁ and X₂ may each independently be S, O, Se, or N(R₁₇). For example, X₁ may be S, O, or Se; and X₂ may be S, O, or N(R₁₇).

In Formula 1, R₁ to R₁₆ may each independently be a hydrogen atom, a deuterium atom, a halogen atom, a cyano group, a nitro group, a hydroxy group, a substituted or unsubstituted silyl group, a substituted or unsubstituted oxy group, a substituted or unsubstituted amine group, a substituted or unsubstituted thio group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₁ to R₁₆ may each independently be a hydrogen atom, a deuterium atom, a substituted or unsubstituted methyl group, a substituted or unsubstituted t-butyl group, a substituted or unsubstituted phenyl group, a substituted or unsubstituted biphenyl group, a substituted or unsubstituted naphthyl group, a substituted or unsubstituted carbazole group, a substituted or unsubstituted diphenylamine group, a substituted or unsubstituted dibenzofuran group, a substituted or unsubstituted dibenzothiophene group, a substituted or unsubstituted pyridine group, a substituted or unsubstituted pyrimidine group, a substituted or unsubstituted triazine group, a substituted or unsubstituted quinoline group, a substituted or unsubstituted quinazoline group, a substituted or unsubstituted phenoxazine group, a substituted or unsubstituted phenothiazine group, or a substituted or unsubstituted dihydroacridine group. For example, when X₂ is N(R₁₇) and R₁₇ is a substituted or unsubstituted phenyl group, R₁₆ may be bonded to R₁₇ to form a fused ring containing a 5-membered or 6-membered heterocycle. As another example, two adjacent groups among R₁ to R₁₆ may be bonded to each other to form a ring.

In Formula 1, R₁₇ may be a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₁₇ may be a substituted or unsubstituted phenyl group, or a substituted or unsubstituted biphenyl group.

In Formula 1, Ar₁ and Ar₂ may each independently be a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, Ar₁ and Ar₂ may each independently be a substituted or unsubstituted biphenyl group, a substituted or unsubstituted terphenyl group, a substituted or unsubstituted quaterphenyl group, a substituted or unsubstituted dibenzofuran group, a substituted or unsubstituted dibenzothiophene group, a substituted or unsubstituted fluorene group, or a substituted or unsubstituted carbazole group.

In Formula 1, at least one of Ar₁ and Ar₂ may each independently be a group represented by Formula 2. In an embodiment, the substituent represented by Formula 2 may correspond to the aforementioned first substituent.

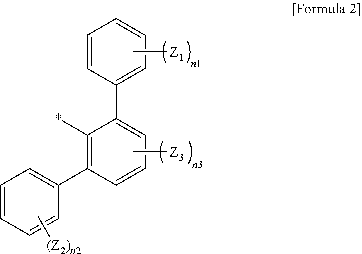

In Formula 2, Z₁ to Z₃ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, Z₁ to Z₃ may each independently be a hydrogen atom, a deuterium atom, a substituted or unsubstituted t-butyl group, or a substituted or unsubstituted phenyl group.

In Formula 2, n1 and n2 may each independently be an integer from 0 to 5. If n1 and n2 are each 0, the fused polycyclic compound may not be substituted with each of Z₁ and Z₂. A case where n1 and n2 are each 5 and five Z₁ groups and five Z₂ groups are all hydrogen atoms may be the same as a case where n1 and n2 are each 0. If n1 and n2 are each 2 or greater, multiple Z₁ groups and multiple Z₂ groups may all be the same or at least one thereof may be different from the remainder.

In Formula 2, n3 may be an integer from 0 to 3. If n3 is 0, the fused polycyclic compound may not be substituted with Z₃. A case where n3 is 3 and three Z₃ groups are all hydrogen atoms may be the same as a case where n3 is 0. If n3 is 2 or greater, multiple Z₃ groups may all be the same, or at least one thereof may be different from the remainder.

In Formula 2,

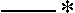 [SMILES: *C]

is a position linked to Formula 1.

The fused polycyclic compound represented by Formula 1 may have a structure in which two hydrocarbon rings are fused to the fused ring core at specific positions via the boron atom and two heteroatoms, thereby achieving high efficiency and long service life.

The fused polycyclic compound may include a fused ring core in which five rings are fused together with a first boron atom, a first nitrogen atom, and a second nitrogen atom in the center, and may have a structure in which two aromatic hydrocarbon rings are linked to the fused ring core. For example, the fused polycyclic compound may include an additional fused ring formed by linking the two aromatic hydrocarbon rings to the fused ring core via the second boron atom, the first heteroatom, and the second heteroatom. The second boron atom, the first heteroatom, and the second heteroatom which link the two aromatic hydrocarbon rings with the fused ring core may be linked to a specific position of the fused ring core, and thus the luminous efficiency and service life characteristics may be improved.

The fused polycyclic compound according to an embodiment has a structure in which two hydrocarbon rings are fused to the fused ring core at specific positions via the boron atom and two heteroatoms, thereby achieving high efficiency and long service life. Since the fused polycyclic compound according to an embodiment has a structure in which a conjugated structure is expanded through an aromatic hydrocarbon ring, multiple resonance effects may be improved, and the luminous efficiency may be further improved. Accordingly, the luminous efficiency and element service life of the light emitting element including the fused polycyclic compound as an emitter may be greatly improved.

The fused polycyclic compound according to an embodiment may effectively maintain a trigonal planar structure of the boron atom through steric hindrance effects of the first substituent. The first boron atom may have electron deficiency characteristics by a vacant p-orbital, thereby forming a bond with other nucleophiles, and thus may be changed into a tetrahedral structure, which may cause deterioration of the device. In an embodiment, the fused polycyclic compound has the first substituent introduced at the fused ring core, thereby effectively protecting the vacant p-orbital of the boron atom, and thus may prevent deterioration due to structural change.

The fused polycyclic compound according to an embodiment may contribute to an increased luminous efficiency because intermolecular interactions may be suppressed through the steric hindrance effects of the first substituent, thereby controlling the formation of aggregates, excimers, or exciplexes. Since the fused polycyclic compound represented by Formula 1 according to an embodiment has a bulky structure, intermolecular distance may be increased to reduce Dexter energy transfer, thereby limiting concentration of triplet excitons in the fused polycyclic compound. A high concentration of triplet excitons remains in an excited state for a long period of time, and thus may induce compound decomposition, leading to the generation of hot excitons having a high energy through triplet-triplet annihilation (TTA), thereby resulting in the destruction of the surrounding compound structure. Since TTA is a bimolecular reaction, which exhausts triplet excitons used for light emission at a high speed, a non-radiative transition may cause a decrease in luminous efficiency. The fused polycyclic compound according to an embodiment has an increased intermolecular distance due to the first substituent to thereby suppress Dexter energy transfer, and thus may suppress the deterioration of service life due to the increase of triplet concentration. Therefore, when the fused polycyclic compound according to an embodiment is applied to the emission layer EML of the light emitting element ED, the luminous efficiency may be increased, and the element service life may also be improved.

In an embodiment, at least one of A₁ and Ar₂ may each independently be a group represented by Formula 2, and the remainder of A₁ and Ar₂ may be a group represented by any one of Formula A-1 to Formula A-3. For example, in Formula 1, Ar₁ may be a group represented by Formula 2, and Ar₂ may be a group represented by any one of Formula A-1 to Formula A-3. As another example, in Formula 1, Ar₂ may be a group represented by Formula 2, and Ar₁ may be a group represented by any one of Formula A-1 to Formula A-3:

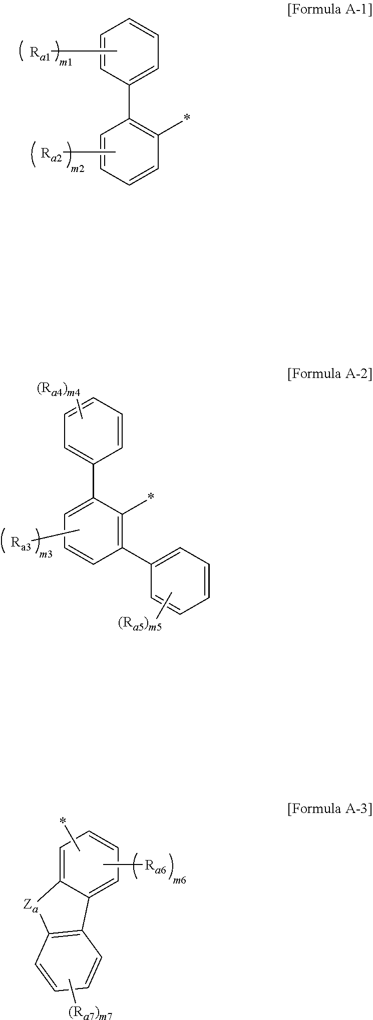

In Formula A-3, Zₐ may be C(Rₐ₈)(Rₐ₉), N(Rₐ₁₀), O, S, or Se. For example, Zₐ may be C(Rₐ₈)(Rₐ₉), N(Rₐ₁₀), O, or S.

In Formula A-1 to Formula A-3, Rₐ₁ to Rₐ₁₀ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms. For example, Rₐ₁ to Rₐ₁₀ may be a hydrogen atom, a deuterium atom, a substituted or unsubstituted t-butyl group, a substituted or unsubstituted phenyl group, a substituted or unsubstituted biphenyl group, a substituted or unsubstituted a dibenzofuran group, or a substituted or unsubstituted dibenzothiophene group, or bonded to an adjacent group to form a ring. For example, Rₐ₈ and Rₐ₉ may be bonded to each other to form a ring. When Rₐ₈ and Rₐ₉ are bonded to each other to form a ring, the substituent represented by Formula A-3 may have a spiro structure.

In Formula A-1 to Formula A-3, m1, m4, and m5 may each independently be an integer from 0 to 5; m2 and m7 may each independently be an integer from 0 to 4; and m3 and m6 may each independently be an integer from 0 to 3. If m1 to m7 are each 0, the fused polycyclic compound may not be substituted with Rₐ₁ to Rₐ₇, respectively. A case where m1, m4, and m5 is 5 and five groups of each of Rₐ₁, Rₐ₄, and Rₐ₈ are all hydrogen atoms may be the same as a case where m1, m4, and m5 are each 0. A case where m2 and m7 are each 4 and four groups of each of Rₐ₂ and Rₐ₇ are all hydrogen atoms may be the same as a case where m2 and m7 are each 0. A case where m3 and m6 are each 3 and three groups of each of Rₐ₃ and Rₐ₆ are all hydrogen atoms may be the same as a case where m3 and m6 are each 0. When m1 to m7 are each 2 or greater, multiple groups of each of Rₐ₁ and Rₐ₇ may all be the same or at least one thereof may be different from the remainder.

In Formula A-1 to Formula A-3,

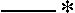 [SMILES: *C]

is a position linked to Formula 1.

In an embodiment, the fused polycyclic compound represented by Formula 1 may be represented by Formula 3:

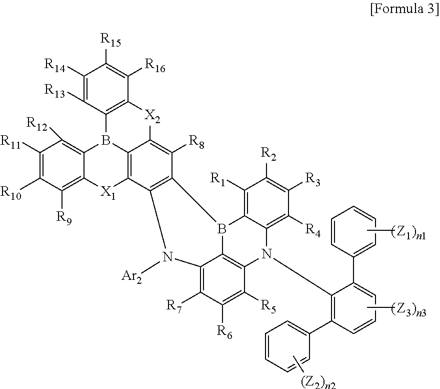

Formula 3 represents a case where Ar₁ in Formula 1 is further defined. Formula 3 represents a case where Ar₁ is represented by Formula 2.

In Formula 3, X₁, X₂, R₁ to R₁₆, Ar₂, Z₁ to Z₃, and n1 to n3 may be the same as defined in Formula 1 and Formula 2.

In an embodiment, the fused polycyclic compound represented by Formula 1 may be represented by any one of Formula 3-a to Formula 3-c:

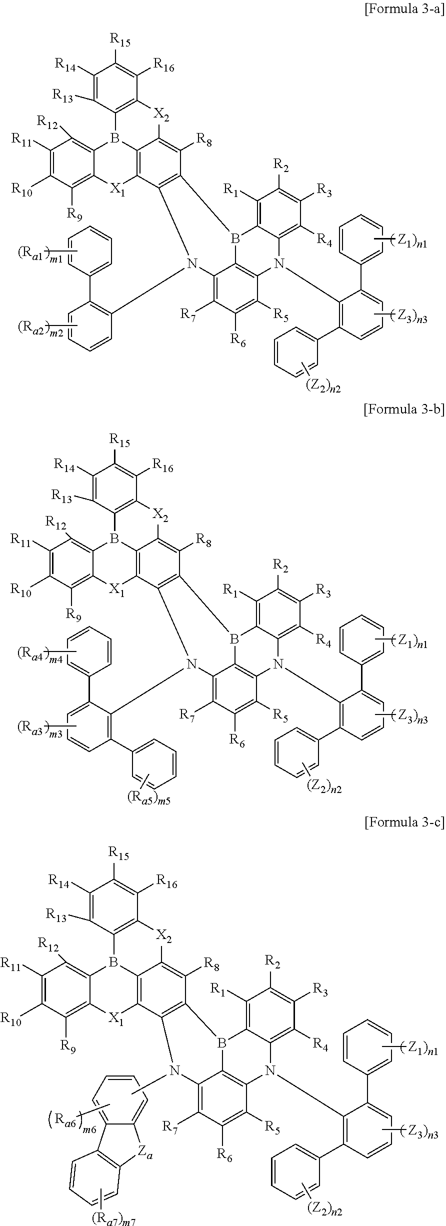

Formula 3-a to Formula 3-c each represent a case where A₁ and Ar₂ in Formula 1 are further defined. Formula 3-a represents a case where Ar₁ is represented by Formula 2, and Ar₂ is represented by Formula A-1. Formula 3-b represents a case where Ar₁ is represented by Formula 2, and Ar₂ is represented by Formula A-2. Formula 3-c represents a case where Ar₁ is represented by Formula 2, and Ar₂ is represented by Formula A-3.

In Formula 3-a to Formula 3-c, Zₐ, Rₐ₁ to Rₐ₇, and m1 to m7 may be the same as defined in Formula A-1 to Formula A-3.

In Formula 3-a to Formula 3-c, X₁, X₂, R₁ to R₁₆, Z₁ to Z₃, and n1 to n3 may be the same as defined Formula 1 and Formula 2.

In an embodiment, at least one of R₅ to R₇ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₆ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, at least one of R₅ to R₇ may each independently be a group selected from Substituent Group 1. For example, R₆ may be a group selected from Substituent Group 1:

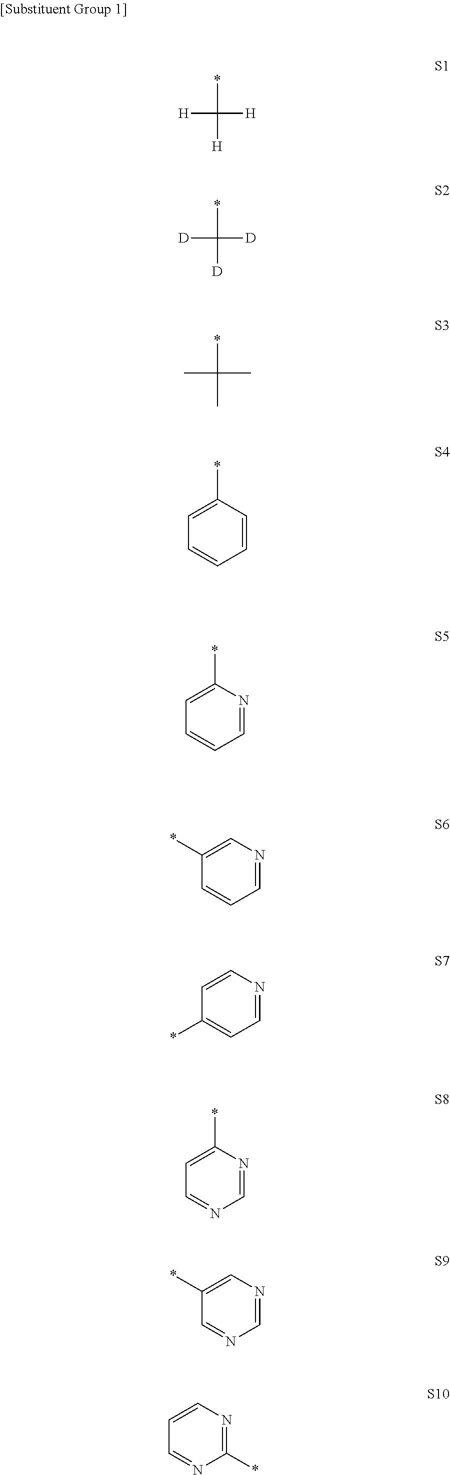

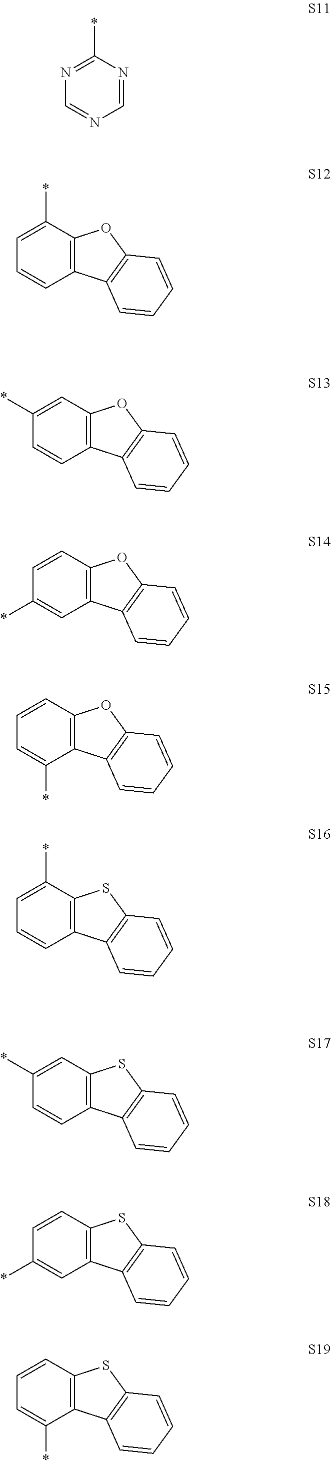

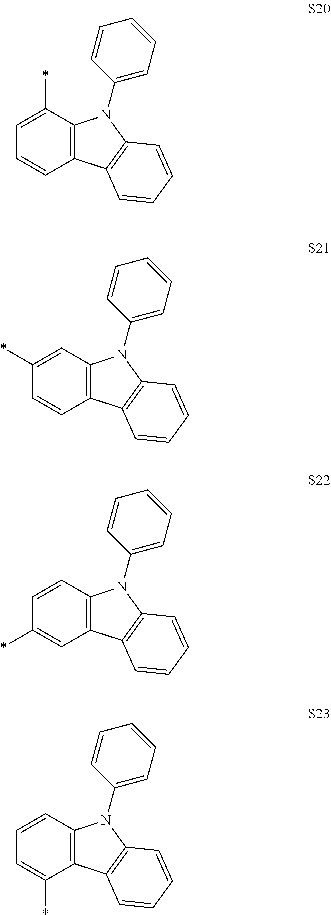 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

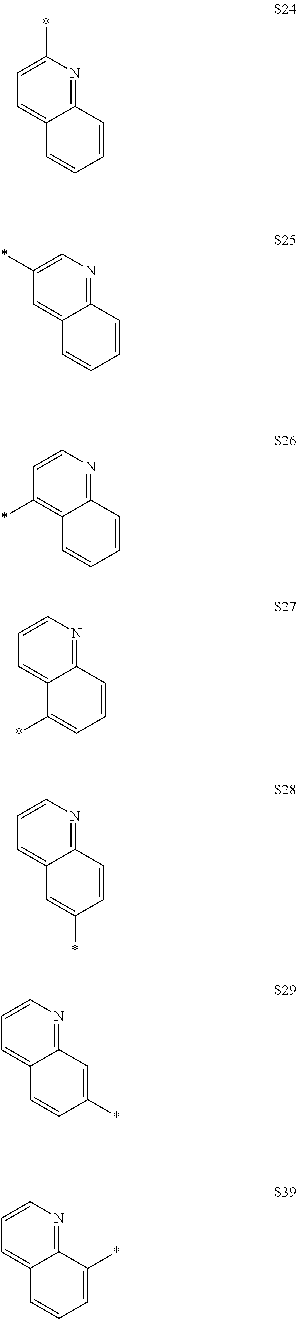

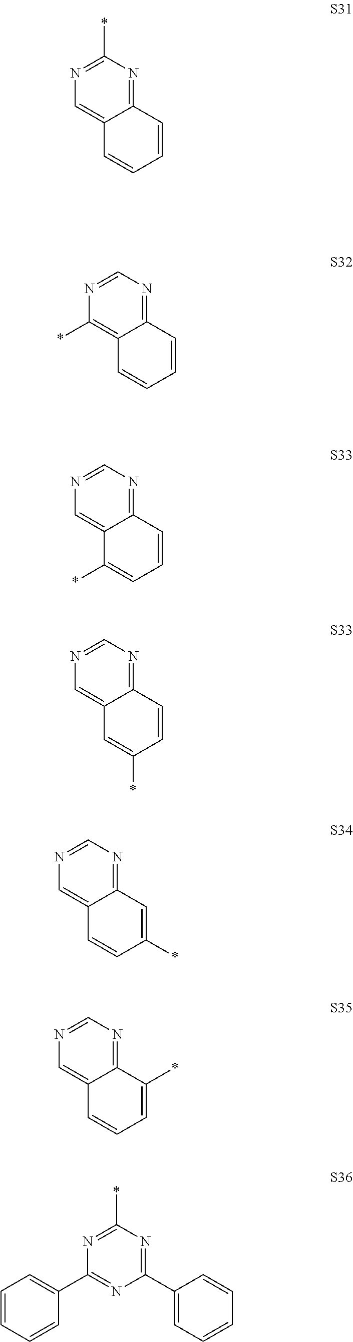

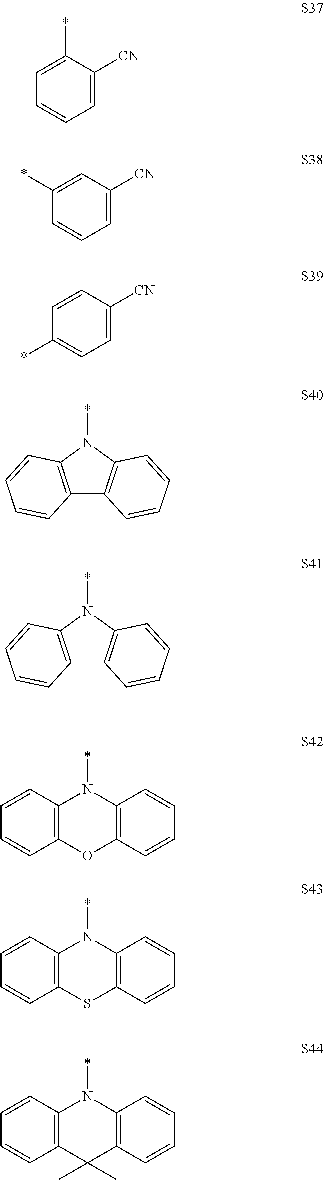

In an embodiment, the fused polycyclic compound represented by Formula 1 may be represented by Formula 4-1 or Formula 4-2:

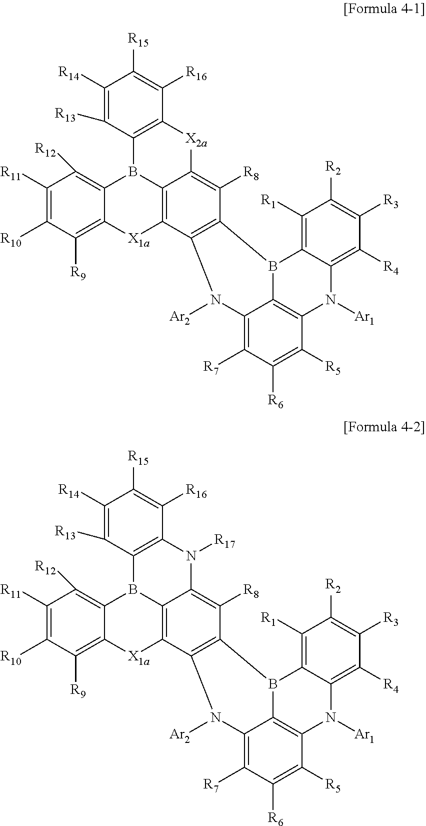

Formula 4-1 and Formula 4-2 each represent a case where X₁ and X₂ in Formula 1 are further defined. Formula 4-1 represents a case where X₁ and X₂ in Formula 1 are each independently S, O, Se, or Te. Formula 4-2 represents a case where X₁ in Formula 1 is S, O, Se, or Te, and X₂ is N(R₁₇). From the viewpoint of efficient synthesis and chemical stability, the first heteroatom may not include a nitrogen atom. Since the first heteroatom linked to an ortho-position carbon with respect to the second nitrogen atom does not include a nitrogen atom, chemical stability may be improved and the fused polycyclic compound may be more readily synthesized.

In Formula 4-1 and Formula 4-2, X₁ₐ and X₂ₐ may each independently be S, O, Se, or Te.

In Formula 4-1 and Formula 4-2, R₁ to R₁₇, Ar₁, and Ar₂ may be the same as defined in Formula 1.

In an embodiment, the fused polycyclic compound represented by Formula 1 may be represented by Formula 5-1 or Formula 5-2:

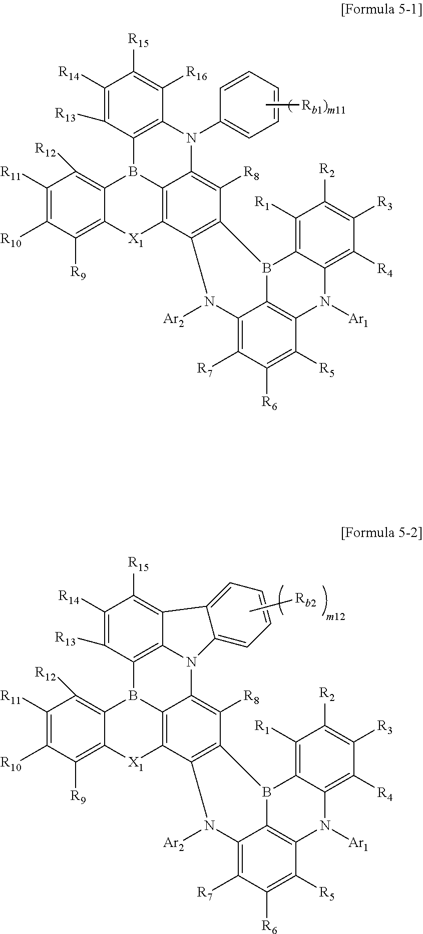

Formula 5-1 and Formula 5-2 each represent a case where X₂ in Formula 1 is further defined. Formula 5-1 represents a case where R₁₇ is a substituted or unsubstituted phenyl group. Formula 5-2 represents a case where R₁₇ is a substituted or unsubstituted phenyl group, and the phenyl group is bonded to R₁₆ as an adjacent group to form a fused ring containing a five-membered heterocycle.

In Formula 5-1 and Formula 5-2, R_{b1} and R_{b2} may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms. For example, R_{b1} and R_{b2} may each independently be a hydrogen atom, a deuterium atom, a substituted or unsubstituted phenyl group, or a substituted or unsubstituted carbazole group.

In Formula 5-1, m11 may be an integer from 0 to 5. If m11 is 0, the fused polycyclic compound may not be substituted with R_{b1}. A case where m11 is 5 and five R_{b1} groups are all hydrogen atoms may be the same as a case where m11 is 0. If m11 is 2 or more, multiple R_{b1} groups may all be the same, or at least one thereof may be different from the remainder.

In Formula 5-2, m12 may be an integer from 0 to 4. If m12 is 0, the fused polycyclic compound may not be substituted with R_{b2}. A case where m12 is 4 and four R_{b2} groups are all hydrogen atoms may be the same as a case where m12 is 0. If m12 is 2 or more, multiple R_{b2} groups may all be the same, or at least one thereof may be different from the remainder.

In Formula 5-1 and Formula 5-2, X₁, R₁ to R₁₆, Ar₁, and Ar₂ may be the same as defined in Formula 1.

In an embodiment, the fused polycyclic compound represented by Formula 1 may be represented by Formula 6-1 or Formula 6-2:

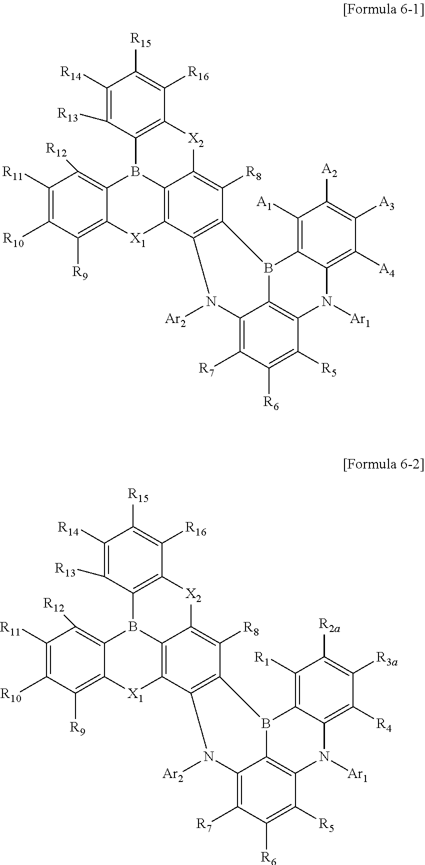

Formula 6-1 and Formula 6-2 each represent a case where at least two of R₁ to R₄ in Formula 1 are further defined.

In Formula 6-1, A₁ to A₄ may each independently be a hydrogen atom or a deuterium atom. For example, A₁ to A₄ may all be hydrogen atoms or deuterium atoms.

In Formula 6-2, R₂ₐ and R₃ₐ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

In Formula 6-2, at least one of R₂ₐ and R₃ₐ may each independently be a group represented by any one of Formula B-1 to Formula B-6, or R₂ₐ and R₃ₐ may be positions at which the substituent represented by Formula C-1 is fused.

In an embodiment, any one of R₂ₐ and R_{2b} may be a group represented by any one of Formula B-1 to Formula B-6. For example, one of R₂ₐ and R₃ₐ may be a group represented by any one of Formula B-1 to Formula B-6, and the remainder of R₂ₐ and R₃ₐ may be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms.

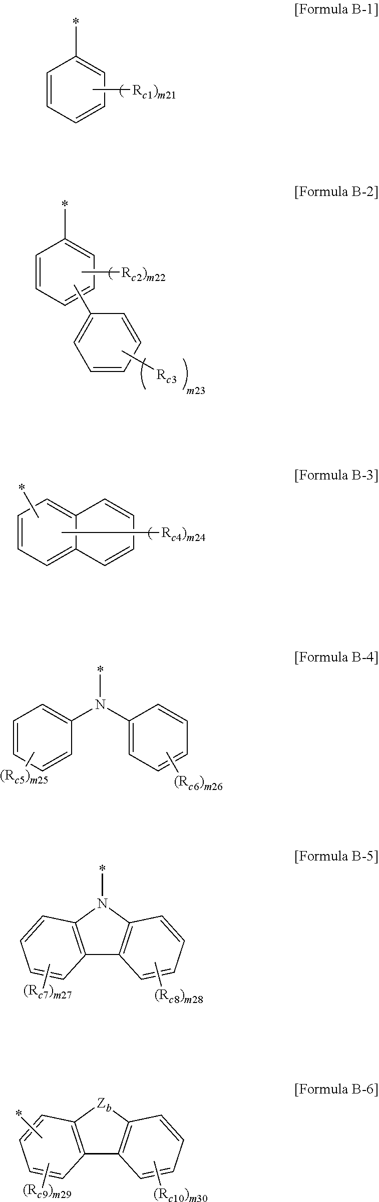

In Formula B-6, Z_{b} may be O, S, Se, or N(R_{c11}). For example, Z_{b} may be O or S.

In Formula B-1 to Formula B-6, R_{c1} to R_{c11} may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R_{c1} to R_{c10} may each independently be a hydrogen atom, a deuterium atom, a substituted or unsubstituted t-butyl group, a substituted or unsubstituted phenyl group, a substituted or unsubstituted biphenyl group, or a substituted or unsubstituted diphenylamine group, and R_{c11} may be a substituted or unsubstituted phenyl group.

In Formula B-1 to Formula B-6, m21, m23, m25, and m26 may each independently be an integer from 0 to 5; m22, m27, m28, and m30 may each independently be an integer from 0 to 4; m24 may be an integer from 0 to 7; and m29 may be an integer from 0 to 3.

If m21 to m30 are each 0, the fused polycyclic compound may not be substituted with R_{c1} to Rₐ₁₀, respectively. A case where m21, m23, m25, and m26 are each 5 and five groups of each of R_{c1}, R_{c3}, Rₐ₅, and R_{c6} are all hydrogen atoms may be the same as a case where m21, m23, m25, and m26 are each 0. A case where m22, m27, m28, and m30 are each 4 and four groups of each of R_{c2}, R_{c7}, Rₐ₈, and R_{c10} are all hydrogen atoms may be the same as a case where m22, m27, m28, and m30 are each 0. A case where m24 is 7 and seven R_{c4} groups are all hydrogen atoms may be the same as a case where m24 is 0. A case where m29 is 3 and three R_{c9} groups are all hydrogen atoms may be the same as a case where m29 is 0. When m21 to m30 are each 2 or greater, multiple groups of each of R_{c1} to R_{c10} may all be the same or at least one thereof may be different from the remainder.

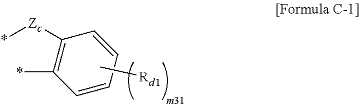

In Formula C-1, Z_{c} may be O, S, or N(R_{d2}).

In Formula C-1, R_{d1} and R_{d2} may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R_{d1} may be a hydrogen atom or a deuterium atom, and R_{d2} may be a substituted or unsubstituted phenyl group.

In Formula C-1, m31 may be an integer from 0 to 4. If m31 is 0, the fused polycyclic compound may not be substituted with R_{d1}. A case where m31 is 4 and four R_{d1} groups are all hydrogen atoms may be the same as a case where m31 is 0. If m31 is 2 or more, multiple R_{d1} groups may all be the same, or at least one thereof may be different from the remainder.

In Formula C-1,

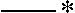 [SMILES: *C]

may be a position fused at R₂ₐ and R₃ₐ in Formula 6-2.

In Formula 6-1 and Formula 6-2, X₁, X₂, R₁, R₄ to R₁₆, Ar₁, and Ar₂ may be the same as defined in Formula 1.

In an embodiment, the fused polycyclic compound represented by Formula 1 may be represented by any one of Formula 6-2a to Formula 6-2d:

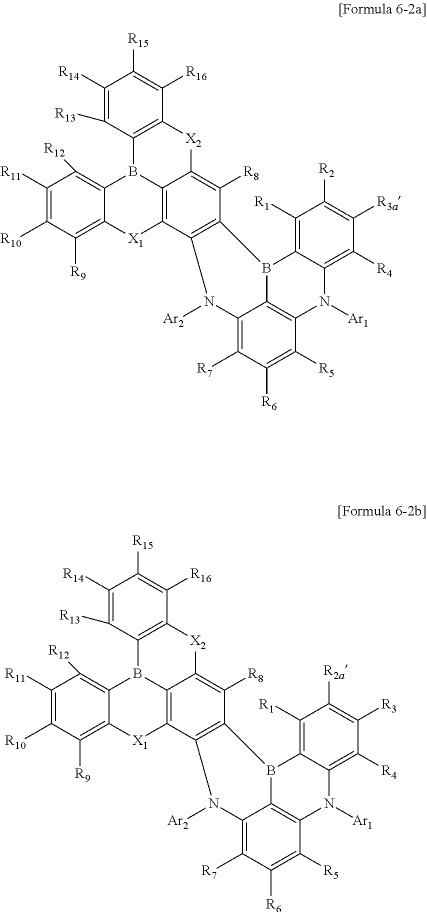

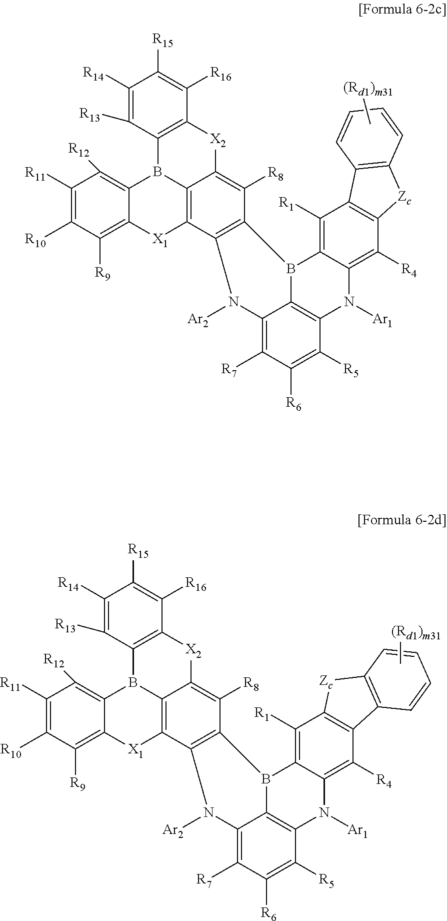

In Formula 6-2a and Formula 6-2b, R₂ₐ′ and R₃ₐ′ may each independently be a substituted or unsubstituted t-butyl group, a substituted or unsubstituted phenyl group, a substituted or unsubstituted biphenyl group, a substituted or unsubstituted naphthyl group, a substituted or unsubstituted carbazole group, a substituted or unsubstituted diphenylamine group, a substituted or unsubstituted dibenzofuran group, or a substituted or unsubstituted dibenzothiophene group. In an embodiment, R₂ₐ′ and R₃ₐ′ may each independently be a group represented by any one of Formula B-1 to Formula B-6.

In Formula 6-2c and Formula 6-2d, Z_{c}, R_{d1}, and m31 may be the same as defined in Formula C-1.

In Formula 6-2a to Formula 6-2d, X₁, X₂, R₁ to R₁₆, Ar₁, and Ar₂ may be the same as defined in Formula 1.

In an embodiment, the fused polycyclic compound represented by Formula 1 may be represented by Formula 7:

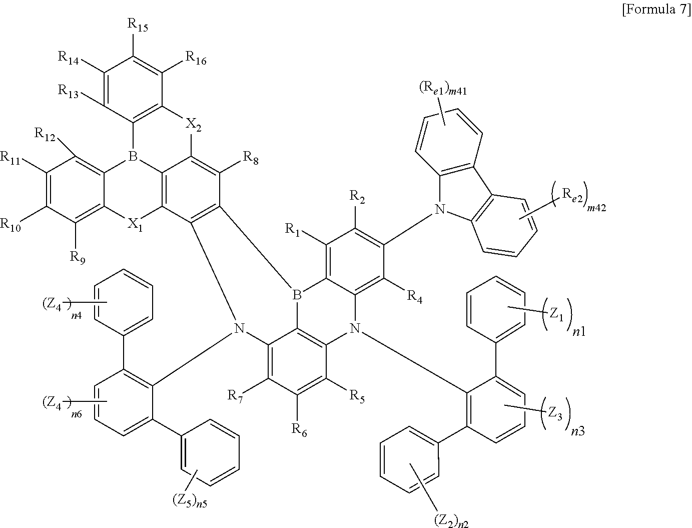

Formula 7 represents a case where Ar₁, Ar₂, and R₃ in Formula 1 are further defined.

In Formula 7, Z₄ to Z₆, Rₑ₁, and Rₑ₂ may each independently be a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, Z₄ to Z₆, Rₑ₁, and Rₑ₂ may each independently be a hydrogen atom, a deuterium atom, a substituted or unsubstituted t-butyl group, or a substituted or unsubstituted phenyl group.

In Formula 7, n4 and n5 may each independently be an integer from 0 to 5. If n4 and n5 are each 0, the fused polycyclic may not be substituted with Z₄ and Z₅, respectively. A case where n4 and n5 are each 5 and five Z₄ groups and five Z₅ groups are all hydrogen atoms may be the same as a case where n4 and n5 are each 0. When n4 and n5 are each 2, multiple Z₄ groups and multiple Z₅ groups may all be the same or at least one thereof may be different from the remainder.

In Formula 7, n6 may be an integer from 0 to 3. If n6 is 0, the fused polycyclic compound may not be substituted with Z₆. A case where n6 is 3 and three Z₆ groups are all hydrogen atoms may be the same as a case where n6 is 0. If n6 is 2 or greater, multiple Z₆ groups may all be the same, or at least one thereof may be different from the remainder.

In Formula 7, m41 and m42 may each independently be an integer from 0 to 4. If m41 and m42 are each 0, the fused polycyclic may not be substituted with Rₑ₁ and Rₑ₂, respectively. A case where m41 and m42 are each 4 and four Rₑ₁ groups and four Rₑ₂ groups are all hydrogen atoms may be the same as a case where m41 and m42 are each 0. When m41 and m42 are each 2 or greater, multiple Rₑ₁ groups and multiple Rₑ₂ groups may all be the same or at least one thereof may be different from the remainder.

In Formula 7, X₁, X₂, R₁, R₂, R₄ to R₁₆, Z₁ to Z₃, and n1 to n3 may be the same as defined in Formula 1 and Formula 2.

In an embodiment, the fused polycyclic compound represented by Formula 1 may include at least one deuterium atom as a substituent. For example, the fused polycyclic compound represented by Formula 1 may have a structure in which at least one hydrogen atom is substituted with a deuterium atom.

In an embodiment, the fused polycyclic compound may be compound selected from Compound Group 1. In an embodiment, in the light emitting element ED, the at least one functional layer (for example, an emission layer EML) may include at least one fused polycyclic compound selected from Compound Group 1.

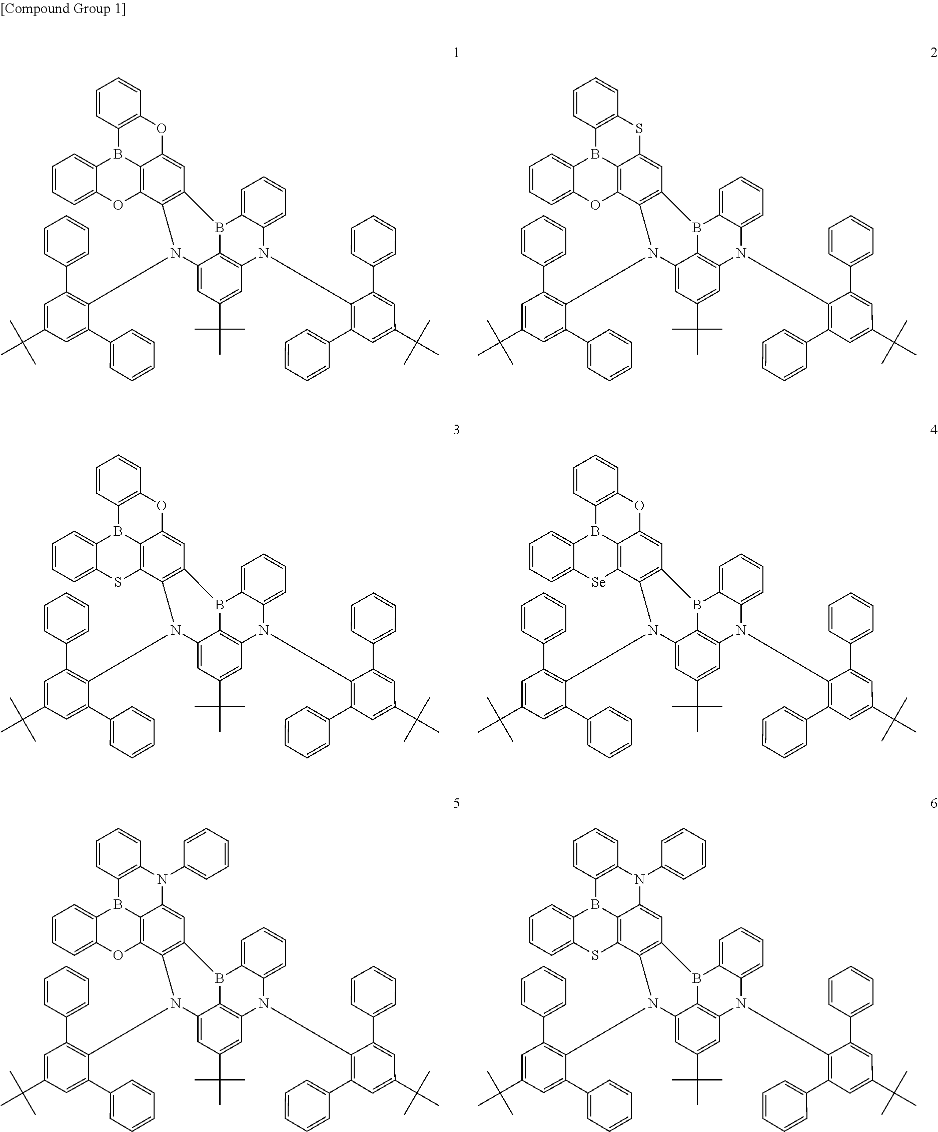

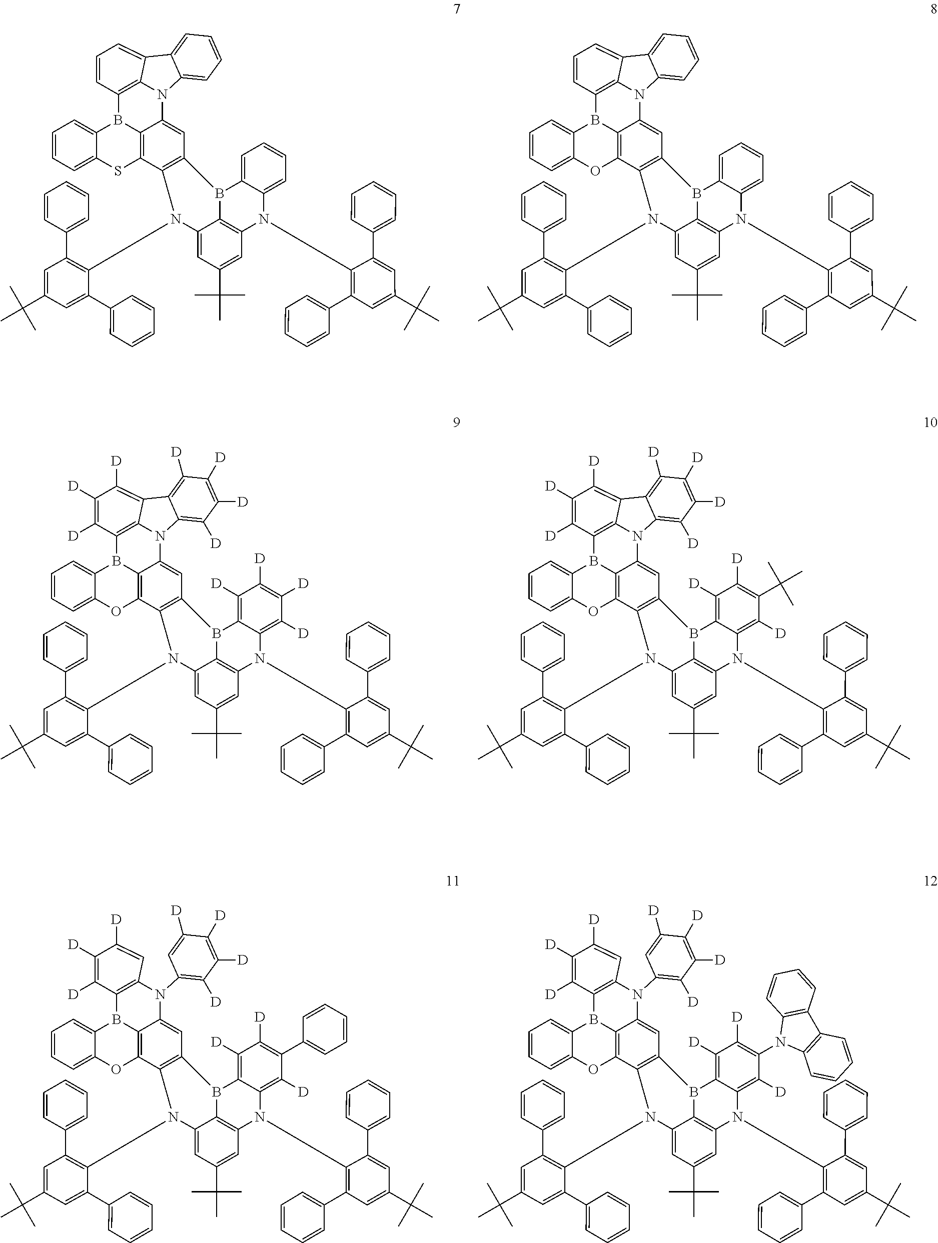

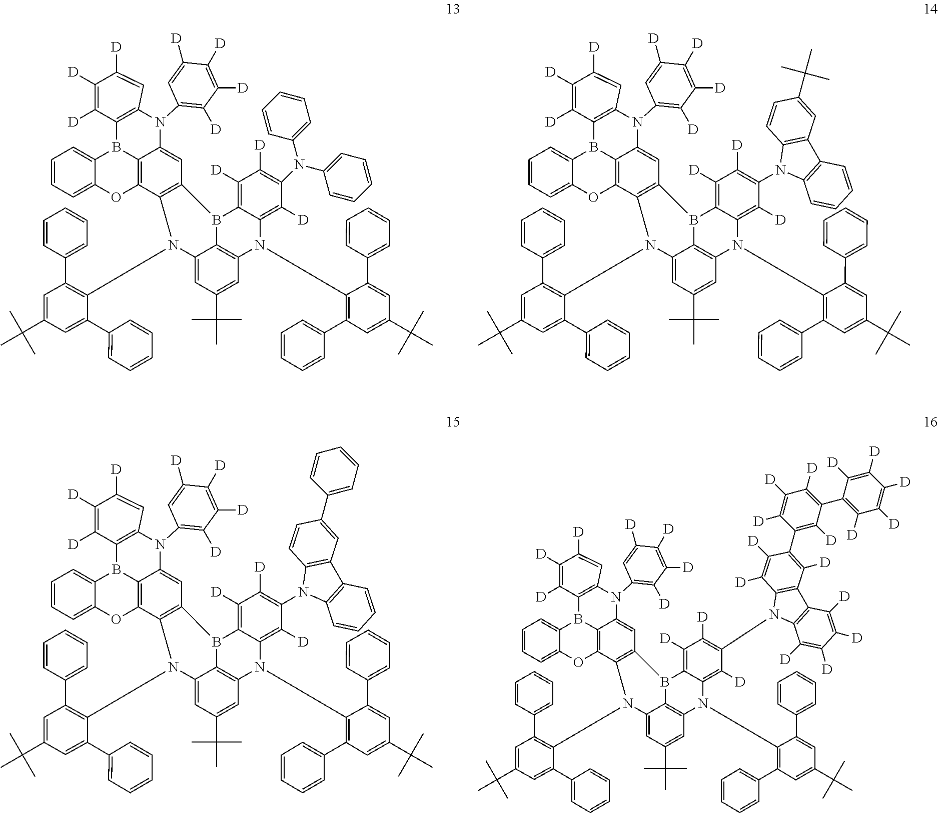

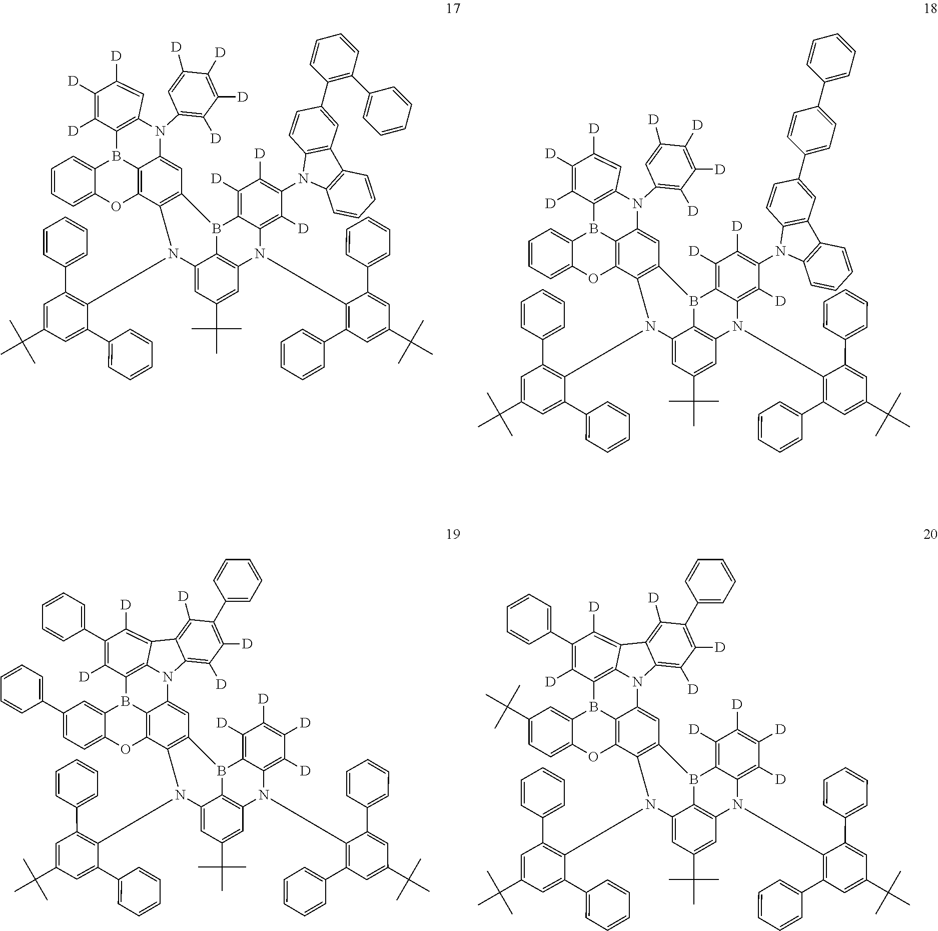

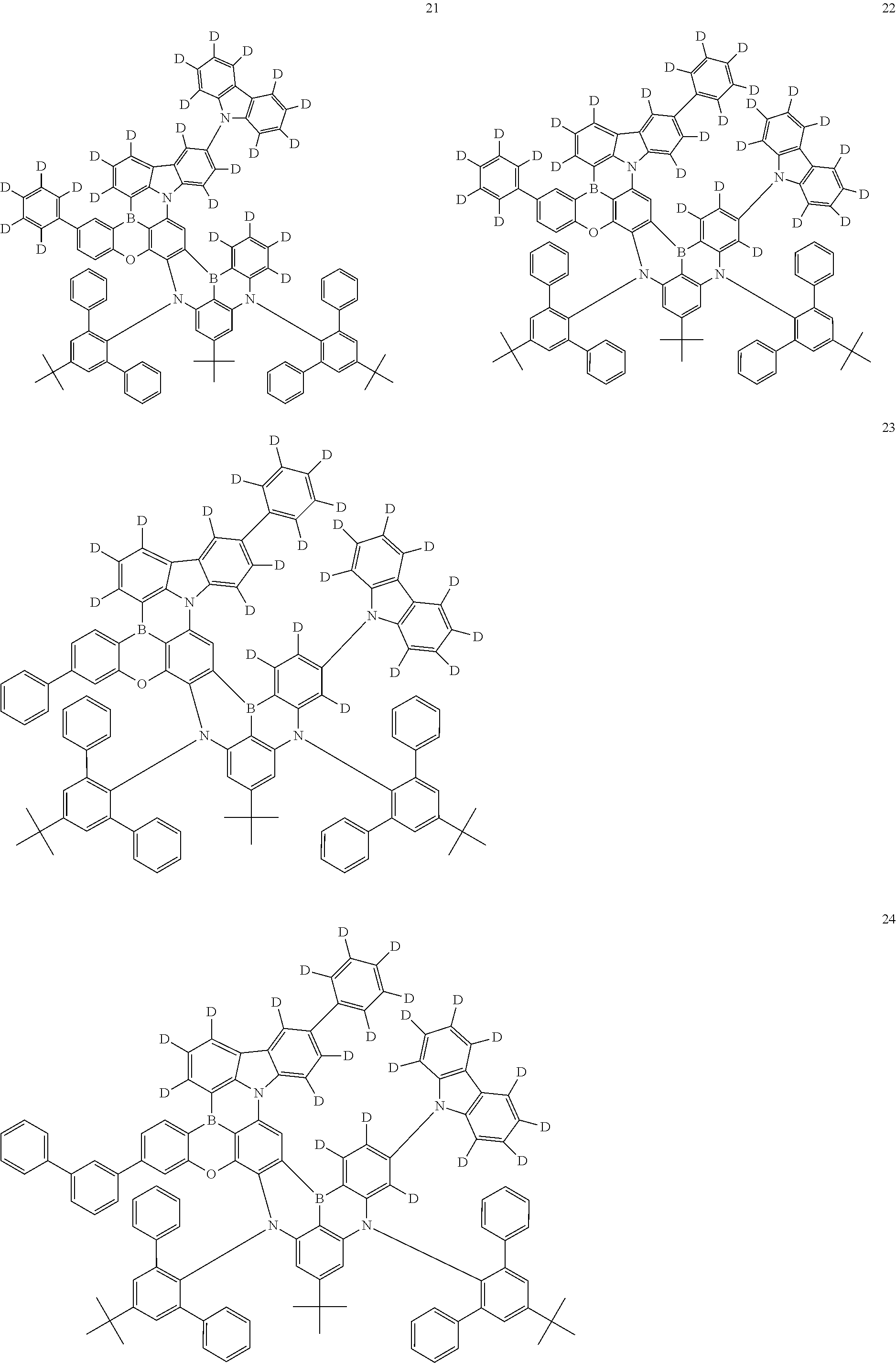

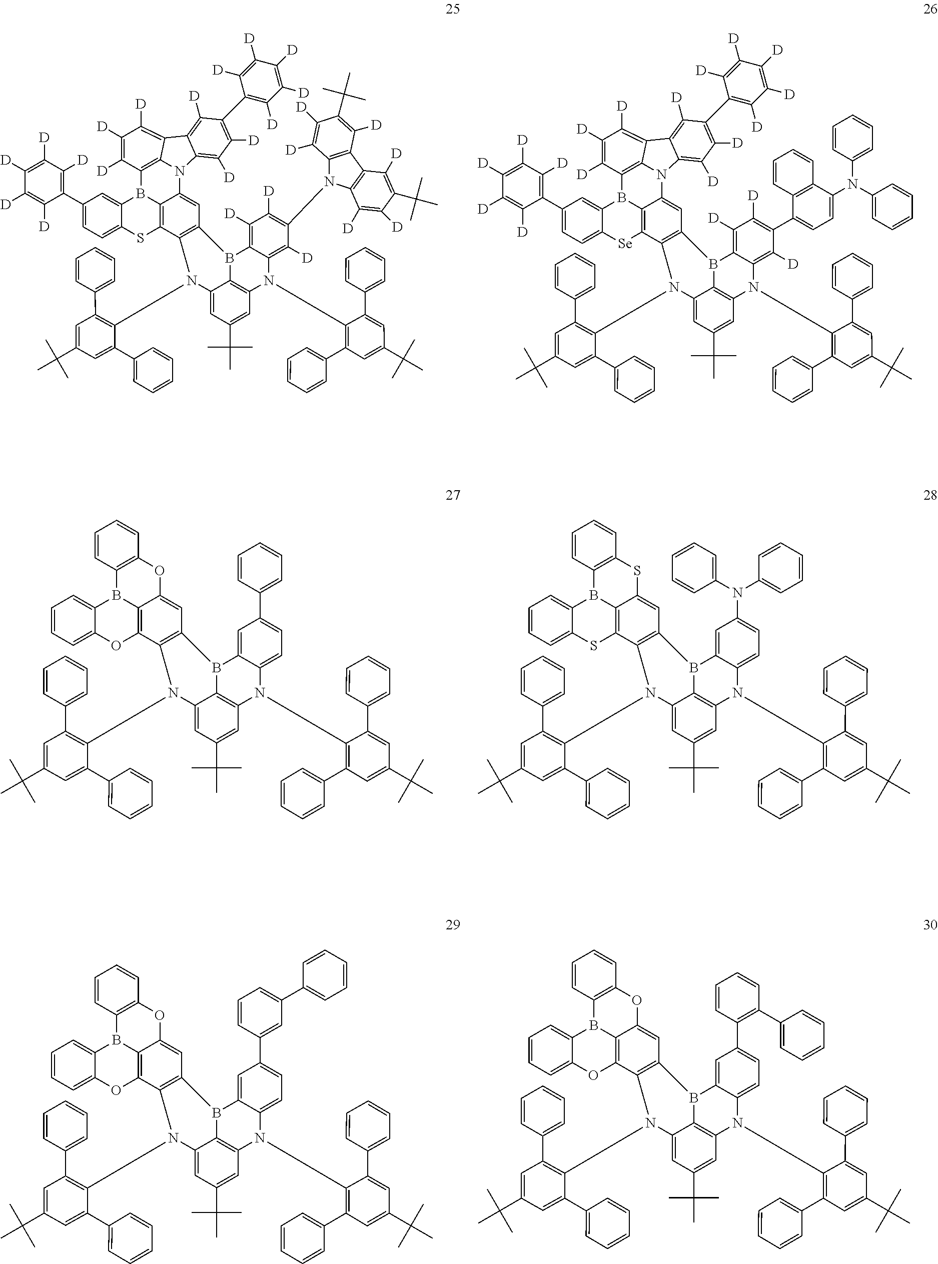

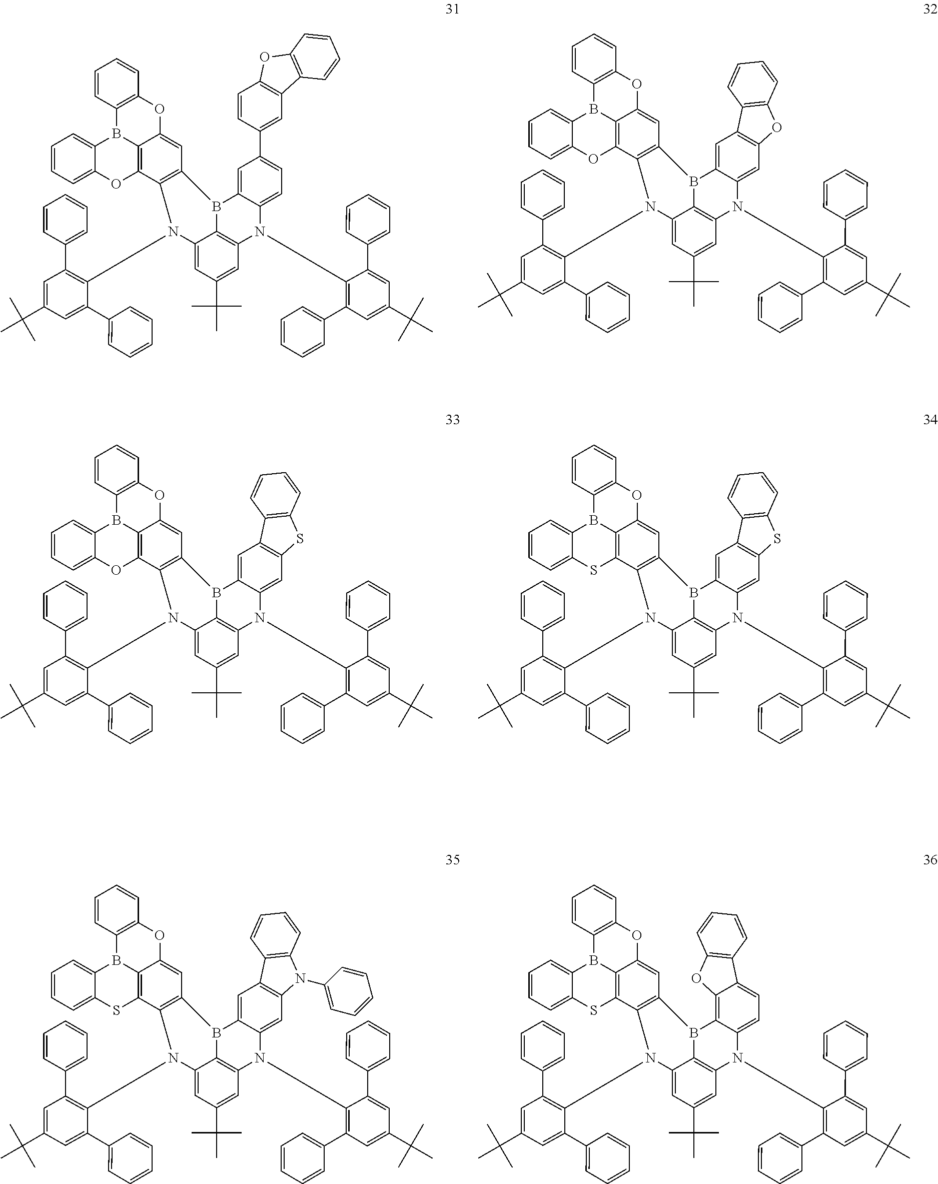

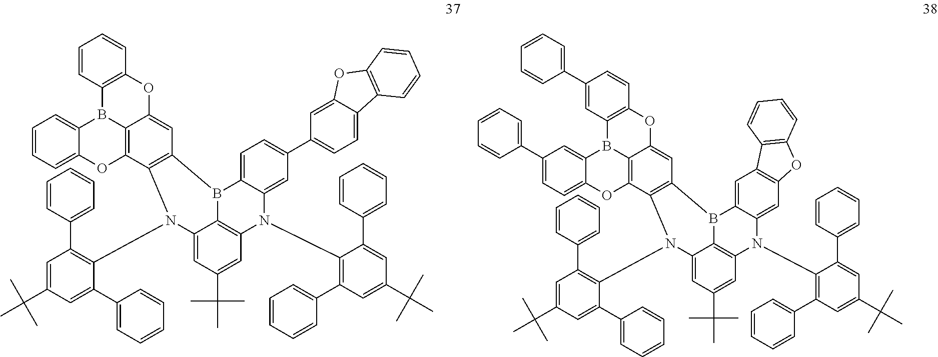 [SMILES: CC(C)(C)c1cc(-c2ccccc2)c(N2c3cc(-c4ccc5c(c4)oc4ccccc45)ccc3B3c4cc5c6c(c4N(c4c(-c7ccccc7)cc(C(C)(C)C)cc4-c4ccccc4)c4cc(C(C)(C)C)cc2c43)Oc2ccccc2B6c2ccccc2O5)c(-c2ccccc2)c1 ; CC(C)(C)c1cc(-c2ccccc2)c(N2c3cc4oc5ccccc5c4cc3B3c4cc5c6c(c4N(c4c(-c7ccccc7)cc(C(C)(C)C)cc4-c4ccccc4)c4cc(C(C)(C)C)cc2c43)Oc2ccc(-c3ccccc3)cc2B6c2cc(-c3ccccc3)ccc2O5)c(-c2ccccc2)c1]

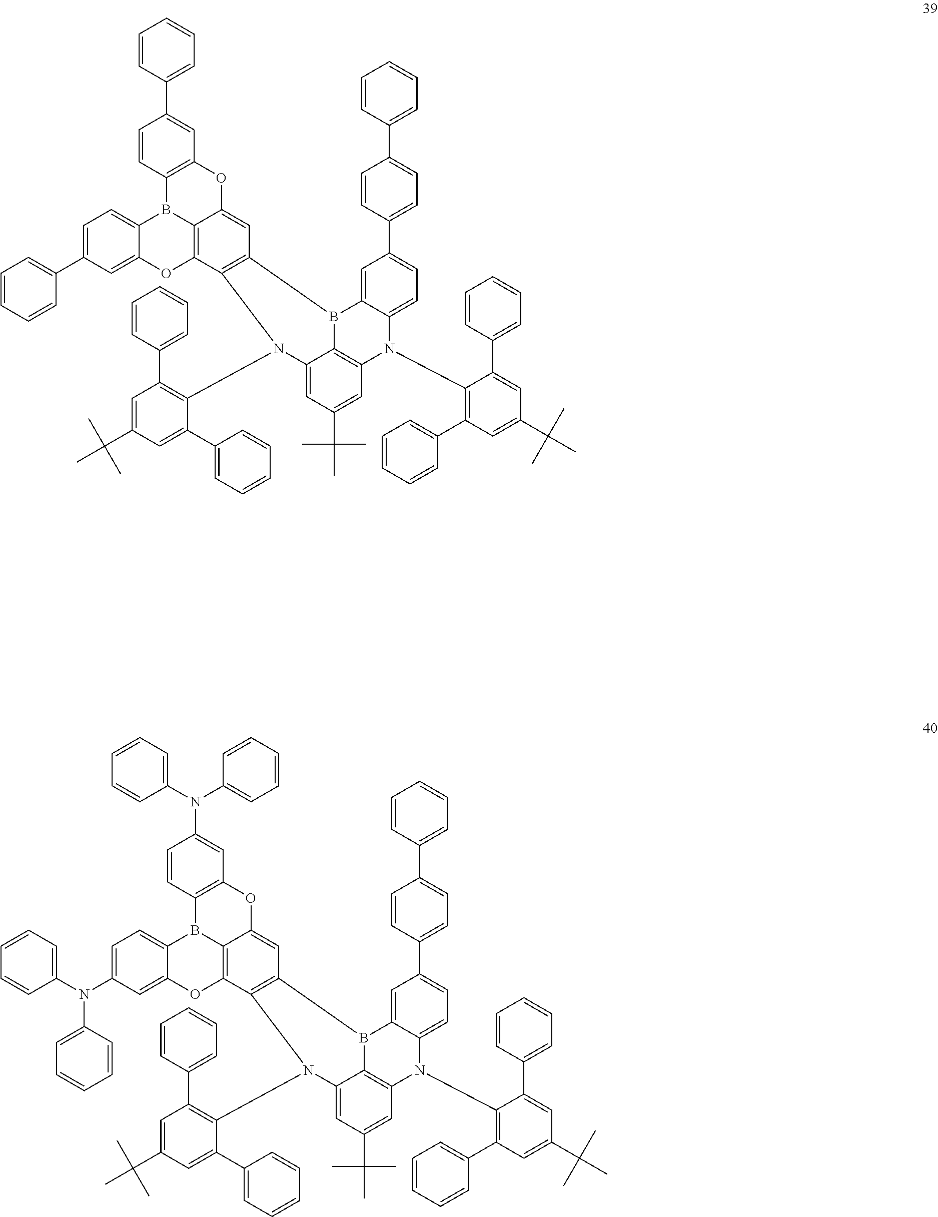 [SMILES: CC(C)(C)c1cc(-c2ccccc2)c(N2c3ccc(-c4ccc(-c5ccccc5)cc4)cc3B3c4cc5c6c(c4N(c4c(-c7ccccc7)cc(C(C)(C)C)cc4-c4ccccc4)c4cc(C(C)(C)C)cc2c43)Oc2cc(-c3ccccc3)ccc2B6c2ccc(-c3ccccc3)cc2O5)c(-c2ccccc2)c1 ; CC(C)(C)c1cc(-c2ccccc2)c(N2c3ccc(-c4ccc(-c5ccccc5)cc4)cc3B3c4cc5c6c(c4N(c4c(-c7ccccc7)cc(C(C)(C)C)cc4-c4ccccc4)c4cc(C(C)(C)C)cc2c43)Oc2cc(N(c3ccccc3)c3ccccc3)ccc2B6c2ccc(N(c3ccccc3)c3ccccc3)cc2O5)c(-c2ccccc2)c1]

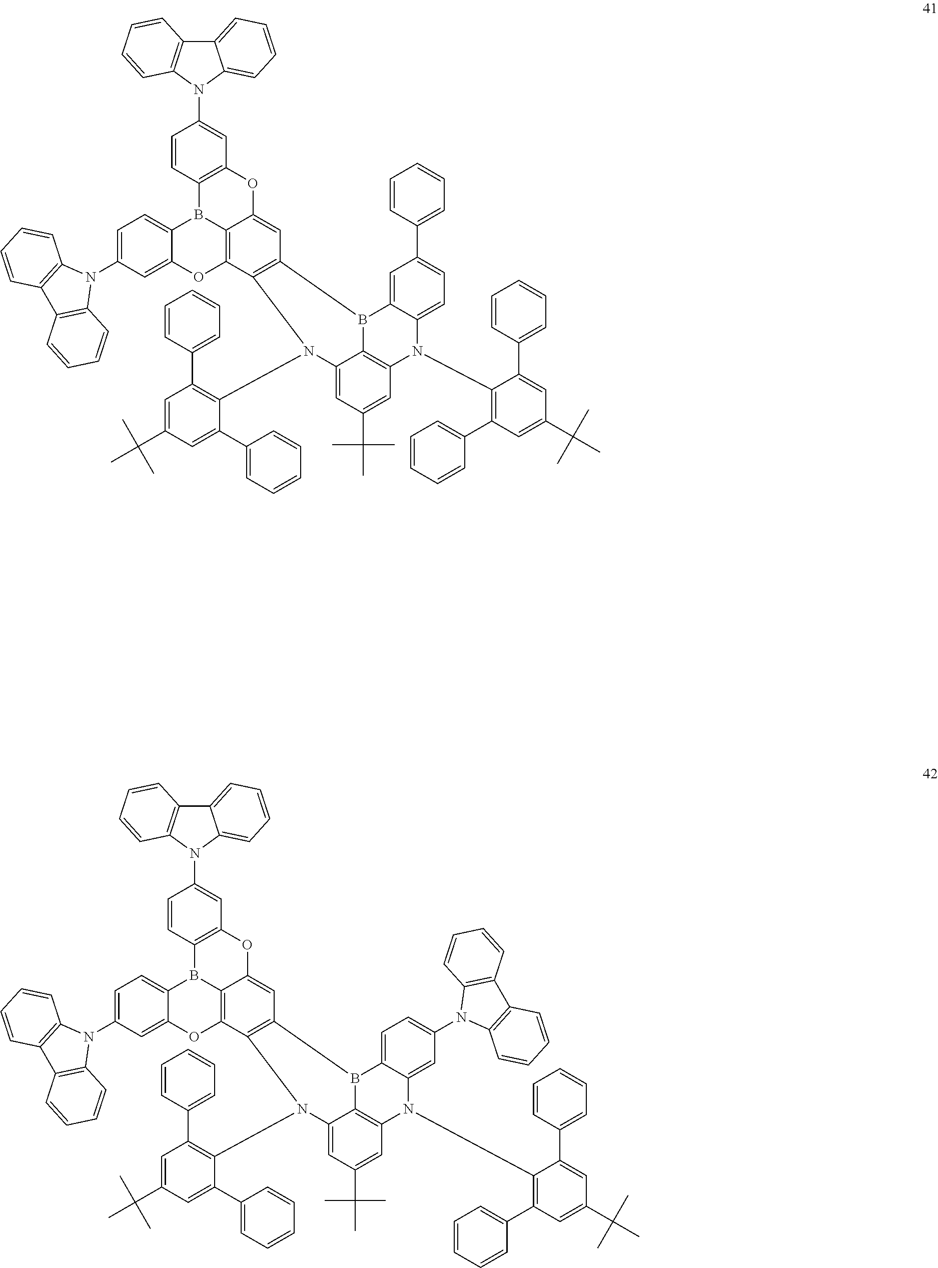 [SMILES: CC(C)(C)c1cc(-c2ccccc2)c(N2c3ccc(-c4ccccc4)cc3B3c4cc5c6c(c4N(c4c(-c7ccccc7)cc(C(C)(C)C)cc4-c4ccccc4)c4cc(C(C)(C)C)cc2c43)Oc2cc(-n3c4ccccc4c4ccccc43)ccc2B6c2ccc(-n3c4ccccc4c4ccccc43)cc2O5)c(-c2ccccc2)c1 ; CC(C)(C)c1cc(-c2ccccc2)c(N2c3cc(-n4c5ccccc5c5ccccc54)ccc3B3c4cc5c6c(c4N(c4c(-c7ccccc7)cc(C(C)(C)C)cc4-c4ccccc4)c4cc(C(C)(C)C)cc2c43)Oc2cc(-n3c4ccccc4c4ccccc43)ccc2B6c2ccc(-n3c4ccccc4c4ccccc43)cc2O5)c(-c2ccccc2)c1]

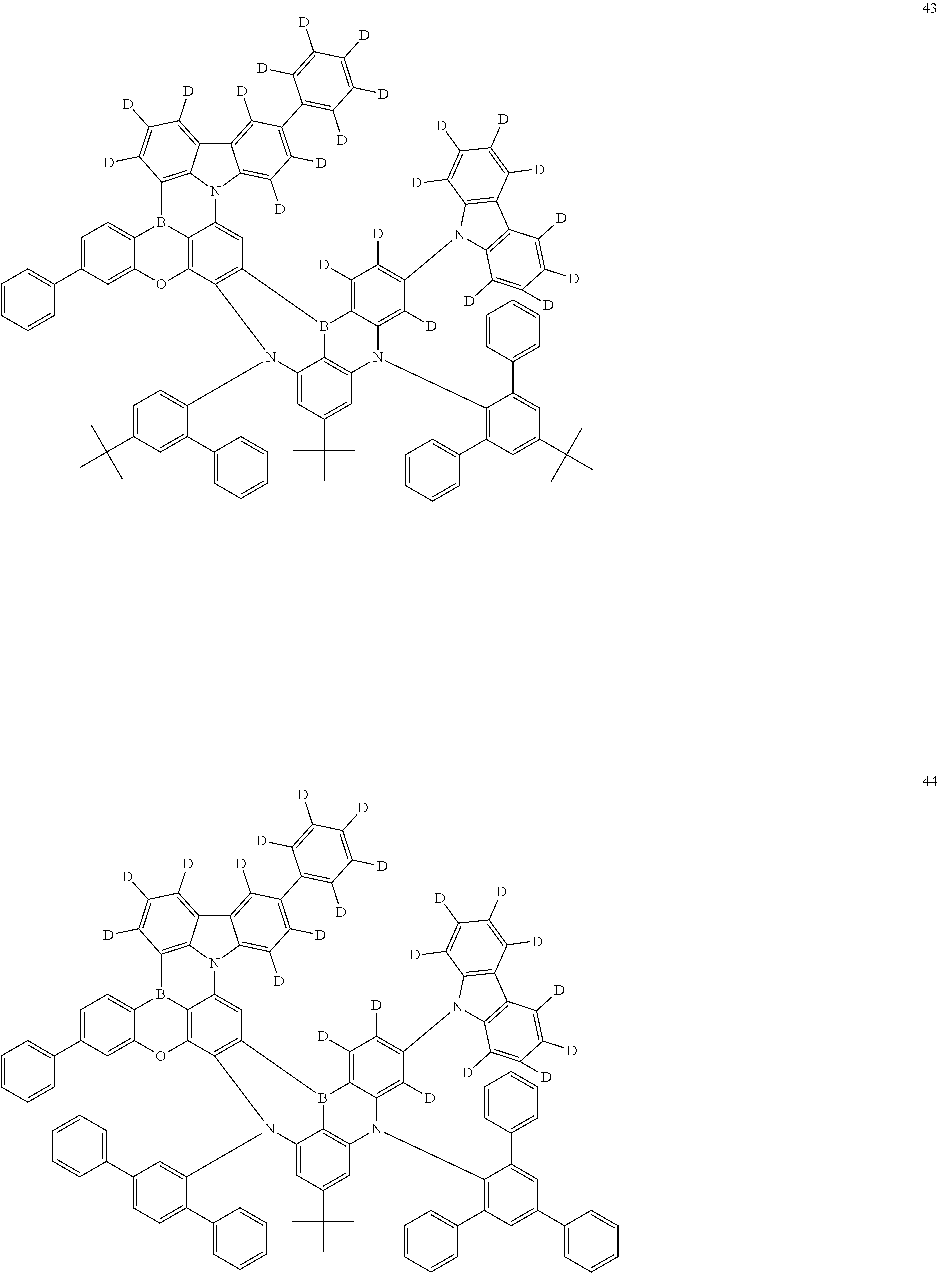

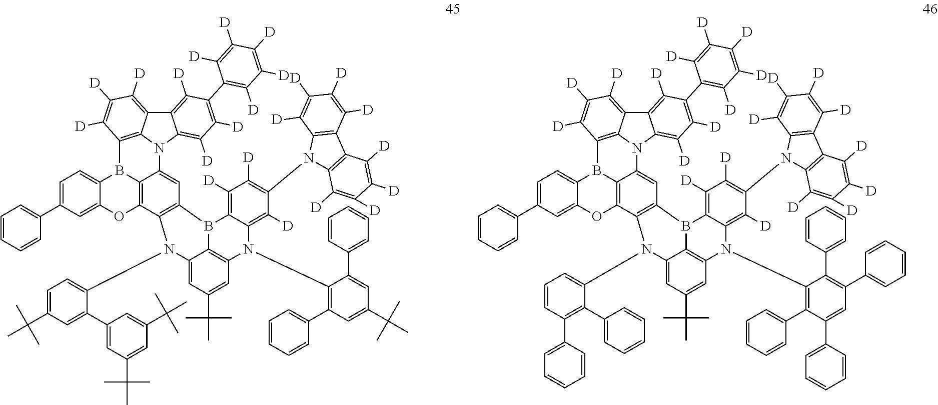

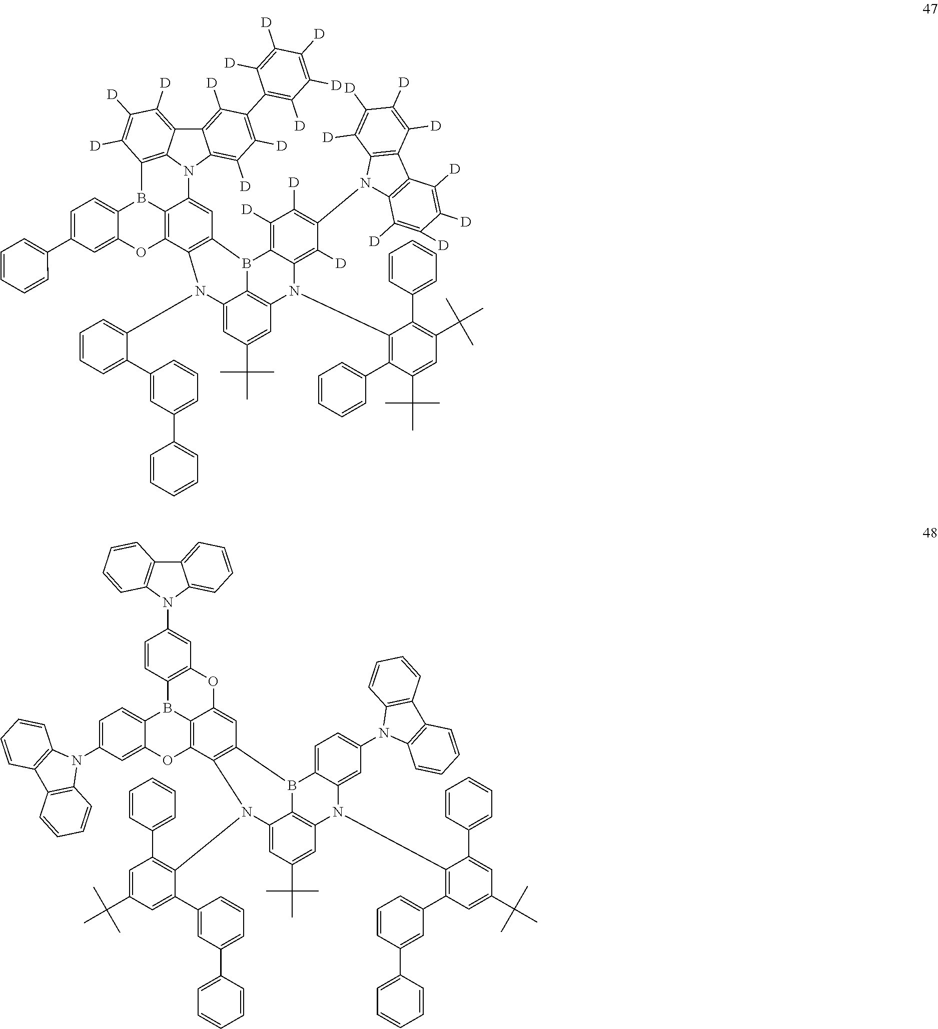

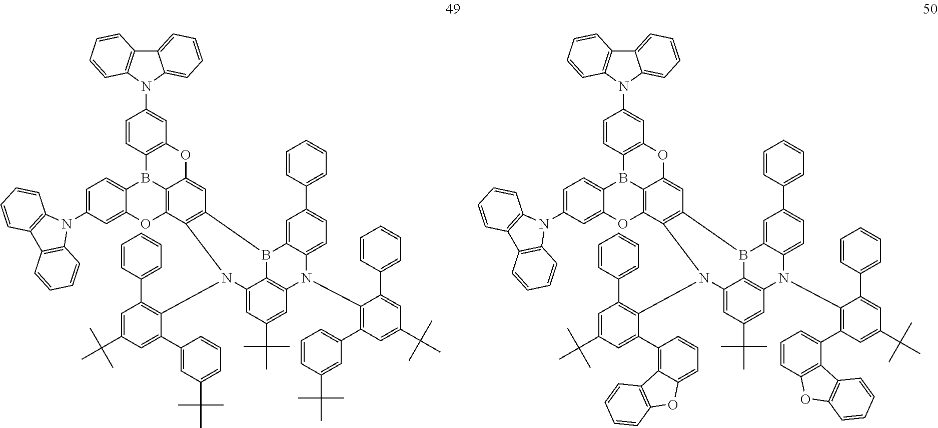 [SMILES: CC(C)(C)c1cccc(-c2cc(C(C)(C)C)cc(-c3ccccc3)c2N2c3ccc(-c4ccccc4)cc3B3c4cc5c6c(c4N(c4c(-c7ccccc7)cc(C(C)(C)C)cc4-c4cccc(C(C)(C)C)c4)c4cc(C(C)(C)C)cc2c43)Oc2cc(-n3c4ccccc4c4ccccc43)ccc2B6c2ccc(-n3c4ccccc4c4ccccc43)cc2O5)c1 ; CC(C)(C)c1cc(-c2ccccc2)c(N2c3ccc(-c4ccccc4)cc3B3c4cc5c6c(c4N(c4c(-c7ccccc7)cc(C(C)(C)C)cc4-c4cccc7oc8ccccc8c47)c4cc(C(C)(C)C)cc2c43)Oc2cc(-n3c4ccccc4c4ccccc43)ccc2B6c2ccc(-n3c4ccccc4c4ccccc43)cc2O5)c(-c2cccc3oc4ccccc4c23)c1]

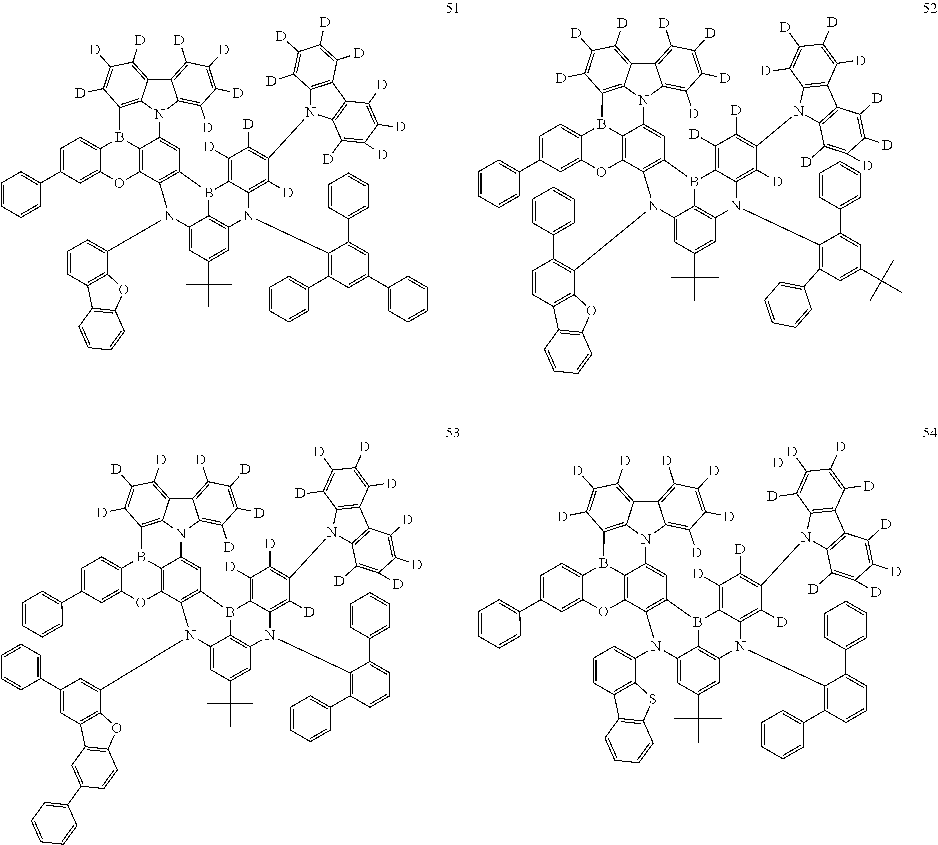

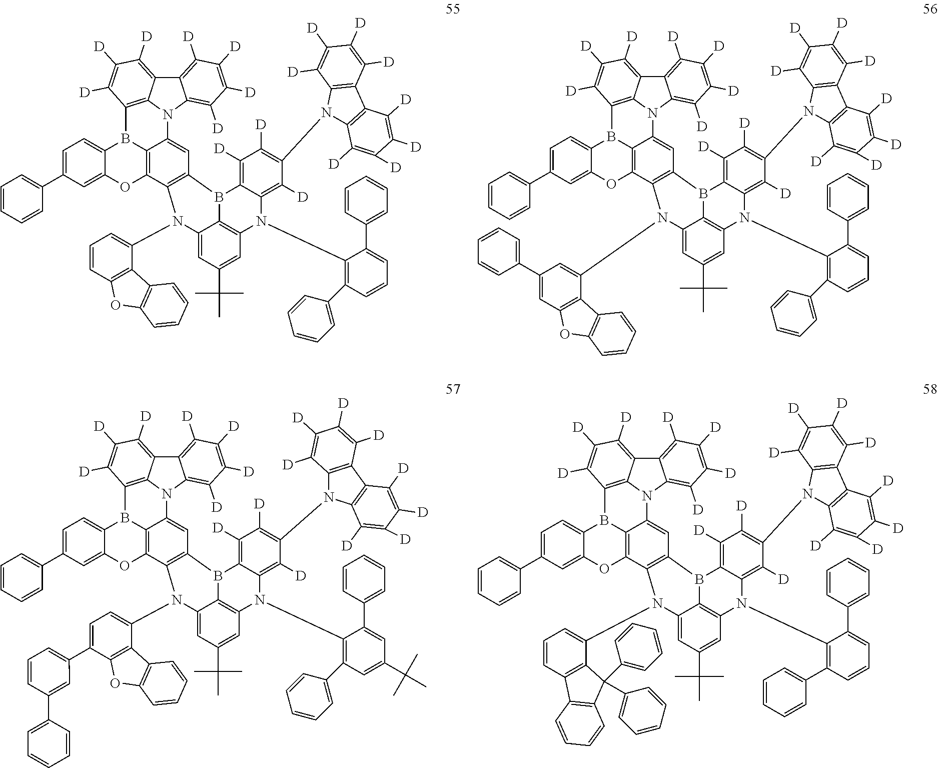

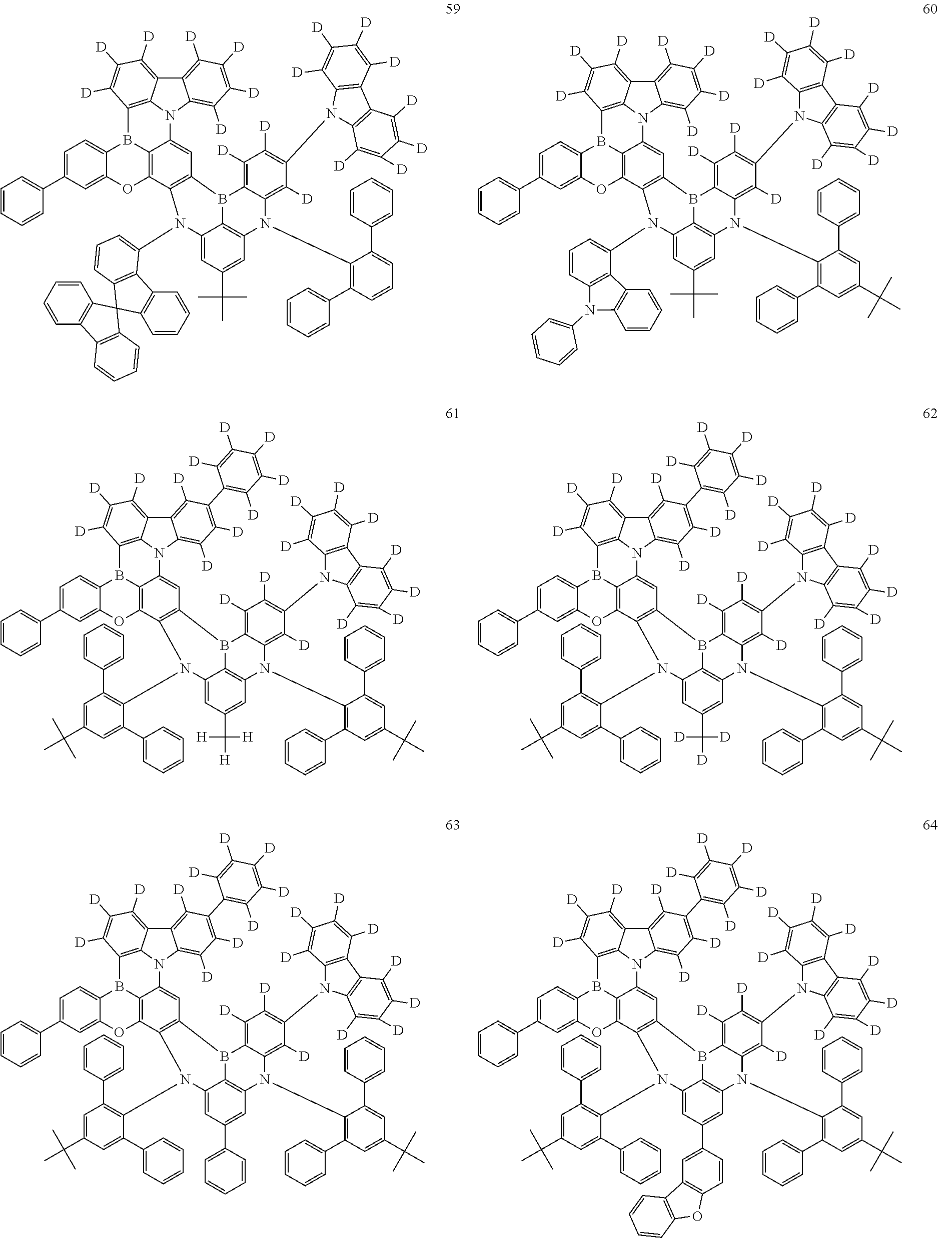

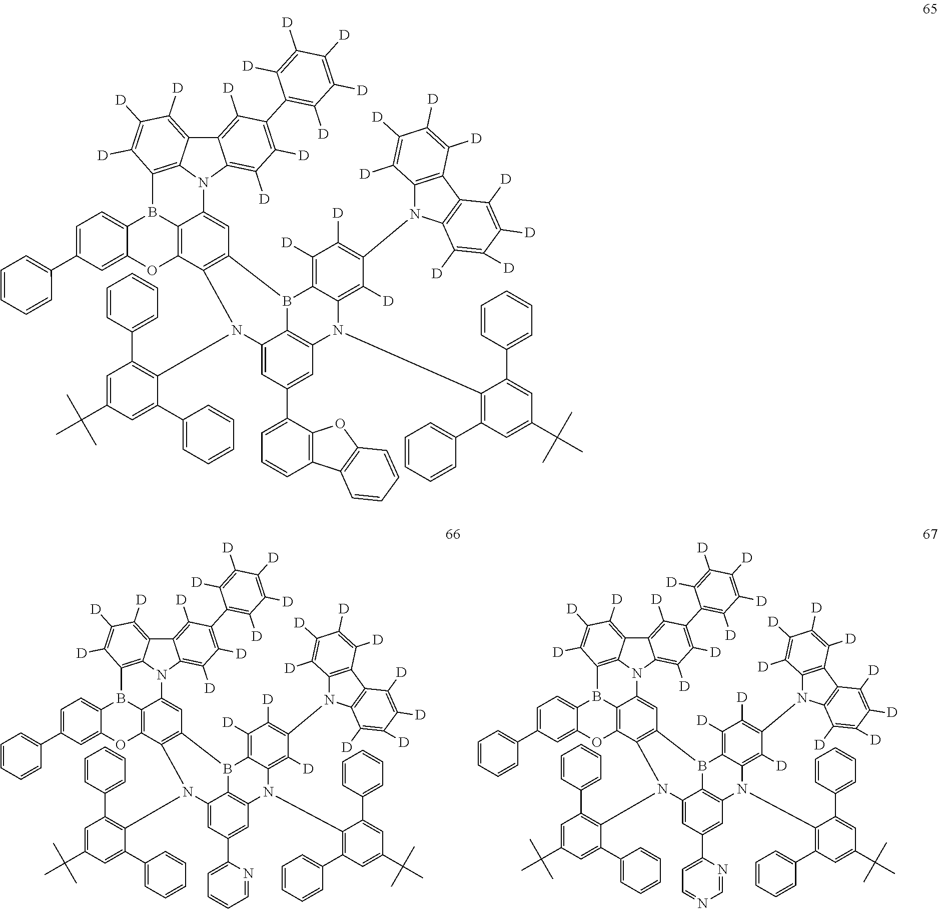

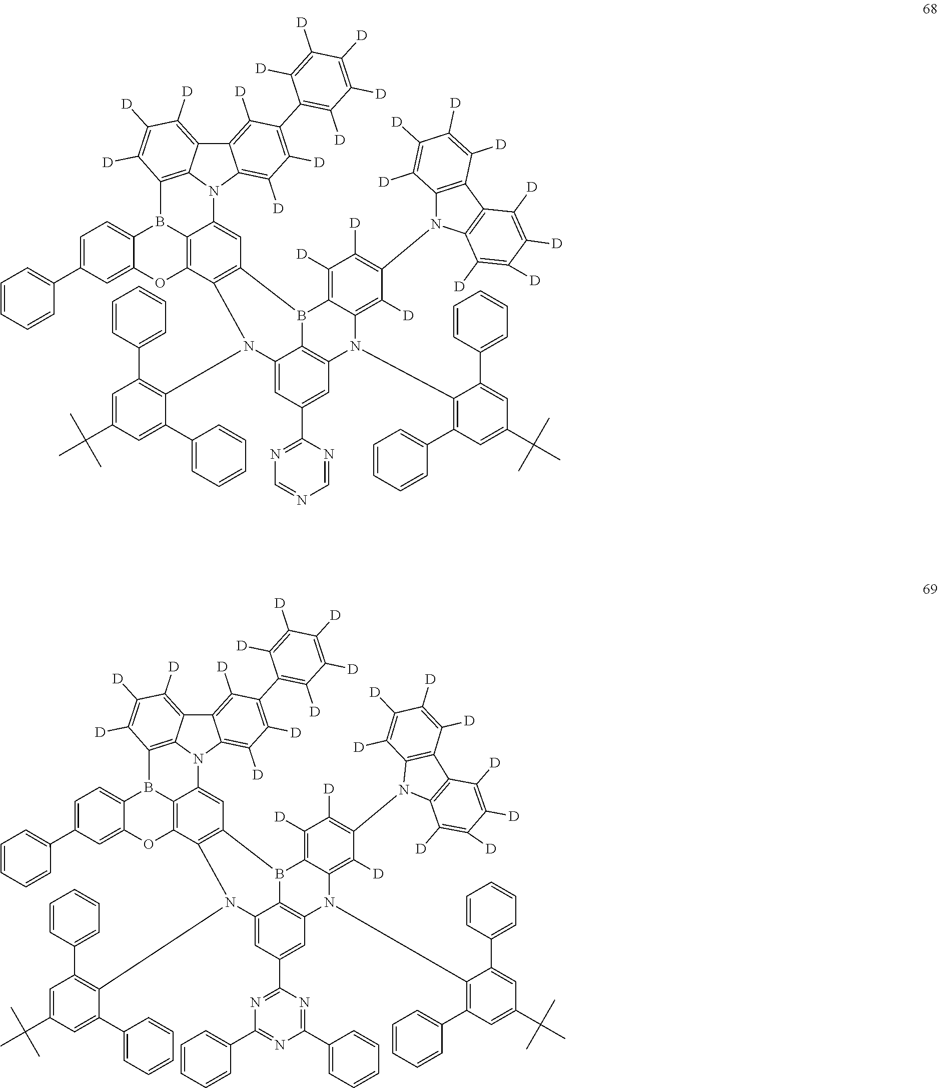

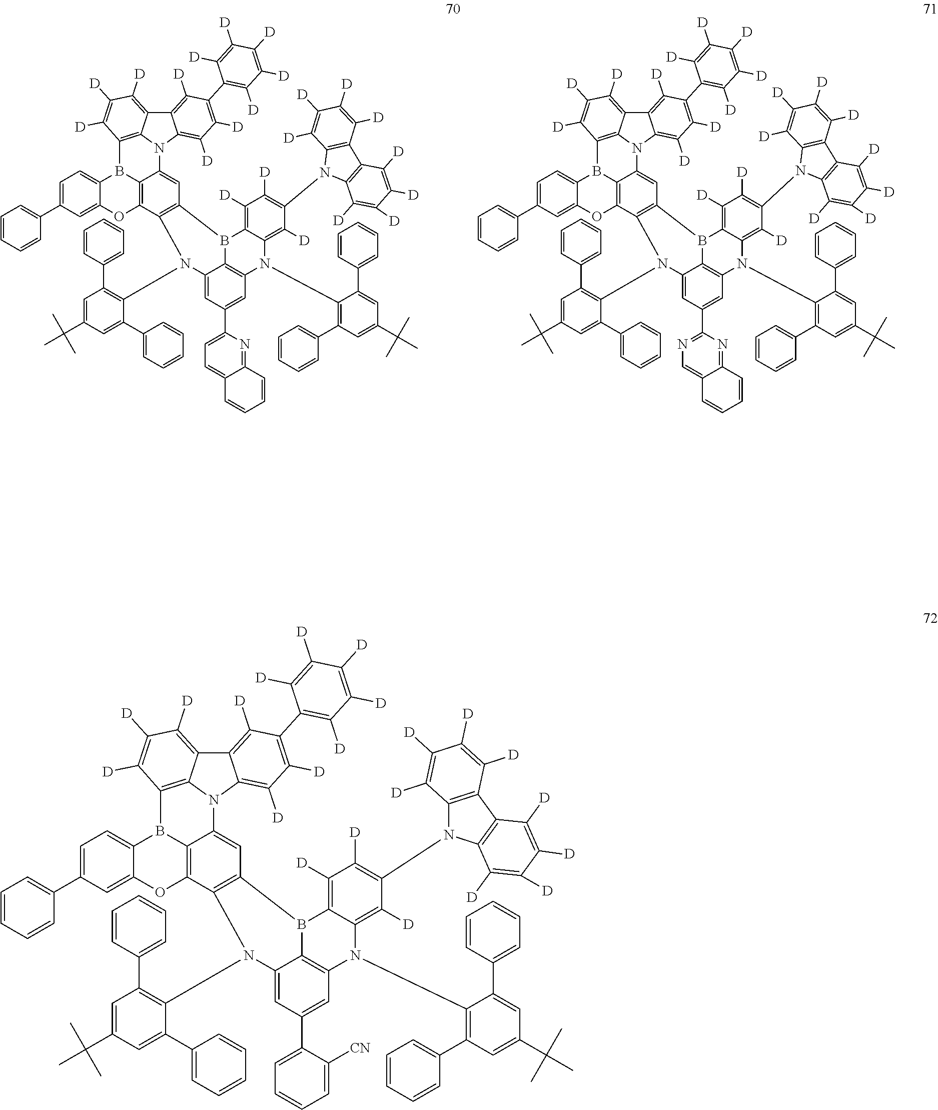

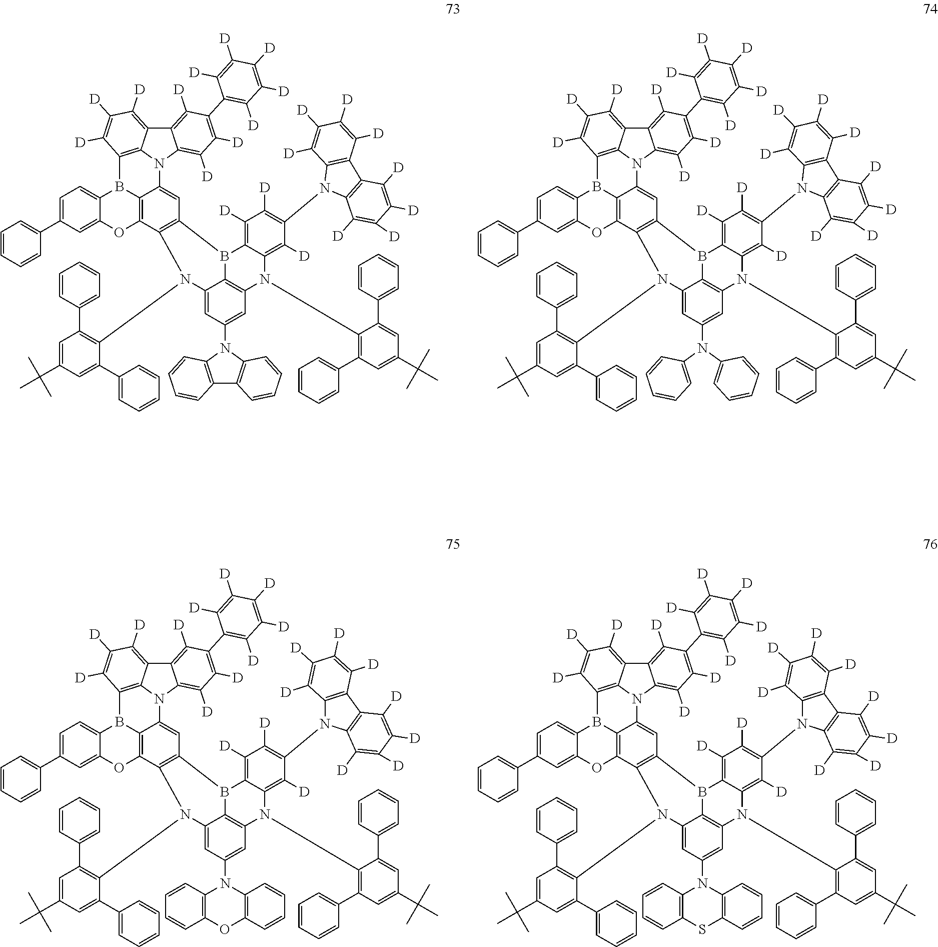

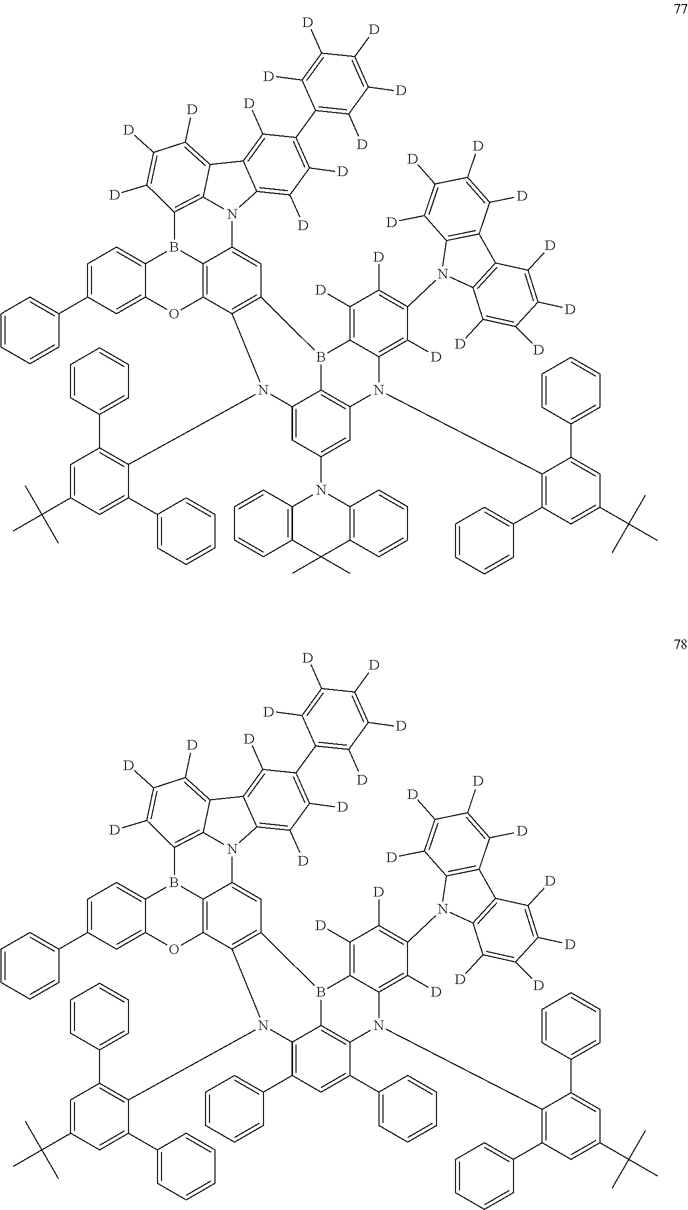

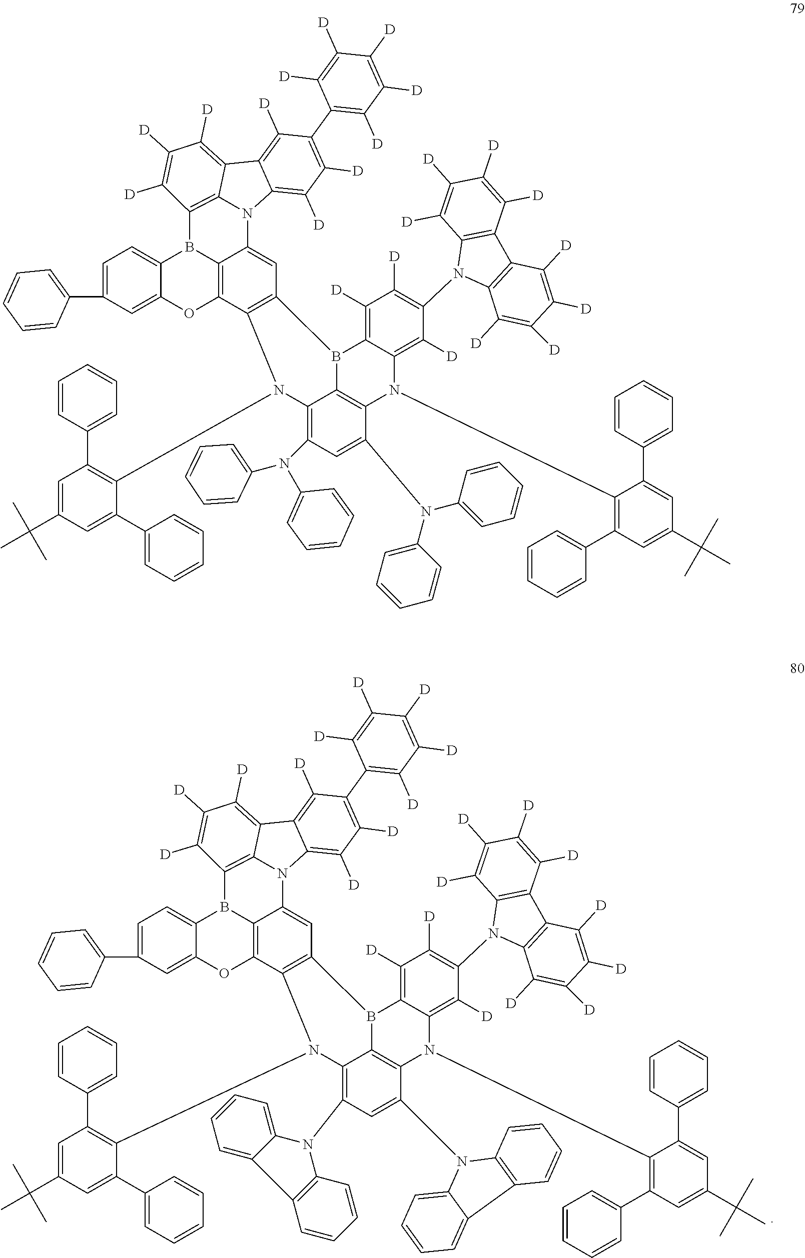

In Compound Group 1, D represents a deuterium atom.

In an embodiment, the fused polycyclic compound represented by Formula 1 may be a luminescent material having a central wavelength (Iₘₐₓ) in a range of about 470 nm to about 650 nm. For example, the fused polycyclic compound represented by Formula 1 may be a luminescent material having a central wavelength (Iₘₐₓ) in a range of about 500 nm to about 550 nm. For example, the fused polycyclic compound represented by Formula 1 may be a green dopant.

In the light emitting element ED according to an embodiment, the emission layer EML may include a host and a dopant, and may include the fused polycyclic compound according to an embodiment as a dopant. For example, the emission layer EML may include a host and a dopant, and may include the fused polycyclic compound as a dopant for emitting a delayed fluorescence. For example, the emission layer EML may include at least one fused polycyclic compound according to an embodiment as a thermally activated delayed fluorescence (TADF) dopant.

A full width at half maximum (FWHM) of an emission spectrum of the fused polycyclic compound represented by Formula 1 may be equal to or less than about 35 nm. For example, the FWHM of an emission spectrum of the fused polycyclic compound represented by Formula 1 may be equal to or less than about 30 nm. For example, the FWHM of an emission spectrum of the fused polycyclic compound represented by Formula 1 may be equal to or less than about 25 nm. In an embodiment, the lower limit of the FWHM of the emission spectrum of the fused polycyclic compound may not be particularly limited, and may be equal to or greater than about 1 nm. Within any of the above ranges, luminous efficiency may be improved when the fused polycyclic compound is applied to a light emitting element. When the fused polycyclic compound according to an embodiment is used as a green light emitting element material for a light emitting element, the element service life may be improved.

The fused polycyclic compound represented by Formula 1 may have a Stokes-shift equal to or less than about 30 nm. For example, the fused polycyclic compound may have a Stokes-shift equal to or less than about 25 nm. For example, the fused polycyclic compound may have a Stokes-shift equal to or less than about 20 nm. The lower limit of the Stokes-shift of the fused polycyclic compound may not be particularly limited, and may be equal to or greater than about 1 nm. Within any of the above ranges, luminous efficiency may be improved when the fused polycyclic compound is applied to a light emitting element. When the fused polycyclic compound according to an embodiment is used as a green light emitting element material for a light emitting element, the element service life may be improved.

In an embodiment, the fused polycyclic compound represented by Formula 1 according to an embodiment may be a thermally activated delayed fluorescence emitting material. Furthermore, the fused polycyclic compound represented by Formula 1 may be a thermally activated delayed fluorescence dopant having the difference (ΔE_{ST}) between the lowest triplet exciton energy level (T1 level), and the lowest singlet exciton energy level (Si level) equal to or less than about 0.6 eV. The fused polycyclic compound represented by Formula 1 may be a thermally activated delayed fluorescence dopant having the difference (ΔE_{ST}) between a lowest triplet exciton energy level (T1 level) and a lowest singlet exciton energy level (Si level) equal to or less than about 0.2 eV. However, embodiments are not limited thereto.

The emission layer EML in the light emitting element ED according to an embodiment may emit delayed fluorescence. For example, the emission layer EML may emit thermally activated delayed fluorescence (TADF).

In an embodiment, the emission layer EML of the light emitting element ED may emit green light. For example, the emission layer EML of the organic electroluminescence element ED according to an embodiment may emit green light. However, embodiments are not limited thereto, and the emission layer EML may emit blue light or red light.

In an embodiment, the fused polycyclic compound according to an embodiment may be included in the emission layer EML. The fused polycyclic compound may be included as a dopant material in the emission layer EML. The fused polycyclic compound may be a thermally activated delayed fluorescence material. The fused polycyclic compound may be used as a thermally activated delayed fluorescence dopant. For example, in the light emitting element ED, the emission layer EML may include, as a thermally activated delayed fluorescence dopant, at least one compound selected from Compound Group 1 as described above. However, a use of the fused polycyclic compound is not limited thereto.

In an embodiment, the emission layer EML may include multiple compounds. In an embodiment, the emission layer EML may include the fused polycyclic compound represented by Formula 1 as a first compound, and at least one of a second compound represented by Formula HT-1, a third compound represented by Formula ET-1, and a fourth compound represented by Formula M-a.

In an embodiment, the emission layer EML may include the first compound represented by Formula 1 and may further include at least one of a second compound represented by Formula HT-1 and a third compound represented by Formula ET-1.

In an embodiment, the emission layer EML may further include a second compound represented by Formula HT-1. In an embodiment, the second compound may be used as a hole transport host material in the emission layer EML.

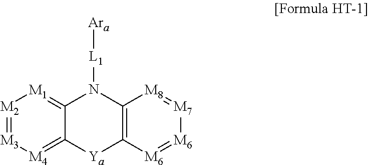

In Formula HT-1, M₁ to M₈ may each independently be N or C(R₅₁). For example, M₁ to M₈ may each independently be C(R₅₁). In another example, one of M₁ to M₈ may be N, and the remainder of M₁ to M₈ may each independently be C(R₅₁).

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅4)(R₅₅). For example, the two benzene rings connected with the nitrogen atom of Formula HT-1 may be connected to each other via a direct linkage,

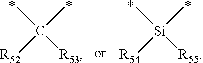

In Formula HT-1, if Yₐ is a direct linkage, the substituent represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

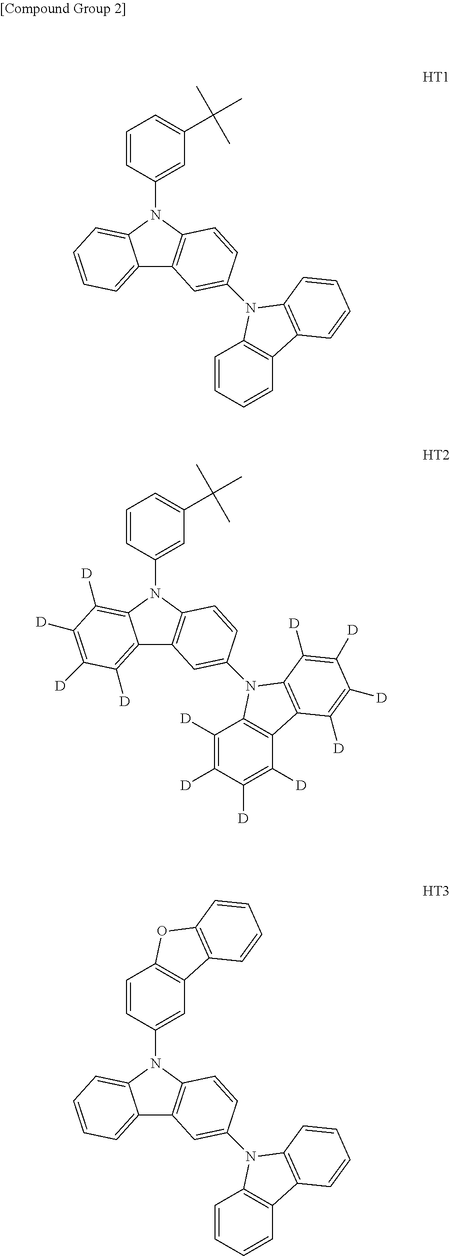 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

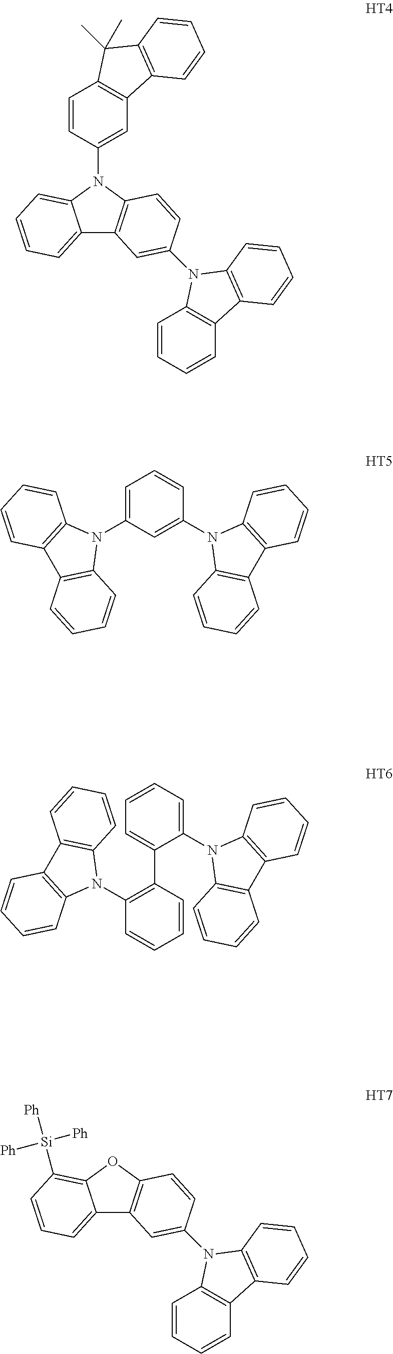 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

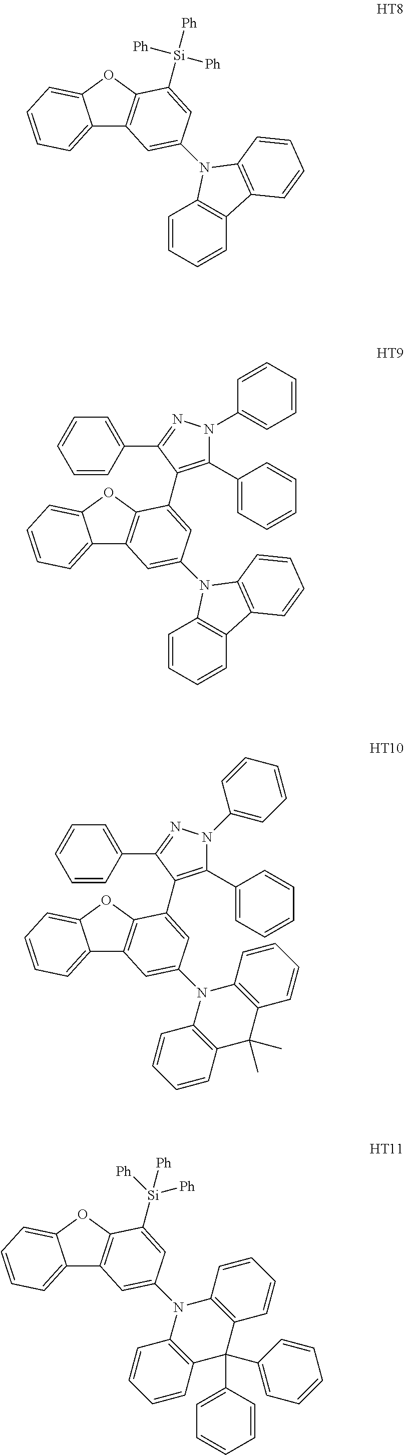 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

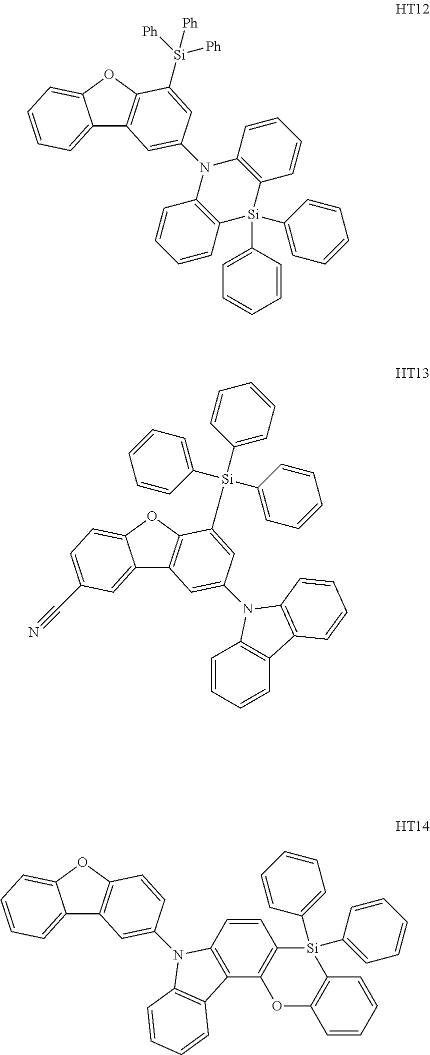 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

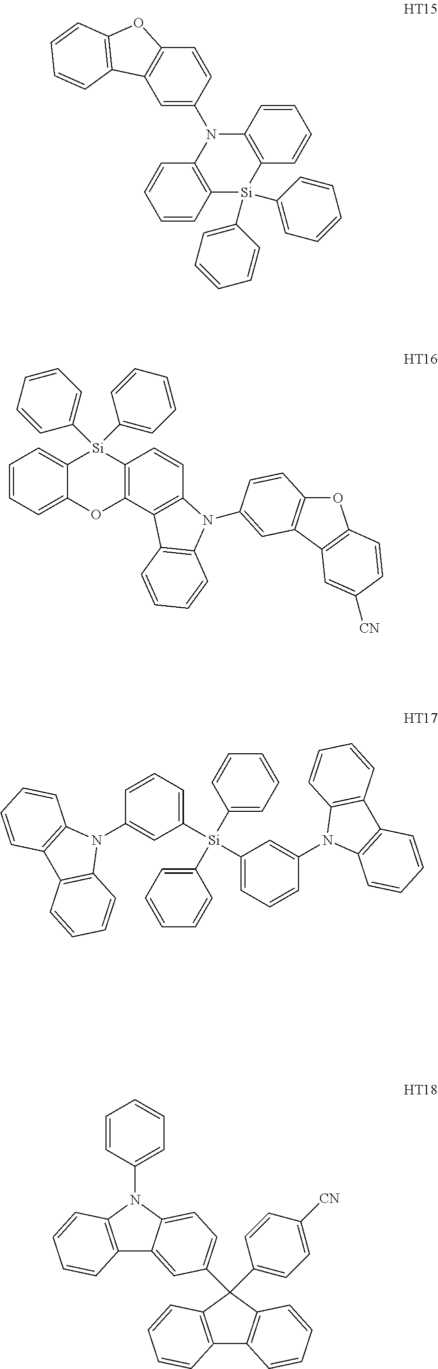 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

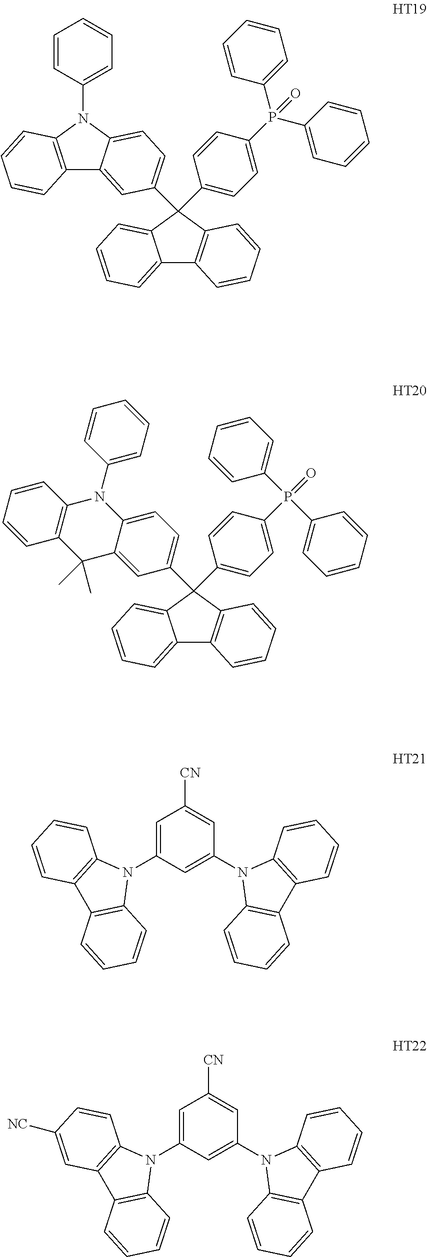 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

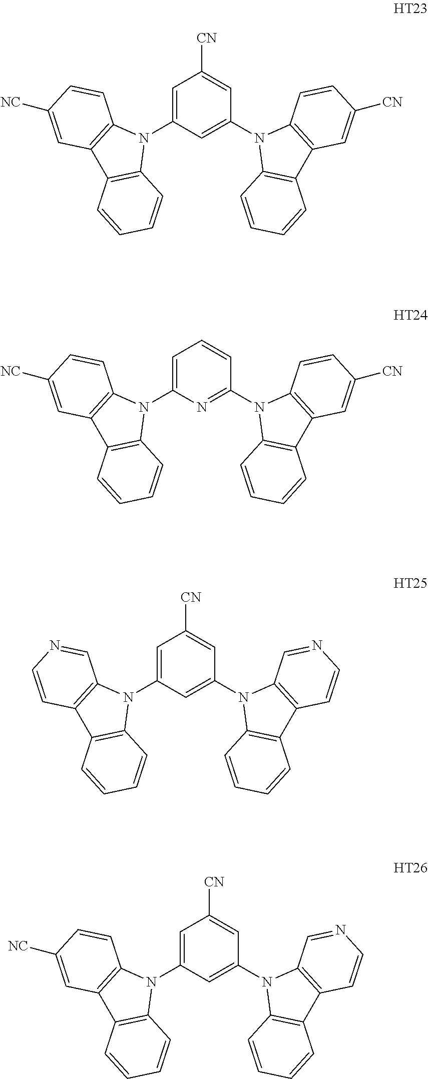 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

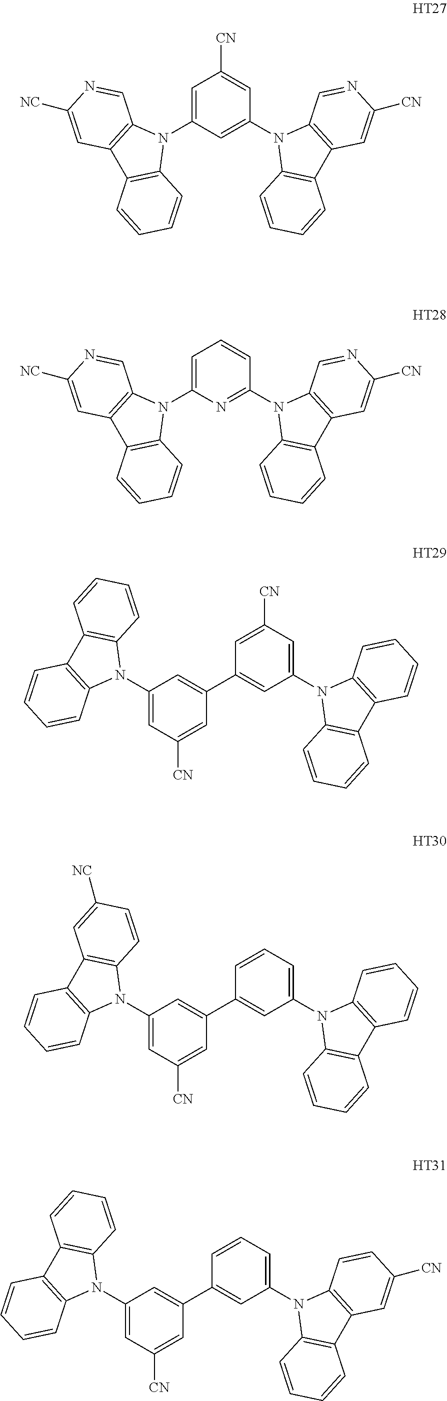 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

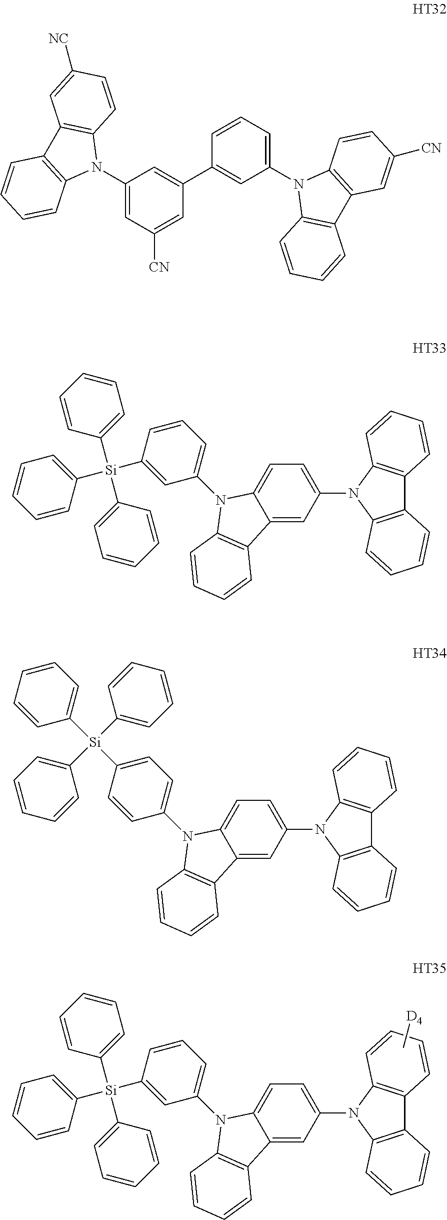

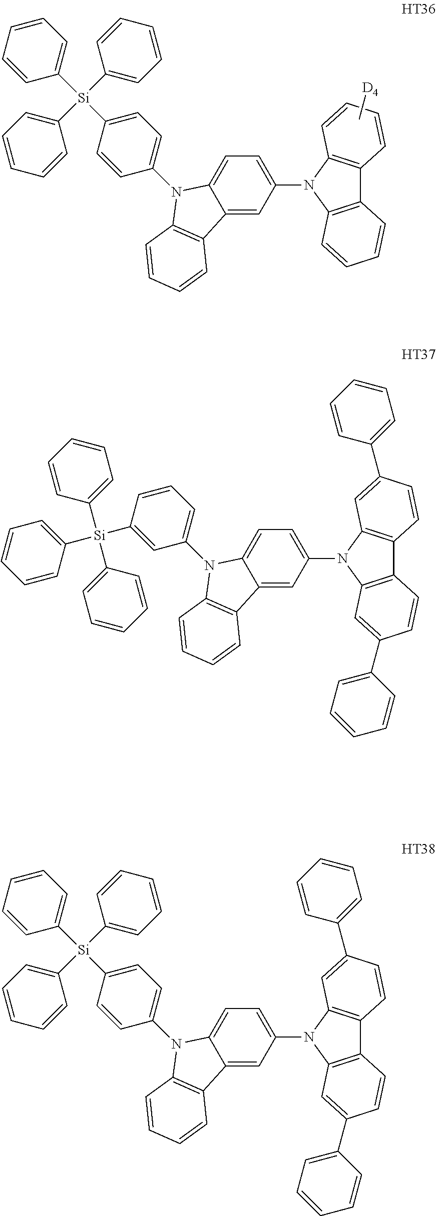

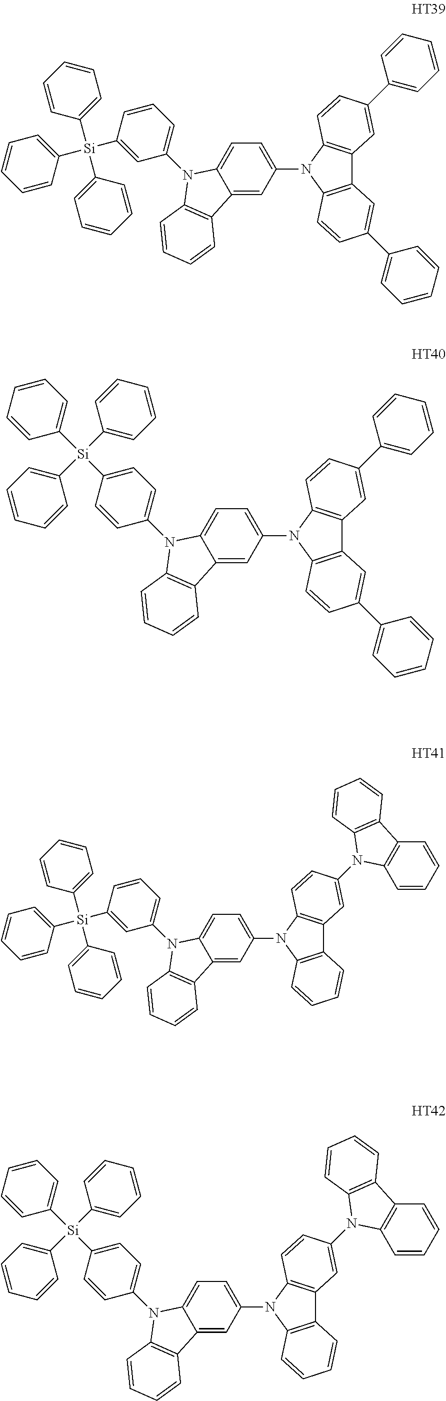 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

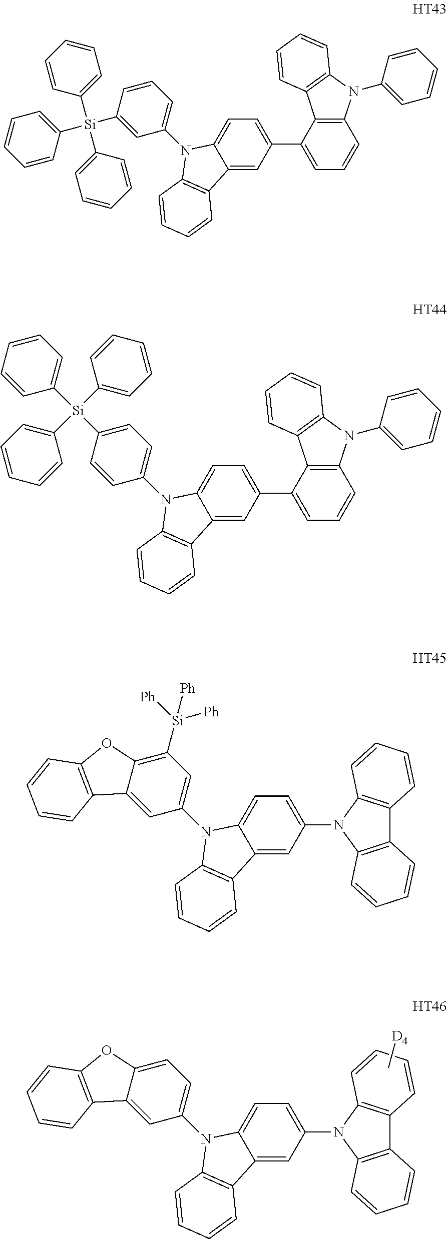

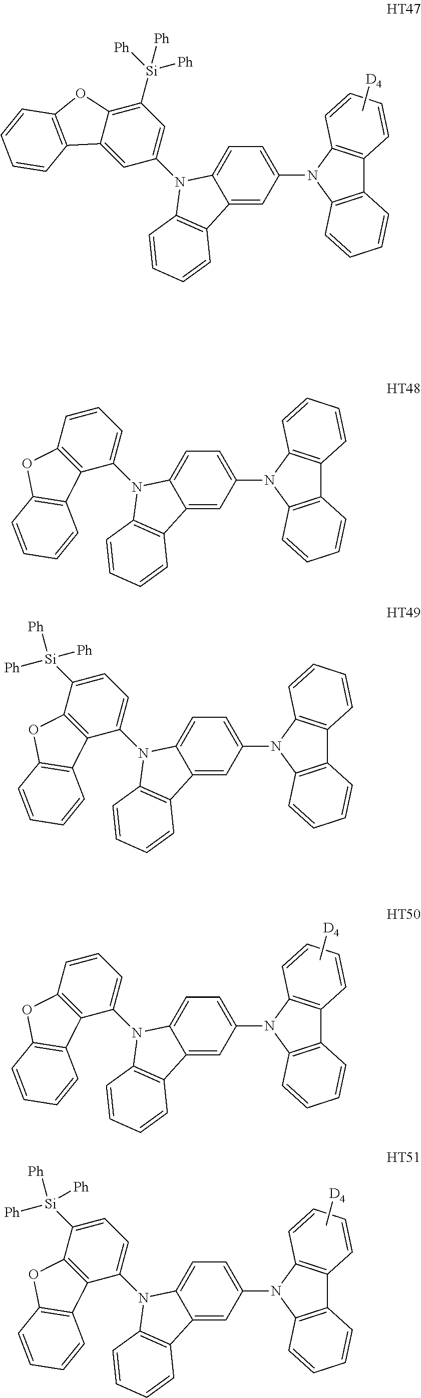

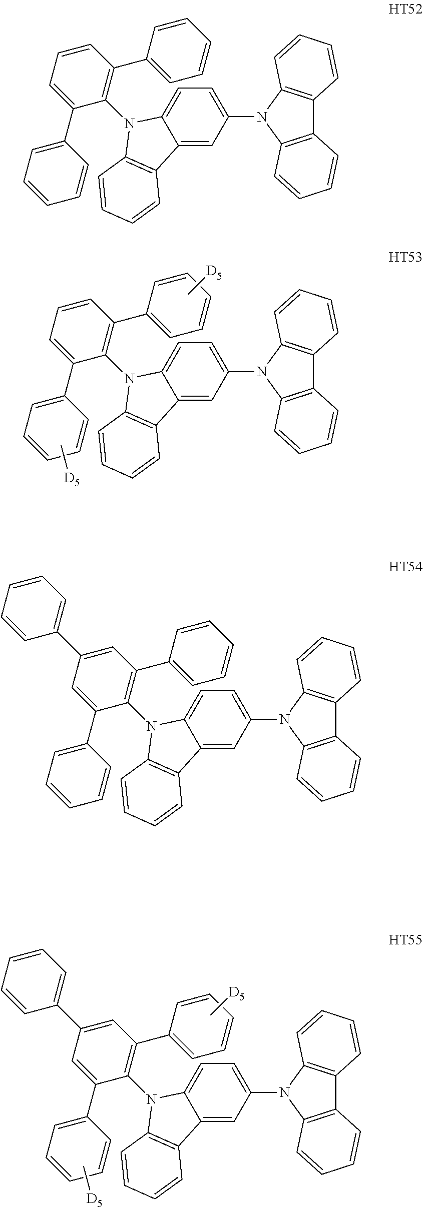

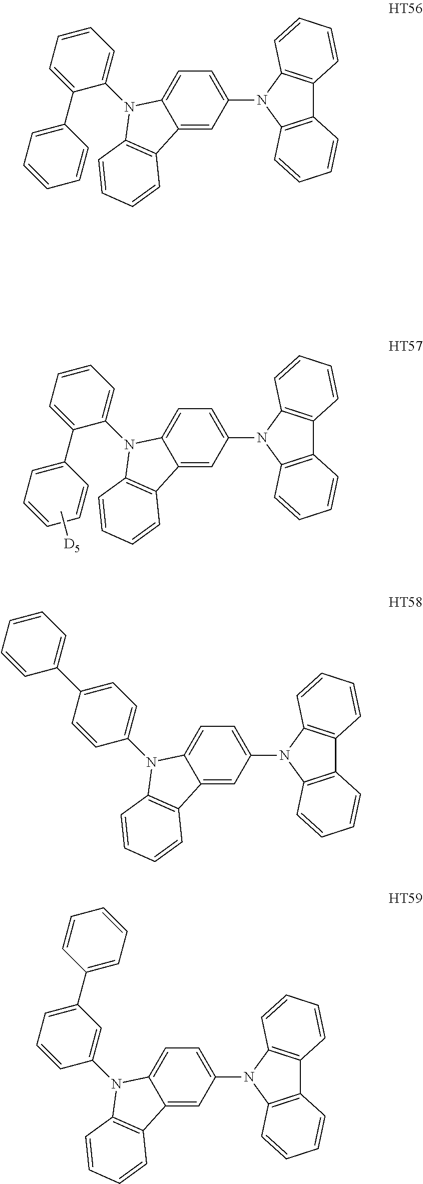

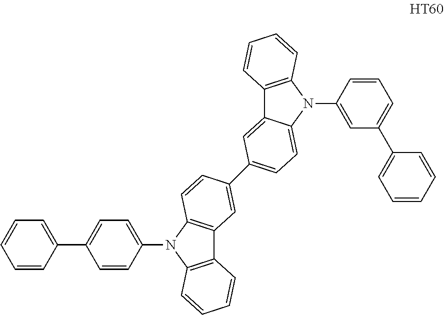 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

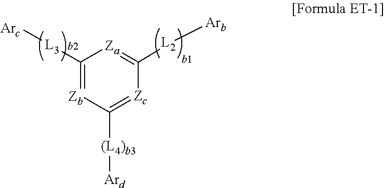

In Formula ET-1, at least one of Zₐ to Z_{c} may each be N, and the remainder of Zₐ to Z_{c} may each independently be C(R₅₆). For example, one of Zₐ to Z_{c} may be N, and the remainder of Zₐ to Z_{c} may each independently be C(R₅₆). Thus, the third compound represented by Formula ET-1 may include a pyridine moiety. As another example, two of Zₐ to Z_{c} may each be N, and the remainder of Zₐ to Z_{c} may be C(R₅₆). Thus, the third compound represented by Formula ET-1 may include a pyrimidine moiety. As yet another example, Zₐ to Z_{c} may each be N. Thus, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer from 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₂ to Ar₄ may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. If b1 to b3 are each 2 or more, L₂ to L₄ may each independently be a substituted or unsubstituted arylene group of 6 to 30 ring-forming carbon atoms or a substituted or unsubstituted heteroarylene group of 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3.

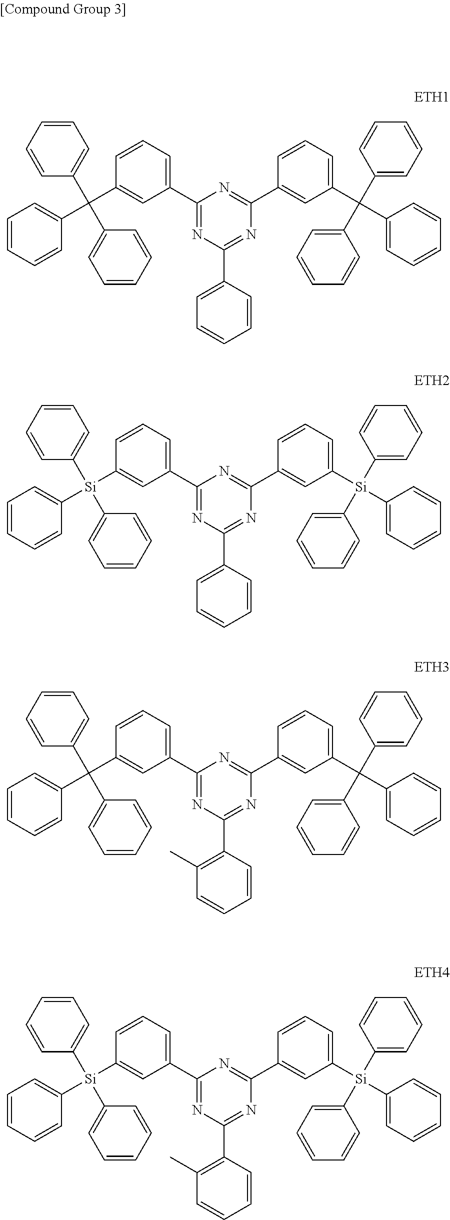 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

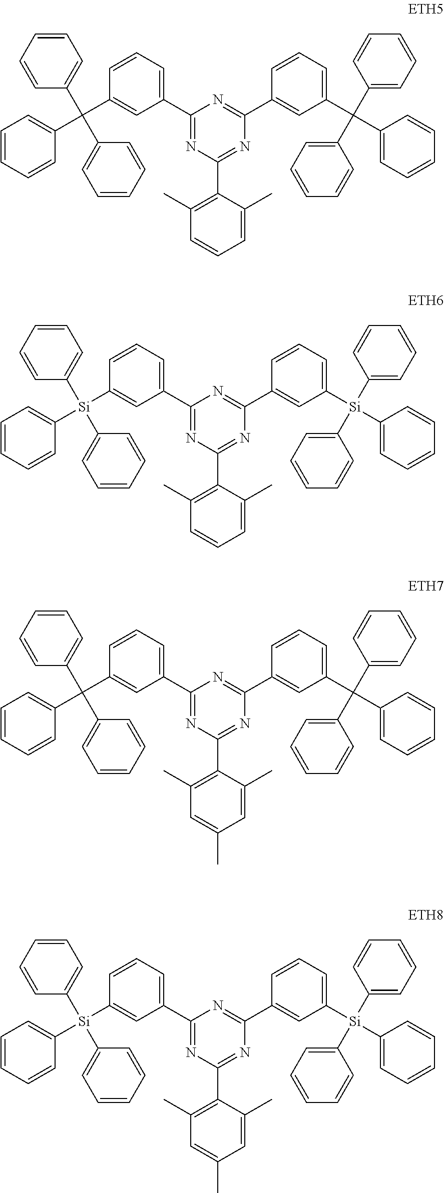 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

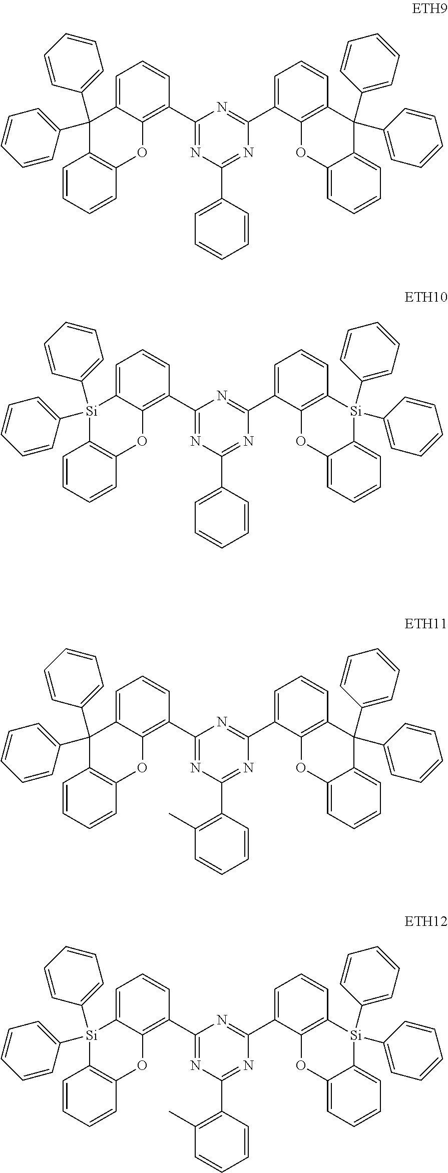 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

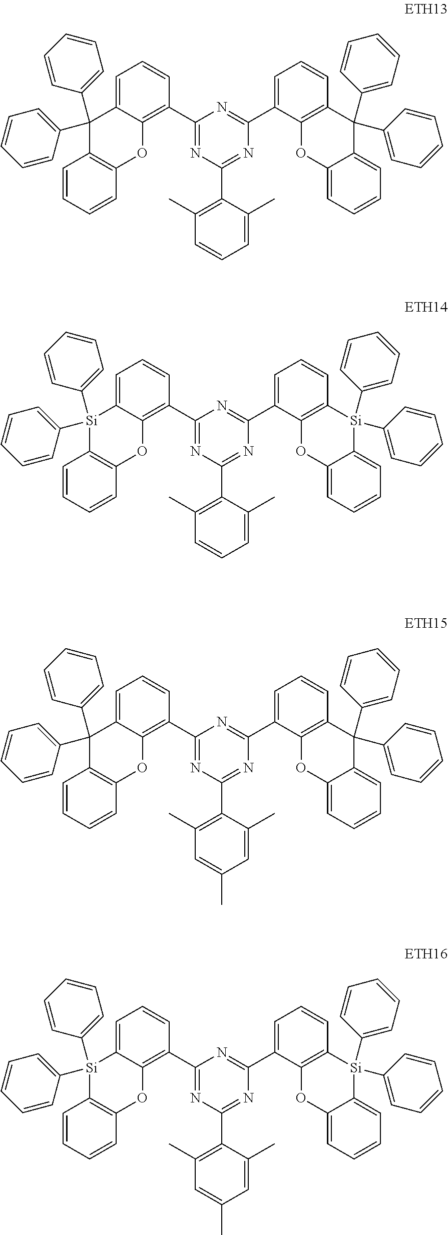 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

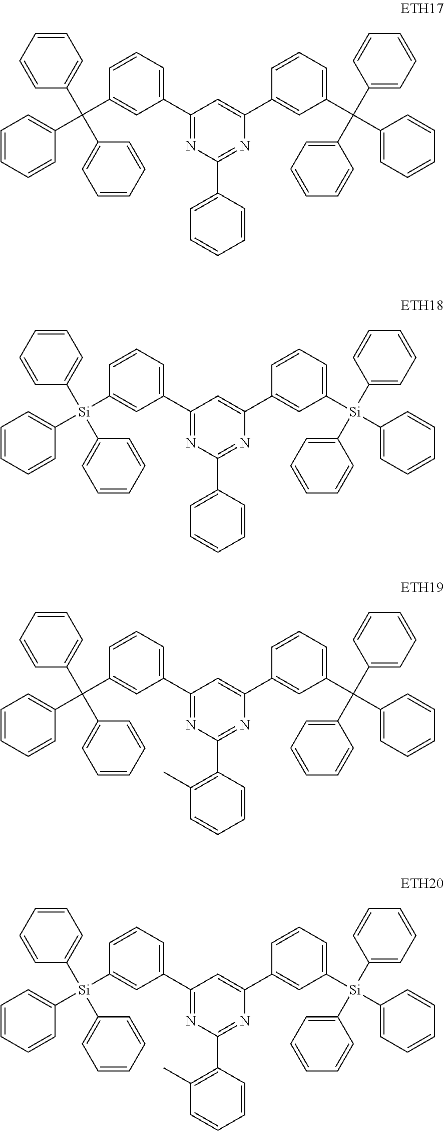 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

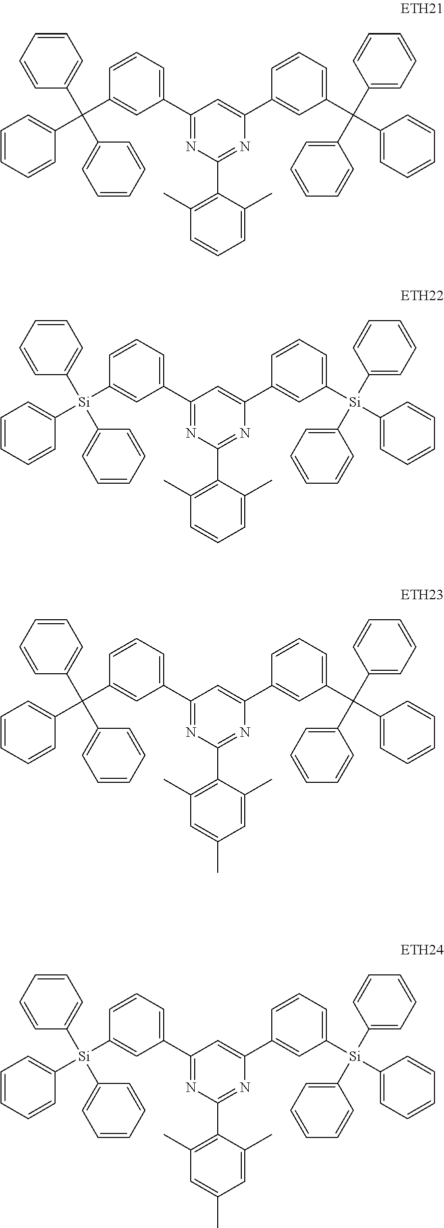 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

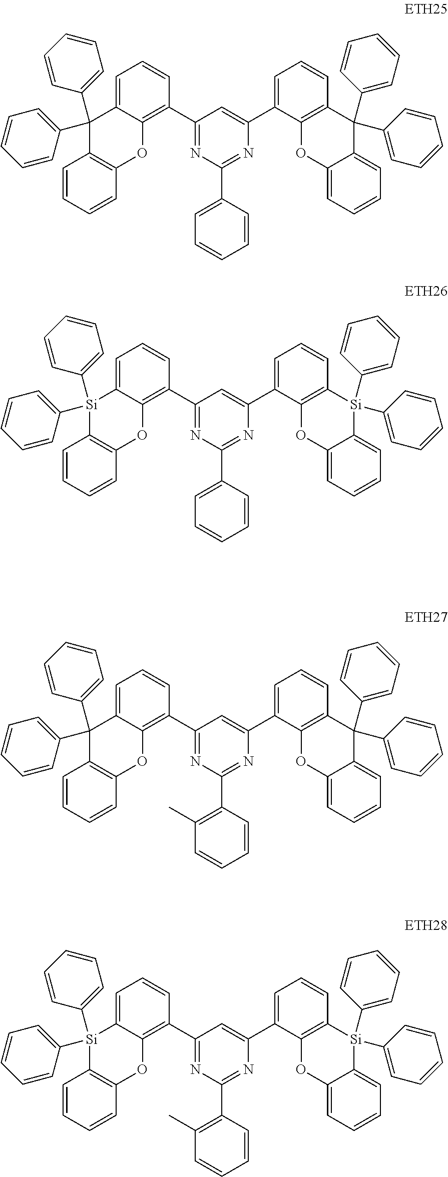 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

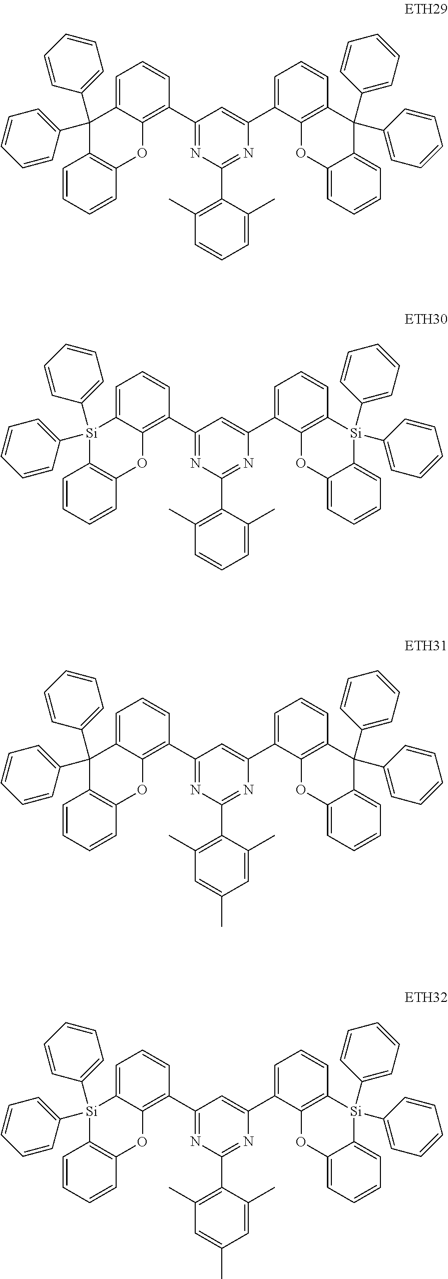 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

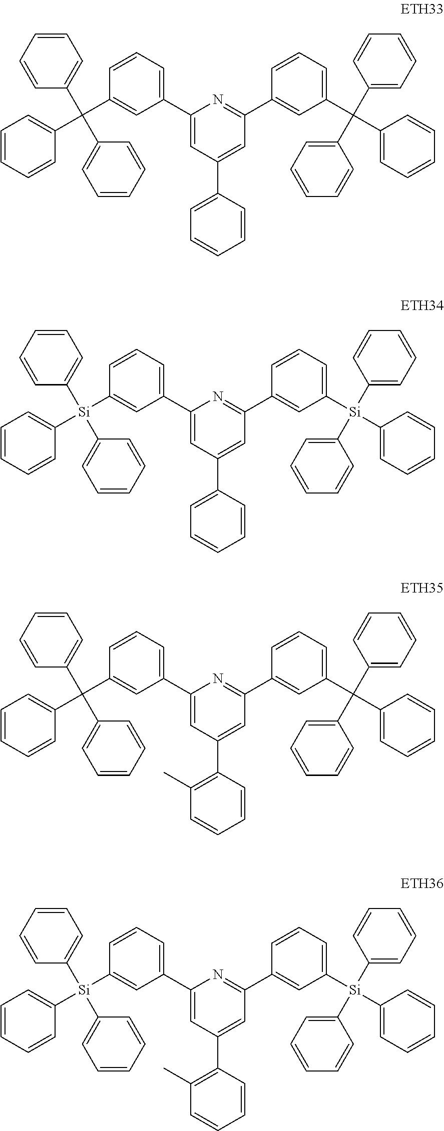 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

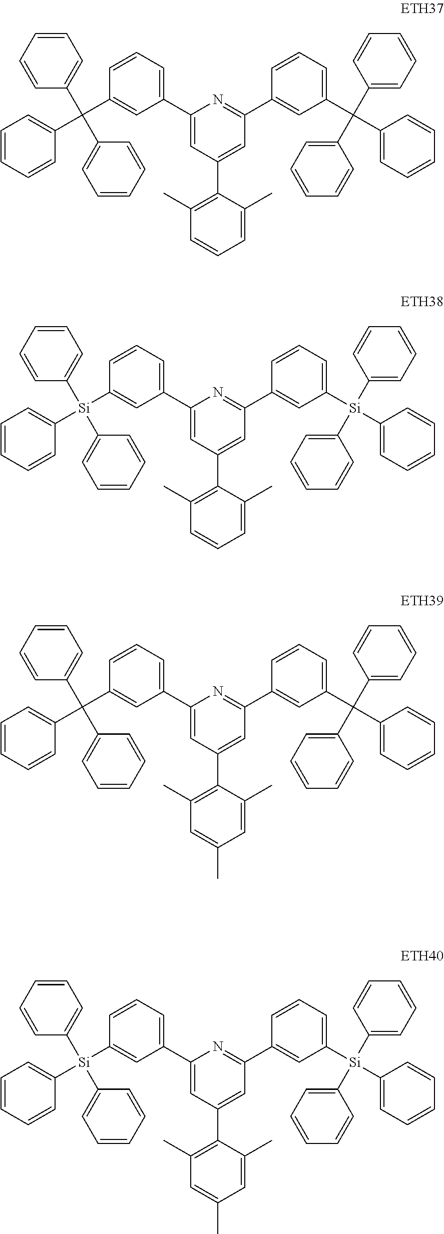 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

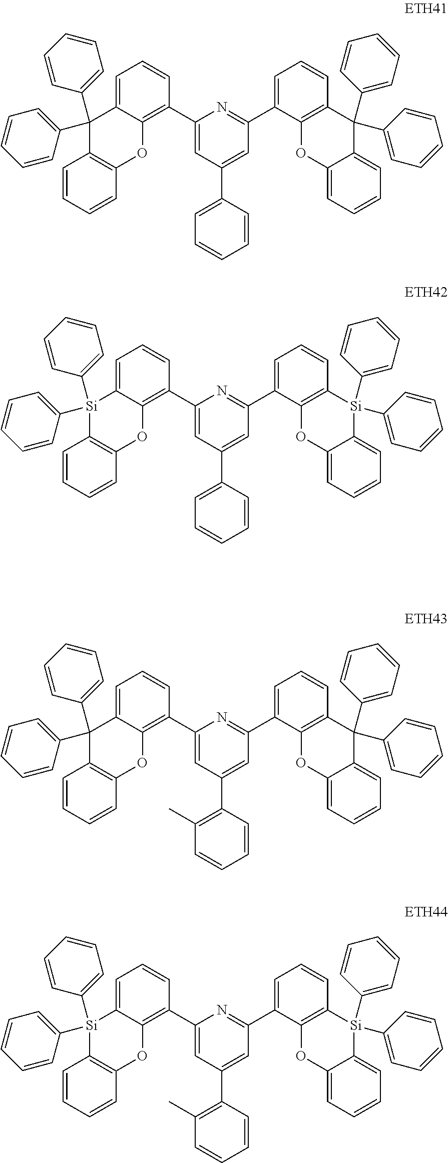 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

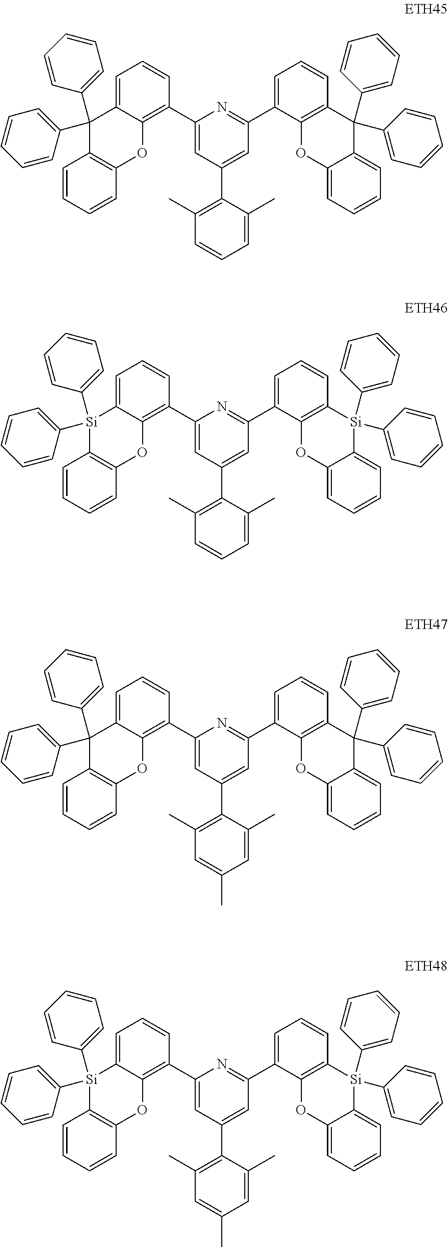 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

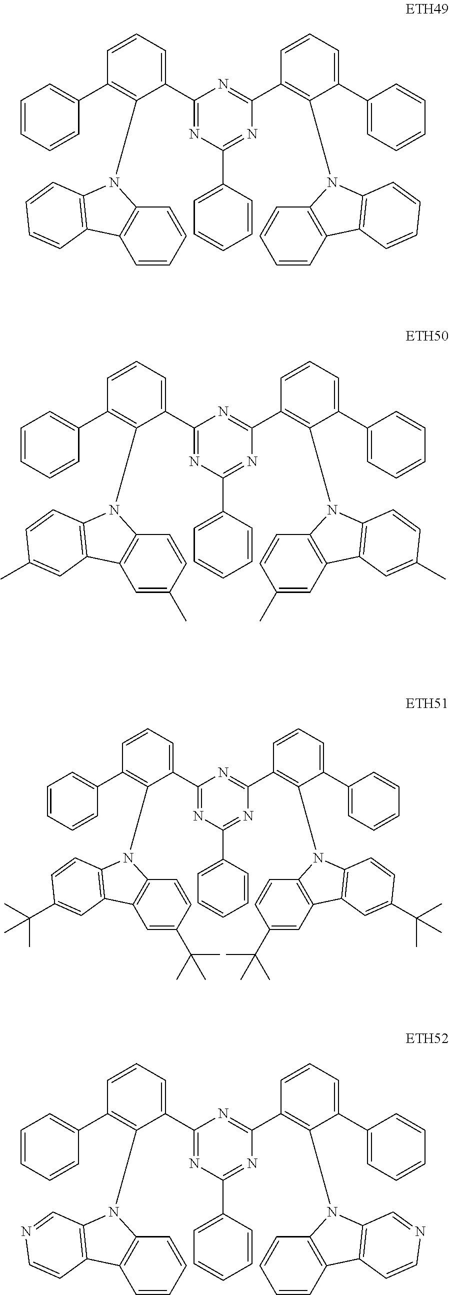

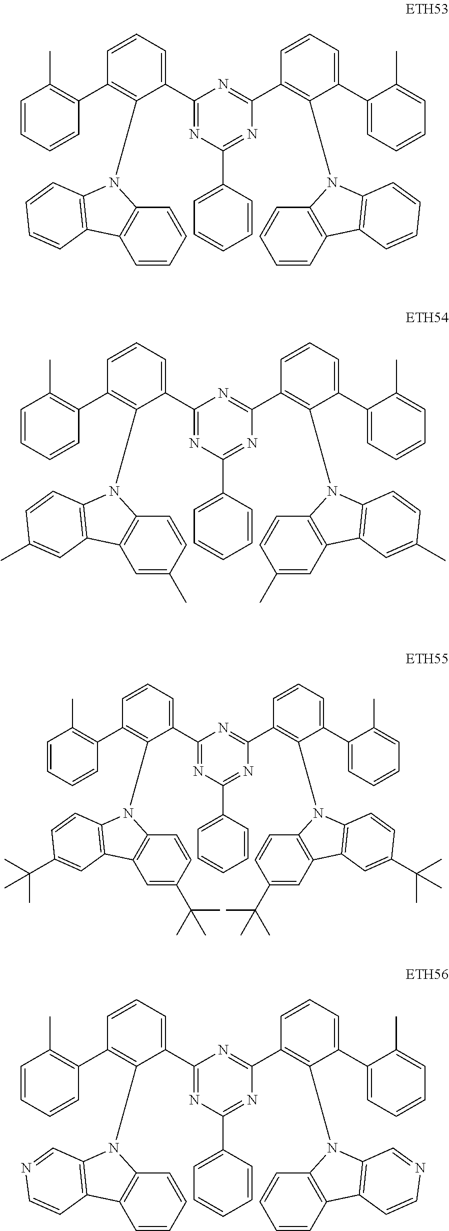

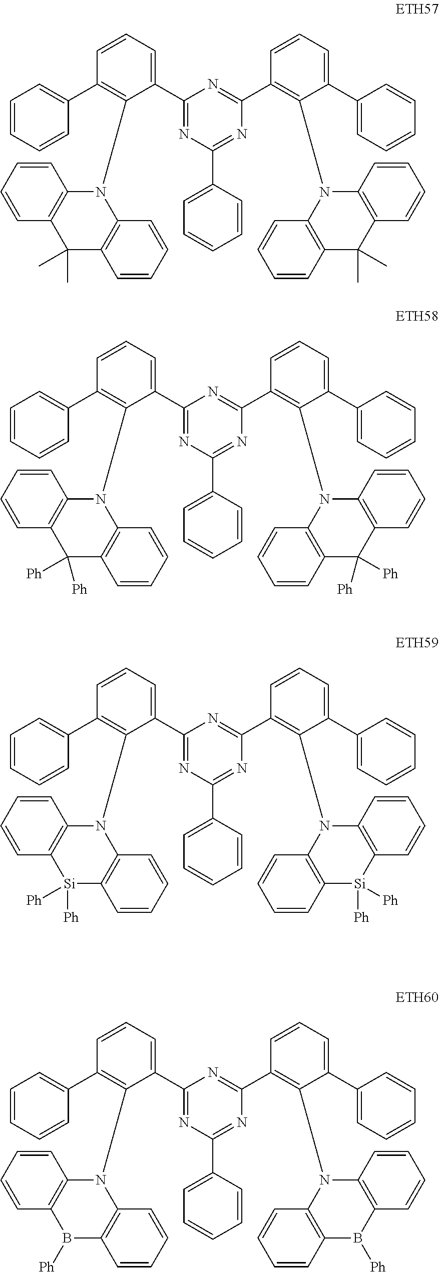

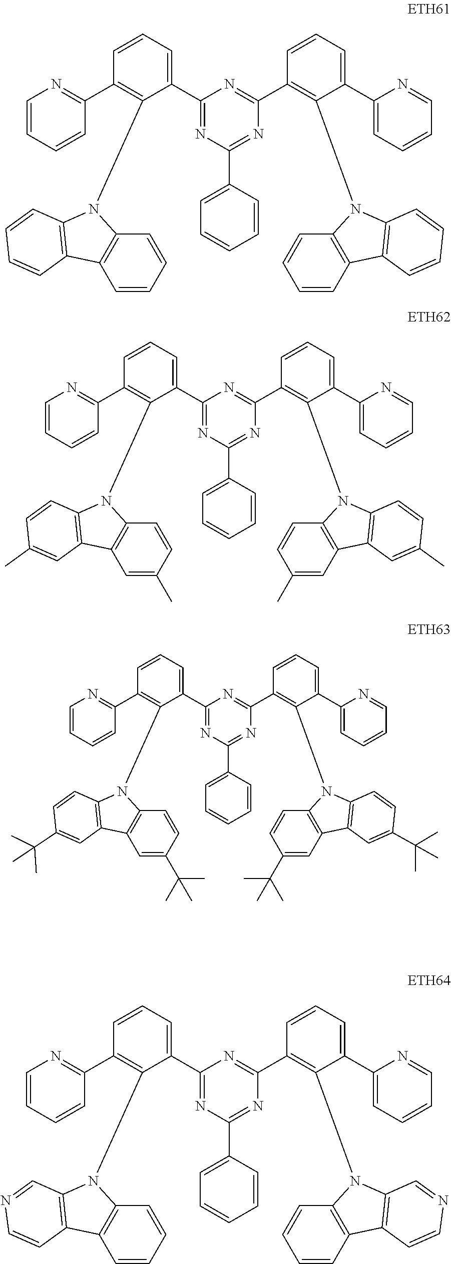

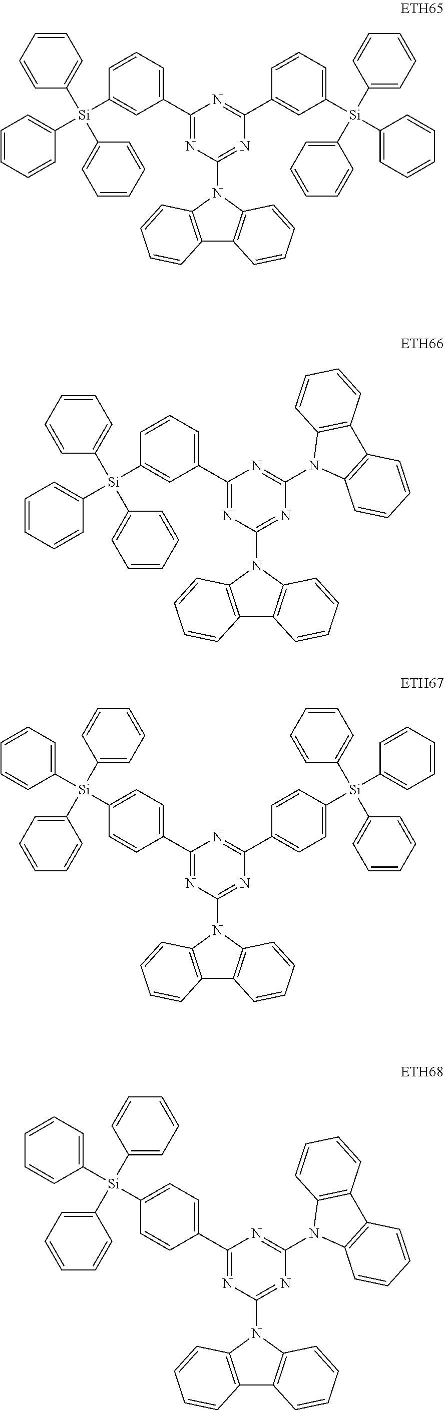 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

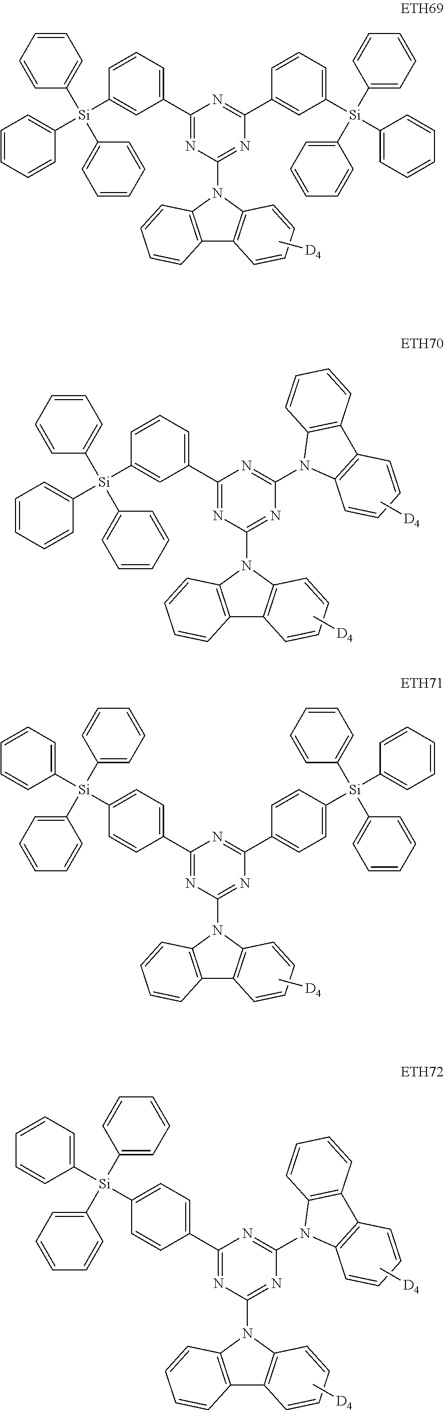

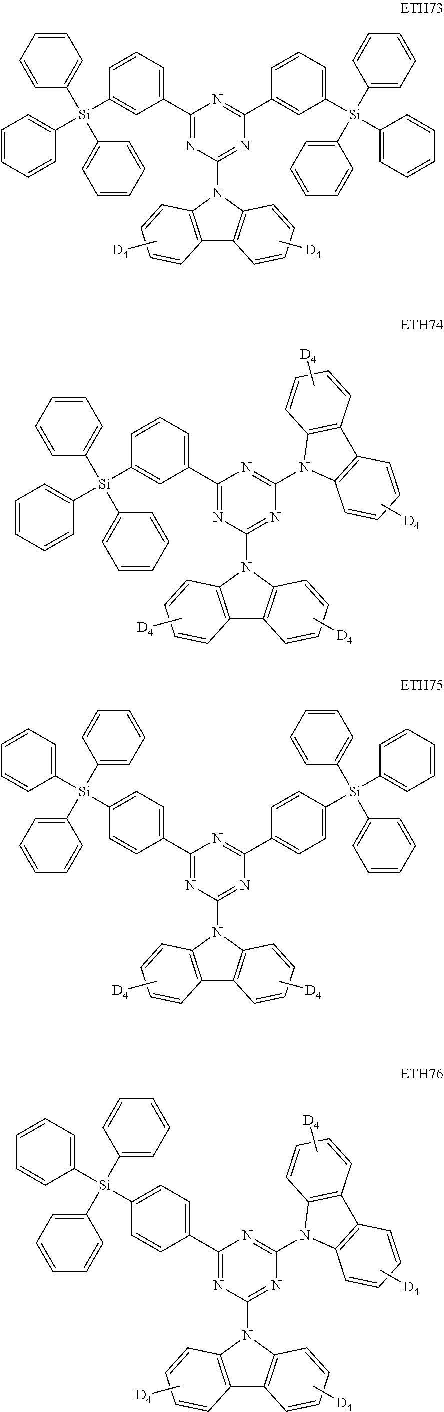

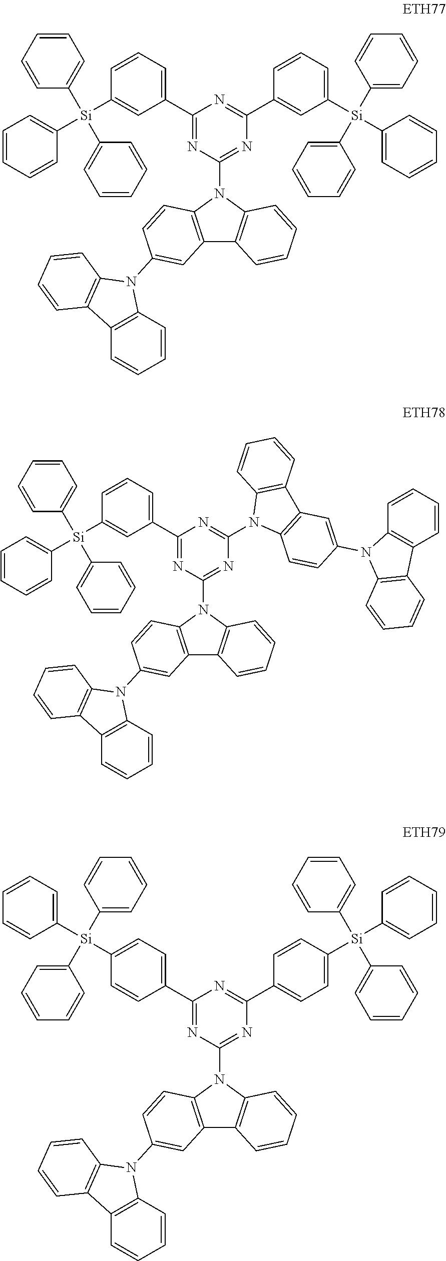 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

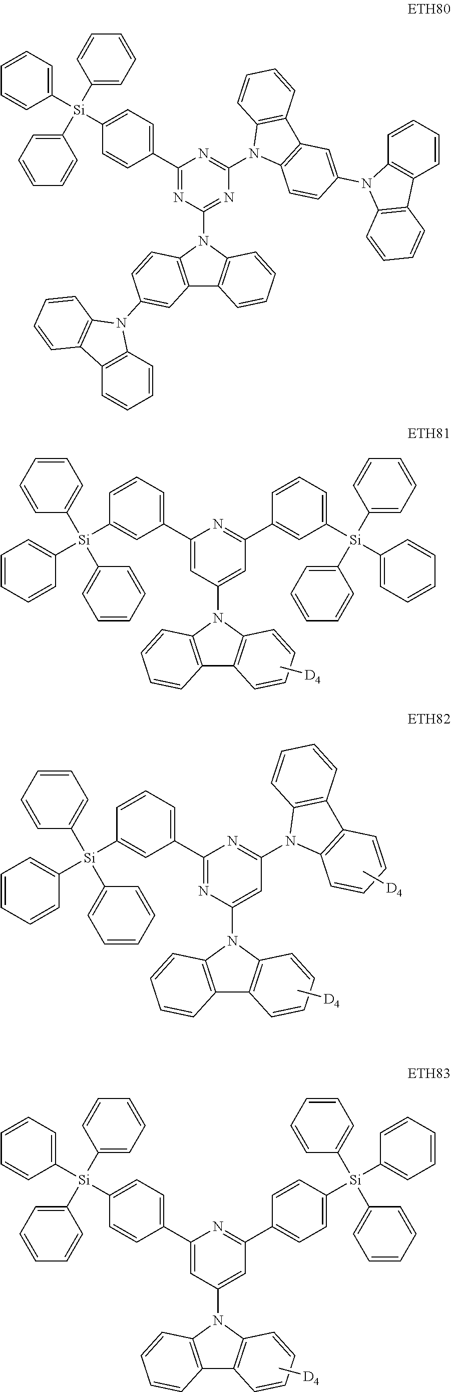

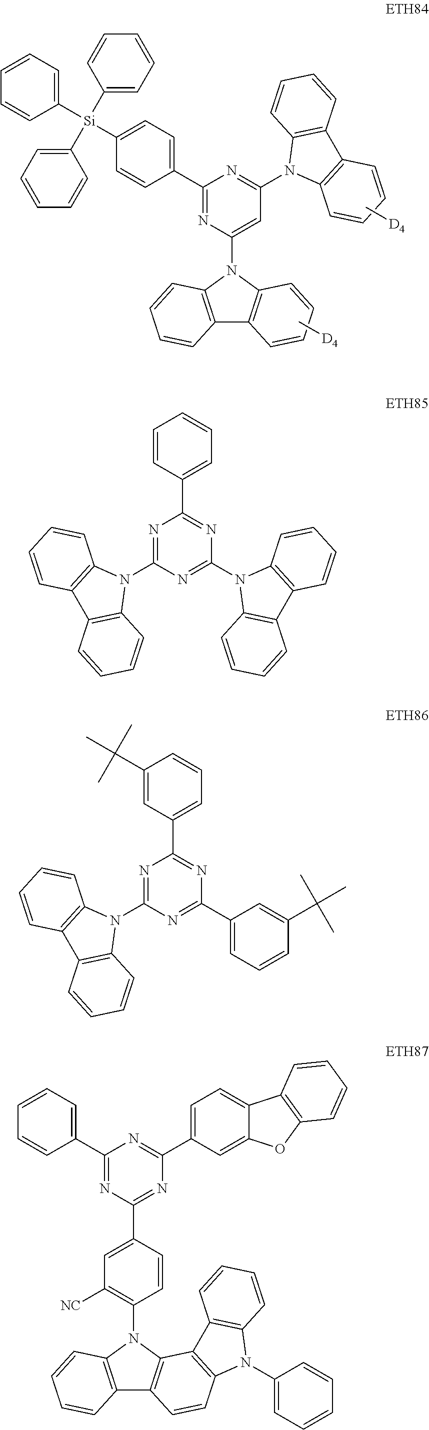

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by the hole transport host and the electron transport host may be in a range of about 2.4 eV to about 3.0 eV. The triplet energy level of the exciplex may have a value that is smaller than an energy gap of each host material. The exciplex may have a triplet energy equal to or less than about 3.0 eV, which is the energy gap between the hole transport host and the electron transport host.

In an embodiment, the emission layer EML may include a fourth compound in addition to the first compound, the second compound, and the third compound. The fourth compound may be used as a phosphorescence sensitizer in an emission layer EML. Energy may be transferred from the fourth compound to the first compound, thereby contributing to light emission.

The emission layer EML may include, as a fourth compound, an organometallic complex that includes platinum (Pt) as a central metal atom and ligands bonded to the central metal atom. In an embodiment, the emission layer EML may further include a fourth compound represented by Formula M-a.

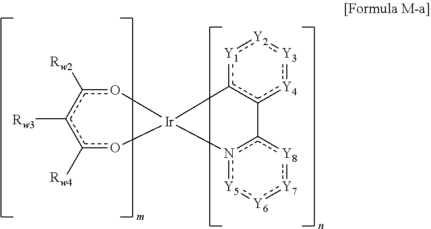

In Formula M-a, Y₁ to Y₈ may each independently be C(R_{w1}) or N.

In Formula M-a, R_{w1} to R_{w4} may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or bonded to an adjacent group to form a ring.

In Formula M-a, m may be 0 or 1, and n may be 2 or 3. In Formula M-a, if m is 0, n may be 3, and if m is 1, n may be 2.

In an embodiment, the emission layer EML may include the first compound represented by Formula 1, and at least one of the second compound, the third compound, and the fourth compound. For example, the emission layer EML may include the first compound, the second compound, and the third compound. In the emission layer EML, the second compound and the third compound may form an exciplex, and energy may be transferred from the exciplex to the first compound, thereby effecting light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby effecting light emission. In an embodiment, the fourth compound may be a sensitizer. In the light emitting element ED, the fourth compound included in the emission layer EML may serve as a sensitizer and may transfer energy from a host (for example, an exciplex host) to the first compound, which is a light-emitting dopant. For example, the fourth compound, which serves as an auxiliary dopant, may accelerate energy transfer to the first compound, which serves as a light emitting dopant, thereby increasing an emission ratio of the first compound. Accordingly, efficiency of the emission layer EML may be improved. When energy transfer to the first compound increases, excitons formed in the emission layer EML may not accumulate and may rapidly emit light, so that deterioration of the light emitting element ED may be reduced. Accordingly, the lifetime of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may show excellent emission efficiency properties.

In an embodiment, the fourth compound represented by Formula M-a may be selected from Compound Group 4. In an embodiment, in the light emitting element ED, the fourth compound may include at least one compound selected from Compound Group 4.

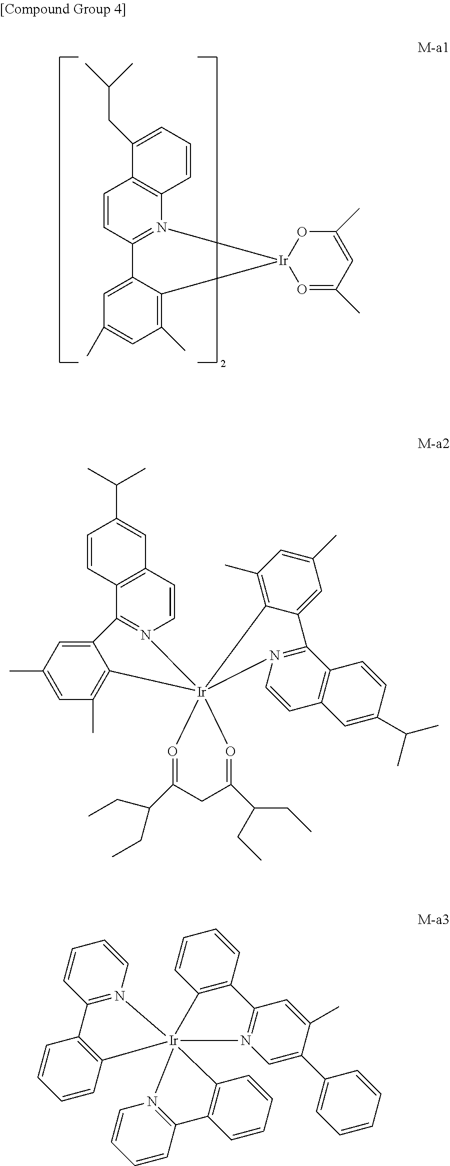

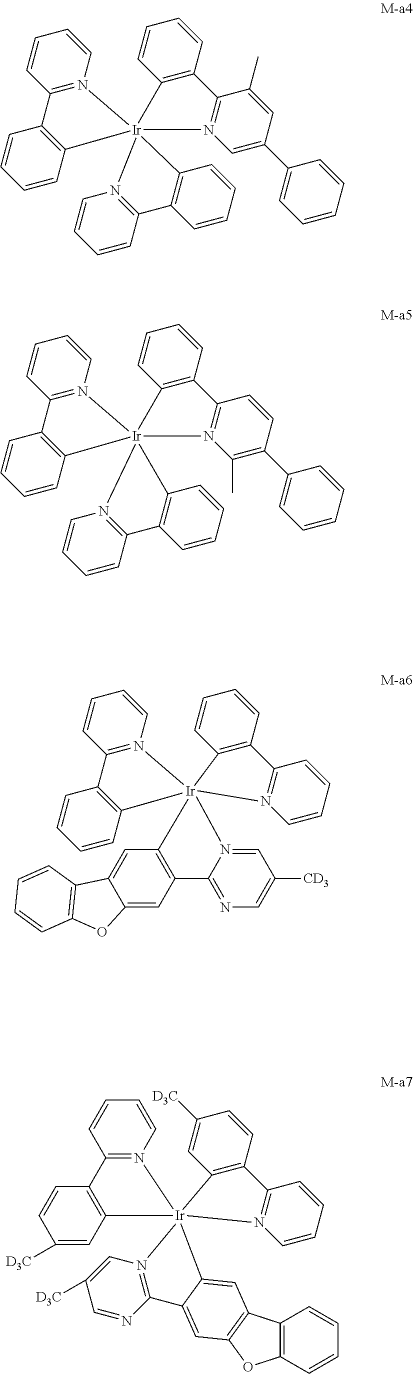

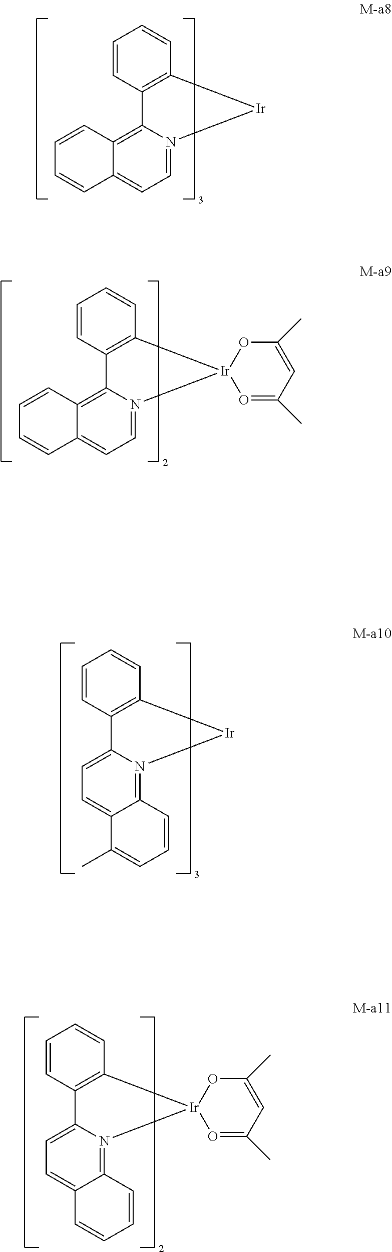

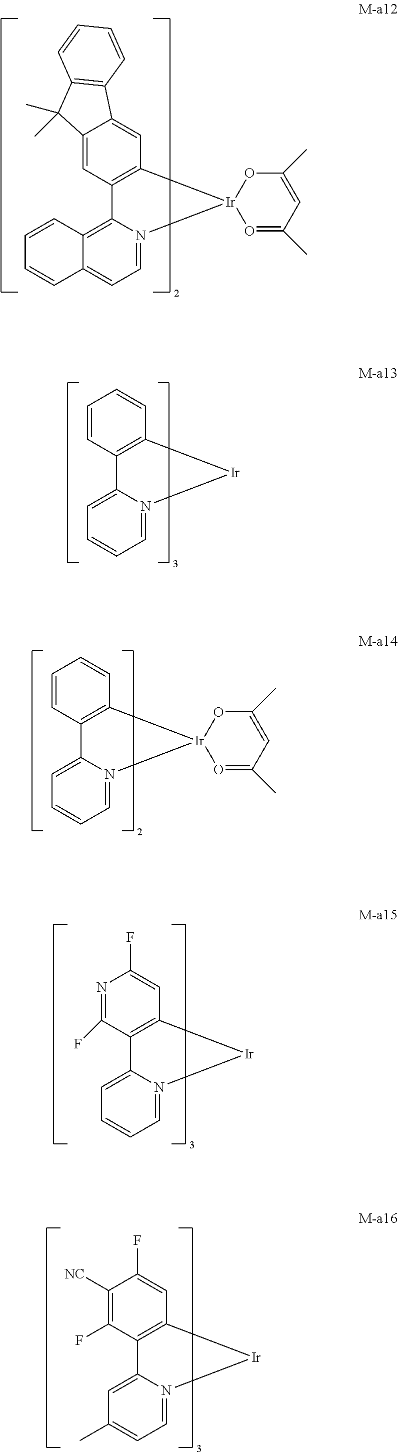

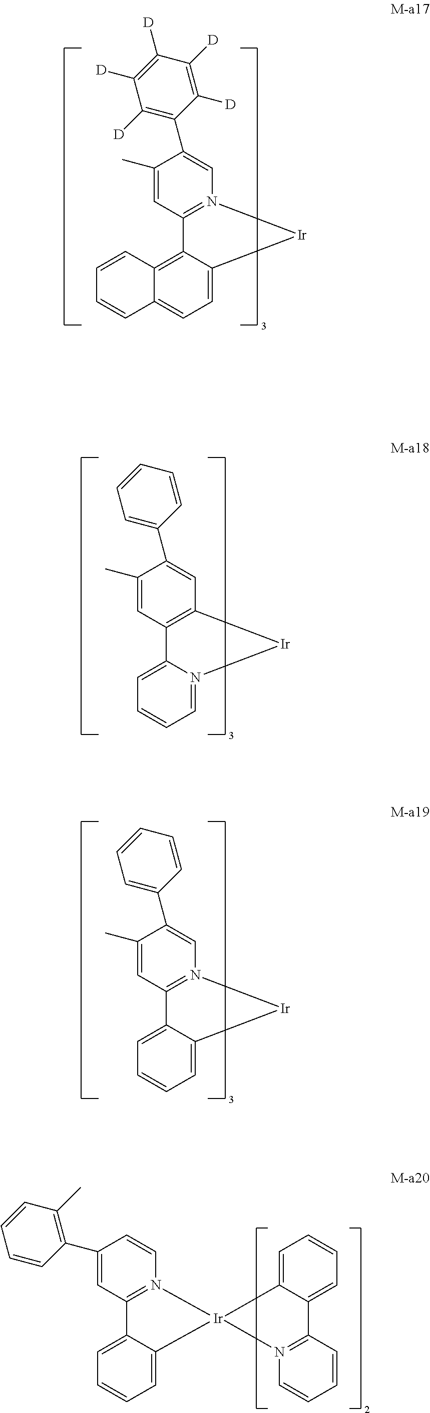

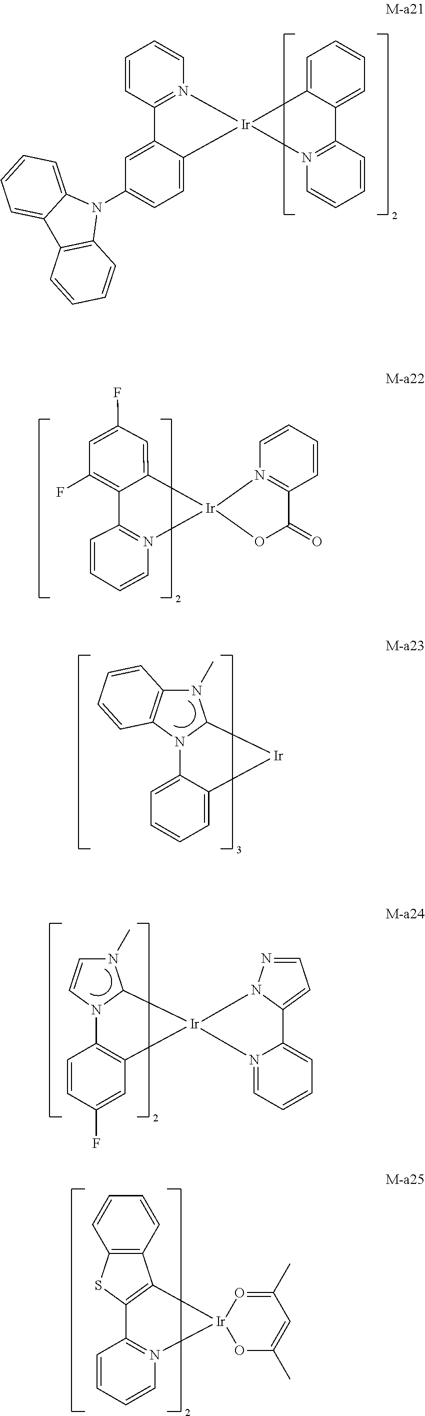

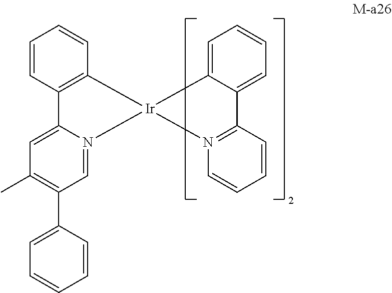

In an embodiment, the light emitting element ED may include multiple emission layers.

The emission layers may be provided as a stack, so that a light emitting element ED including multiple emission layers may emit white light. The light emitting element ED including multiple emission layers may be a light emitting element having a tandem structure. If the light emitting element ED includes multiple emission layers, at least one emission layer EML may include the first compound represented by Formula 1. For example, if the light emitting element ED includes multiple emission layers, at least one emission layer EML may include the first compound, the second compound, the third compound, and the fourth compound.

In the light emitting element ED, if the emission layer EML includes the first compound, the second compound, the third compound, and the fourth compound, an amount of the first compound may be in a range of about 0.1 wt % to about 5 wt %, based on a total weight of the first compound, the second compound, the third compound, and the fourth compound. However, embodiments are not limited thereto. If an amount of the first compound satisfies the above-described range, energy transfer from the second compound and the third compound to the first compound may increase, and accordingly, the emission efficiency and device lifetime may increase.

In the emission layer EML, a total amount of the second compound and the third compound may be the remainder of the total weight of the first compound, the second compound, the third compound, and the fourth compound, excluding the amount of the first compound and the fourth compound. For example, a combined amount of the second compound and the third compound may be in a range of about 65 wt % to about 95 wt %, based on a total weight of the first compound, the second compound, the third compound, and the fourth compound.

Within the combined amount of the second compound and the third compound in the emission layer EML, a weight ratio of the second compound to the third compound may be in a range of about 3:7 to about 7:3.

If the amounts of the second compound and the third compound satisfy the above-described ranges and ratios, charge balance properties in the emission layer EML may be improved, and emission efficiency and device lifetime may be improved. If the amounts of the second compound and the third compound deviates from the above-described ranges and ratios, charge balance in the emission layer EML may not be achieved, so that emission efficiency may be reduced, and the device may readily deteriorate.

If the emission layer EML includes the fourth compound, an amount of the fourth compound may be in a range of about 4 wt % to 30 wt %, based on a total weight of the first compound, the second compound, the third compound, and the fourth compound in the emission layer EML. However, embodiments are not limited thereto. If an amount of the fourth compound satisfies the above-described range, energy transfer from a host to the first compound, which is a light emitting dopant, may increase, so that an emission ratio may improve.

Accordingly, emission efficiency of the emission layer EML may improve. If the amounts of the first compound, the second compound, the third compound, and the fourth compound included in the emission layer EML satisfy the above-described ranges and ratios, excellent emission efficiency and long lifetime may be achieved.

In the light emitting element ED according to an embodiment, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in each of FIG. 3 to FIG. 6, the emission layer EML may further include a host and a dopant of the related art, in addition to the above-described host and dopant.

In an embodiment, the emission layer EML may include a compound represented by Formula E-1. The compound represented by Formula E-1 may be used as a fluorescence host material.

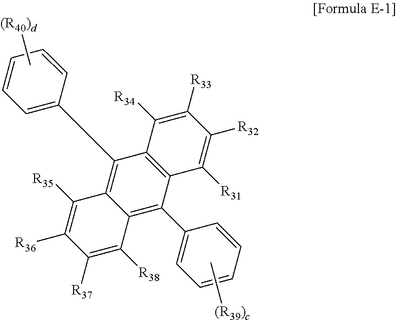

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19.

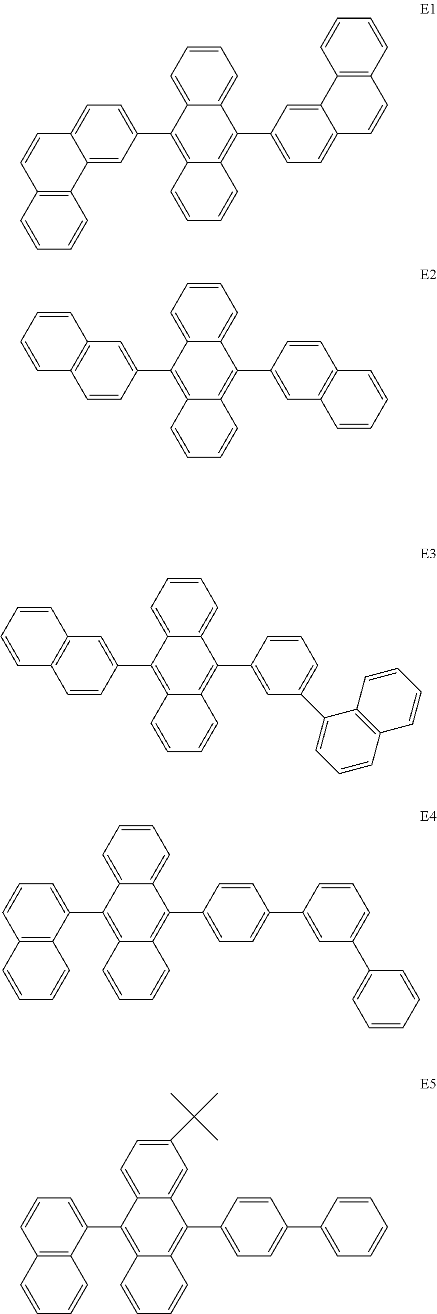

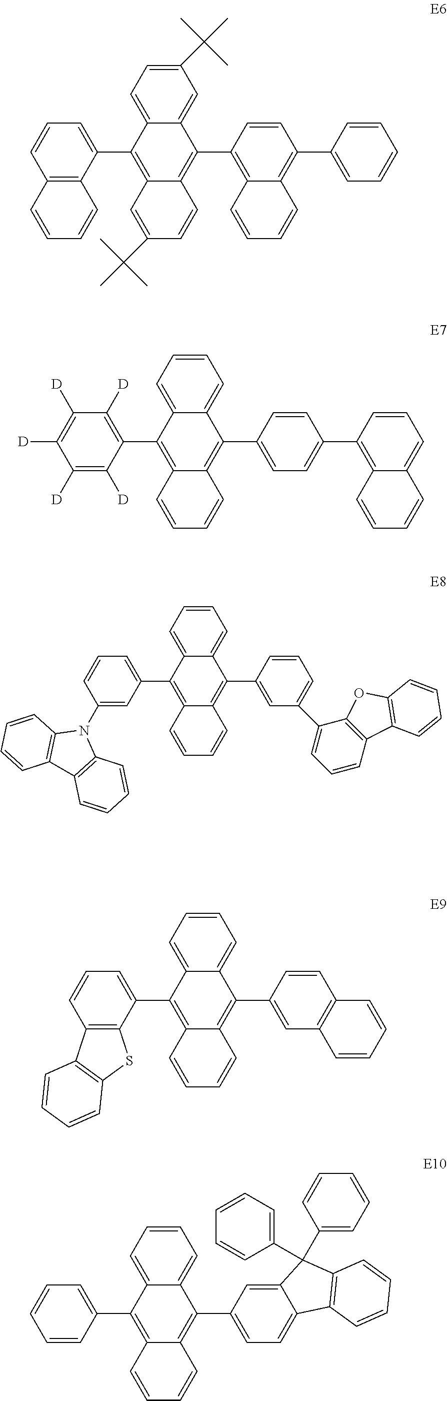

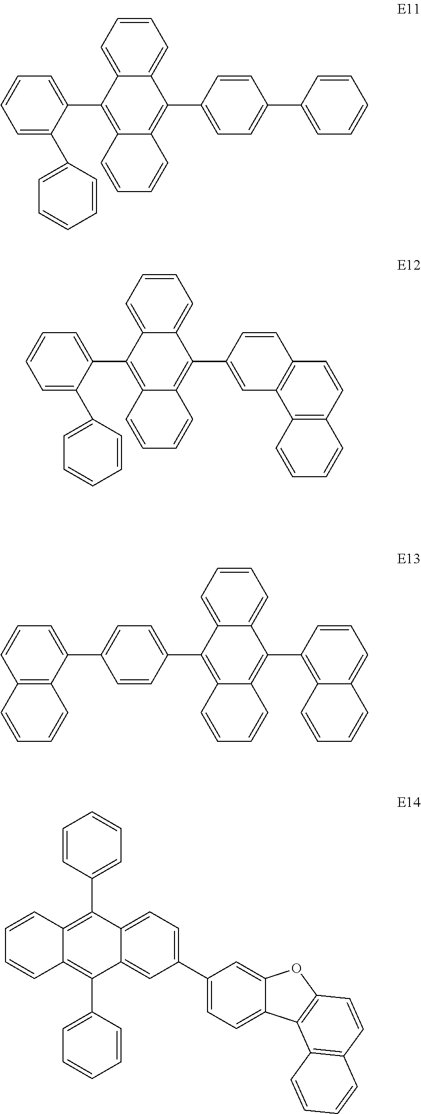

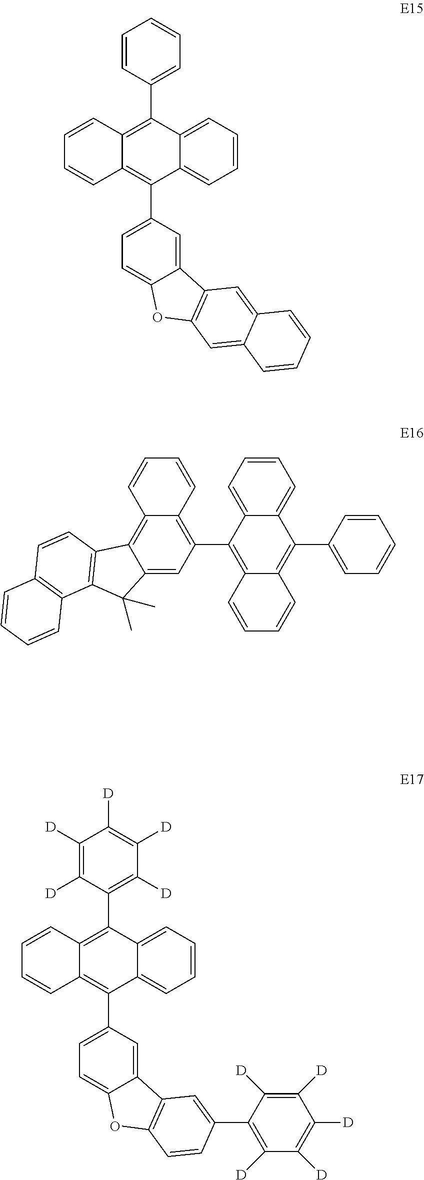

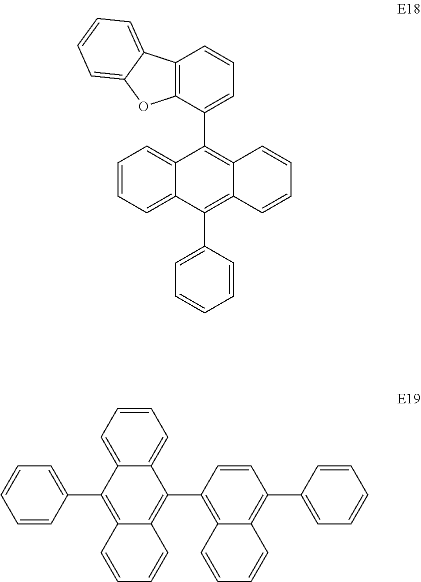

In an embodiment, the emission layer EML may include a compound represented by Formula E-2a or Formula E-2b. The compound represented by Formula E-2a or Formula E-2b may be used as a phosphorescence host material.

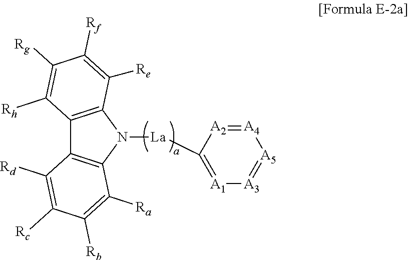

In Formula E-2a, a may be an integer from 0 to 10; Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is equal to or greater than 2, multiple Lₐ groups may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ).

In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or bonded to an adjacent group to form a ring. For example, Rₐ to Rᵢ may be bonded to an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

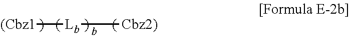

In Formula E-2b, Cbz1 and Cbz2 may each independently be an unsubstituted carbazole group or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms.

In Formula E-2b, b may be an integer from 0 to 10, and if b is equal to or greater than 2, multiple L_{b} groups may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2.

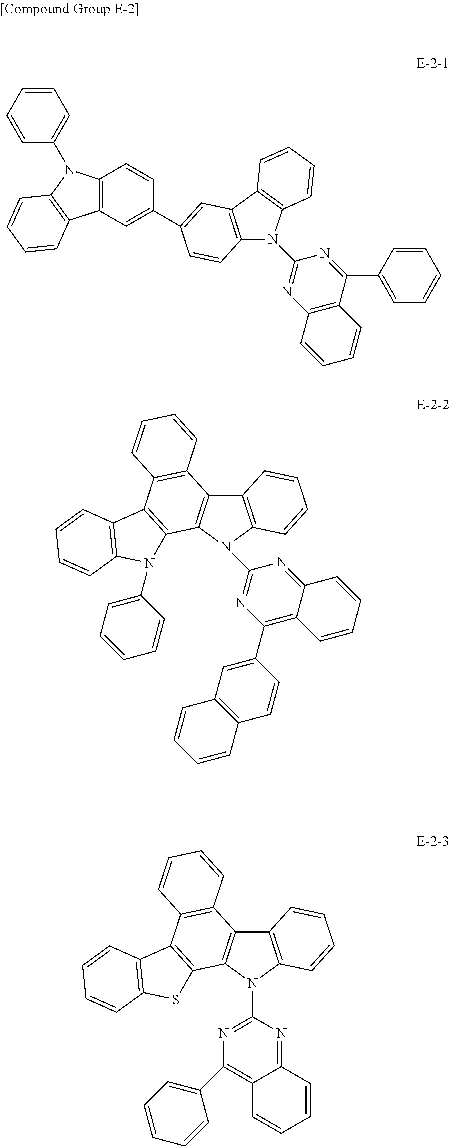 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

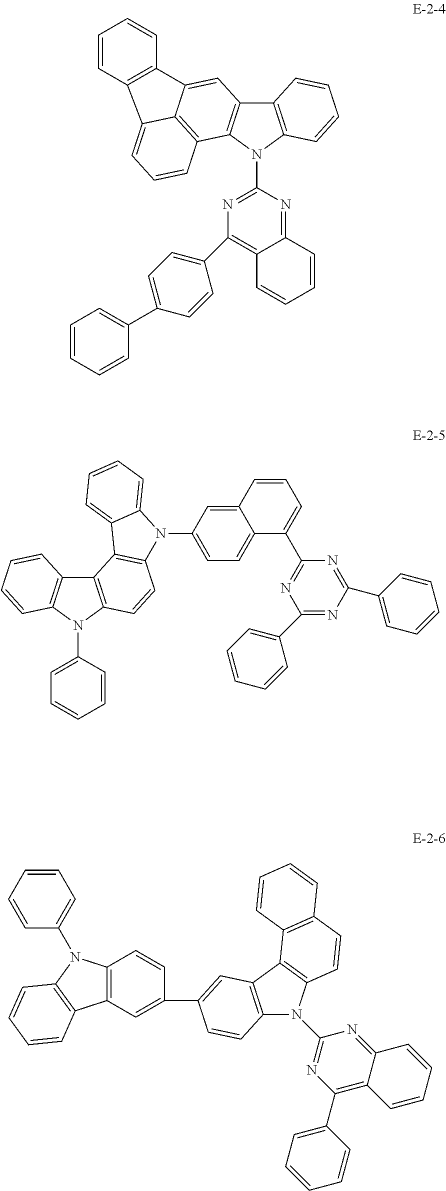 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

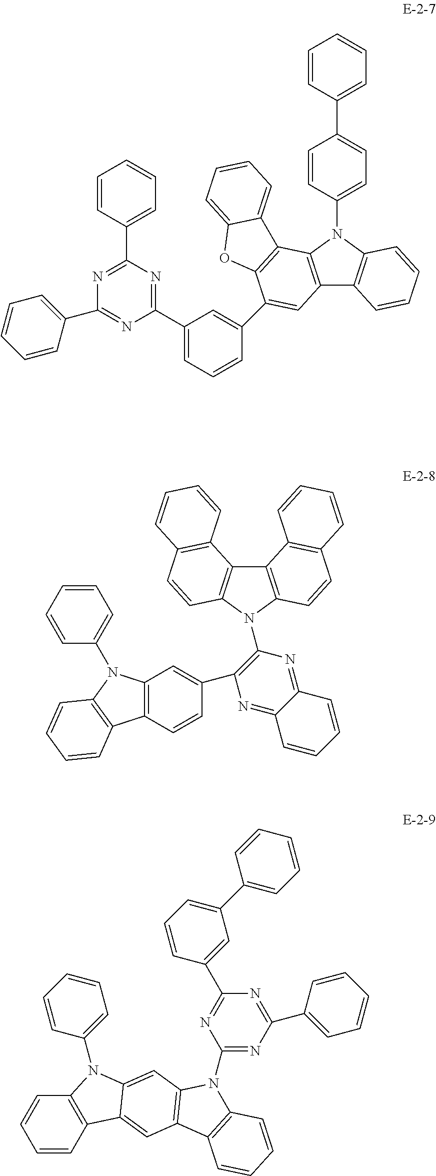 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

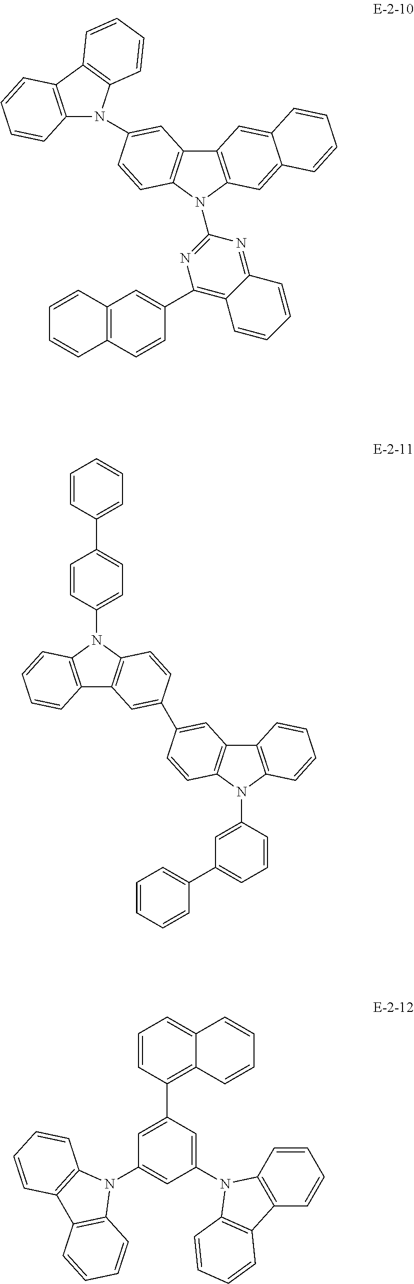 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

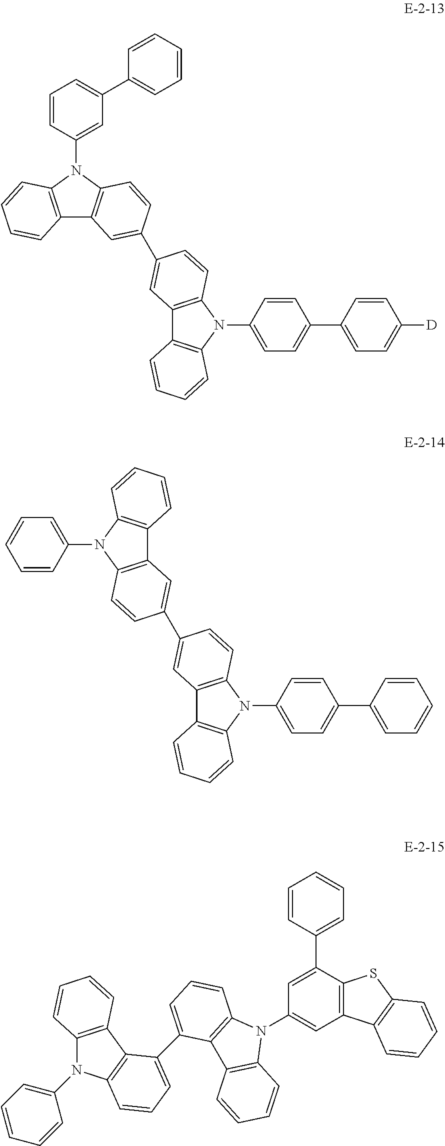 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

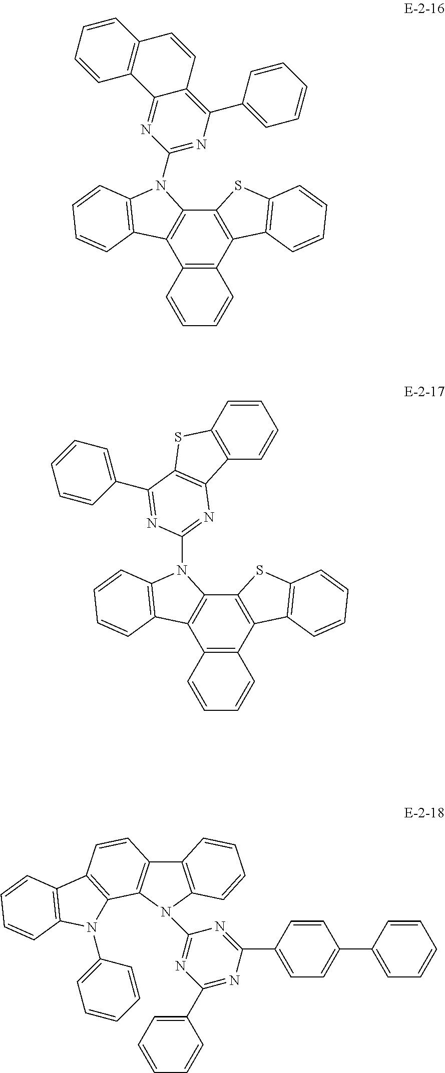 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

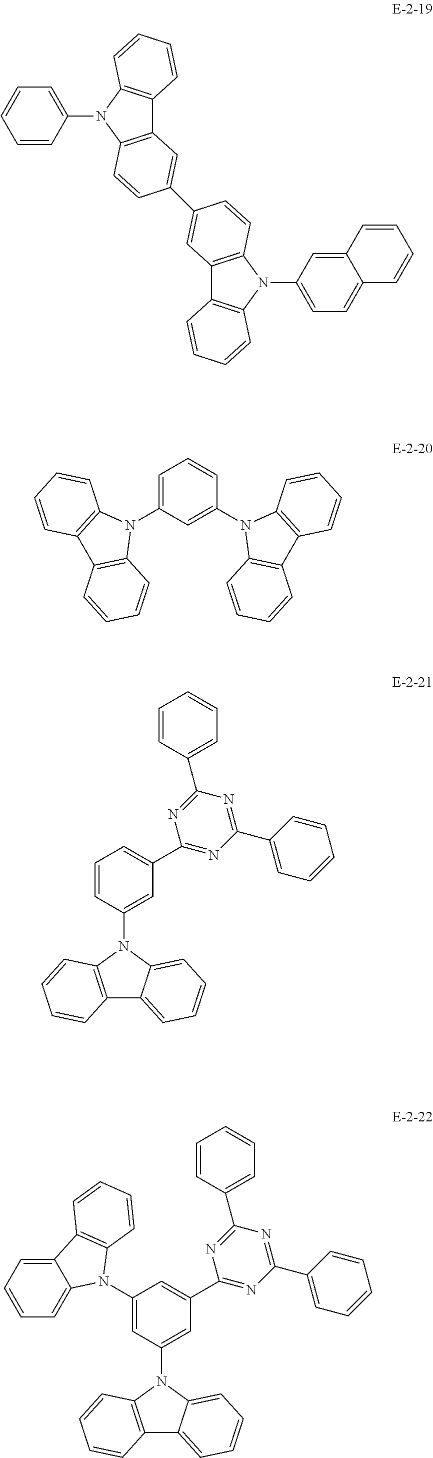 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

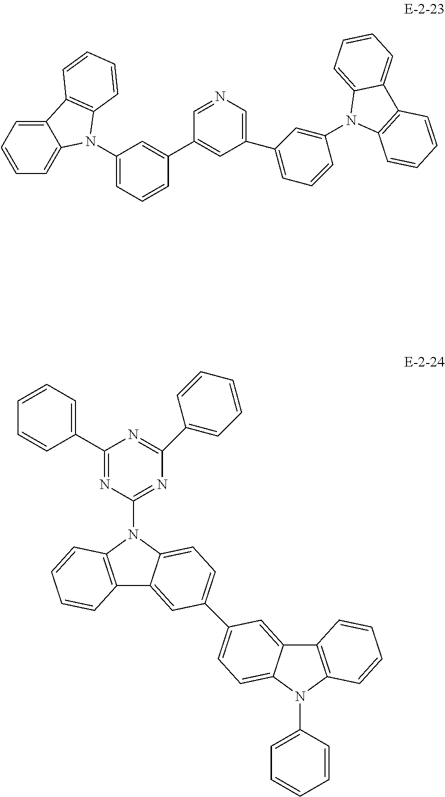 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolinato)aluminum (Alq₃), 9,10-di(naphthalene-2-yl)anthracene (AdN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

In an embodiment, the emission layer EML may include a compound represented by Formula D-1. The compound represented by Formula M-a may be used as a phosphorescence dopant material or phosphorescence sensitizer material.

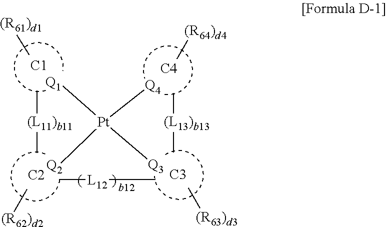

In Formula D-1, Q₁ to Q₄ may each independently be C or N.

In Formula D-1, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₁₁ to L₁₃ may each independently be a direct linkage,

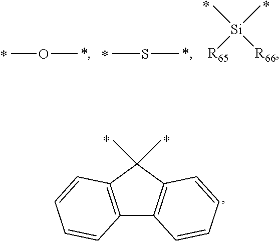

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃,

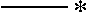

represent a bond connected with C1 to C4.

In Formula D-1, b11 to b13 may each independently be 0 or 1. If b11 is 0, C1 and C2 may not be directly linked to each other. If b12 is 0, C2 and C3 may not be directly linked to each other. If b3 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In another example, R₆₁ to R₆₆ may each be bonded to an adjacent group to form a ring. For example, R₆₁ to R₆₆ may each be independently a substituted or unsubstituted methyl group, or a substituted or unsubstituted t-butyl group.

In Formula D-1, d1 to d4 may each independently be an integer from 0 to 4. If d1 to d4 are each 0, the fourth compound may be unsubstituted with any of R₆₁ to R₆₄. A case where d1 to d4 are each 4, and groups of each of R₆₁ to R₆₄ are hydrogen atoms may be the same as a case where d1 to d4 are each 0. If d1 to d4 are each equal to or greater than 2, groups of each of R₆₁ to R₆₄ may be all the same as each other, or at least one group thereof may be different from the remainder.

In an embodiment, in Formula D-1, C1 to C4 may each independently be a substituted or unsubstituted hydrocarbon ring or a substituted or unsubstituted heterocycle that is represented by any one of Formula C-1 to Formula C-4.

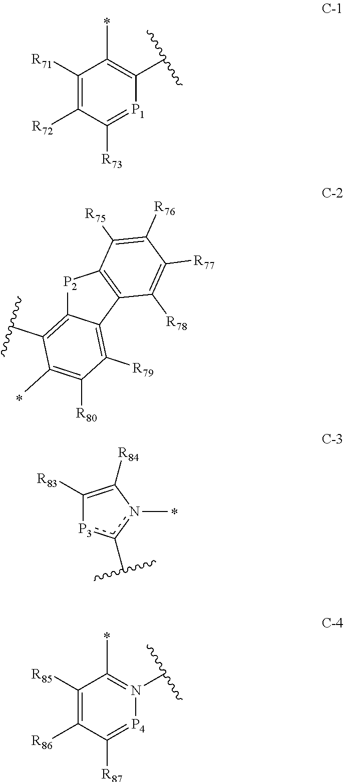

In Formula C-1 to Formula C-4, P₁ may be

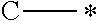

or C(R₇₄), P₂ may be

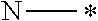

or N(R₈₁), P₃ may be

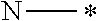

or N(R₈₂), and P₄ may be

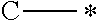

### or C(R₈₈).

In Formula C-1 to Formula C-4, R₇₁ to Rss may each independently be a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or bonded to an adjacent group to form a ring.

In Formula C-1 to Formula C-4,

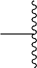

represents a bond to a central metal atom of Pt, and

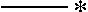

represents a bond to an adjacent cyclic group (C1 to C4) or to linker (L₁₁ to L₁₃).

In an embodiment, the compound represented by Formula D-1 may be any compound selected from Compounds AD-01 to AD-40. However, Compounds AD-01 to AD-40 are only examples, and the compound represented by Formula D-1 is not limited to the compounds represented by Compounds AD-01 to AD-40.

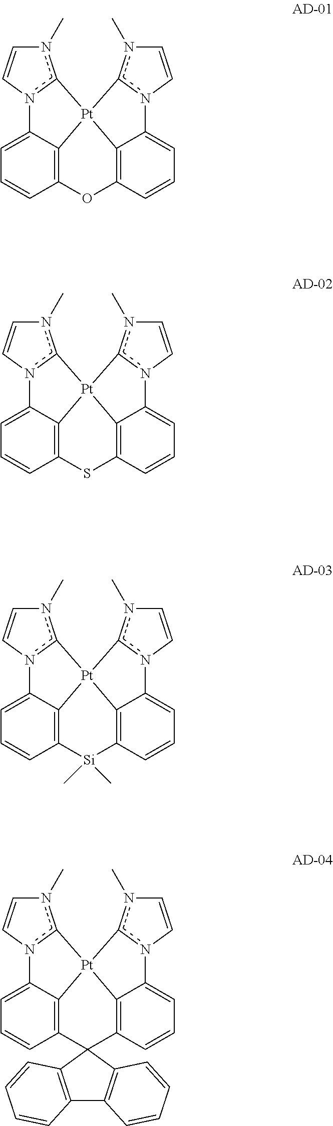

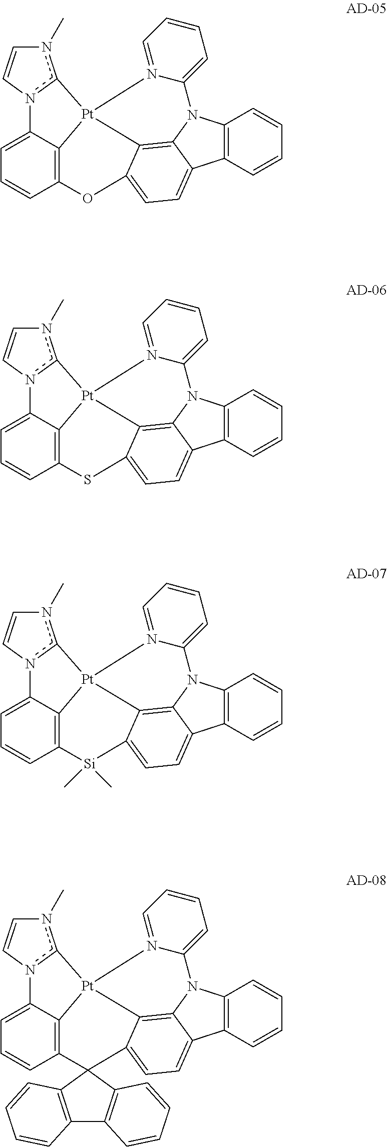

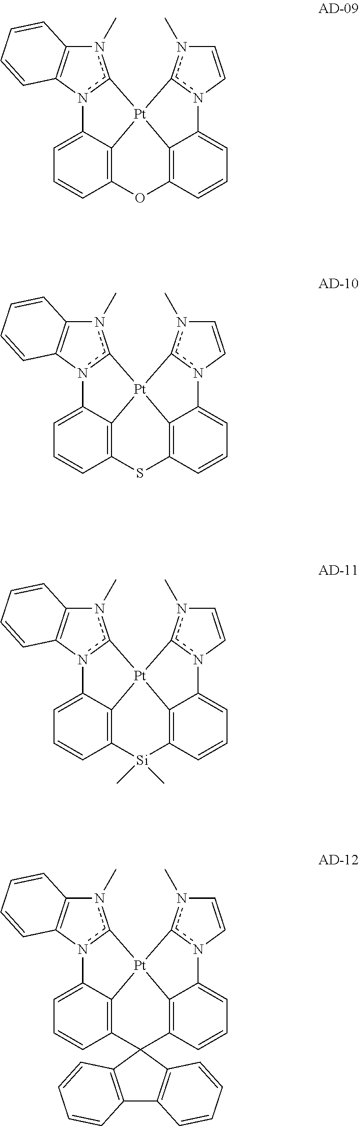

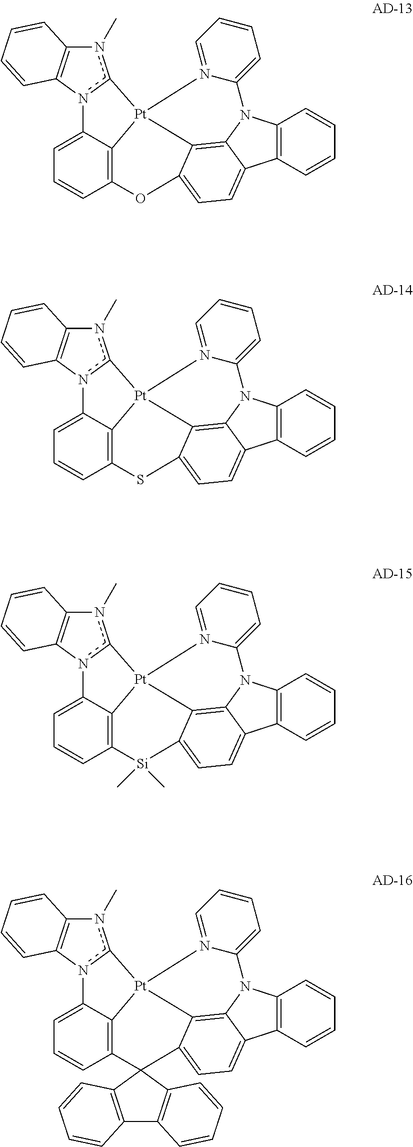

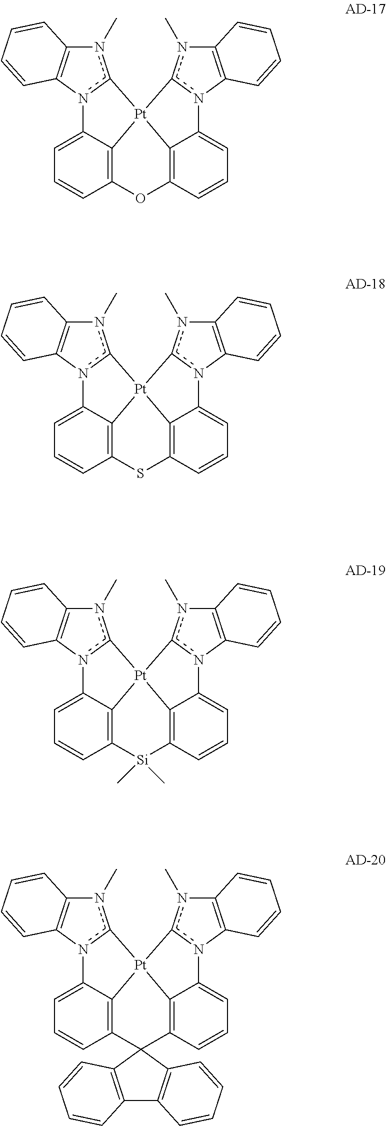

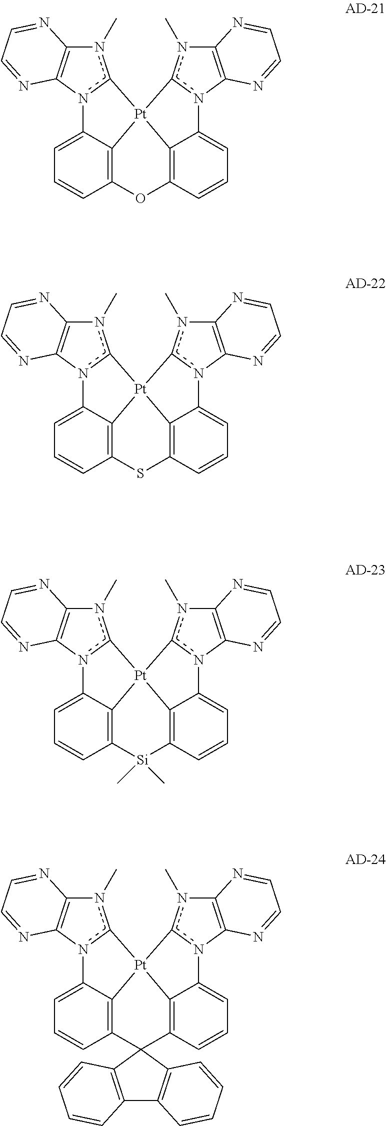

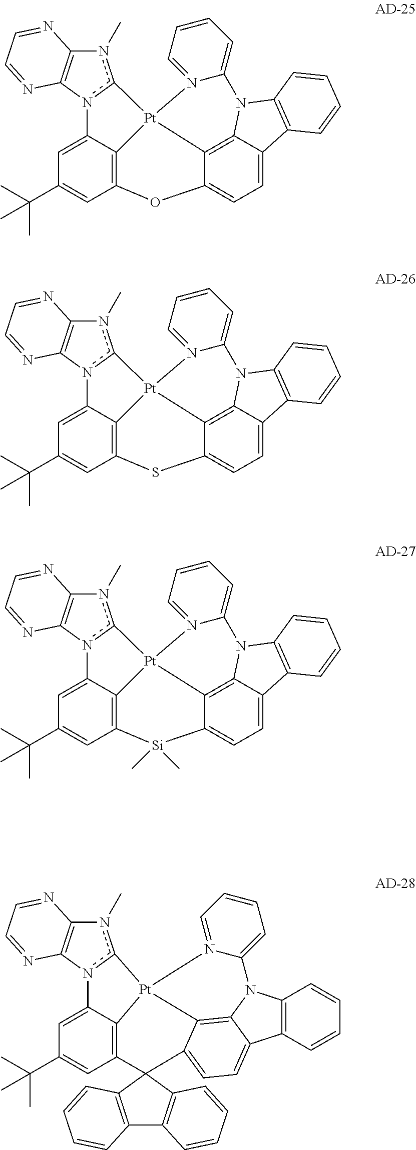

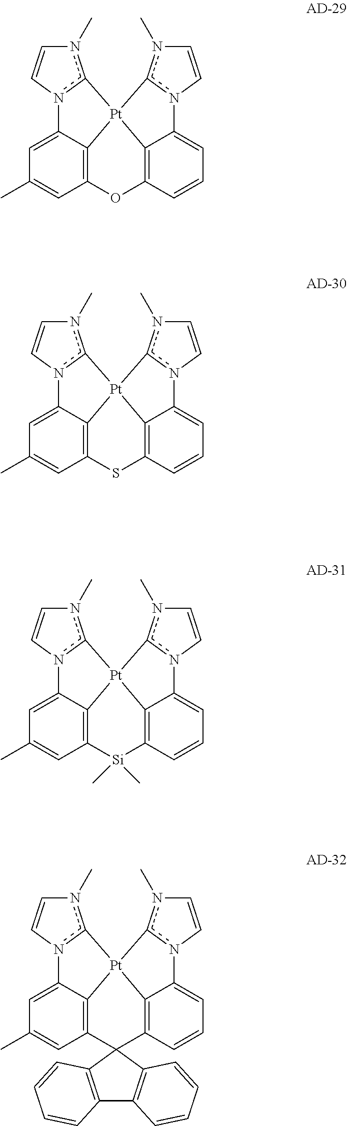

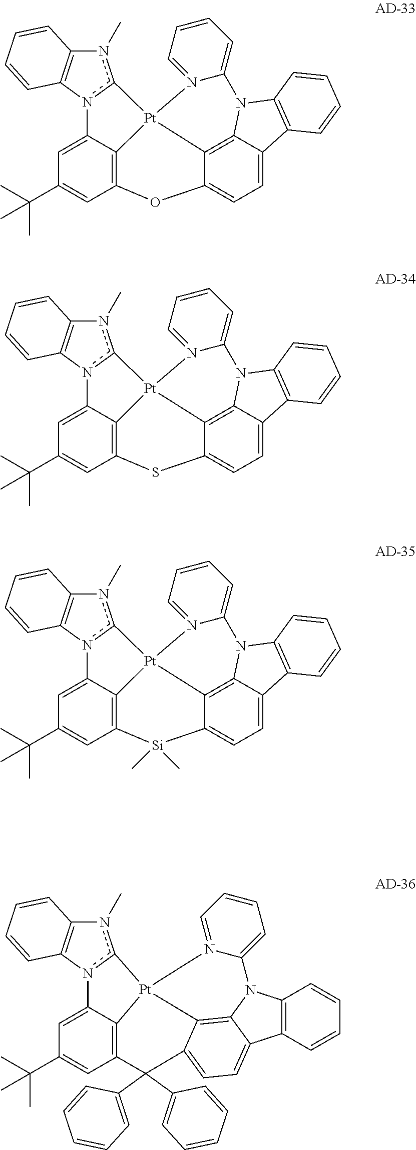

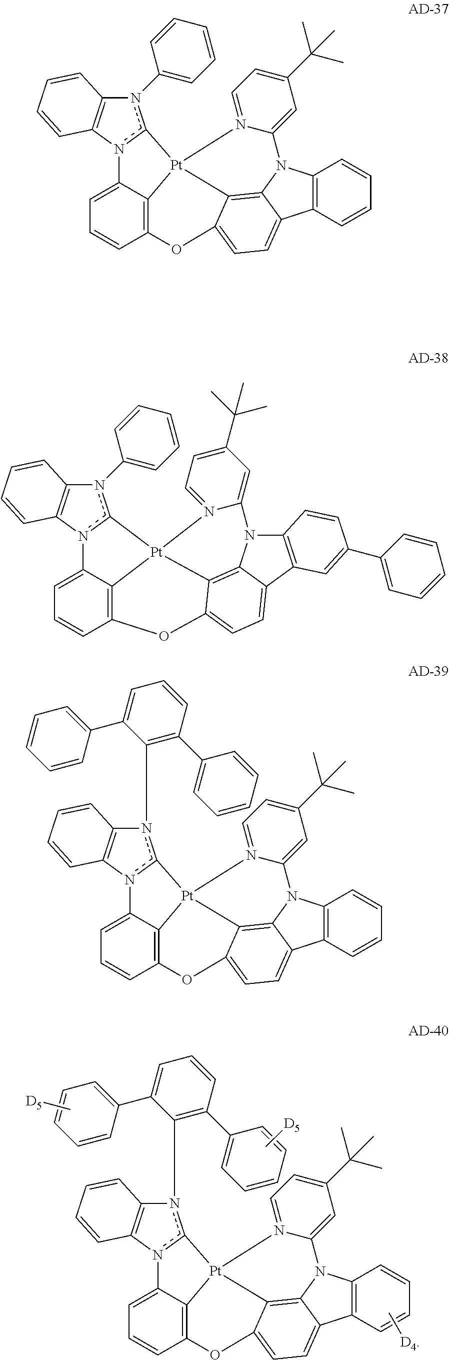

In Compound Group 4, D represents a deuterium atom.

In an embodiment, the emission layer EML may further include a compound represented by one of Formula F-a to Formula F-c. The compounds represented by one of Formula F-a to Formula F-c may be used as fluorescence dopant materials.

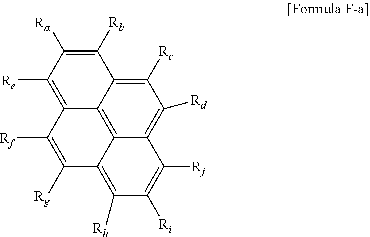

In Formula F-a, two of Rₐ to Rⱼ may each independently be substituted with a group represented by

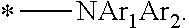

The remainder of Rₐ to Rⱼ which are not substituted with the group represented by

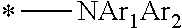

may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by

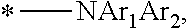

A₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of A₁ and Ar₂ may be a heteroaryl group including O or S as a ring-forming atom.

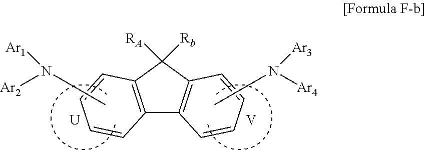

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or bonded to an adjacent group to form a ring.

In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at the part indicated by U or V, and if the number of U or V is 0, a fused ring may not be present at the part indicated by U or V. If the number of U is 0 and the number of V is 1, or if the number of U is 1 and the number of V is 0, a fused ring having a fluorene core of Formula F-b may be a cyclic compound with four rings. If the number of U and V is each 0, a fused ring having a fluorene core of Formula F-b may be a cyclic compound with three rings. If the number of U and V is each 1, a fused ring having the fluorene core of Formula F-b may be a cyclic compound with five rings.

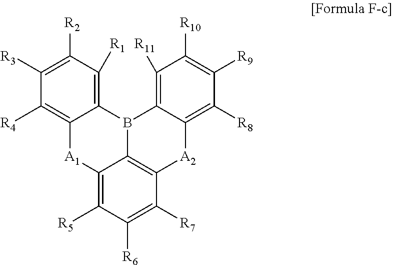

In Formula F-c, A₁ and A₂ may each independently be O, S, Se, or N(Rₘ), and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or bonded to an adjacent group to form a ring.

In Formula F-c, A₁ and A₂ may each independently be bonded to a substituent of an adjacent ring to form a fused ring. For example, if A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, styryl derivatives (for example, 1,4-bis [2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and a derivative thereof (for example, 2,5,8,11-tetra-t-butylperylene (TBP)), pyrene and a derivative thereof (for example, 1,1-dipyrene, 1,4-dipyrenylbenzene, or 1,4-bis(N,N-diphenylamino)pyrene), etc.

The emission layer EML may include a phosphorescence dopant material of the related art. For example, the phosphorescence dopant may use a metal complex such as iridium (Ir), platinum (Pt), osmium (Os), gold (Au), titanium (Ti), zirconium (Zr), hafnium (Hf), europium (Eu), terbium (Tb), or thulium (tm). For example, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, embodiments are not limited thereto.

In an embodiment, the emission layer EML may include a quantum dot. The quantum dot may be a crystal of a semiconductor compound. The quantum dot may emit light of various emission wavelengths, according to a size of the crystal. The quantum dot may emit light of various emission wavelengths by adjusting an elemental ratio in a quantum dot compound.

A diameter of the quantum dot may be, for example, in a range of about 1 nm to about 10 nm.

The quantum dot may be synthesized by a chemical bath deposition, a metal organic chemical vapor deposition, a molecular beam epitaxy, or a similar process therewith.

The chemical bath deposition is a method of mixing an organic solvent and a precursor material and growing a quantum dot particle crystal. While growing the crystal, the organic solvent may naturally serve as a dispersant which is coordinated on the surface of the quantum dot crystal and may control the growth of the crystal. Accordingly, the chemical bath deposition is more advantageous when compared to a vapor deposition method including a metal organic chemical vapor deposition (MOCVD) and molecular beam epitaxy (MBE), and the growth of the quantum dot particle may be controlled through a low-cost process.

The quantum dot maybe a Group II-VI compound, a Group III-VI compound, a Group 1-III-VI compound, a Group III-V compound, a Group III-II-V compound, a Group IV-VI compound, a Group IV element, a Group IV compound, or combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, or a mixture thereof. In an embodiment, the Group II-VI compound may further include a Group I element and/or a Group IV element. Examples of a Group 1-II-VI compound may include: CuSnS or CuZnS, and examples of a Group II-IV-VI compound may include: ZnSnS and the like. Examples of a Group I-II-IV-VI compound may include a quaternary compounds selected from the group consisting of Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S3 and In₂Se₃; a ternary compound such as InGaS₃, and InGaSe₃; or any combination thereof.

Examples of a Group 1-III-VI compound may include: a ternary compound such as AgInS, AgInS₂, CuInS, CuInS₂, AgGaS₂, CuGaS₂, CuGaO₂, AgGaO₂, AgAlO₂; a quaternary compound such as AgInGaS₂ and CuInGaS₂; or any combination thereof.

Examples of a Group III-V compound may include: a binary compound such as GaN, GaP, GaAs, GaSb, AlN, AlP, AlAs, AlSb, InN, InP, InAs, InSb; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb; or any combination thereof. The Group III-V compound may further include a Group II metal. For example, InZnP, etc. may be selected as a III-II-V group compound.

Examples of a Group IV-VI compound may include: a binary compound such as SnS, SnSe, SnTe, PbS, PbSe, PbTe; a ternary compound such as SnSeS, SnSeTe, SnSTe, PbSeS, PbSeTe, PbSTe, SnPbS, SnPbSe, SnPbTe; a quaternary compound such as SnPbSSe, SnPbSeTe, SnPbSTe; or any combination thereof.

Examples of a Group II-IV-V compound may include: a ternary compound such as ZnSnP, ZnSnP₂, ZnSnAs2, ZnGeP₂, ZnGeAs₂, CdSnP₂, CdGeP₂; or any combination thereof.

Examples of a Group IV element may include: Si, Ge, and a mixture thereof. Examples of a Group IV compound may include a binary compound such as SiC, SiGe, or any combination thereof.

Each element in the multi-element compound, such as the binary compound, ternary compound, and quaternary compound, may be present in particles at a uniform concentration or at a non-uniform concentration. For example, a formula may indicate the elements in a compound, but an elemental ratios in the compound may be different. For example, AgInGaS₂ may indicate AgInₓGa₁₋ₓS₂ (x is a real number from 0 and 1).

In an embodiment, the binary compound, the ternary compound, or the quaternary compound may be present at uniform concentration in a particle or may be present at a partially different concentration distribution state in the same particle. For example, a core/shell structure in which one quantum dot surrounds another quantum dot may be possible. The interface of the core and the shell may have a concentration gradient in which the concentration of an element that is present in the shell decreases toward the core.

In embodiments, the quantum dot may have the core-shell structure including a core including a nanocrystal and a shell surrounding the core. The shell of the quantum dot may play the role of a protection layer for preventing the chemical deformation of the core to maintain semiconductor properties and/or a charging layer for imparting the quantum dot with electrophoretic properties. The shell may have a single layer or a multilayer. Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a ternary compound such as MgAl₂O₄, CoFe₂O₄, NiFe₂O₄, and CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of emission wavelength spectrum equal to or less than about 40 nm. For example, the quantum dot may have a FWHM of emission wavelength spectrum equal to or less than about 30 nm. Within any of the above ranges, color purity or color reproducibility may be improved. Light emitted via a quantum dot may be emitted in all directions, so that light view angle properties may be improved.

The shape of a quantum dot may not be particularly limited. For example, the quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

As a size of the quantum dot or an elemental ratio of a quantum dot compound is regulated, the energy band gap may be accordingly controlled to obtain light in various wavelengths from a quantum dot emission layer. Therefore, by using a quantum dot as described (using a quantum dot of different sizes or having different elemental ratios of a quantum dot compound), a light emitting element emitting light of various wavelengths may be obtained. For example, a size of a quantum dot or an elemental ratio of a quantum dot compound may each independently be regulated to emit red light, green light, and/or blue light. For example, the quantum dots may be configured to emit white light by combining light of various colors.

In the light emitting element ED according to an embodiment as shown in each of FIG. 3 to FIG. 6, the electron transport region ETR may be provided on the emission layer EML. The electron transport region ETR may include at least one of an electron blocking layer HBL, an electron transport layer ETL, and an electron injection layer EIL. However, embodiments are not limited thereto.

The electron transport region ETR may have a single layer formed of a single material, a single layer including multiple different materials, or a structure having multiple layers including multiple different materials.

For example, the electron transport region ETR may have a single layer structure of an electron injection layer EIL or an electron transport layer ETL, or a single layer structure formed of an electron injection material and an electron transport material. In other embodiments, the electron transport region ETR may have a single layer structure formed of different materials, or may have a structure in which an emission layer EML of electron transport layer ETL/electron injection layer EIL, or hole blocking layer HBL/electron transport layer ETL/electron injection layer EIL are stacked in its respective stated order from the emission layer EML, but embodiments are not limited thereto. For example, the thickness of the electron transport region ETR may be in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2.

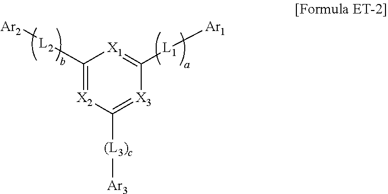

In Formula ET-2, at least one of X₁ to X₃ may each be N; and the remainder of X₁ to X₃ may each independently C(Rₐ). In Formula ET-2, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may each independently be an integer from 0 to 10.

In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each equal to or greater than 2, groups of each of L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (Balq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), CNNPTRZ (4′-(4-(4-(4,6-diphenyl-1,3,5-triazin-2-yl)phenyl)naphthalen-1-yl)-[1,1′-biphenyl]-4-carbonitrile), and mixtures thereof.

In an embodiment, the electron transport region ETR may include at least one compound selected from Compound Group 3.

In an embodiment, the electron transport region ETR may include at least one compound selected from Compounds ET1 to ET36.

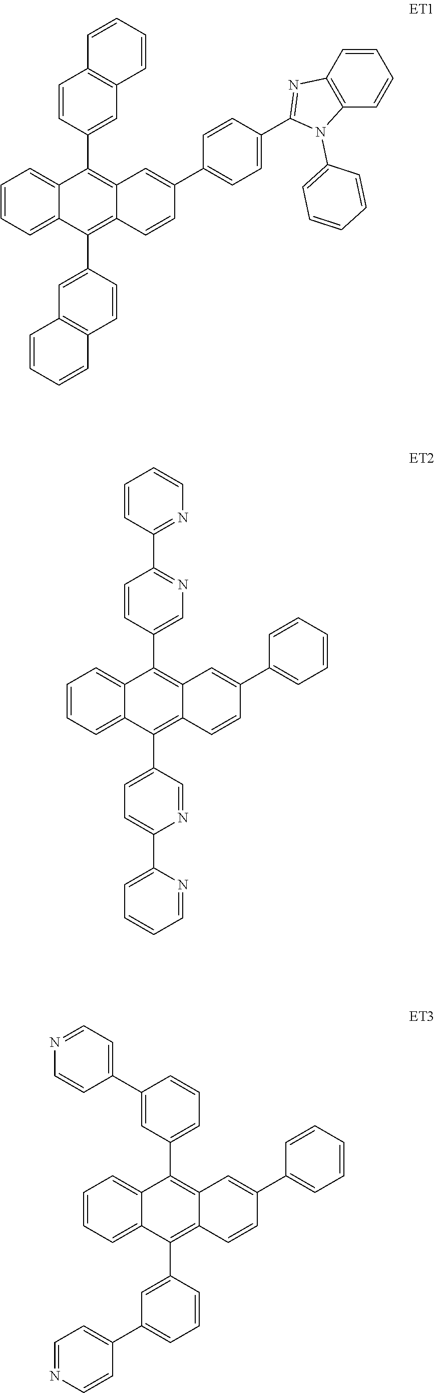 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

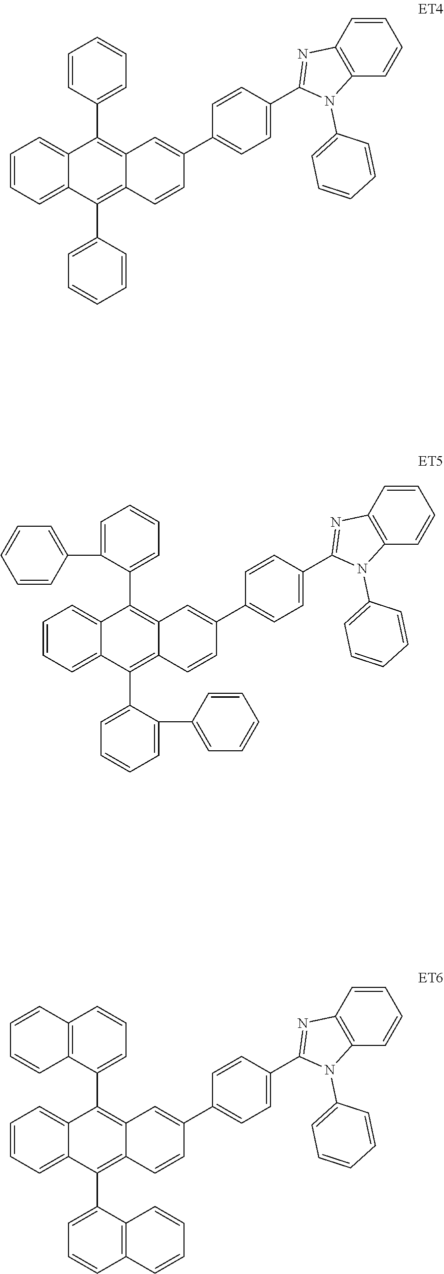 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

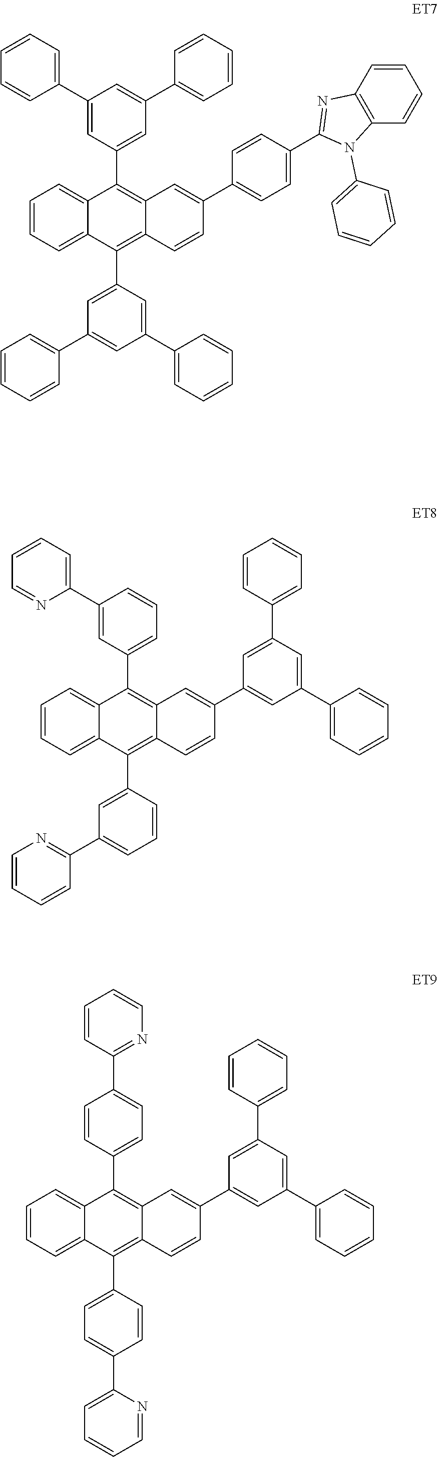 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

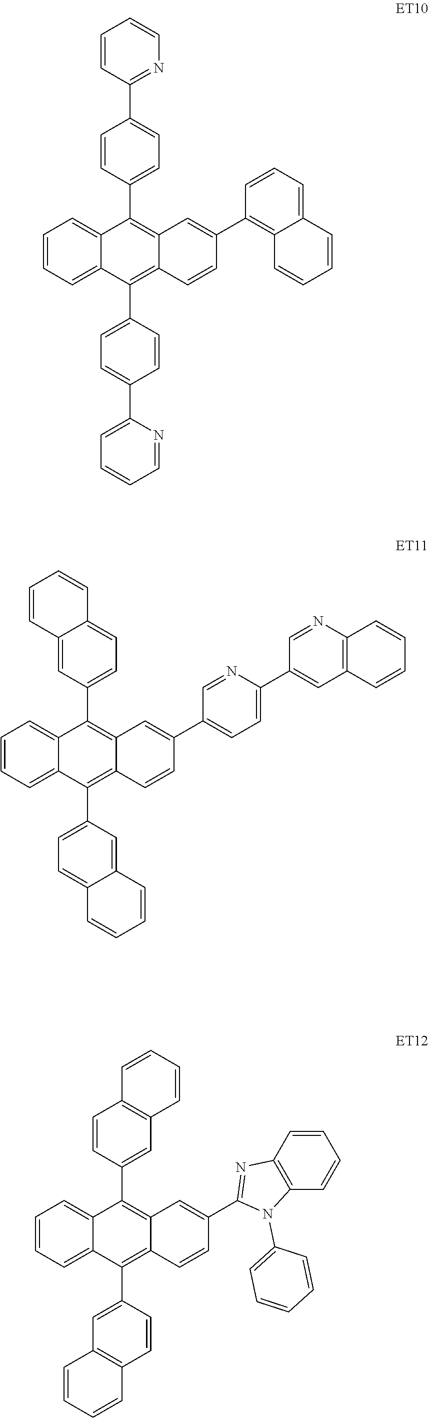 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

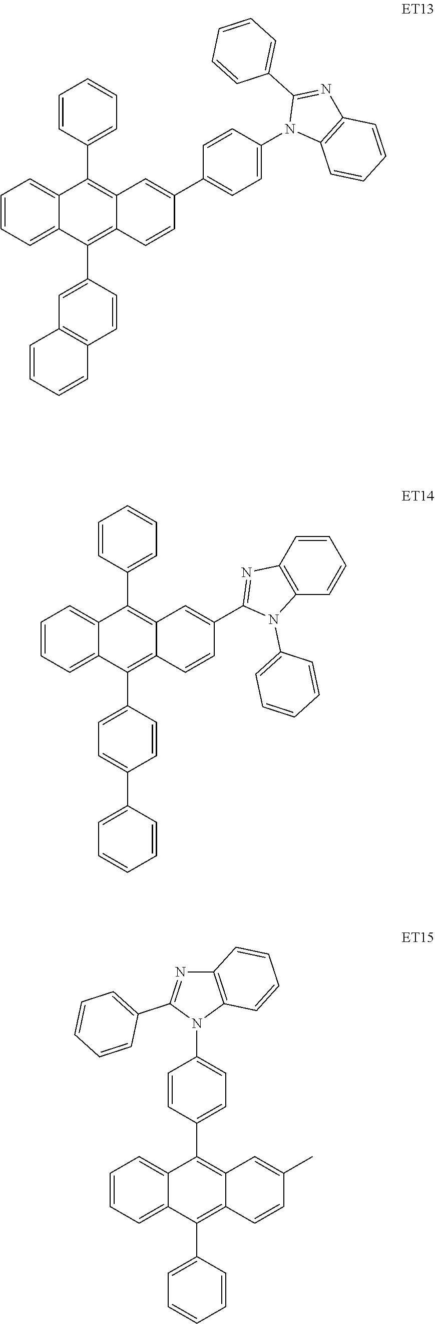 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

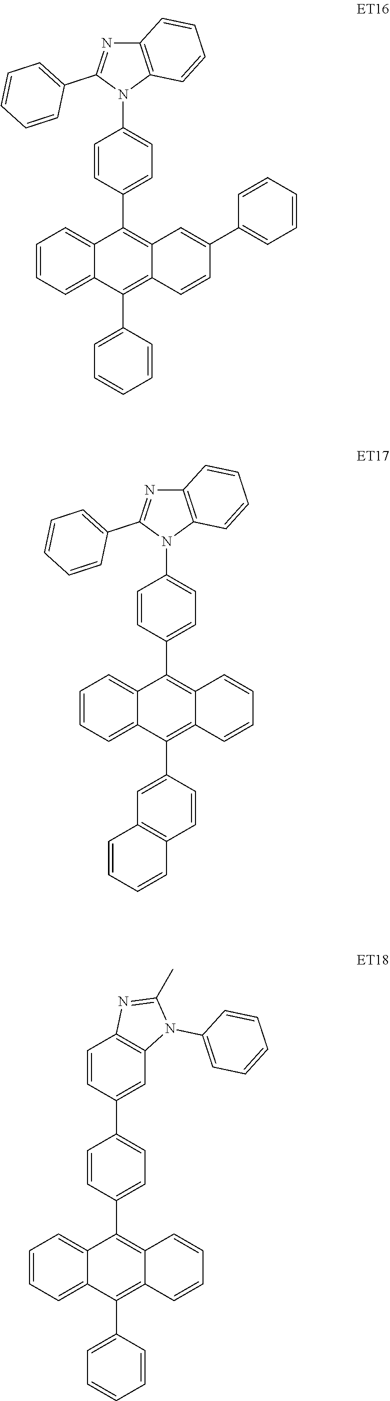 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

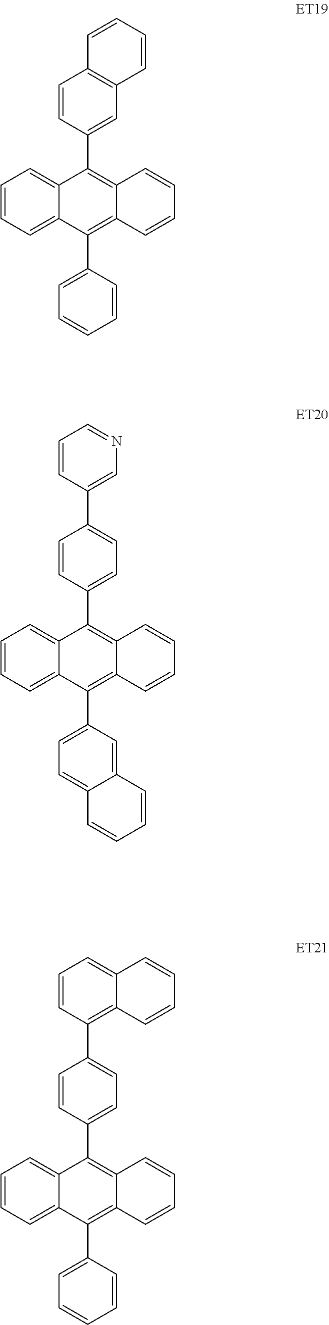

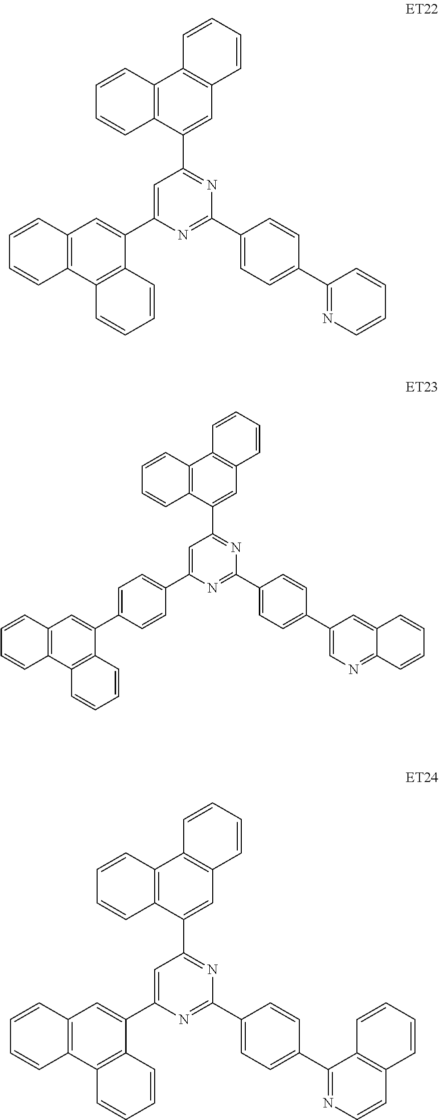 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

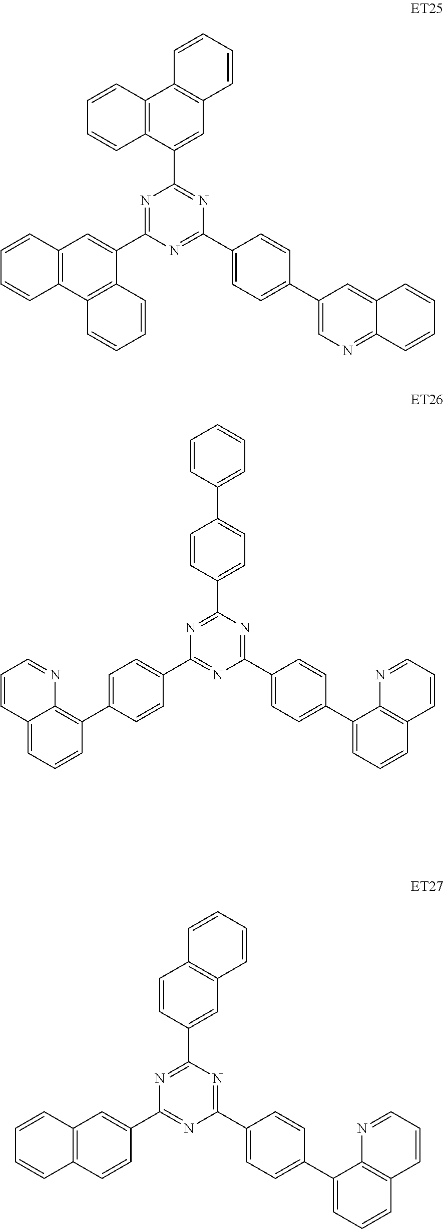 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

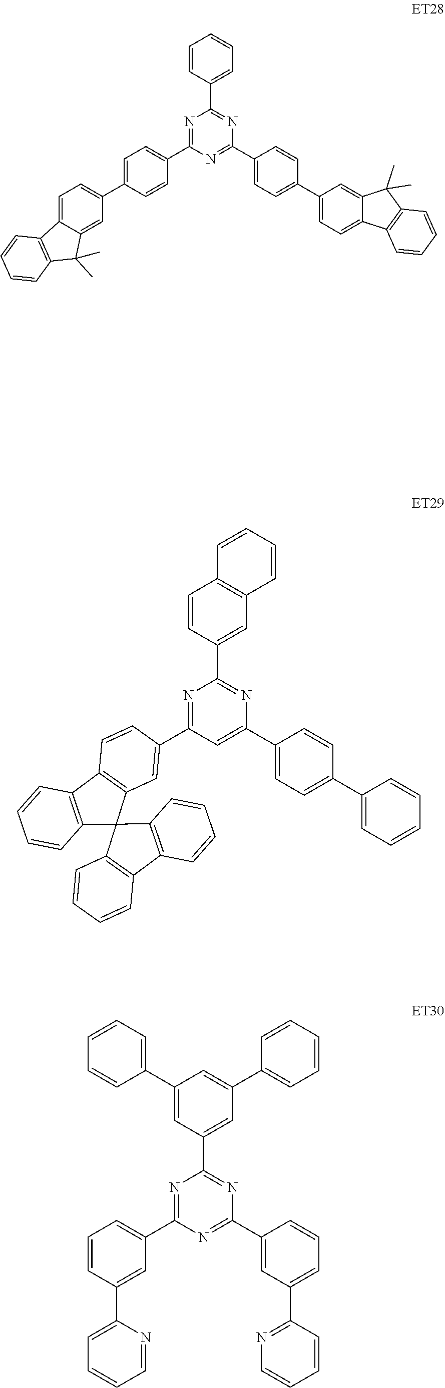 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

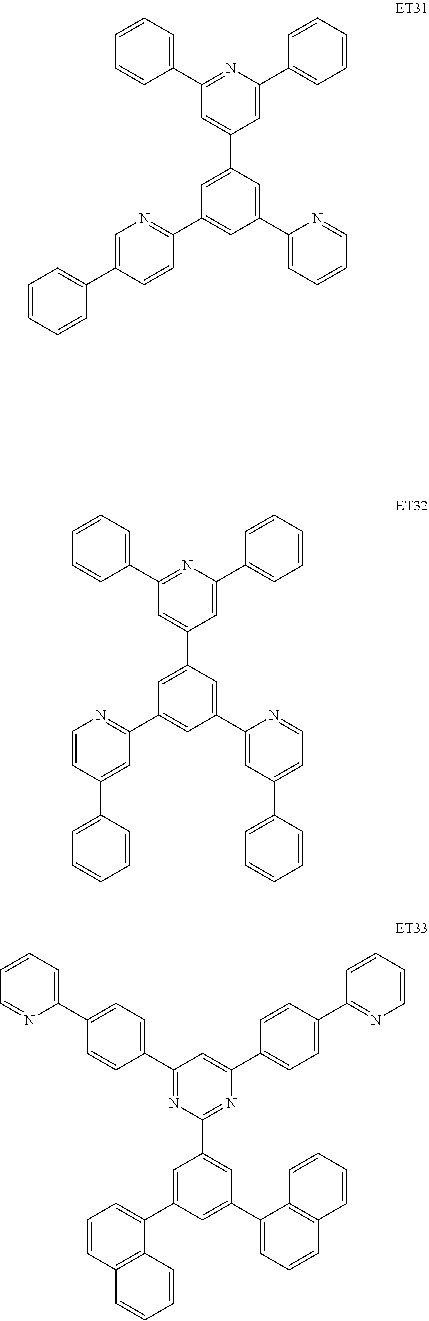 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

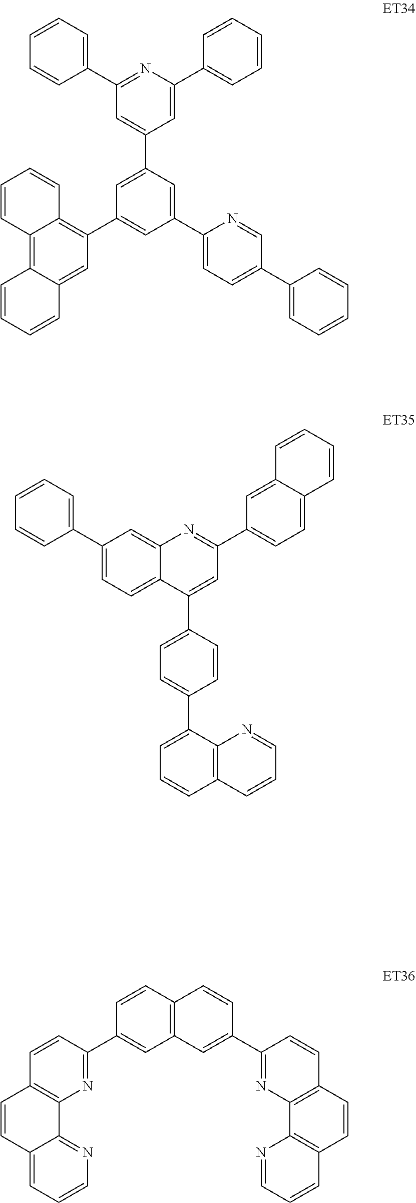 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxy-lithium quinolate (Liq). However, embodiments are not limited thereto. The electron transport region ETR also may be formed of a mixture material of an electron transport material and an insulating organometallic salt. The insulating organometallic salt may be a material having an energy band gap equal to or greater than about 4 eV. For example, the insulating organometallic salt may include metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, embodiments are not limited thereto.

The electron transport region ETR may include the compounds of the electron transport region in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies the above described ranges, satisfactory electron injection properties may be obtained without inducing a substantial increase of driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is a transmissive electrode, the second electrode EL2 may include a transparent metal oxide such as ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound including thereof, or a mixture thereof (for example, AgMg, AgYb, or MgYb). In an embodiment, the second electrode EL2 may have a multilayered structure including a reflective layer or a transflective layer formed of the above-described materials and a transparent conductive layer formed of ITO, IZO, ZnO, or ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include, a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or an acrylate such as methacrylate. In an embodiment, a capping layer CPL may include at least one of Compounds P1 to P5, but embodiments are not limited thereto.

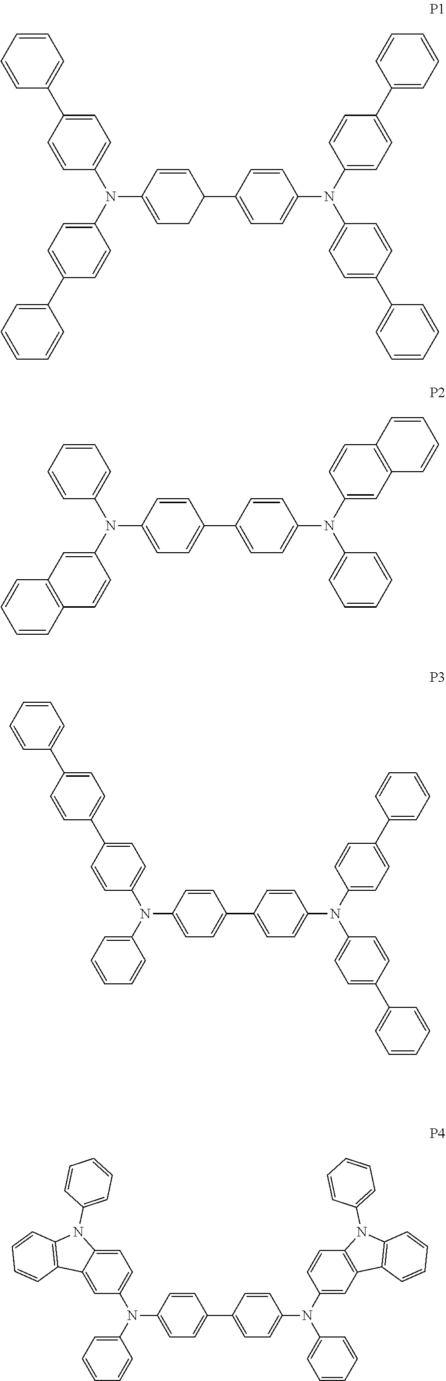 [SMILES: C1=CC(c2ccc(N(c3ccc(-c4ccccc4)cc3)c3ccc(-c4ccccc4)cc3)cc2)CC=C1N(c1ccc(-c2ccccc2)cc1)c1ccc(-c2ccccc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

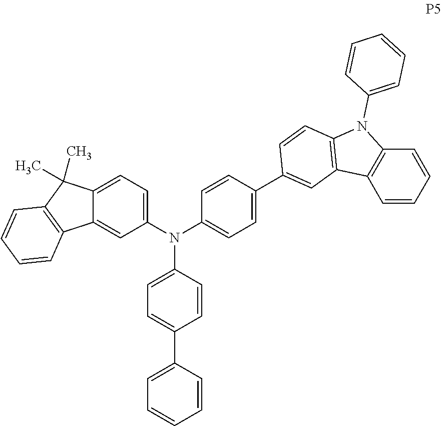 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6 with respect to light in a wavelength range of about 550 nm to about 660 nm.

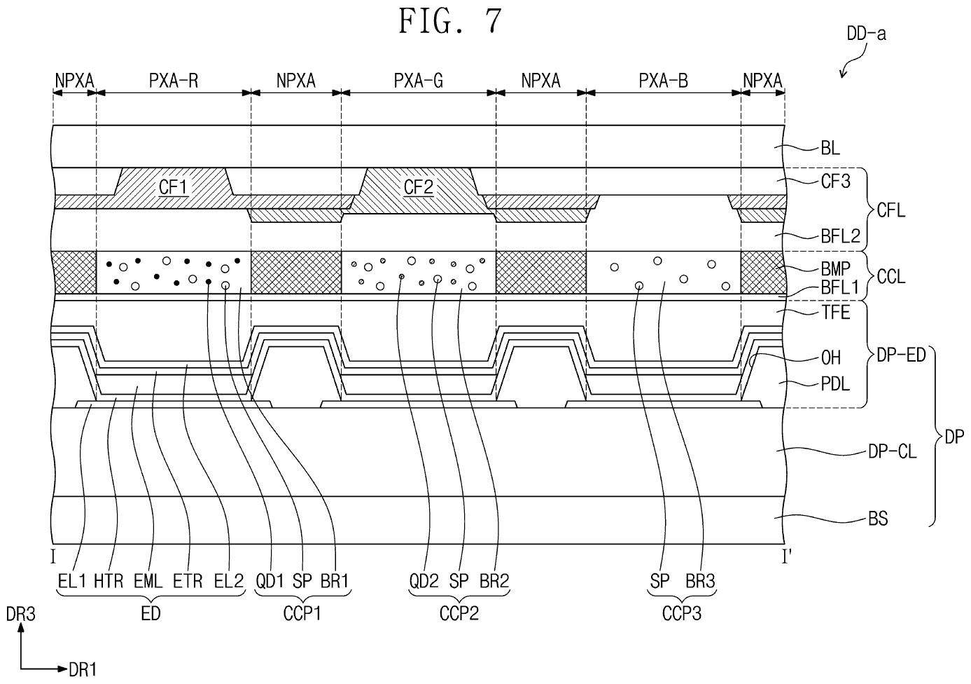

FIG. 7 to FIG. 10 are each a schematic cross-sectional views of a display device according to an embodiment. In the descriptions of the display devices according to embodiments as shown in FIG. 7 to FIG. 10, the features which have been described above with respect to FIG. 1 to FIG. 6 will not be explained again, and the differing features will be explained.

Referring to FIG. 7, the display device DD-a may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting elements ED according to one of FIG. 3 to FIG. 6.

In an embodiment, the emission layer EML of the light emitting element ED in the display device DD-a according to an embodiment may include the fused polycyclic compound according to an embodiment.

Referring to FIG. 7, the emission layer EML may be disposed in an opening OH defined in a pixel definition layer PDL. For example, the emission layer EML, which is separated by the pixel definition layer PDL and correspondingly provided to each of the light emitting regions PXA-R, PXA-G, and PXA-B, may emit light in a same wavelength region. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light controlling layer CCL may be disposed on the display panel DP. The light controlling layer CCL may include a light converter. The light converter may be a quantum dot or a phosphor. The light converter may transform the wavelength of a provided light and may emit the resulting light. For example, the light controlling layer CCL may be a layer including a quantum dot or a layer including a phosphor.

The light controlling layer CCL may include light controlling parts CCP1, CCP2, and CCP3. The light controlling parts CCP1, CCP2, and CCP3 may be separated from one another.

Referring to FIG. 7, a partition pattern BMP may be disposed between the separated light controlling parts CCP1, CCP2, and CCP3, but embodiments are not limited thereto. In FIG. 7, it is shown that the partition pattern BMP do not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts a first color light provided from the light emitting element ED into a second color light, a second light controlling part CCP2 including a second quantum dot QD2 that converts the first color light into a third color light, and a third light controlling part CCP3 transmitting the first color light. In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or may be a mixture of two or more materials selected from TiO₂, ZnO, Al₂O₃, SiO₂, and hollow silica.

The first light controlling part CCP1, the second light controlling part CCP2, and the third light controlling part CCP3 may each include base resins BR1, BR2, and BR3, in which the quantum dots QD1 and QD2 and the scatterer SP are scattered. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2, and BR3 may be mediums in which the quantum dots QD1 and QD2 and the scatterer SP are dispersed, and may be composed of various resin compositions which maybe generally referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same or different from each other.

The light controlling layer CCL may include a barrier layer BFL1. The barrier layer BFL1 may prevent the penetration of moisture and/or oxygen (hereinafter, will be referred to as “humidity/oxygen”). The barrier layer BFL1 may block the light controlling parts CCP1, CCP2, and CCP3 from exposure to humidity/oxygen. The barrier layer BFL1 may cover the light controlling parts CCP1, CCP2, and CCP3. A color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. The barrier layers BFL1 and BFL2 may each independently include an organic layer. The barrier layers BFL1 and BFL2 may each be formed of a single layer or of multiple layers.

In the display device DD-a, the color filter layer CFL may be disposed on the light controlling layer CCL. In an embodiment, the color filter layer CFL may be disposed directly on the light controlling layer CCL. For example, the barrier layer BFL2 may be omitted.

The color filter layer CFL may include filters CF1, CF2, and CF3. The first to third filters CF1, CF2, and CF3 may be disposed to respectively correspond to a red light emitting region PXA-R, a green light emitting region PXA-G, and a blue light emitting region PXA-B.

In an embodiment, the color filter layer CFL may include a first filter CF1 that transmits a second color light, a second filter CF2 that transmits a third color light, and a third filter CF3 that transmits a first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be yellow filters. The first filter CF1 and the second filter CF2 may not be separated but may be provided as one filter.

Although not shown in the drawings, the color filter layer CFL may further include a light blocking part (not shown). The light blocking part (not shown) may be a black matrix.

The light blocking part (not shown) may include an organic light blocking material or an inorganic light blocking material, each including a black pigment or black dye. The light blocking part (not shown) may prevent light leakage phenomenon and divide the boundaries between adjacent filters CF1, CF2, and CF3.

In an embodiment, a base substrate BL may be disposed on the color filter layer CFL.

The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

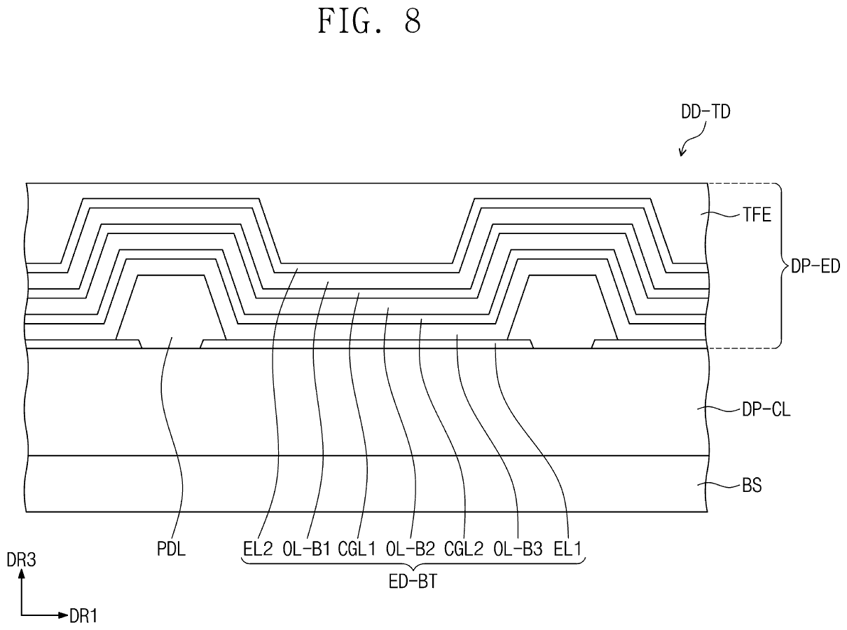

FIG. 8 is a schematic cross-sectional view of a portion of a display device according to an embodiment. In a display device DD-TD according to an embodiment, the light emitting element ED-BT may include multiple light emitting structures OL-B1, OL-B2, and OL-B3. The light emitting element ED-BT may include a first electrode EL1 and a second electrode EL2 which face each other, and the light emitting structures OL-B1, OL-B2, and OL-B3, which are stacked in a thickness direction between the first electrode EL1 and the second electrode EL2.

The light emitting structures OL-B1, OL-B2, and OL-B3 may each include an emission layer EML (FIG. 7), and a hole transport region HTR and an electron transport region ETR disposed with the emission layer EML (FIG. 7) located between the hole transport region HTR and the electron transport region ETR.

For example, the light emitting element ED-BT in the display device DD-TD may be a light emitting element of a tandem structure including multiple emission layers.

In an embodiment shown in FIG. 8, light emitted from each of the light emitting structures OL-B1, OL-B2, and OL-B3 may be all blue light. However, embodiments are not limited thereto, and the wavelength regions of light emitted from each of the light emitting structures OL-B1, OL-B2, and OL-B3 may be different from each other. For example, the light emitting element ED-BT that includes the light emitting structures OL-B1, OL-B2, and OL-B3 emitting light in different wavelength regions may emit white light.

Charge generating layers CGL1 and CGL2 may each be disposed between neighboring light emitting structures OL-B1, OL-B2, and OL-B3. The charge generating layers CGL1 and CGL2 may each independently include a p-type charge generating layer and/or an n-type charge generating layer.

At least one of the light emitting structures OL-B1, OL-B2, and OL-B3 in the display device DD-TD may include the fused polycyclic compound according to an embodiment. For example, at least one of emission layers in the light emitting element ED-BT may include the fused polycyclic compound according to an embodiment.

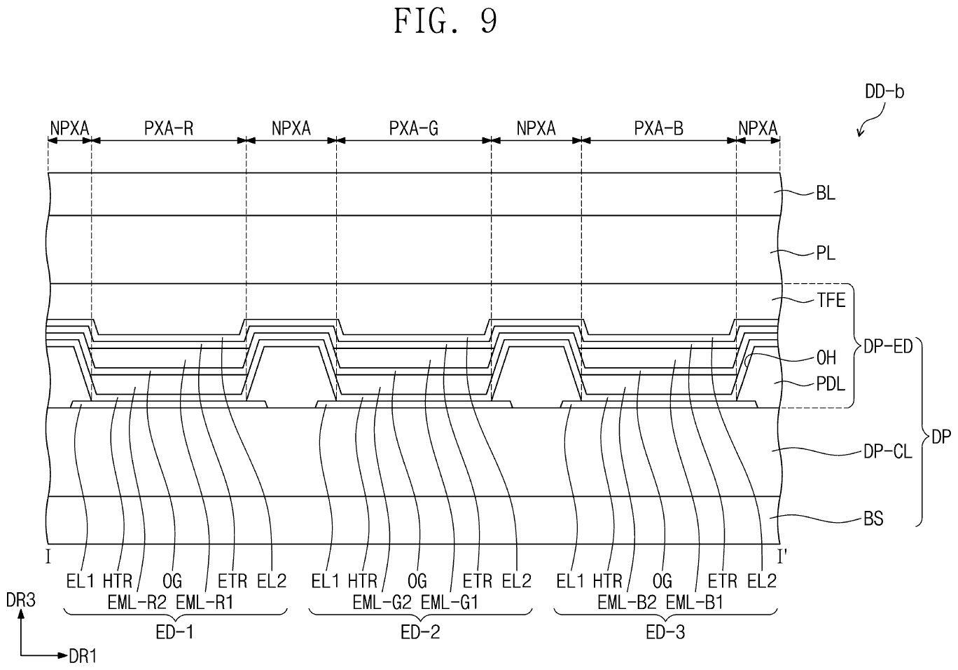

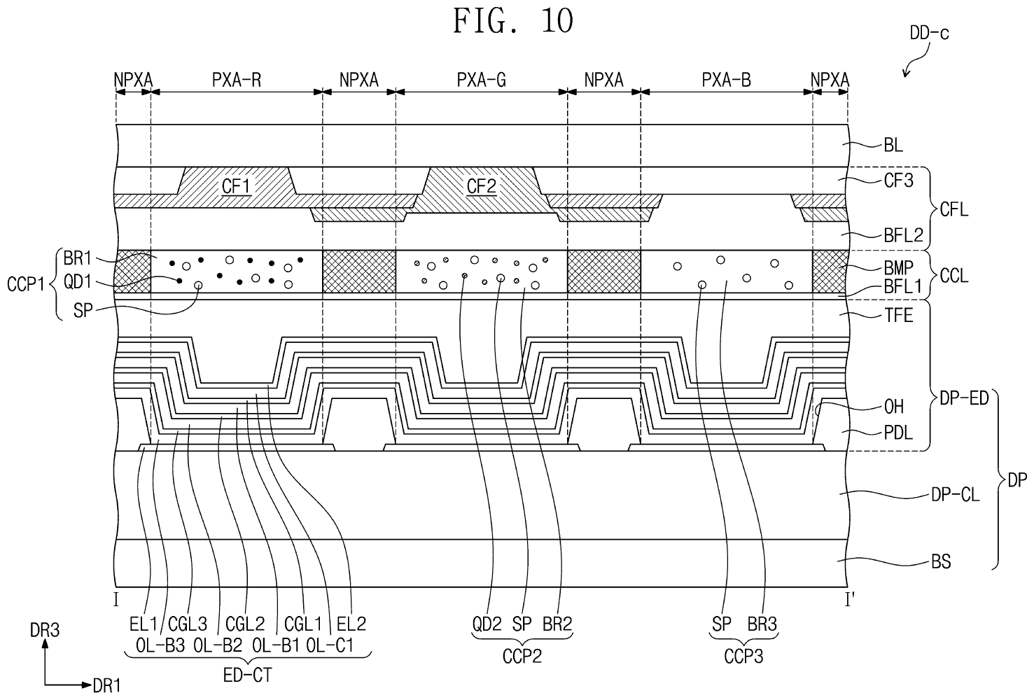

FIG. 9 is a schematic cross-sectional view of a display device according to an embodiment. FIG. 10 is a schematic cross-sectional view of a display device according to an embodiment.

Referring to FIG. 9, a display device DD-b according to an embodiment may include light emitting elements ED-1, ED-2, and ED-3, in which two emission layers are stacked. In comparison to the display device DD shown in FIG. 2, the embodiment shown in FIG. 9 is different at least in that first to third light emitting elements ED-1, ED-2, and ED-3 each include two emission layers that are stacked in a thickness direction. In the first to third light emitting elements ED-1, ED-2, and ED-3, two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may be a single layer or a multilayer. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer in all of the first to third light emitting elements ED-1, ED-2, and ED-3. However, embodiments are not limited thereto, and the emission auxiliary part OG may be patterned and provided in openings OH defined in a pixel definition layer PDL.

The first red emission layer EML-R1, the first green emission layer EML-G1, and the first blue emission layer EML-B1 may be each disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on a display device layer DP-ED. The optical auxiliary layer PL may include a polarization layer. The optical auxiliary layer PL may be disposed on a display panel DP and may control light that is reflected at the display panel DP from an external light. Although not shown in the drawings, in an embodiment, the optical auxiliary layer PL may be omitted from the display device DD.

At least one emission layer in the display device DD-b according to an embodiment shown in FIG. 9 may include the fused polycyclic compound according to an embodiment. For example, at least one of the first blue emission layer EML-B1 and the second blue emission layer may include the fused polycyclic compound according to an embodiment.

In contrast to FIG. 8 and FIG. 9, FIG. 10 shows a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. The third light emitting structures OL-B3, the second light emitting structures OL-B2, the first light emitting structures OL-B1, and the fourth light emitting structures OL-C1 may be stacked in a thickness direction. Charge generating layers CGL1, CGL2, and CGL3 may be disposed between the first to fourth light emitting structures OL-B1, OL-B2, OL-B3, and OL-C1. For example, a first charge generating layer CGL1 may be disposed between the first light emitting structures OL-B1 and the fourth light emitting structures OL-C1. For example, a second charge generating layer CGL2 may be disposed between the first light emitting structures OL-B1 and the second light emitting structures OL-B2. For example, a third charge generating layer CGL3 may be disposed between the second light emitting structures OL-B2 and the third light emitting structures OL-B3.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

Charge generating layers CGL1, CGL2, and CGL3 which are disposed between neighboring light emitting structures among the first to fourth light emitting structures OL-B1, OL-B2, OL-B3, and OL-C1 may each independently include a p-type charge generating layer and/or an n-type charge generating layer.

In the display device DD-c, at least one of the light emitting structures OL-B1, OL-B2, OL-B3, and OL-C1 may each independently include the fused polycyclic compound according to an embodiment. For example, in an embodiment, at least one of the first to third light emitting structures OL-B1, OL-B2, and OL-B3 may each independently include the fused polycyclic compound.

The light emitting element ED according to an embodiment may include the fused polycyclic compound represented by Formula 1 in at least one functional layer disposed between the first electrode EL1 and the second electrode EL2, thereby exhibiting excellent luminous efficiency and improved service life characteristics. For example, the emission layer of the light emitting element ED may include the fused polycyclic compound, and the light emitting element ED may exhibit long service life characteristics.

In an embodiment, an electronic apparatus may include a display device including multiple light emitting elements and a control part controlling the display device. The electronic apparatus according to an embodiment may be an apparatus activated according to electrical signals. The electronic apparatus may include display devices of various embodiments. Examples of an electronic apparatus may include televisions, monitors, large-size display devices such as outside billboards, personal computers, laptop computers, personal digital terminals, display devices for automobiles, game consoles, portable electronic devices, medium-size display device, and small-size display devices such as cameras.

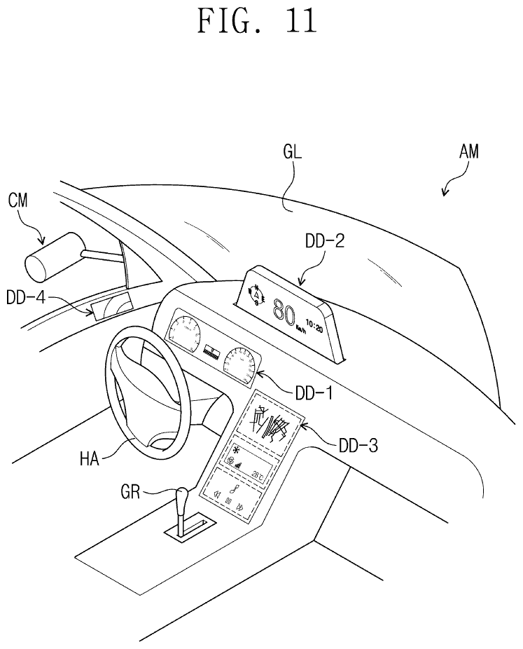

FIG. 11 is a schematic diagram of a vehicle AM in which first to fourth display devices DD-1, DD-2, DD-3, and DD-4 are disposed. At least one of the first to fourth display devices DD-1, DD-2, DD-3, and DD-4 may have a structure according to one of the display devices DD, DD-TD, DD-a, DD-b, and DD-c, as explained with reference to FIGS. 1, 2, and 7 to 10.

In FIG. 11, a vehicle AM is shown as an automobile, but this is only an example, and the first to fourth display devices DD-1, DD-2, DD-3, and DD-4 may be disposed in various other transportation means such as bicycles, motorcycles, trains, ships, and airplanes. In an embodiment, at least one of the first to fourth display devices DD-1, DD-2, DD-3, and DD-4 may have a structure according to one of the display devices DD, DD-TD, DD-a, DD-b, and DD-c, and may be employed in personal computers, laptop computers, personal digital terminals, game consoles, portable electronic devices, televisions, monitors, external billboards, or the like. However, these are merely presented as examples, and the display device may be employed in other electronic devices.

At least one of the first to fourth display devices DD-1, DD-2, DD-3, and DD-4 may each independently include a light emitting element ED according to an embodiment as described with reference to FIGS. 3 to 6. The light emitting element ED may include a fused polycyclic compound according to an embodiment. At least one of the first to fourth display devices DD-1, DD-2, DD-3, and DD-4 may include a light emitting element ED including the fused polycyclic compound according to an embodiment, thereby improving a display service life.

Referring to FIG. 11, the vehicle AM may include a steering wheel HA and a gearshift GR for the operation of the vehicle AM, and a front window GL that is disposed so as to face a driver.

A first display device DD-1 may be disposed in a first region that overlaps with the steering wheel HA. For example, the first display device DD-1 may be a digital cluster that displays the first information of the vehicle AM. The first information may include a first scale that indicates a driving speed of the vehicle AM, a second scale that indicates an engine speed (for example, revolutions per minute (RPM)), and images showing a fuel level. The first scale and the second scale may each be represented by digital images.

A second display device DD-2 may be disposed in a second region facing a driver's seat and overlapping the front window GL. The driver's seat may be a seat where the steering wheel HA is disposed. For example, the second display device DD-2 may be a head up display (HUD) that shows the second information of the vehicle AM. The second display device DD-2 may be transparent. The second information may include digital numbers that indicates a driving speed of the vehicle AM and may further include information, such as the current time. Although not shown in the drawings, in an embodiment, the second information of the second display device DD-2 may be projected and displayed on the front window GL.

A third display device DD-3 may be disposed in a third region that is adjacent to the gearshift GR. For example, the third display device DD-3 may be a center information display (CID) for an automobile which shows third information and may be disposed between a driver's seat and a passenger seat. The passenger seat may be a seat that is separated apart from the driver's seat, with the gearshift GR disposed therebetween. The third information may include information on road conditions (for example, navigation information), on music or radio that is playing, on a dynamic or still image that is displayed, on a temperature in the vehicle AM, or the like.

A fourth display device DD-4 may be disposed in a fourth region that is spaced apart from the steering wheel HA and the gearshift GR and is adjacent to a side of the vehicle AM. For example, the fourth display device DD-4 may be a digital side-view mirror that shows fourth information. The fourth display device DD-4 may display an image of the exterior of the vehicle AM, which may be taken by a camera module CM disposed outside of the vehicle AM. The fourth information may include an external image of the vehicle AM.

The first to fourth information as described above are only presented as examples, and the first to fourth display devices DD-1, DD-2, DD-3, and DD-4 may further display information about the interior and exterior of the vehicle AM. The first to fourth information may include information that is different from each other. However, embodiments are not limited thereto, and a portion of the first to fourth information may include a same information.

Hereinafter, with reference to Examples and Comparative Examples, a fused polycyclic compound according to an embodiment and a light emitting element according to an embodiment will be described. The Examples described below are only provided as illustrations to assist in understanding the disclosure, and the scope thereof is not limited thereto.

### EXAMPLES

### 1. Synthesis of Fused Polycyclic Compound

A synthesis method of the fused polycyclic compound according to an embodiment will be described by illustrating the synthesis methods of Compounds 16, 22, 26, 63, 71, 41, and 51. The synthesis methods of the fused polycyclic compounds as described below are only examples, and the synthesis method of the fused polycyclic compound according to an embodiment is not limited to the following examples.

### (1) Synthesis of Compound 16

Compound 16 according to an example may be synthesized, for example, by the reaction below:

### (Synthesis of Intermediate 16-a)

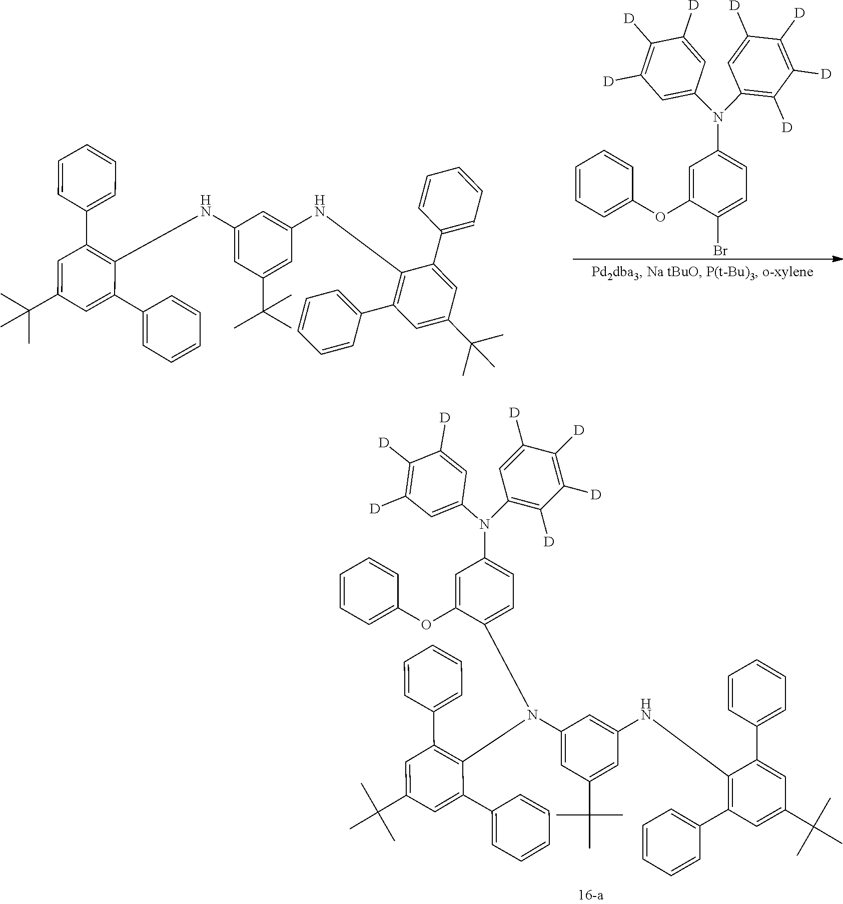

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), N-(4-bromo-3-phenoxyphenyl)-N-(phenyl-3,4,5-d3)aniline-2,3,4,5-d4 (5.7 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 16-a (white solid, 10.8 g, yield: 75%).

ESI-LCMS: [M]⁺: C₇₈H₆₆D₇N₃O. 1074.6122.

### (Synthesis of Intermediate 16-b)

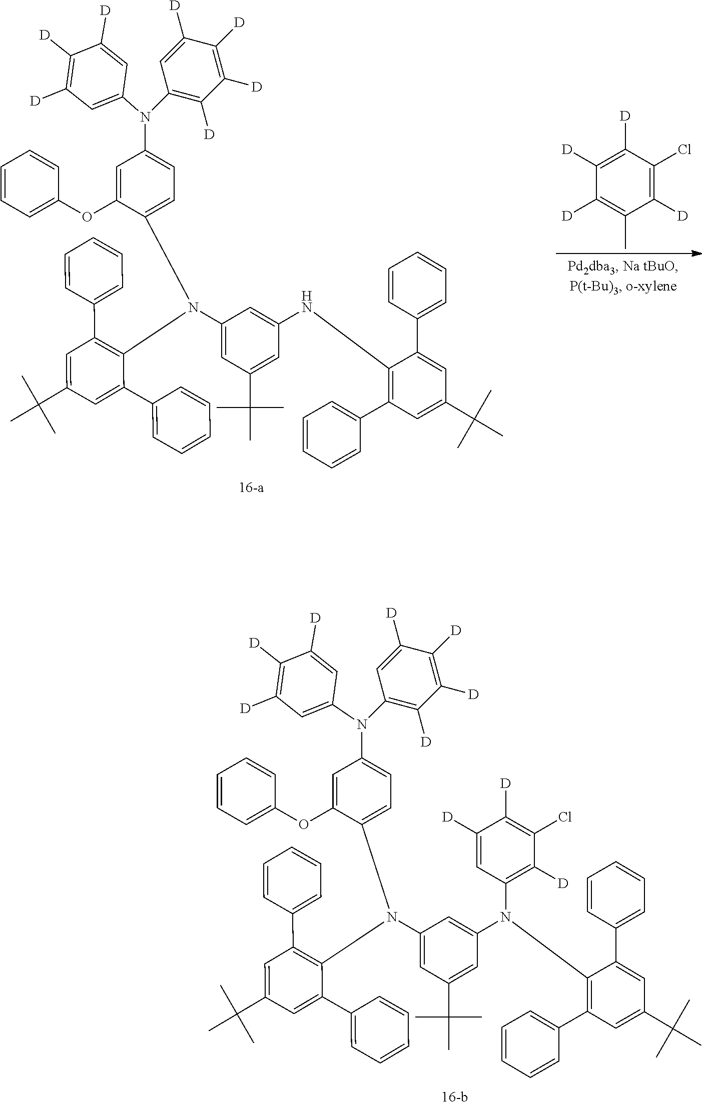

In an argon atmosphere, to a 2-L flask, Intermediate 16-a (10.8 g, 10 mmol), 1-chloro-3-iodobenzene-2,4,5,6-d4 (2.4 g, 10 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 16-b (white solid, 6.6 g, yield: 56%).

ESI-LCMS: [M]⁺: C₈₄H₆₆D₁₀ClN₃O. 1187.6312.

### (Synthesis of Intermediate 16-c)

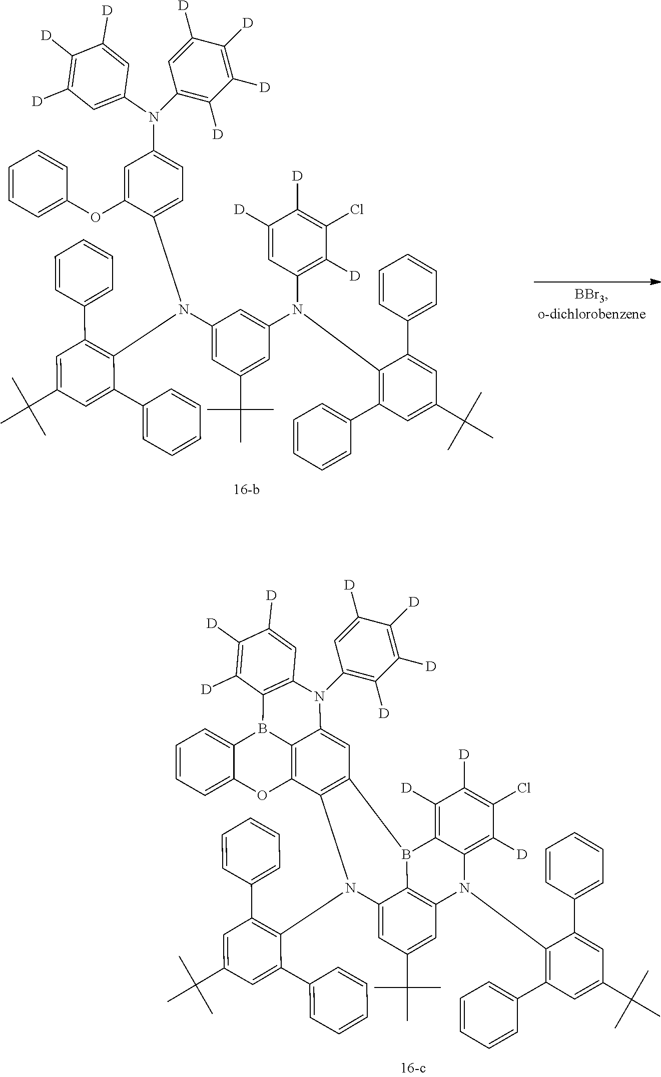

In an argon atmosphere, to a 1-L flask, Intermediate 16-b (6.6 g, 5.6 mmol) was added and dissolved in 100 mL of o-dichlorobenzene, and BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to Intermediate 16-c (yellow solid, 1.5 g, yield: 22%).

ESI-LCMS: [M]⁺: C₈₄H₆₀D₁₀B₂ClN₃O. 1206.0062

### (Synthesis of Compound 16)

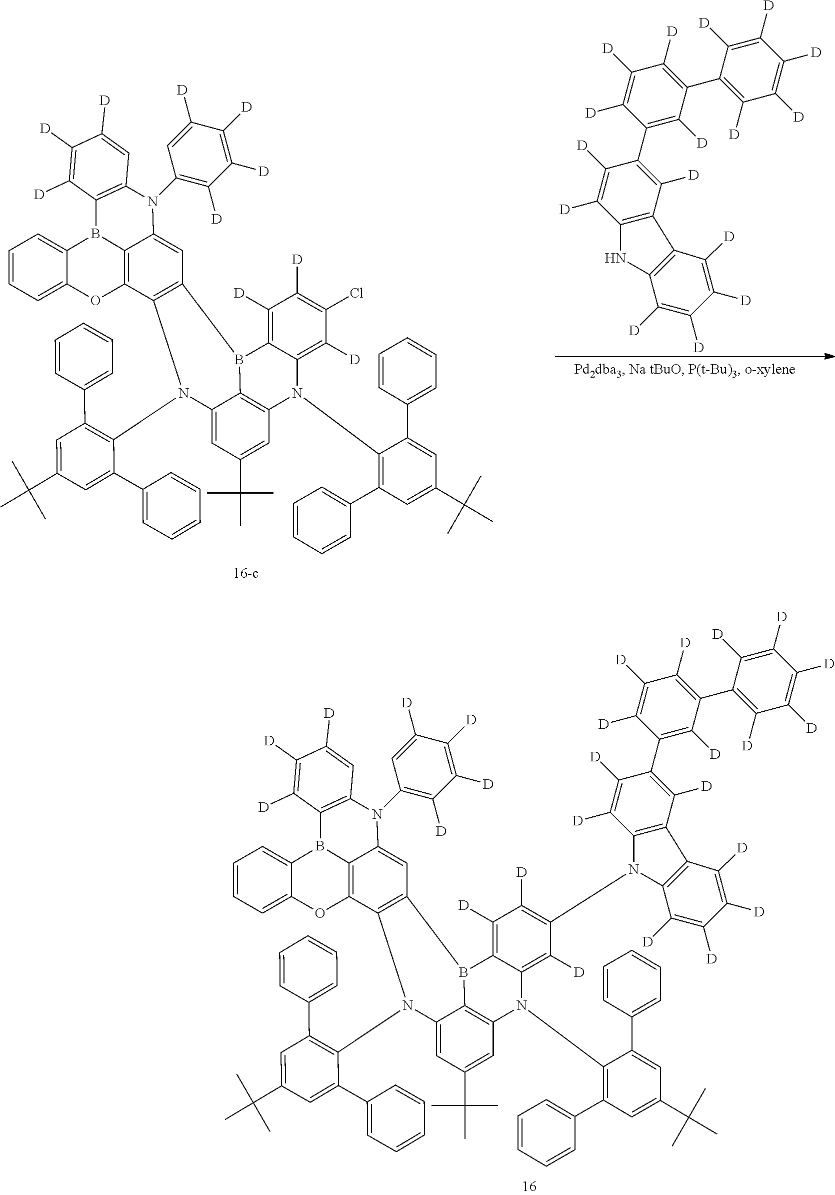

In an argon atmosphere, to a 1-L flask, Intermediate 16-c (1.5 g, 1.2 mmol), 3-([1,1′-biphenyl]-3-yl)-d9)-9H-carbazole-1,2,4,5,6,7,8-d7 (0.42 g, 1.2 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 16 (yellow solid, 1.4 g, yield: 80%).

ESI-LCMS: [M]⁺: C₁₀₈H₆₀D₂₆B₂N₄O. 1502.8116

¹H-NMR (CDCl₃): d=8.48 (d, 1H), 7.66 (m, 1H), 7.45 (s, 4H), 7.18 (m, 12H), 7.05 (m, 8H), 6.88 (s, 2H), 6.79 (s, 1H), 1.39 (s, 18H), 1.22 (s, 9H)

### (2) Synthesis of Compound 22

Compound 22 according to an example may be synthesized by, for example, the reaction:

### (Synthesis of Intermediate 22-a)

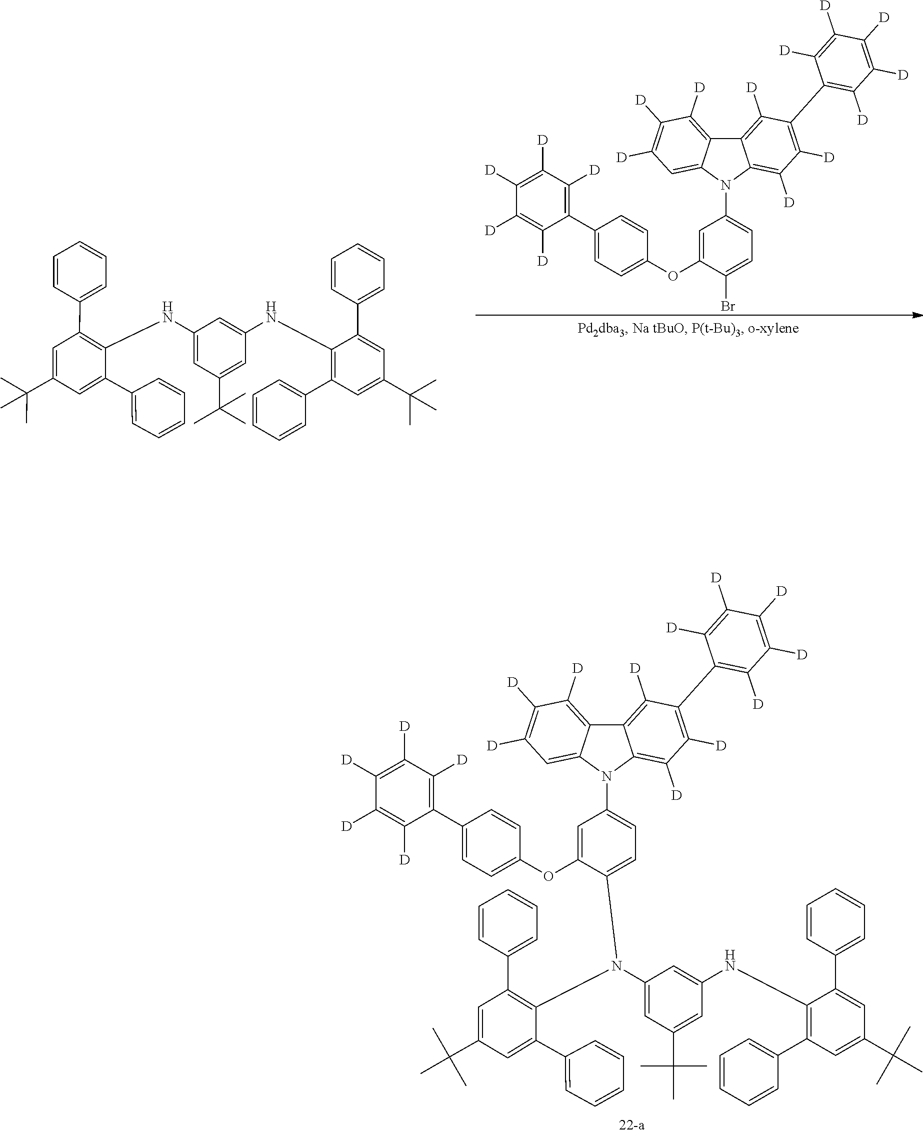

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 9-(3-(([1,1′-biphenyl]-4-yl-2′,3′,4′,5′,6′-d5)oxy)-4-bromophenyl)-3-(phenyl-d5)-9H-carbazole-1,2,4,5,6,7-d6 (7.9 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 22-a (white solid, 13 g, yield: 79%).

ESI-LCMS: [M]⁺: C₉₀H₆₃D₁₆N₃O. 1233.7279.

### (Synthesis of Intermediate 22-b)

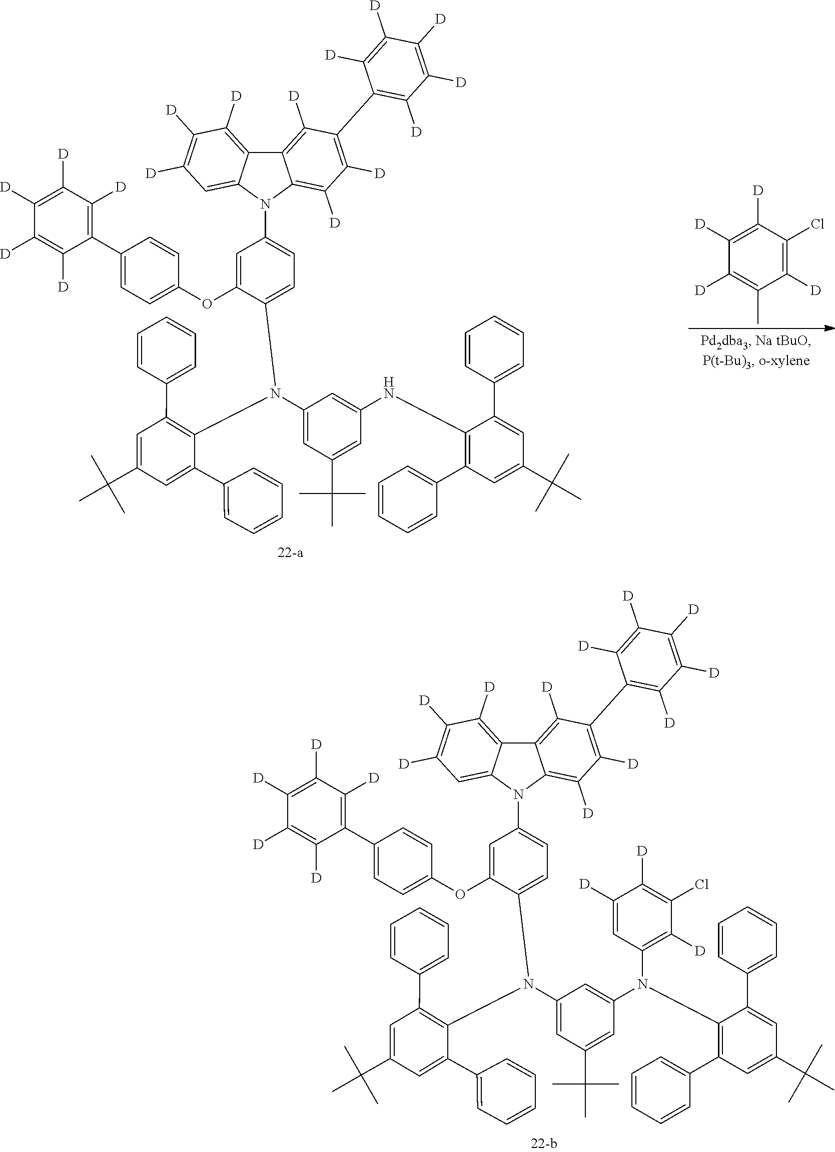

In an argon atmosphere, to a 2-L flask, Intermediate 22-a (13 g, 10.5 mmol), 1-chloro-3-iodobenzene-2,4,5,6-d4 (2.4 g, 10.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 22-b (white solid, 8.5 g, yield: 60%).

ESI-LCMS: [M]⁺: C₉₆H₆₃D₁₉ClN₃O. 1346.7003.

### (Synthesis of Intermediate 22-c)

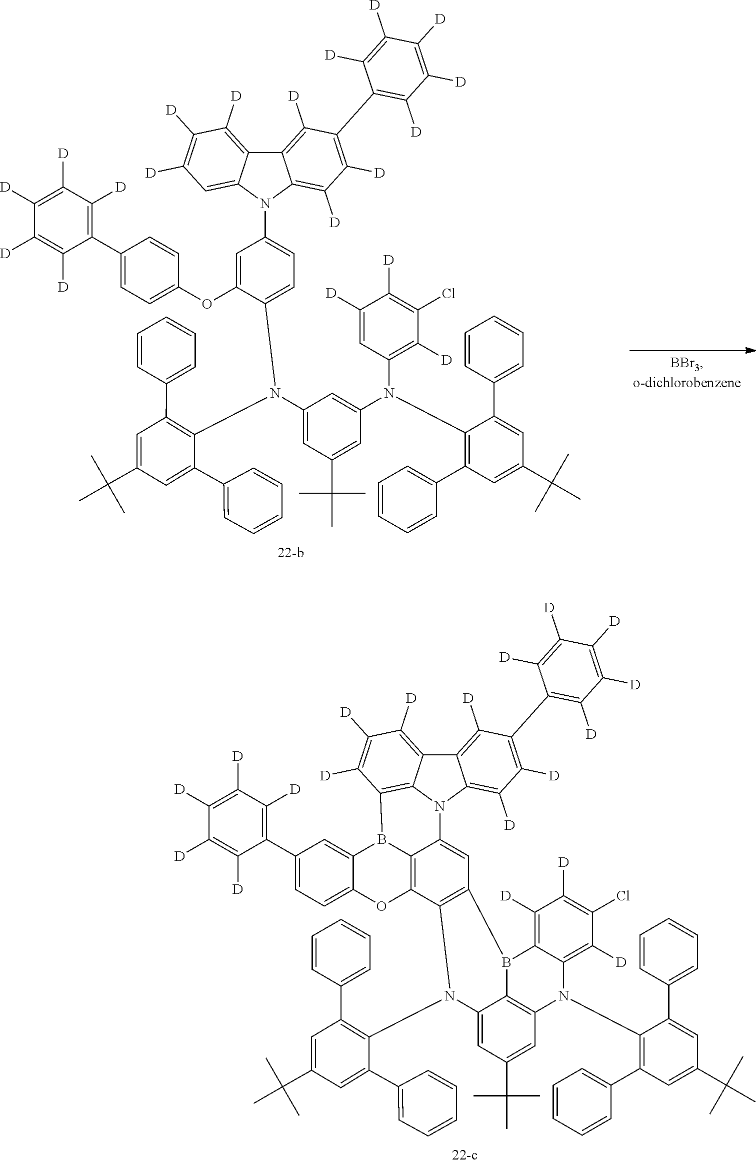

In an argon atmosphere, to a 1-L flask, Intermediate 22-b (8.5 g, 6.3 mmol) was added and dissolved in 100 mL of o-dichlorobenzene, and BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate Compound 22-c (yellow solid, 1.8 g, yield: 21%).

ESI-LCMS: [M]⁺: C₉₆H₅₇D₁₉B₂ClN₃O. 1362.7172

### (Synthesis of Compound 22)

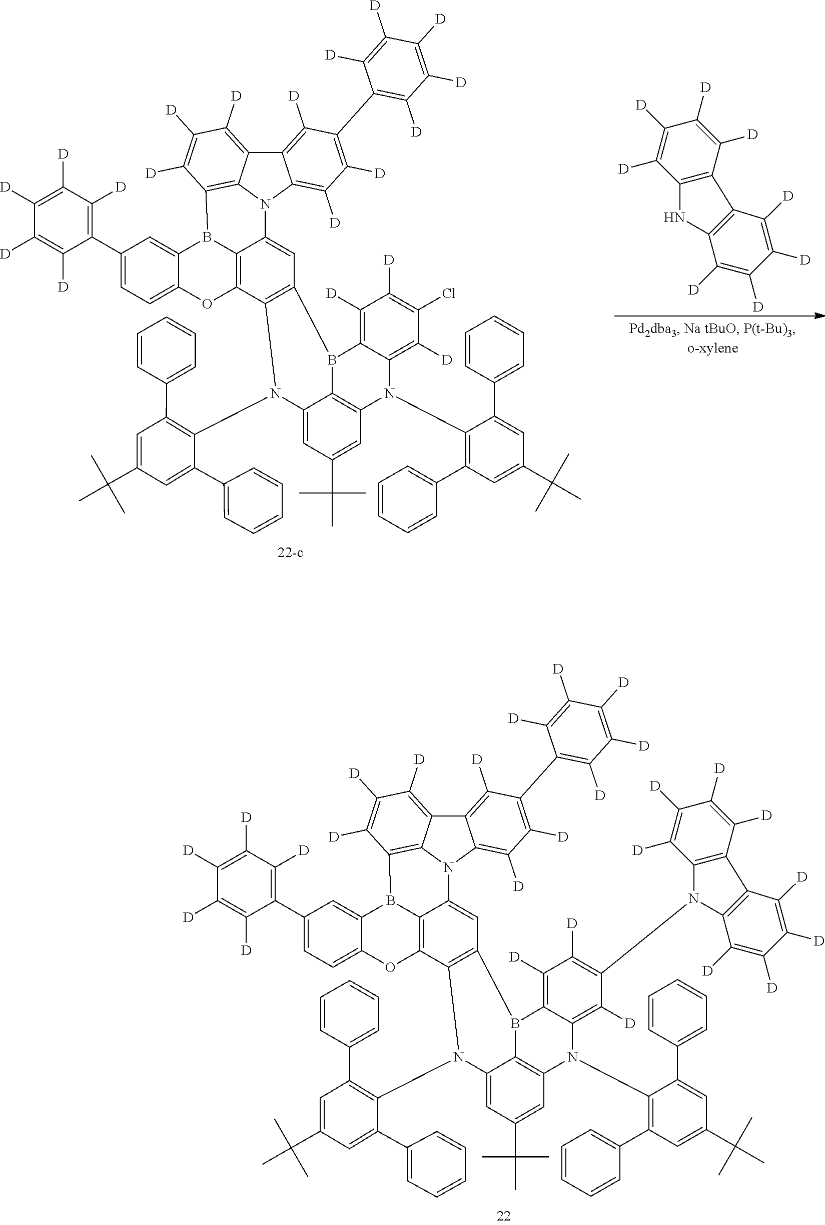

In an argon atmosphere, to a 1-L flask, Intermediate 22-c (1.8 g, 1.3 mmol), 9H-carbazole-1,2,3,4,5,6,7,8-d8 (0.23 g, 1.3 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of o-xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 22 (yellow solid, 1.46 g, yield: 75%).

ESI-LCMS: [M]⁺: C₁₀₈H₅₇D₂₇B₂N₄O. 1501.8516

¹H-NMR (CDCl₃): d=8.98 (s, 1H), 8.32 (d, 1H), 7.66 (d, 1H), 7.45 (s, 4H), 7.33 (d, 1H), 7.15 (m, 12H), 7.03 (m, 8H), 6.86 (s, 2H), 6.77 (s, 1H), 1.44 (s, 18H), 1.25 (s, 9H)

### (3) Synthesis of Compound 26

Compound 26 according to an example may be synthesized, for example, by the reaction:

### (Synthesis of Intermediate 26-a)

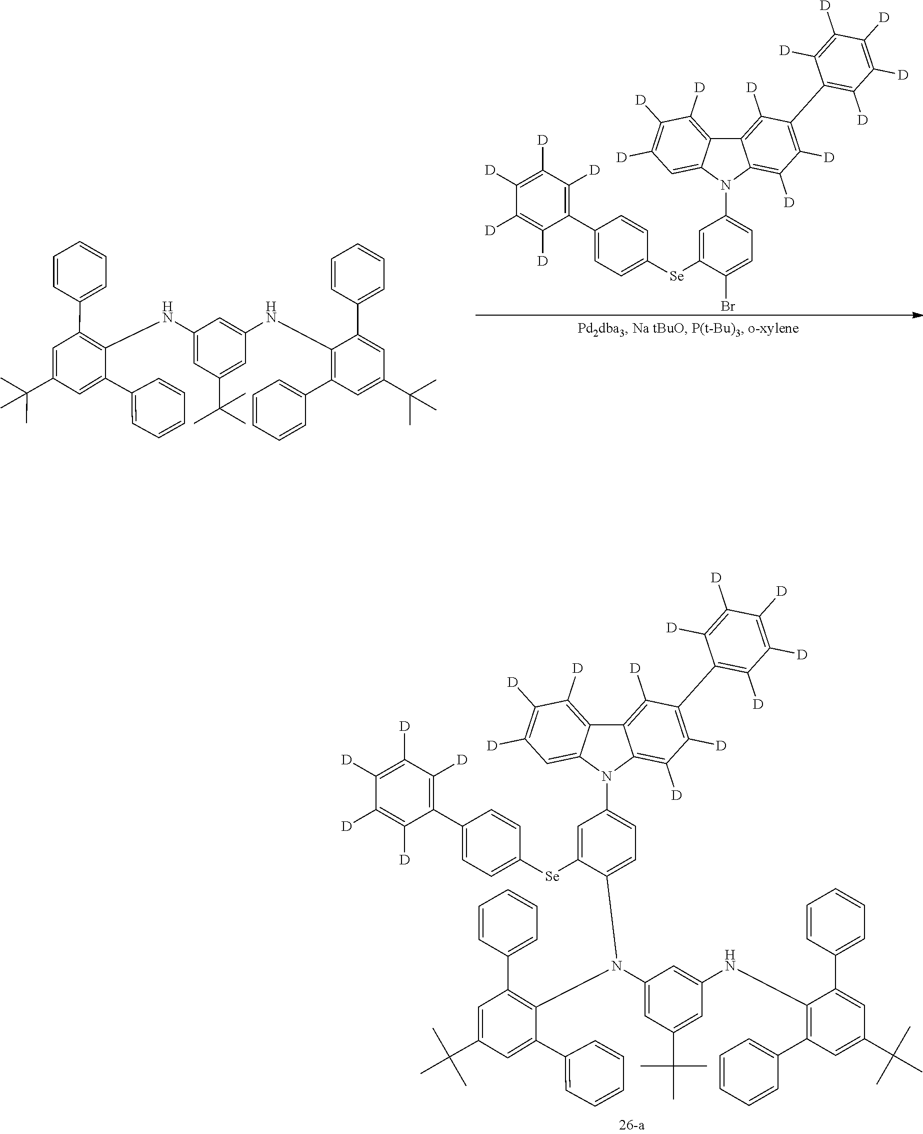

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 9-(3-(([1,1′-biphenyl]-4-yl-2′,3′,4′,5′,6′-d5)selanyl)-4-bromophenyl)-3-(phenyl-d5)-9H-carbazole-1,2,4,5,6,7-d6 (7.8 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 26-a (white solid, 12.6 g, yield: 72%).

ESI-LCMS: [M]⁺: C₉₀H₆₃D₁₆N₃Se. 1297.6463.

### (Synthesis of Intermediate 26-b)

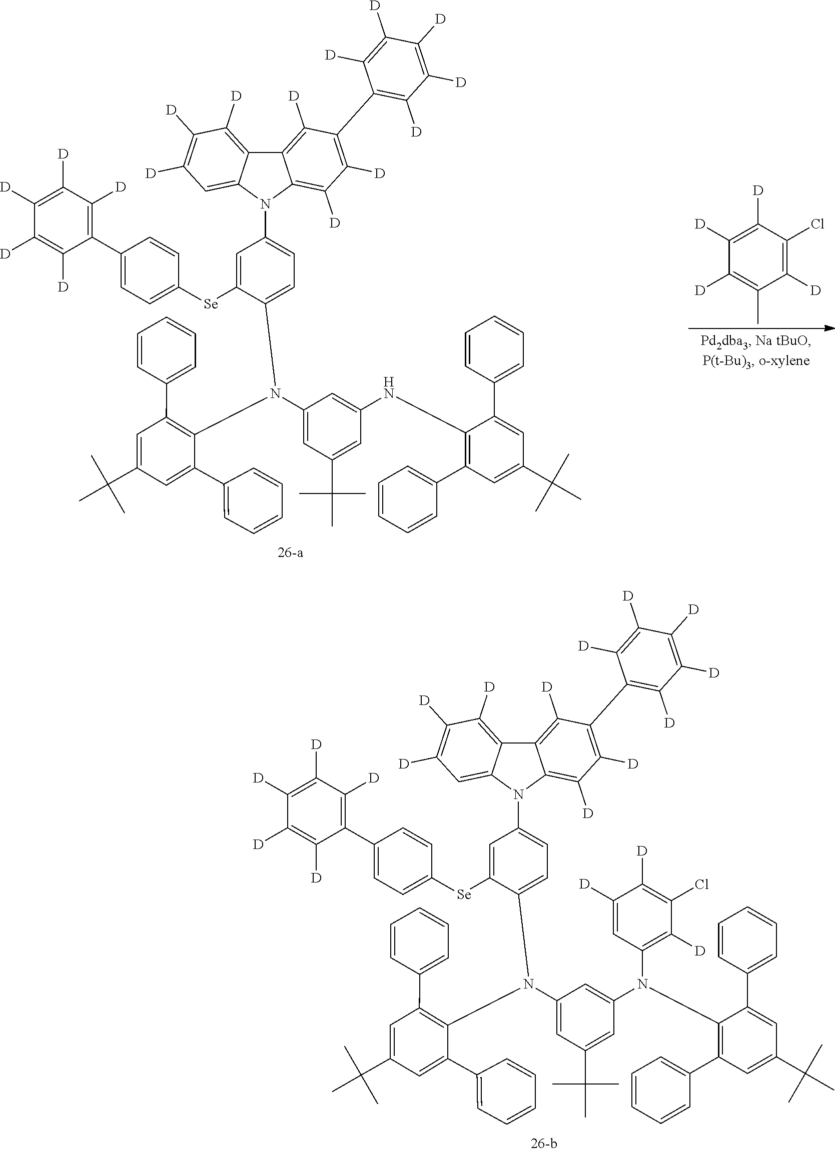

In an argon atmosphere, to a 2-L flask, Intermediate 26-a (12.6 g, 10 mmol), 1-chloro-3-iodobenzene-2,4,5,6-d4 (2.4 g, 10 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 26-b (white solid, 8 g, yield: 59%).

ESI-LCMS: [M]⁺: C₉₆H₆₃D₁₉ClN₃Se. 1410.6601.

### (Synthesis of Intermediate 26-c)

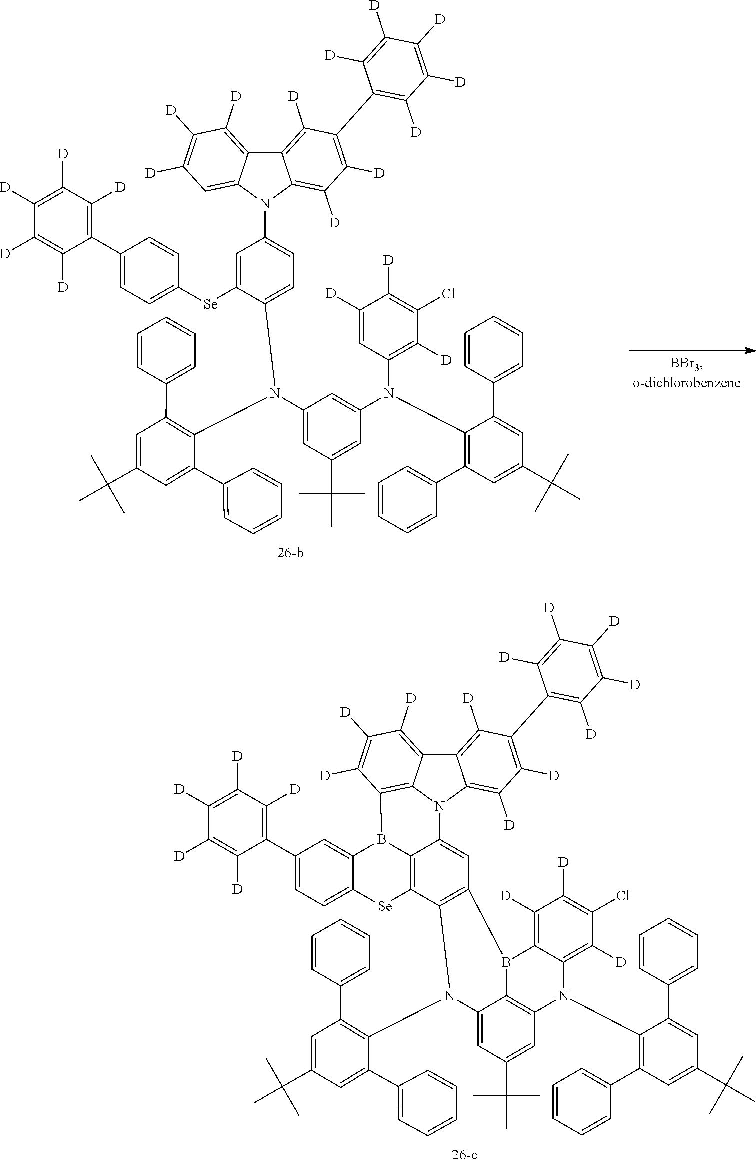

In an argon atmosphere, to a 1-L flask, Intermediate 26-b (8 g, 5.6 mmol) was added and dissolved in 100 mL of o-dichlorobenzene, and BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to Intermediate 26-c (yellow solid, 1.8 g, yield: 23%).

ESI-LCMS: [M]⁺: C₉₆H₅₇D₁₉B₂ClN₃Se. 1426.2663

### (Synthesis of Compound 26)

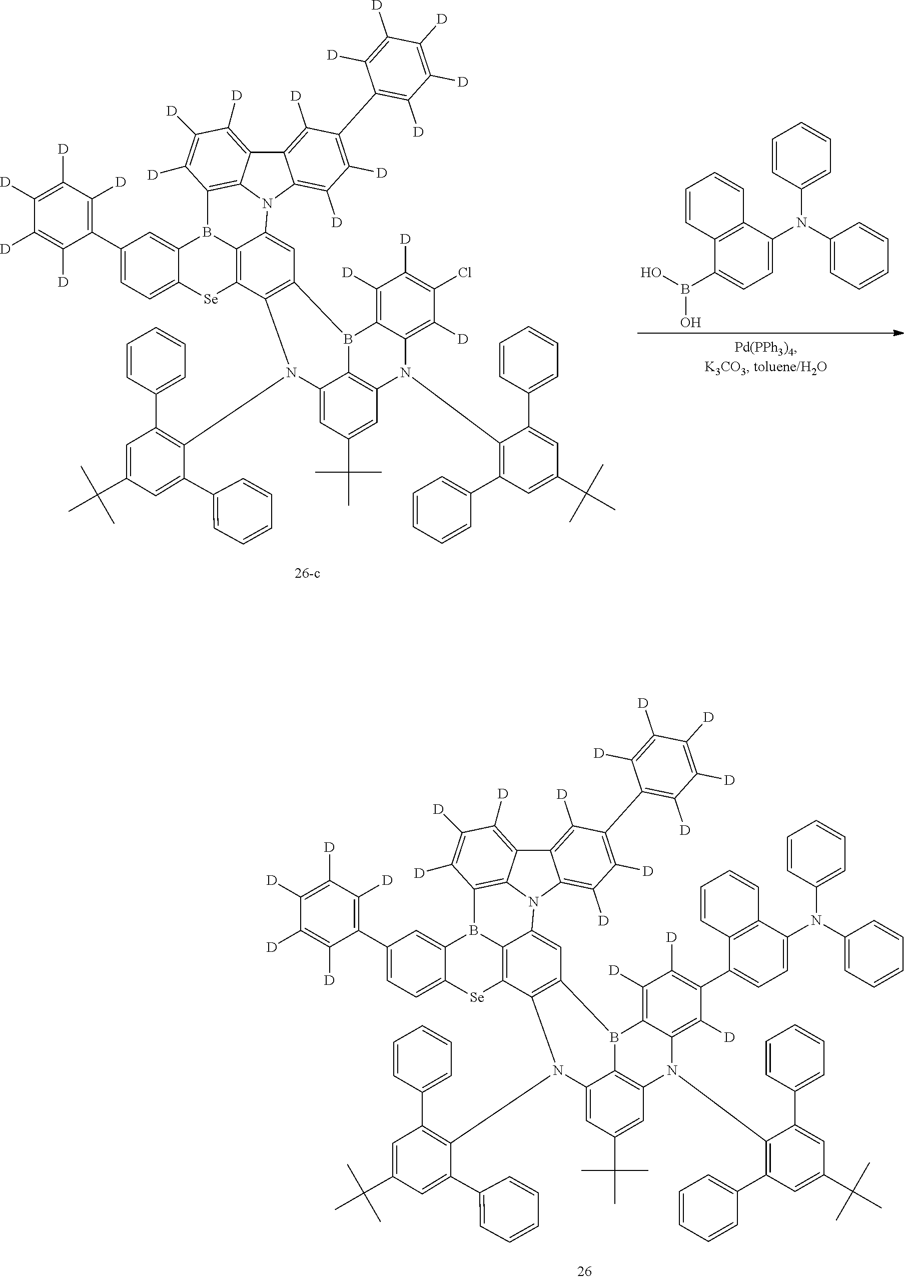

In an argon atmosphere, to a 1 L-flask, Intermediate 26-c (1.8 g, 15 mmol), (4-(diphenylamino)naphthalen-1-yl)boronic acid (0.44 g, 1.3 mmol), Pd(PPh₃)₄ (0.08 g, 0.06 mmol), and potassium carbonate (0.5 g, 3.9 mmol) were added and dissolved in 100 mL toluene and 30 mL of H₂O, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 26 (yellow solid, 1.7 g, yield: 77%).

ESI-LCMS: [M]⁺: C₁₁₈H₇₃D₁₉B₂N₄Se. 1685.7981

¹H-NMR (CDCl₃): d=9.12 (s, 1H), 8.85 (d, 1H), 8.32 (d, 1H), 7.77 (d, 1H), 7.67 (s, 1H), 7.55 (m, 4H), 7.45 (s, 4H), 7.25 (m, 4H), 7.15 (m, 12H), 7.03 (m, 8H), 6.88 (s, 2H), 1.41 (s, 18H), 1.21 (s, 9H)

### (4) Synthesis of Compound 63

Compound 63 according to an example may be synthesized, for example, by the reaction:

### (Synthesis of Intermediate 63-a)

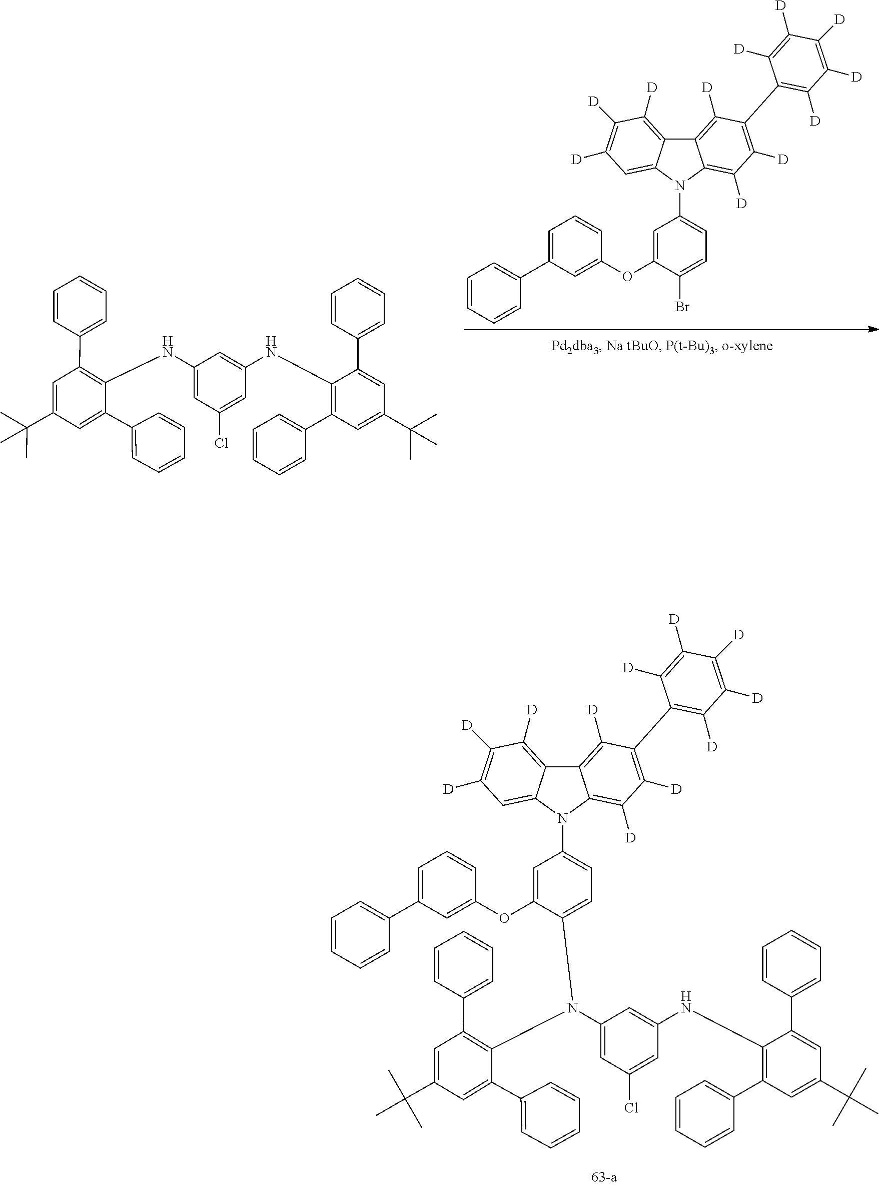 [SMILES: CC(C)(C)c1cc(-c2ccccc2)c(Nc2cc(Cl)cc(Nc3c(-c4ccccc4)cc(C(C)(C)C)cc3-c3ccccc3)c2)c(-c2ccccc2)c1 ; [2H]c1cc2c(c([2H])c1[2H])c1c([2H])c(-c3c([2H])c([2H])c([2H])c([2H])c3[2H])c([2H])c([2H])c1n2-c1ccc(Br)c(Oc2cccc(-c3ccccc3)c2)c1 ; [2H]c1cc2c(c([2H])c1[2H])c1c([2H])c(-c3c([2H])c([2H])c([2H])c([2H])c3[2H])c([2H])c([2H])c1n2-c1ccc(N(c2cc(Cl)cc(Nc3c(-c4ccccc4)cc(C(C)(C)C)cc3-c3ccccc3)c2)c2c(-c3ccccc3)cc(C(C)(C)C)cc2-c2ccccc2)c(Oc2cccc(-c3ccccc3)c2)c1]

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 9-(3-([1,1′-biphenyl]-3-yloxy)-4-bromophenyl)-3-(phenyl-d5)-9H-carbazole-1,2,4,5,6,7-d6 (7.8 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 63-a (white solid, 13 g, yield: 80%).

ESI-LCMS: [M]⁺: C₈₆H₅₉D₁₁ClN₃O. 1206.5951.

### (Synthesis of Intermediate 63-b)

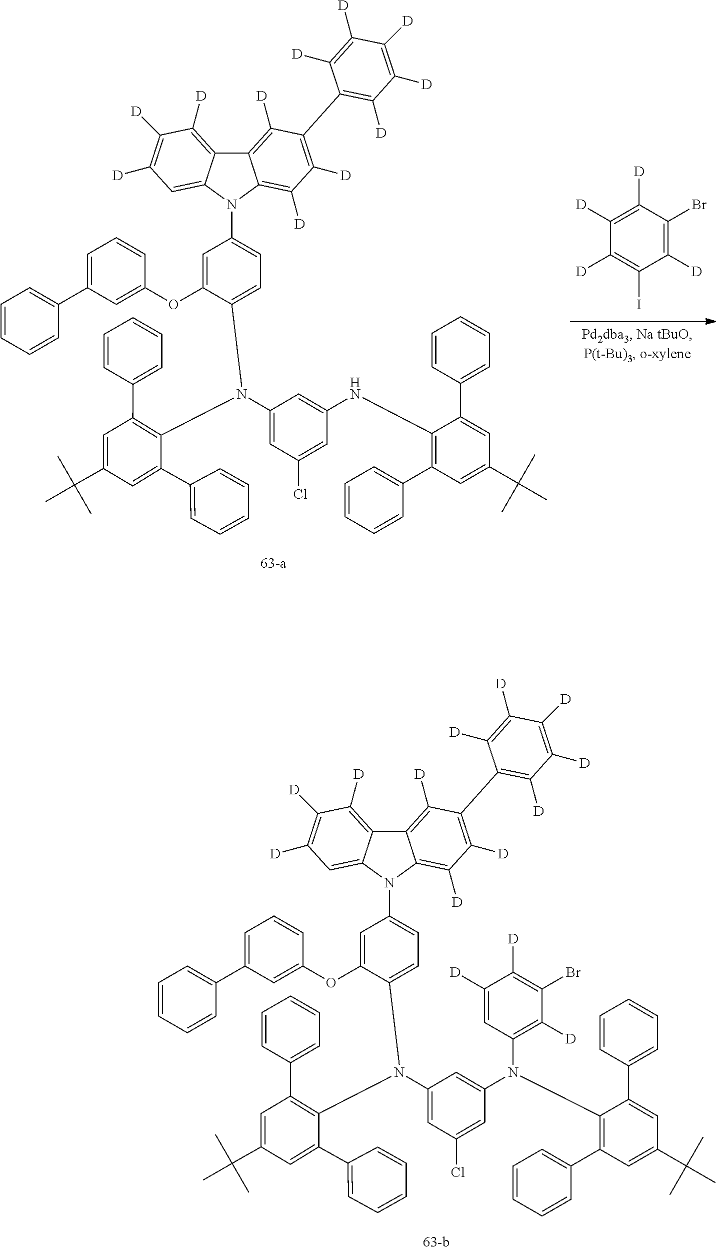

In an argon atmosphere, to a 2-L flask, Intermediate 63-a (13 g, 10 mmol), 1-bromo-3-iodobenzene-2,4,5,6-d4 (3.1 g, 10 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 63-b (white solid, 8.3 g, yield: 61%).

ESI-LCMS: [M]⁺: C₉₂H₅₉D₁₄BrClN₃O. 1363.5005.

### (Synthesis of Intermediate 63-c)

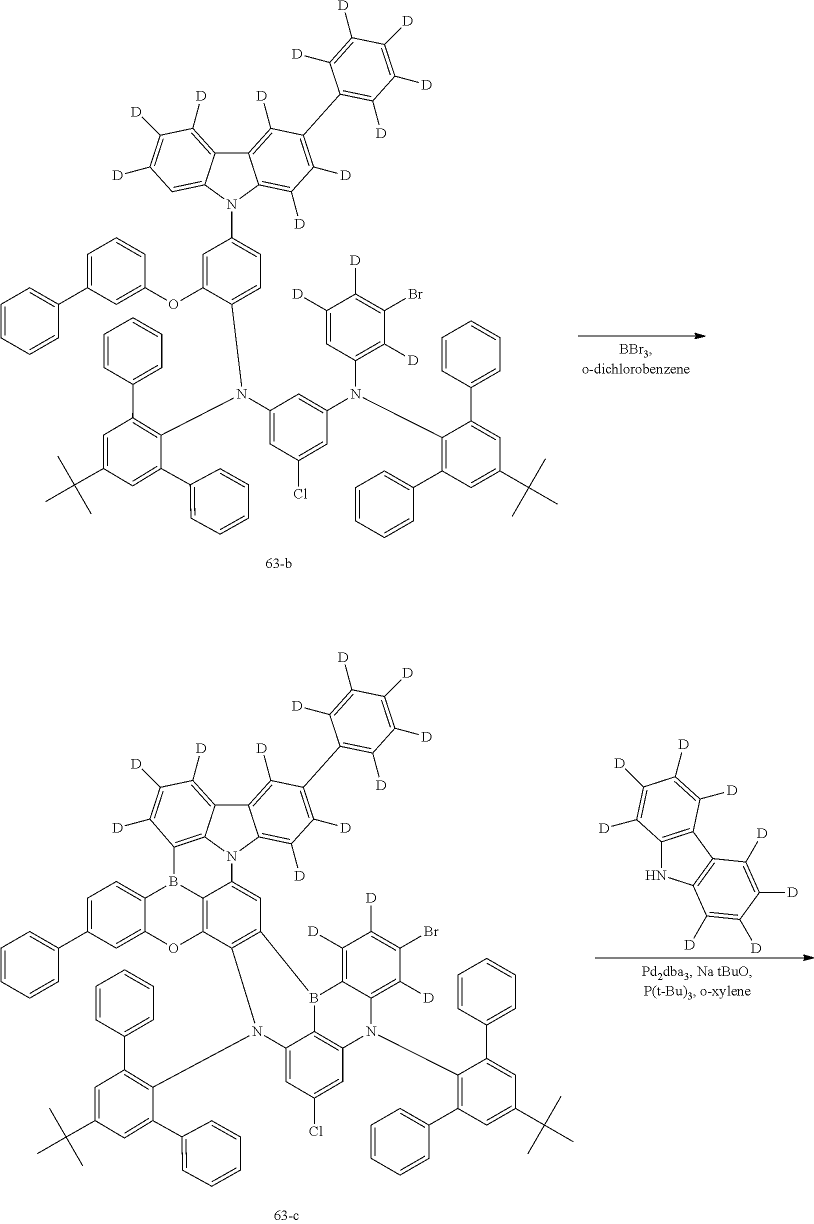

In an argon atmosphere, to a 1-L flask, Intermediate 63-b (8.3 g, 5.6 mmol) was added and dissolved in 100 mL of o-dichlorobenzene, and BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to Intermediate 63-c (yellow solid, 1.9 g, yield: 25%).

ESI-LCMS: [M]⁺: C₉₂H₅₃D₁₄B₂BrClN₃O. 1379.5243

### (Synthesis of Intermediate 63-d)

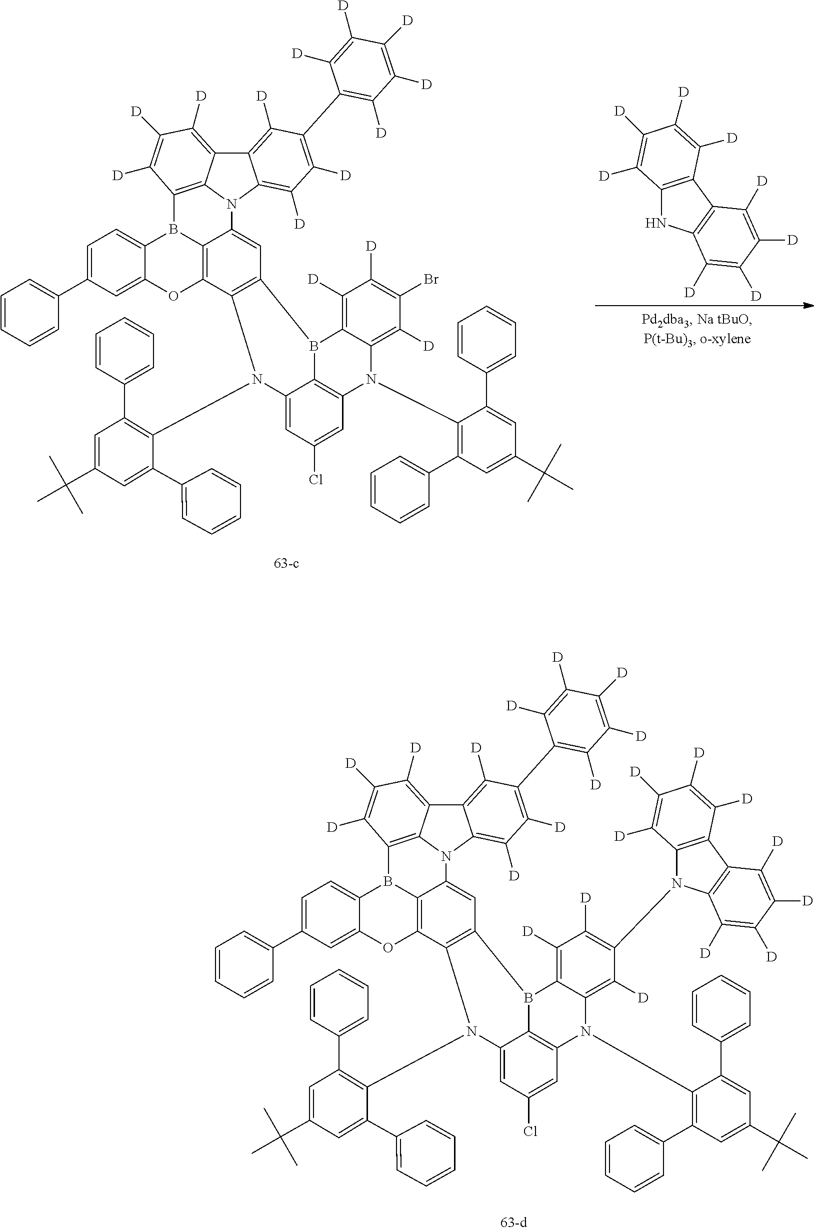

In an argon atmosphere, to a 1-L flask, Intermediate 63-c (1.9 g, 1.4 mmol), 9H-carbazole-1,2,3,4,5,6,7,8-d8 (0.25 g, 1.4 mmol), Pd₂dba₃ (0.06 g, 0.12 mmol), tris-tert-butyl phosphine (0.06 mL, 0.24 mmol), and sodium tert-butoxide (0.5 g, 5.1 mmol) were added and dissolved in 100 mL of o-xylene, and the reaction solution was stirred at about 140° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 63-d (yellow solid, 1.6 g, yield: 76%).

ESI-LCMS: [M]⁺: C₁₀₄H₅₃D₂₂B₂ClN₄O. 1474.7216

### (Synthesis of Compound 63)

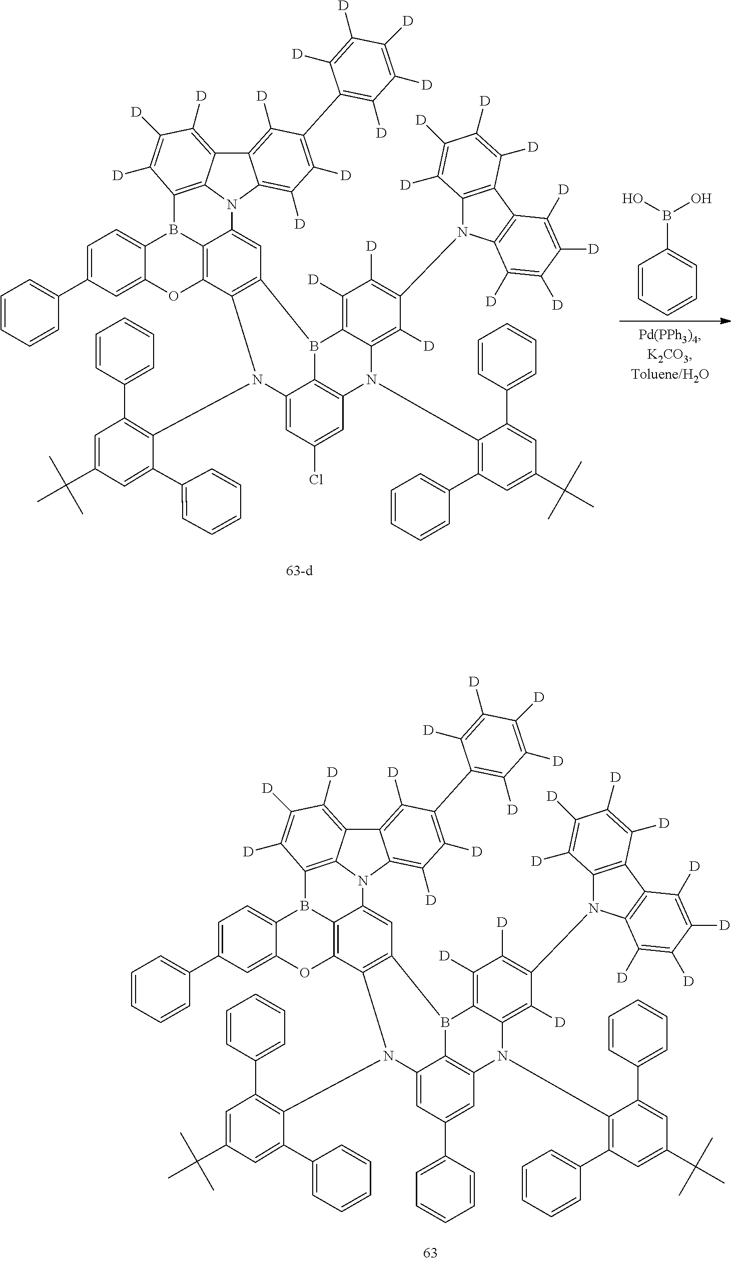

In an argon atmosphere, to a 1 L-flask, Intermediate 63-d (1.6 g, 15 mmol), phenyl boronic acid (0.1 g, 1 mmol), Pd(PPh₃)₄ (0.08 g, 0.06 mmol), and potassium carbonate (0.5 g, 3.9 mmol) were added and dissolved in 100 mL toluene and 30 mL of H₂O, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 63 (yellow solid, 0.98 g, yield: 71%).

ESI-LCMS: [M]⁺: C₁₁₀H₅₈D₂₂B₂N₄O. 1516.7192

¹H-NMR (CDCl₃): d=8.86 (s, 1H), 7.90 (d, 1H), 7.75 (m, 4H), 7.51 (m, 7H), 7.41 (s, 4H), 7.19 (m, 12H), 7.05 (m, 8H), 6.87 (s, 2H), 1.36 (s, 18H), 1.25 (s, 9H)

### (5) Synthesis of Compound 71

Compound 71 according to an example may be synthesized, for example, by the reaction:

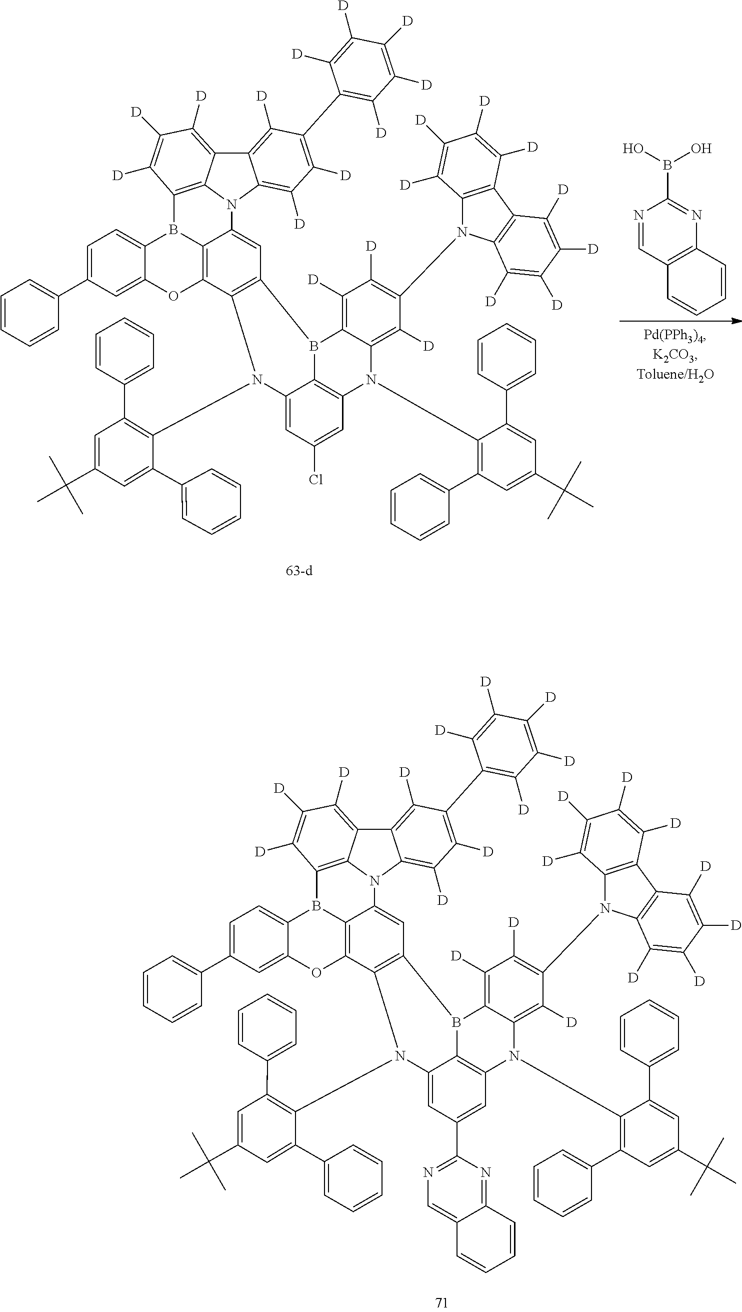

In an argon atmosphere, to a 1 L-flask, Intermediate 63-d (1.6 g, 15 mmol), quinazolin-2-ylboronic acid (0.17 g, 1 mmol), Pd(PPh₃)₄ (0.08 g, 0.06 mmol), and potassium carbonate (0.5 g, 3.9 mmol) were added and dissolved in 100 mL of toluene and 30 mL of H₂O, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 71 (yellow solid, 1.1 g, yield: 74%).

ESI-LCMS: [M]⁺: C₁₁₂H₅₈D₂₂B₂N₆O. 1568.8775

¹H-NMR (CDCl₃): d=9.71 (s, 1H), 8.95 (s, 1H), 8.32 (d, 1H), 7.91 (d, 1H), 7.80 (m, 2H), 7.65 (m, 2H), 7.51 (t, 1H), 7.47 (m, 4H), 7.38 (s, 4H), 7.18 (m, 12H), 7.07 (m, 8H), 6.93 (s, 2H), 1.33 (s, 18H), 1.22 (s, 9H)

### (6) Synthesis of Compound 41

Compound 41 according to an example may be synthesized, for example, by the reaction:

### (Synthesis of Intermediate 41-a)

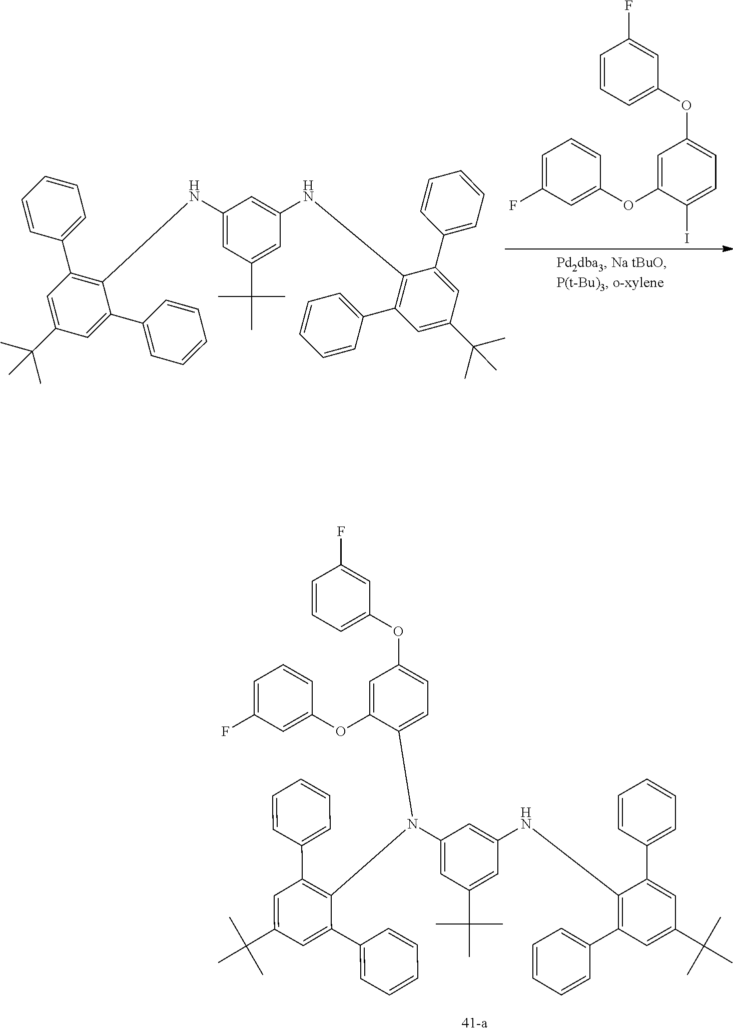

In an argon atmosphere, to a 2-L flask, 5-(tert-butyl)-N1,N3-bis(5′-(tert-butyl)-[1,1′:3′,1″-terphenyl]-2′-yl)benzene-1,3-diamine (10 g, 13.5 mmol), 3,3′-((4-iodo-1,3-phenylene)bis(oxy))bis(fluorobenzene) (5.7 g, 13.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 41-a (white solid, 9 g, yield: 65%).

ESI-LCMS: [M]⁺: C₇₂H₆₆F₂N₂O₂. 1028.5113.

### (Synthesis of Intermediate 41-b)

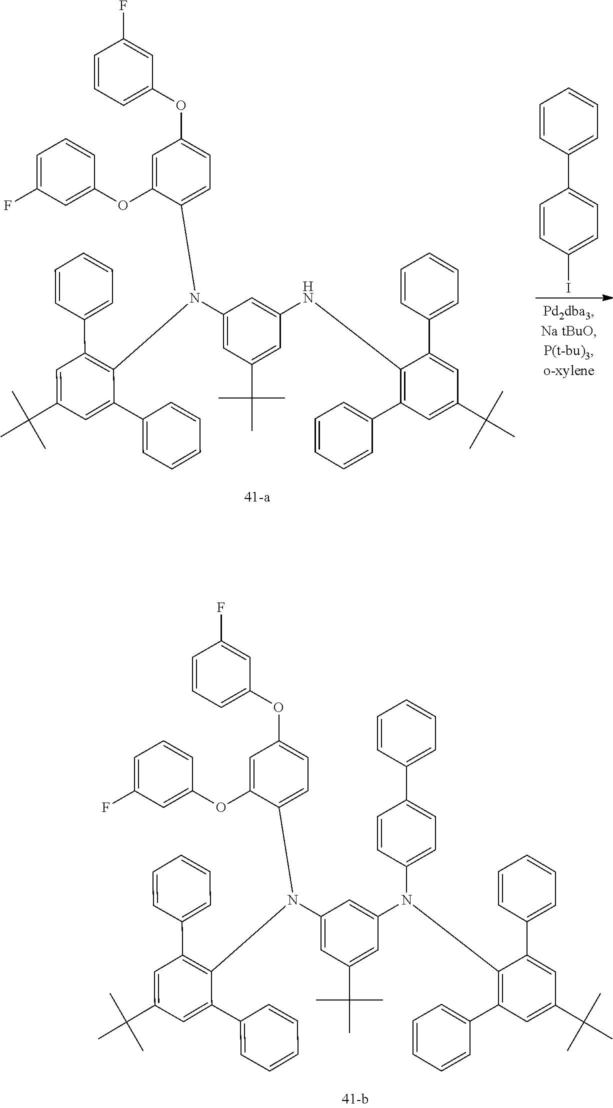

In an argon atmosphere, to a 2-L flask, Intermediate 41-a (9 g, 8.7 mmol), 4-iodo-1,1′-biphenyl (2.5 g, 8.7 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 41-b (white solid, 7.3 g, yield: 71%).

ESI-LCMS: [M]⁺: C₈₄H₇₄F₂N₂O₂. 1180.5771.

### (Synthesis of Intermediate 41-c)

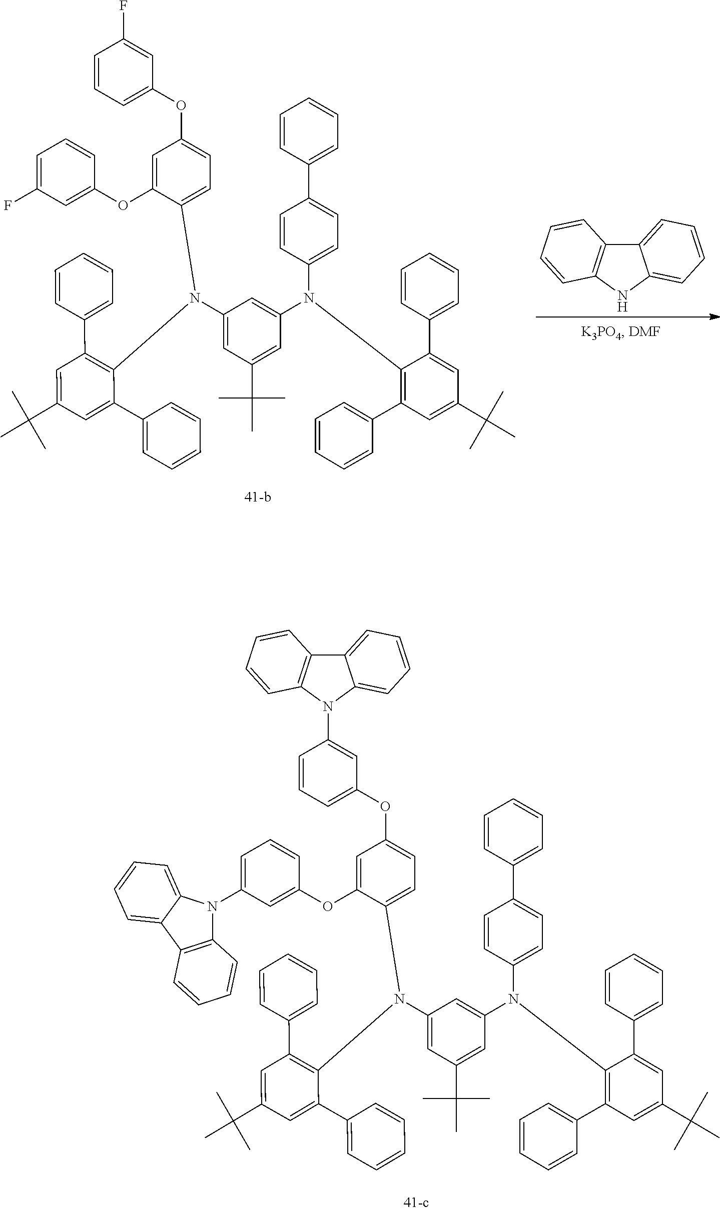 [SMILES: CC(C)(C)c1cc(N(c2ccc(-c3ccccc3)cc2)c2c(-c3ccccc3)cc(C(C)(C)C)cc2-c2ccccc2)cc(N(c2ccc(Oc3cccc(F)c3)cc2Oc2cccc(F)c2)c2c(-c3ccccc3)cc(C(C)(C)C)cc2-c2ccccc2)c1 ; c1ccc2c(c1)[nH]c1ccccc12 ; CC(C)(C)c1cc(N(c2ccc(-c3ccccc3)cc2)c2c(-c3ccccc3)cc(C(C)(C)C)cc2-c2ccccc2)cc(N(c2ccc(Oc3cccc(-n4c5ccccc5c5ccccc54)c3)cc2Oc2cccc(-n3c4ccccc4c4ccccc43)c2)c2c(-c3ccccc3)cc(C(C)(C)C)cc2-c2ccccc2)c1]

In an argon atmosphere, in a 2-L flask, Intermediate 41-b (7.3 g, 6.2 mmol), 9H-carbazole (2.1 g, 12.4 mmol), and K₃PO₄ (3.9 g, 18.6 mmol) were added and dissolved in 100 mL of DMF, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 41-c (white solid, 7 g, yield: 77%).

ESI-LCMS: [M]⁺: C₁₀₈H₉₀N₄O₂. 1474.7101.

### (Synthesis of Compound 41)

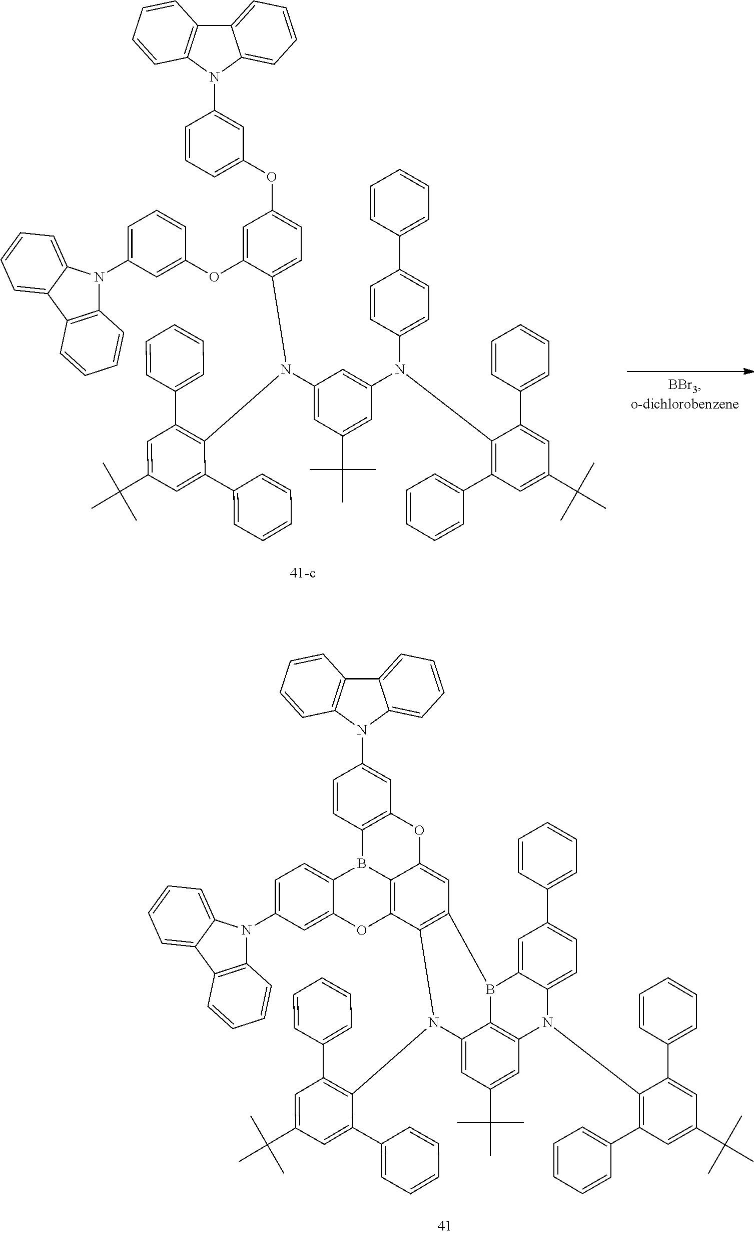 [SMILES: CC(C)(C)c1cc(N(c2ccc(-c3ccccc3)cc2)c2c(-c3ccccc3)cc(C(C)(C)C)cc2-c2ccccc2)cc(N(c2ccc(Oc3cccc(-n4c5ccccc5c5ccccc54)c3)cc2Oc2cccc(-n3c4ccccc4c4ccccc43)c2)c2c(-c3ccccc3)cc(C(C)(C)C)cc2-c2ccccc2)c1 ; CC(C)(C)c1cc(-c2ccccc2)c(N2c3ccc(-c4ccccc4)cc3B3c4cc5c6c(c4N(c4c(-c7ccccc7)cc(C(C)(C)C)cc4-c4ccccc4)c4cc(C(C)(C)C)cc2c43)Oc2cc(-n3c4ccccc4c4ccccc43)ccc2B6c2ccc(-n3c4ccccc4c4ccccc43)cc2O5)c(-c2ccccc2)c1]

In an argon atmosphere, to a 1-L flask, Intermediate 41-c (7 g, 4.8 mmol) was added and dissolved in 100 mL of o-dichlorobenzene, and BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Compound 41 (yellow solid, 1.9 g, yield: 25%).

ESI-LCMS: [M]⁺: C₁₀₈H₈₄B₂N₄O₂. 1490.6815

¹H-NMR (CDCl₃): d=8.55 (d, 4H), 7.94 (d, 4H), 7.85 (d, 2H), 7.75 (d, 2H), 7.58 (m, 14H), 7.43 (s, 4H), 7.33 (t, 4H), 7.14 (m, 12H), 7.11 (s, 2H), 7.02 (m, 8H), 6.99 (s, 2H), 1.39 (s, 18H), 1.22 (s, 9H)

### (7) Synthesis of Compound 51

Compound 51 according to an example may be synthesized, for example, by the reaction:

### (Synthesis of Intermediate 51-a)

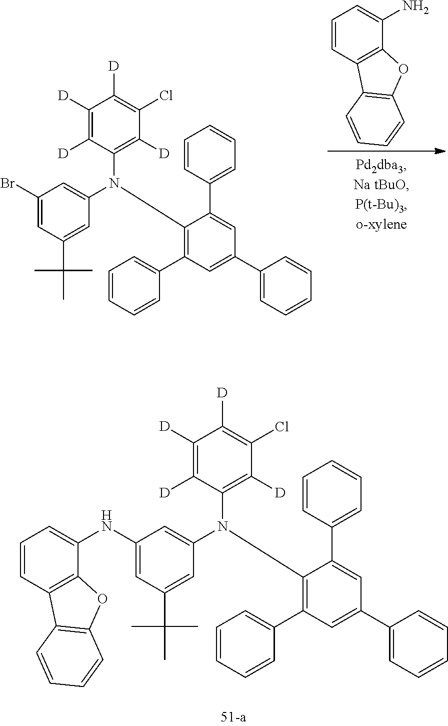 [SMILES: [2H]c1c([2H])c(Cl)c([2H])c(N(c2cc(Br)cc(C(C)(C)C)c2)c2c(-c3ccccc3)cc(-c3ccccc3)cc2-c2ccccc2)c1[2H] ; Nc1cccc2c1oc1ccccc12 ; [2H]c1c([2H])c(Cl)c([2H])c(N(c2cc(Nc3cccc4c3oc3ccccc34)cc(C(C)(C)C)c2)c2c(-c3ccccc3)cc(-c3ccccc3)cc2-c2ccccc2)c1[2H]]

In an argon atmosphere, to a 2-L flask, N-(3-bromo-5-(tert-butyl)phenyl)-N-(3-chlorophenyl-2,4,5,6-d4)-5′-phenyl-[1,1′:3′,1″-terphenyl]-2′-amine (10 g, 15.5 mmol), dibenzo[b,d]furan-4-amine (2.8 g, 15.5 mmol), Pd₂dba₃ (1.6 g, 1.9 mmol), tris-tert-butyl phosphine (1.6 mL, 3.8 mmol), and sodium tert-butoxide (11.5 g, 120 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 51-a (white solid, 7.7 g, yield: 66%).

ESI-LCMS: [M]⁺: C₅₂H₃₇D₄ClN₂O. 748.3112.

### (Synthesis of Intermediate 51-b)

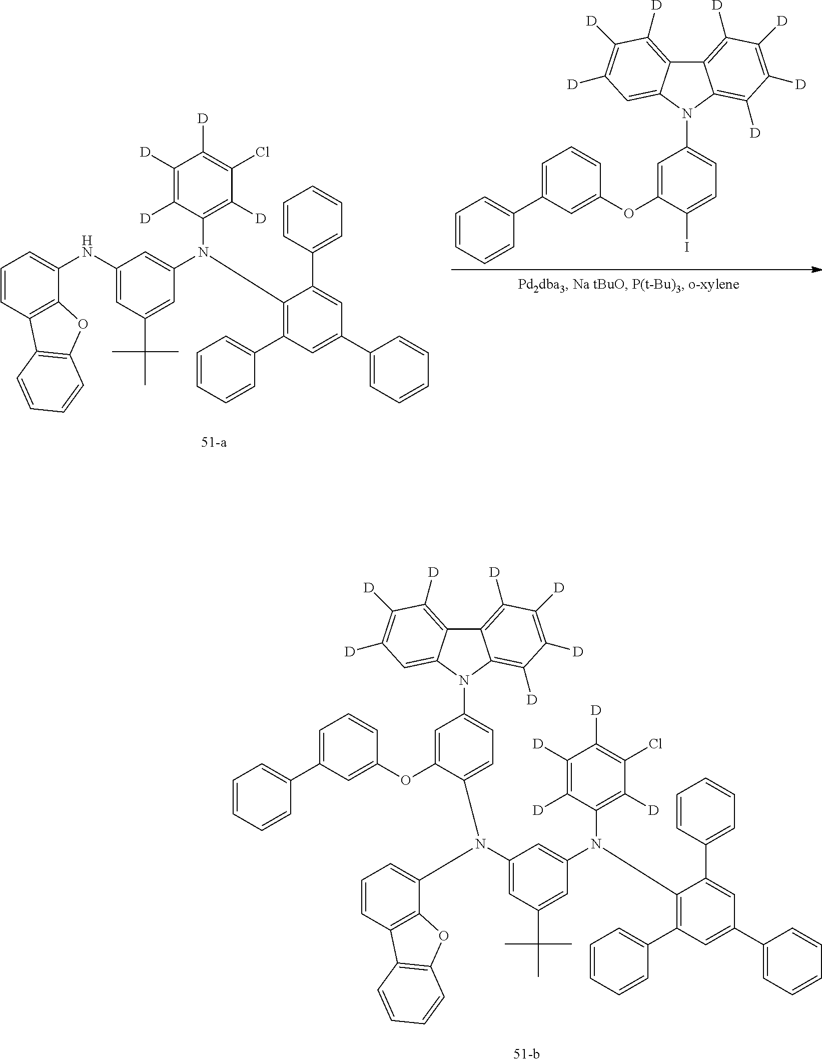 [SMILES: [2H]c1c([2H])c(Cl)c([2H])c(N(c2cc(Nc3cccc4c3oc3ccccc34)cc(C(C)(C)C)c2)c2c(-c3ccccc3)cc(-c3ccccc3)cc2-c2ccccc2)c1[2H] ; [2H]c1cc2c(c([2H])c1[2H])c1c([2H])c([2H])c([2H])c([2H])c1n2-c1ccc(I)c(Oc2cccc(-c3ccccc3)c2)c1 ; [2H]c1cc2c(c([2H])c1[2H])c1c([2H])c([2H])c([2H])c([2H])c1n2-c1ccc(N(c2cc(N(c3c(-c4ccccc4)cc(-c4ccccc4)cc3-c3ccccc3)c3c([2H])c([2H])c([2H])c(Cl)c3[2H])cc(C(C)(C)C)c2)c2cccc3c2oc2ccccc23)c(Oc2cccc(-c3ccccc3)c2)c1]

In an argon atmosphere, to a 2-L flask, Intermediate 51-a (7.7 g, 10 mmol), 9-(3-([1,1′-biphenyl]-3-yloxy)-4-iodophenyl)-9H-carbazole-1,2,3,4,5,6,7-d7 (5.6 g, 10 mmol), Pd₂dba₃ (1.6 g, 1.9 mmol), tris-tert-butyl phosphine (1.6 mL, 3.8 mmol), and sodium tert-butoxide (2.9 g, 30 mmol) were added and dissolved in 300 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate 51-b (white solid, 7.3 g, yield: 71%).

ESI-LCMS: [M]⁺: C₈₂H₄₉D₁₁ClN₃O₂. 1164.5151.

### (Synthesis of Intermediate 51-c)

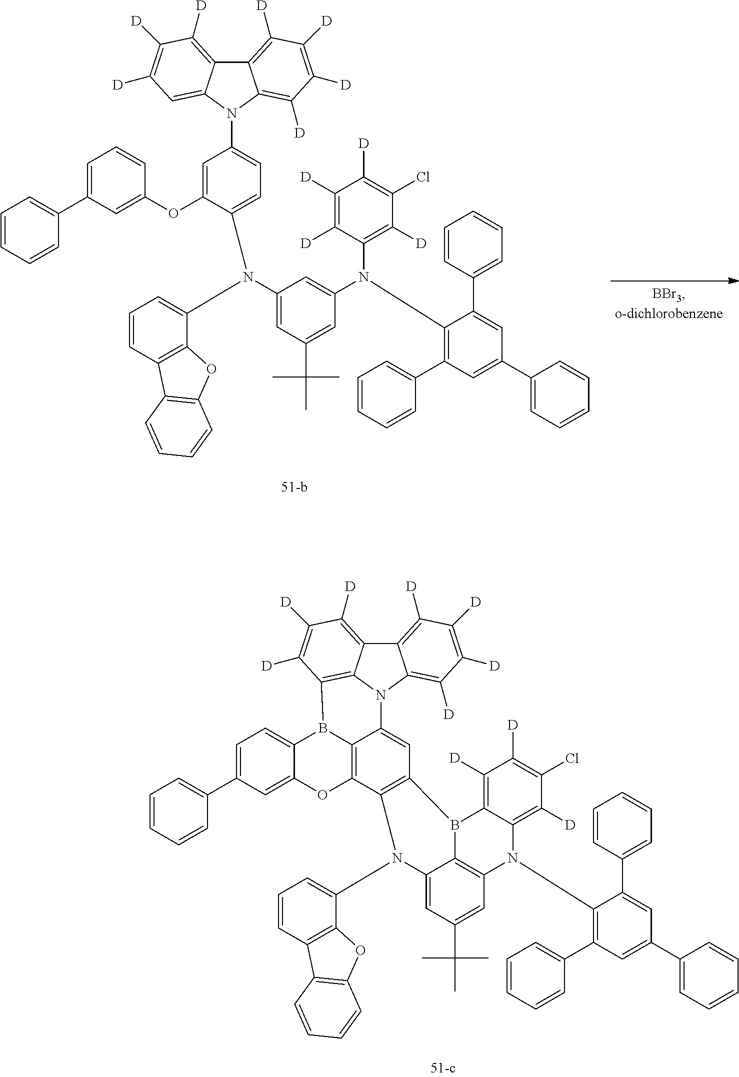 [SMILES: [2H]c1cc2c(c([2H])c1[2H])c1c([2H])c([2H])c([2H])c([2H])c1n2-c1ccc(N(c2cc(N(c3c(-c4ccccc4)cc(-c4ccccc4)cc3-c3ccccc3)c3c([2H])c([2H])c([2H])c(Cl)c3[2H])cc(C(C)(C)C)c2)c2cccc3c2oc2ccccc23)c(Oc2cccc(-c3ccccc3)c2)c1 ; [2H]c1c([2H])c2c(c([2H])c1Cl)N(c1c(-c3ccccc3)cc(-c3ccccc3)cc1-c1ccccc1)c1cc(C(C)(C)C)cc3c1B2c1cc2c4c(c1N3c1cccc3c1oc1ccccc13)Oc1cc(-c3ccccc3)ccc1B4c1c([2H])c([2H])c([2H])c3c4c([2H])c([2H])c([2H])c([2H])c4n-2c13]

In an argon atmosphere, to a 1-L flask, Intermediate 51-b (7 g, 6.2 mmol) was added and dissolved in 100 mL of o-dichlorobenzene, and BBr₃ (2.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to Intermediate 51-c (yellow solid, 1.55 g, yield: 21%).

ESI-LCMS: [M]⁺: C₈₂H₄₄D₁₀B₂ClN₃O₂. 1179.4717.

### (Synthesis of Compound 51)

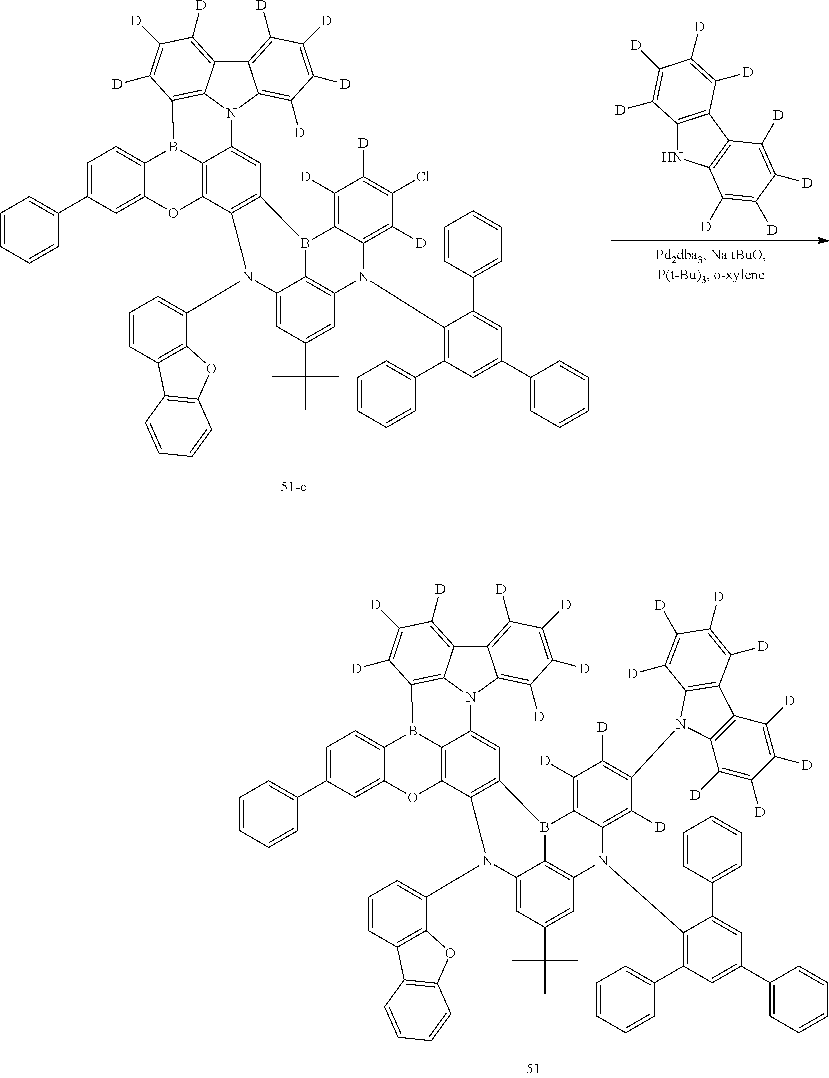

In an argon atmosphere, to a 2-L flask, Intermediate 51-c (1.5 g, 1.2 mmol), 9H-carbazole-1,2,3,4,5,6,7,8-d8 (0.22 g, 1.2 mmol), Pd₂dba₃ (0.2 g, 0.2 mmol), tris-tert-butyl phosphine (0.2 mL, 0.4 mmol), and sodium tert-butoxide (0.3 g, 3 mmol) were added and dissolved in 50 mL of o-xylene, and the reaction solution was stirred at about 140° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 51 (white solid, 1.2 g, yield: 75%).

ESI-LCMS: [M]⁺: C₉₄H₄₄D₁₈B₂N₄O₂. 1318.6212.

¹H-NMR (CDCl₃): d=7.98 (d, 2H), 7.90 (d, 1H), 7.75 (d, 2H), 7.58 (m, 9H), 7.43 (s, 2H), 7.36 (m, 3H), 7.21 (m, 12H), 7.13 (s, 1H), 7.05 (m, 8H), 6.88 (s, 2H), 1.27 (s, 9H)

### 2. Manufacture and Evaluation of Light Emitting Elements

The light emitting element according to an embodiment, including the fused polycyclic compound according to an embodiment, in an emission layer, was manufactured as follows. Compounds 16, 22, 26, 63, 71, 41, and 51, which are Example Compounds as described above, were used as dopant materials for the emission layers to manufacture the light emitting elements of Examples 1 to 7, respectively. Comparative Examples 1 to 5 correspond to the light emitting elements manufactured by using Comparative Example Compounds A to E as dopant materials for the emission layers, respectively.

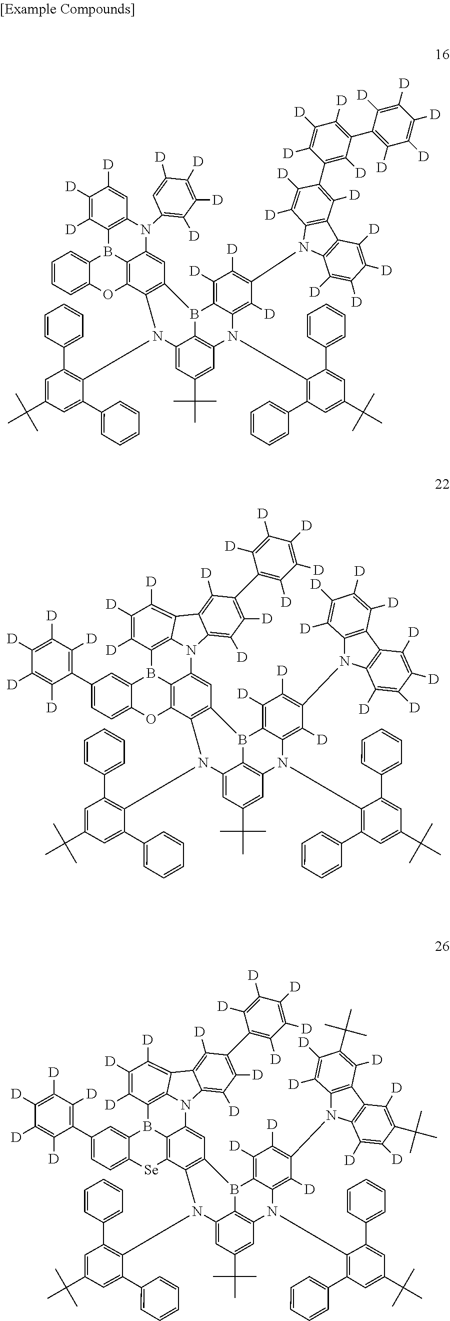

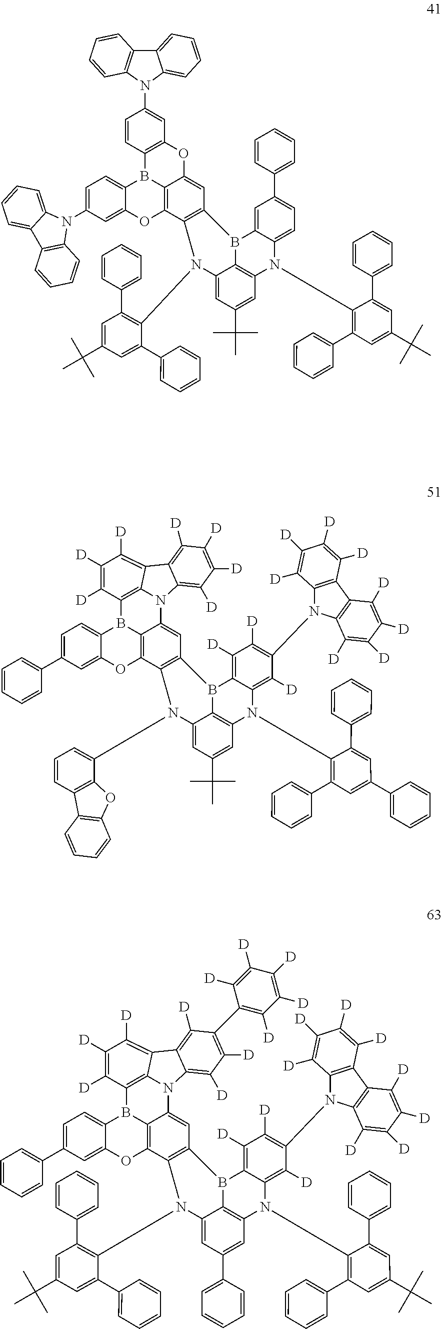

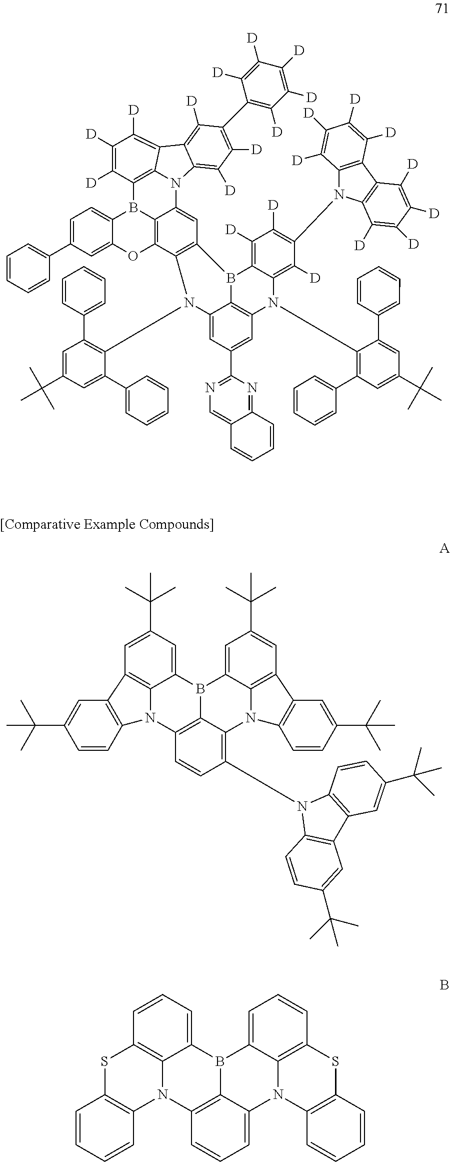

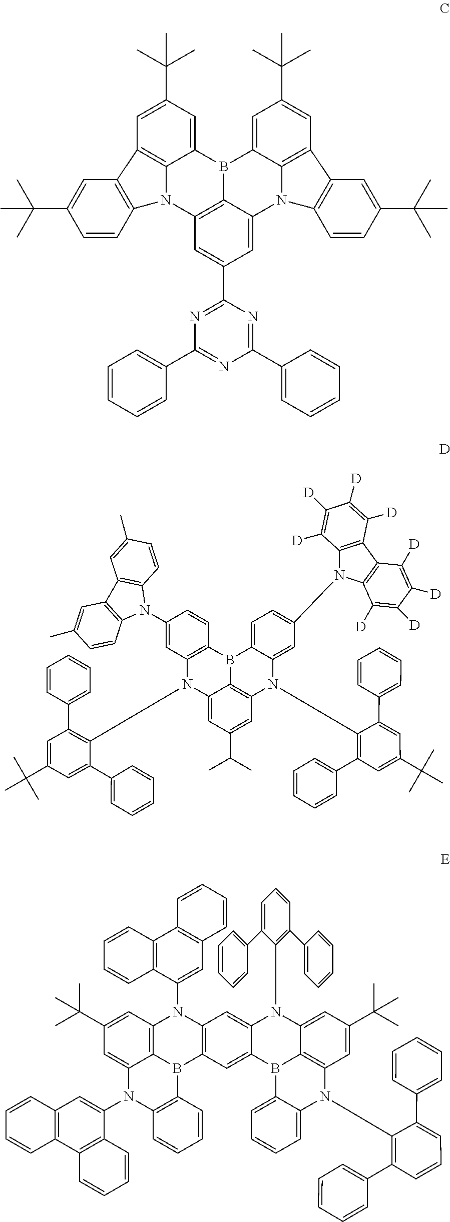

### (Manufacture of Light Emitting Elements)

In the light emitting elements of Examples and Comparative Examples, a glass substrate (made by Corning Co.), on which an ITO electrode of about 15 Ω/cm² (about 1200 Å) is formed as an anode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone and cleansed. The glass substrate was installed on a vacuum deposition apparatus.

NPD was deposited on the upper portion of the anode to form a 300 Å-thick hole injection layer. Compound H-1-19 was deposited on the upper portion of the hole injection layer to form a 200 Å-thick hole transport layer. CzSi was deposited on the upper portion of the hole transport layer to form a 100 Å-thick electron blocking layer.

A mixed host, in which a second compound and a third compound according to an embodiment were mixed in ratio of about 1:1, a fourth compound, and an Example Compound or a Comparative Example Compound were co-deposited at a weight ratio of about 85:14:1 to form a 200 Å-thick emission layer. On the upper portion of the emission layer, TSPO1 was deposited to form a 200 Å-thick hole blocking layer. On the upper portion of the hole blocking layer, TPBi was deposited to form a 300 Å-thick electron transport layer. On the upper portion of the electron transport layer, LiF was deposited to form a 10 Å-thick electron injection layer. A1 was used to form a 3,000 Å-thick second electrode, thereby forming a LiF/Al electrode. On the upper portion of the electrode, P4 was used to form a 700 Å-thick capping layer.

Each layer was formed by a vacuum deposition method. Compound HT60 from Compound Group 2 was used as the second compound, Compound ETH87 from Compound Group 3 was used as the third compound, and Compound M-a26 from Compound Group 4 was used as the fourth compound.

The compounds used for manufacturing the light emitting elements of the Examples and the Comparative Examples are disclosed below. The materials below were used to manufacture the elements by subjecting commercial products to sublimation purification.

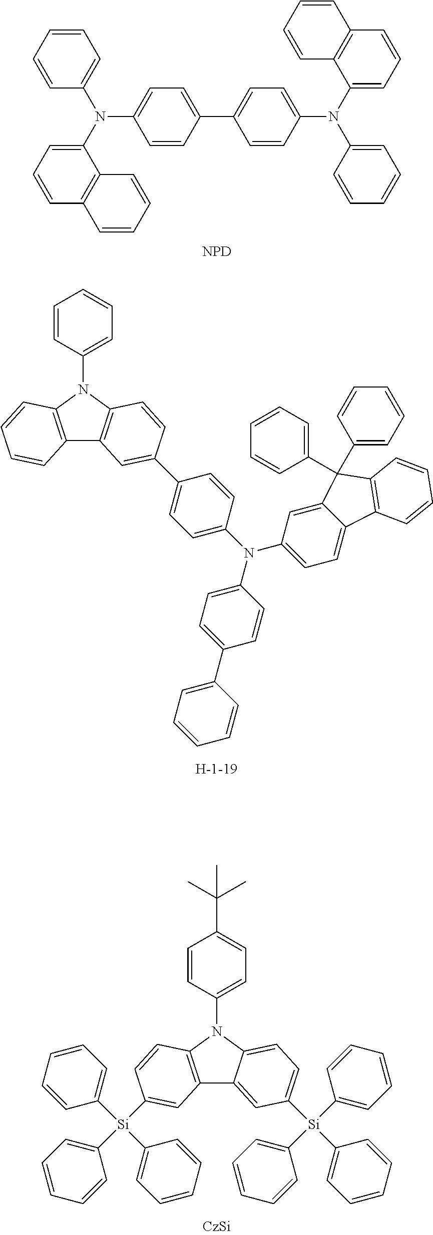

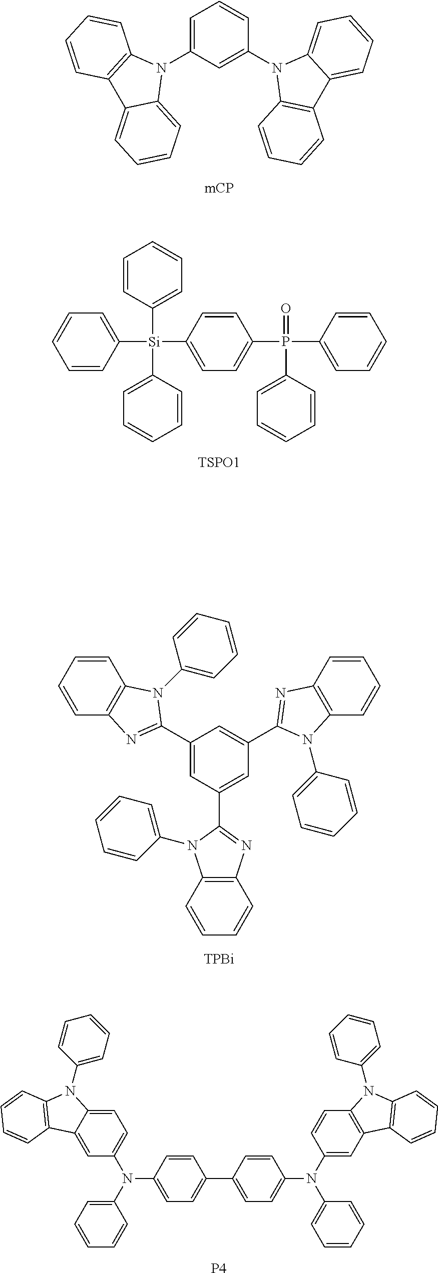

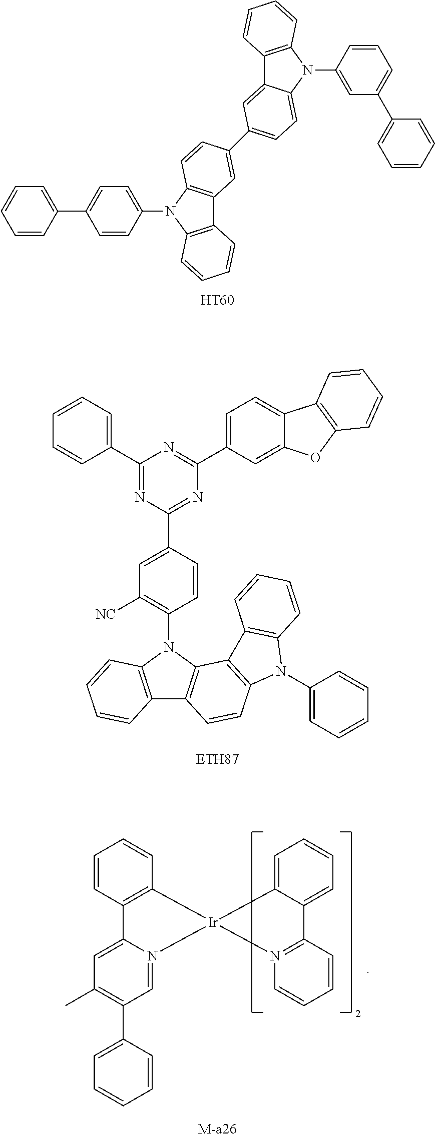

### (Evaluation of Light Emitting Element Characteristics)

### (Evaluation of Physical Properties of Example and Comparative Example Compounds)

Physical properties of Compounds 16, 22, 26, 63, 71, 41, and 51, which are Example Compounds, and Comparative Example Compounds A to E, which are Comparative Example Compounds, were evaluated and the results are listed in Table 1.

Highest occupied molecular orbital (HOMO) energy levels, lowest excited singlet energy levels (S1), lowest excited triplet energy levels (T1), absorption wavelengths (λ_{Abs}) and luminescence wavelengths (λₑₘᵢ) in a solution, Stokes-shift, and full width at half maximum (FWHM) were measured and the results are listed in Table 1.

In Table 1, λ_{Abs} was measured using Labsolution UV-Vis software with the UV-1800 UV/visible scanning spectrophotometer equipment, made by SHIMADZU Corp., equipped with a deuterium/tungsten-halogen light source and a silicon photodiode. The S1, T1, and λₑₘᵢ were measured using FluorEssence software with fluoromax+spectrometer equipment, made by HORIBA, Ltd., equipped with a xenon light source and a monochromator. Stokes-shift represents a difference between the maximum wavelength when the energy is absorbed and the maximum wavelength when the energy is emitted. The HOMO energy level was measured using Smart Manager software of SP2 electrochemical workstation equipment made by ZIVE LAB.

TABLE 1

| | | HOMO | S1 | T1 | λ_{Abs} | λₑₘᵢ | Stokes- | FWHM |
|---|---|---|---|---|---|---|---|---|
| | Dopant | (eV) | (eV) | (eV) | (nm) | (nm) | shift (nm) | (nm) |
| Example 1 | Compound 16 | −5.38 | 2.35 | 2.25 | 500 | 515 | 15 | 22 |
| Example 2 | Compound 22 | −5.34 | 2.32 | 2.21 | 515 | 525 | 10 | 19 |
| Example 3 | Compound 26 | −5.35 | 2.30 | 2.20 | 519 | 528 | 9 | 20 |
| Example 4 | Compound 63 | −5.45 | 2.29 | 2.20 | 522 | 530 | 8 | 18 |
| Example 5 | Compound 71 | −5.39 | 2.28 | 2.21 | 525 | 535 | 10 | 19 |
| Example 6 | Compound 41 | −5.50 | 2.40 | 2.33 | 490 | 498 | 8 | 16 |
| Example 7 | Compound 51 | −5.45 | 2.35 | 2.27 | 505 | 519 | 14 | 22 |
| Comparative | Comparative | −5.12 | 2.30 | 2.15 | 480 | 519 | 35 | 39 |
| Example 1 | Example | | | | | | | |
| | Compound A | | | | | | | |
| Comparative | Comparative | −5.02 | 2.32 | 2.17 | 468 | 510 | 39 | 42 |
| Example 2 | Example | | | | | | | |
| | Compound B | | | | | | | |
| Comparative | Comparative | −5.19 | 2.35 | 2.15 | 481 | 505 | 24 | 36 |
| Example 3 | Example | | | | | | | |
| | Compound C | | | | | | | |
| Comparative | Comparative | −5.35 | 2.70 | 2.56 | 450 | 460 | 10 | 39 |
| Example 4 | Example | | | | | | | |
| | Compound D | | | | | | | |
| Comparative | Comparative | −5.05 | 2.61 | 2.51 | 460 | 470 | 10 | 28 |
| Example 5 | Example | | | | | | | |
| | Compound E | | | | | | | |

Referring to Table 1, the compounds of Examples each may be used as a luminescence material which emits green light. Example Compounds in Examples 1 to 7 have smaller FWHM than compounds in Comparative Examples 1 and 5. Therefore, the light emitting elements of Examples 1 to 7 may exhibit higher color purities as compared with the light emitting elements of Comparative Examples 1 to 5.

### (Evaluation of Light Emitting Element Characteristics)

Driving voltages, element efficiencies, luminescence wavelengths, and element service lives of the light emitting elements manufactured with Experimental Example Compounds 16, 22, 26, 63, 71, 41, and 51, and Comparative Example Compounds A to E as described above were evaluated. Evaluation results of the light emitting elements of Examples 1 to 7 and Comparative Examples 1 to 5 are listed in Table 2. In the characteristic evaluation results of Examples and Comparative Example listed in Table 2, driving voltages and current densities were measured by using V7000 OLED JVL Test System (Polaronix). To evaluate the characteristics of the light emitting elements manufactured in Examples 1 to 7 and Comparative Examples 1 to 5, driving voltages and efficiencies (cd/A) at a current density of 10 mA/cm² were measured, and the relative device service life was set as a numerical value in which the deterioration time from an initial value to 95% brightness when the device was continuously operated at a current density of 10 mA/cm² was compared to Comparative Example 1, and the evaluation was carried out.

TABLE 2

| | Host | | | | | | |
|---|---|---|---|---|---|---|---|
| | (second | | | | | | |
| | compound:third | | | Driving | Top | | |
| | compound = | Fourth | First | voltage | efficiency | Luminescence | Service |
| | 5:5) | compound | compound | (V) | (cd/A/y) | wavelength (nm) | life (T95) |
| Example 1 | HT60/EHT87 | M-a26 | Compound 16 | 3.3 | 280 | 519 | 5.3 |
| Example 2 | HT60/EHT87 | M-a26 | Compound 22 | 3.2 | 275 | 528 | 8.5 |
| Example 3 | HT60/EHT87 | M-a26 | Compound 26 | 3.3 | 305 | 530 | 6.4 |
| Example 4 | HT60/EHT87 | M-a26 | Compound 63 | 3.3 | 290 | 532 | 7.0 |
| Example 5 | HT60/EHT87 | M-a26 | Compound 71 | 3.2 | 270 | 537 | 7.4 |
| Example 6 | HT60/EHT87 | M-a26 | Compound 41 | 3.4 | 230 | 505 | 6.8 |
| Example 7 | HT60/EHT87 | M-a26 | Compound 51 | 3.1 | 250 | 522 | 5.1 |
| Comparative | HT60/EHT87 | M-a26 | Comparative | 3.8 | 190 | 530 | 1 |
| Example 1 | | | Example | | | | |
| | | | Compound A | | | | |
| Comparative | HT60/EHT87 | M-a26 | Comparative | 3.7 | 180 | 524 | 0.2 |
| Example 2 | | | Example | | | | |
| | | | Compound B | | | | |
| Comparative | HT60/EHT87 | M-a26 | Comparative | 4.0 | 220 | 515 | 1.3 |
| Example 3 | | | Example | | | | |
| | | | Compound C | | | | |
| Comparative | HT60/EHT87 | M-a26 | Comparative | 4.1 | 150 | 470 | 0.5 |
| Example 4 | | | Example | | | | |
| | | | Compound D | | | | |
| Comparative | HT60/EHT87 | M-a26 | Comparative | 4.0 | 170 | 480 | 0.01 |
| Example 5 | | | Example | | | | |
| | | | Compound E | | | | |

Referring to the results of Table 2, it may be confirmed that Examples of the light emitting elements, in which the fused polycyclic compounds according to the Examples are used as a luminescent material, all emit light in a green wavelength region. It may be confirmed that Examples 1 to 7 have low driving voltages, and improved luminous efficiency and service life characteristics as compared to Comparative Examples 1 to 5. Therefore, it may be seen that the fused polycyclic compound according to an embodiment may be used as a dopant material for the emission layer which emits light in the green wavelength region, and exhibits improved luminous efficiency and excellent service life characteristics compared with the case of use of the conventional host material. The fused polycyclic compound according to an embodiment has a structure in which two hydrocarbon rings are fused to the fused polycyclic heterocycle at specific positions via the boron atom and two heteroatoms, thereby achieving high efficiency and long service life. The fused polycyclic compounds of Example Compounds have an increase in the luminous efficiency and service life because the first substituent is included and thus the boron atom may be effectively protected and the intermolecular interaction may be suppressed, thereby controlling the formation of excimer or exciplex. The fused polycyclic compounds of Example Compounds each have an increase in the distance between adjacent molecules due to the first substituent to thereby suppress the Dexter energy transfer, and thus may suppress the deterioration of service life due to the increase of triplet concentration.

The light emitting element according to the Examples includes the fused polycyclic compound according to embodiments as a light emitting dopant of a thermally activated delayed fluorescence (TADF) light emitting element, and thus may achieve high element efficiency in a green wavelength region, and improved service life characteristics.

The light emitting element according to an embodiment may exhibit improved element characteristics with high efficiency and a long service life.

The fused polycyclic compound according to an embodiment may be included in the emission layer according to the light emitting element to contribute to high efficiency and a long service life of the light emitting element.

The display device according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode and comprising a first compound represented by Formula 1: 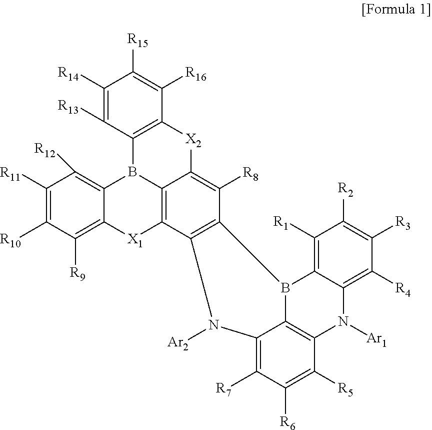
wherein in Formula 1,
X₁ and X₂ are each independently S, O, Se, Te, or N(R₁₇),
R₁ to R₁₆ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted amine group, a substituted or unsubstituted thio group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
R₁₇ is a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
Ar₁ and Ar₂ are each independently substituted or unsubstituted aryl group having 6 to 60 ring-forming carbon atoms, a substituted or unsubstituted heteroaryl group having 2 to 60 ring-forming carbon atoms, or bonded to an adjacent group to form a ring, and
at least one of Ar₁ and Ar₂ is each independently a group represented by Formula 2: 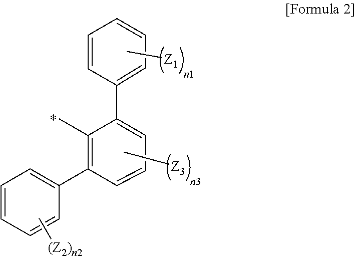
wherein in Formula 2,
Z₁ to Z₃ are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
n1 and n2 are each independently an integer from 0 to 5,
n3 is an integer from 0 to 3, and 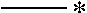
is a position linked to Formula 1.

2. The light emitting element of claim 1, wherein
at least one of Ar₁ and Ar₂ is each independently a group represented by Formula 2, and
the remainder of Ar₁ and Ar₂ is a group represented by one of Formula A-1 to Formula A-3: 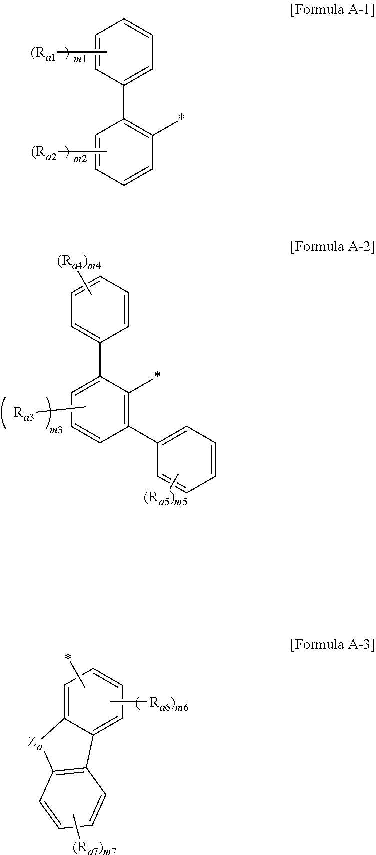
wherein in Formula A-1 to Formula A-3,
Zₐ is C(Rₐ₈)(Rₐ₉), N(Rₐ₁₀), O, S, or Se,
Rₐ₁ to Rₐ₁₀ are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
m1, m4, and m5 are each independently an integer from 0 to 5,
m2 and m7 are each independently an integer from 0 to 4,
m3 and m6 are each independently an integer from 0 to 3, and 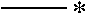
is a position linked to Formula 1.

3. The light emitting element of claim 1, wherein the first compound is represented by Formula 3: 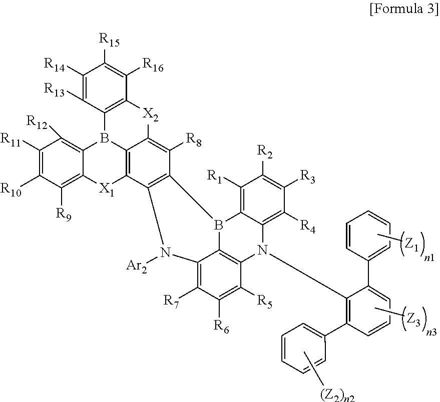
wherein in Formula 3,
X₁, X₂, R₁ to R₁₆, Ar₂, Z₁ to Z₃, and n1 to n3 are the same as defined in Formula 1 and Formula 2.

4. The light emitting element of claim 1, wherein the first compound is represented by Formula 4-1 or Formula 4-2: 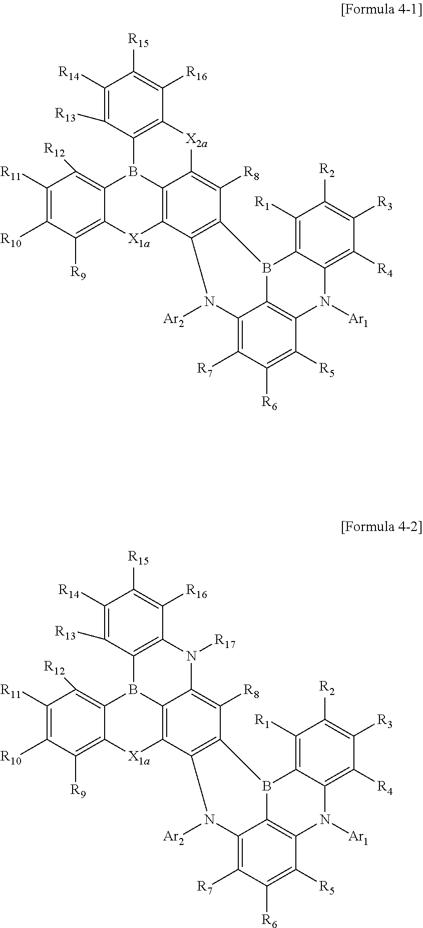
wherein in Formula 4-1 and Formula 4-2,
X₁ₐ and X₂ₐ are each independently S, O, Se, or Te, and
R₁ to R₁₇, Ar₁, and Ar₂ are the same as defined in Formula 1.

5. The light emitting element of claim 1, wherein the first compound is represented by Formula 5-1 or Formula 5-2: 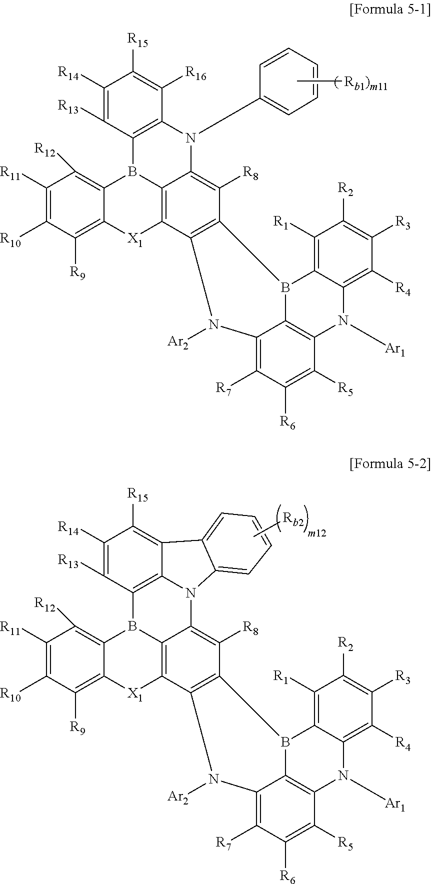
wherein in Formula 5-1 and Formula 5-2,
R_{b1} and R_{b2} are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms,
m11 is an integer from 0 to 5,
m12 is an integer from 0 to 4, and
X₁, R₁ to R₁₆, Ar₁, and Ar₂ are the same as defined in Formula 1.

6. The light emitting element of claim 1, wherein the first compound is represented by Formula 6-1 or Formula 6-2: 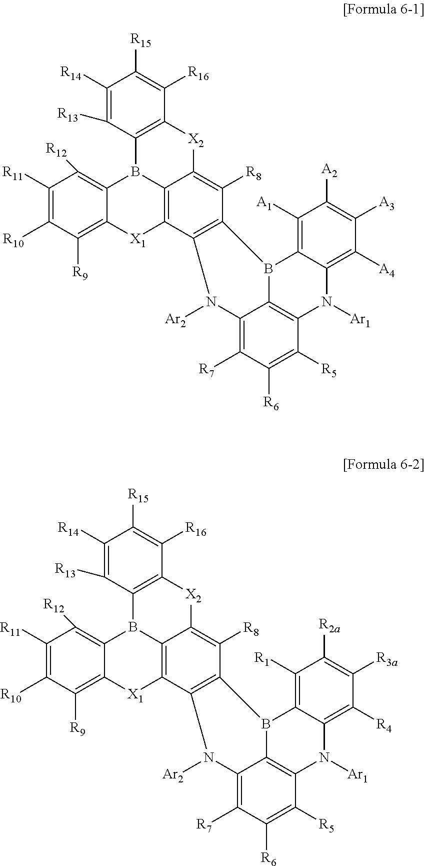
wherein in Formula 6-1 and Formula 6-2,
X₁, X₂, R₁, R₄ to R₁₆, Ar₁, and Ar₂ are the same as defined in Formula 1,
A₁ to A₄ are each independently a hydrogen atom or a deuterium atom,
R₂ₐ and R₃ₐ are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring, and
at least one of R₂ₐ and R₃ₐ is each independently a group represented by one of Formula B-1 to Formula B-6, or R₂ₐ and R₃ₐ are positions at which the substituent represented by Formula C-1 is fused: 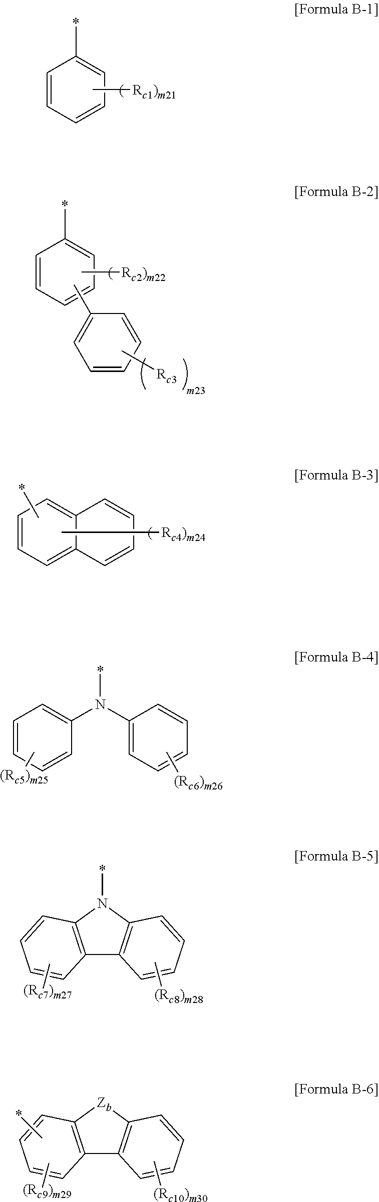
wherein in Formula B-1 to Formula B-6,
Z_{b} is O, S, Se, or N(R_{c11}),
R_{c1} to R_{c11} are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
m21, m23, m25, and m26 are each independently an integer from 0 to 5,
m22, m27, m28, and m30 are each independently an integer from 0 to 4,
m24 is an integer from 0 to 7, and
m29 is an integer from 0 to 3; and 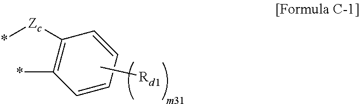
wherein in Formula C-1,
Z_{c} is O, S, or N(R_{d2}),
R_{d1} and R_{d2} are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
m31 is an integer from 0 to 4, and 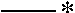 [SMILES: *C]
is a position fused at R₂ₐ and R₃ₐ in Formula 6-2.

7. The light emitting element of claim 1, wherein at least one of R₅ to R₇ is each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

8. The light emitting element of claim 1, wherein the first compound is represented by Formula 7: 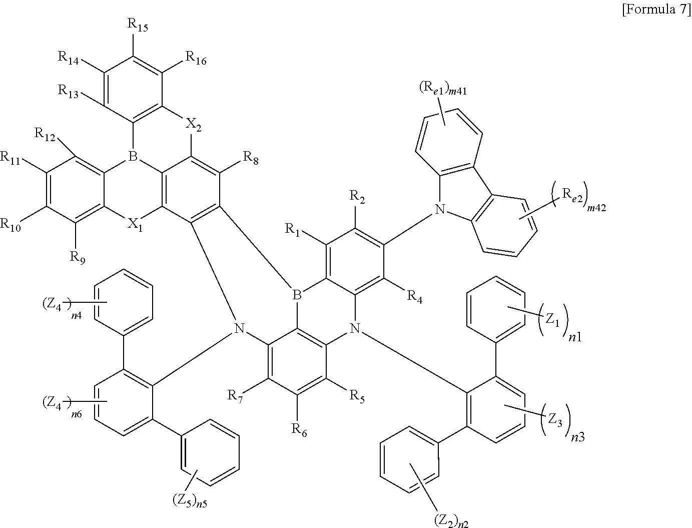
wherein in Formula 7,
Z₄ to Z₆, Rₑ₁, and Rₑ₂ are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
m41 and m42 are each independently an integer from 0 to 4,
n4 and n5 are each independently an integer from 0 to 5,
n6 is an integer from 0 to 3, and
X₁, X₂, R₁, R₂, R₄ to R₁₆, Z₁ to Z₃, and n1 to n3 are the same as defined in Formula 1 and Formula 2.

9. The light emitting element of claim 1, wherein the emission layer emits green light.

10. The light emitting element of claim 1, wherein the emission layer further comprises at least one of a second compound represented by Formula HT-1, a third compound represented by Formula ET-1, and a fourth compound represented by Formula M-a: 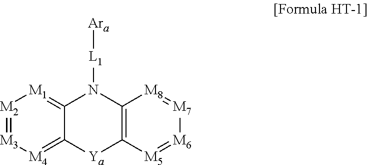
wherein in Formula HT-1,
M₁ to M₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Arₐ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring; 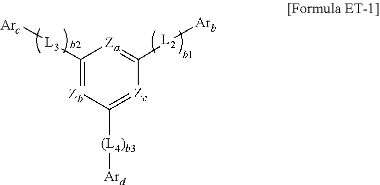
wherein in Formula ET-1,
at least one of Zₐ to Z_{c} is each N,
the remainder of Zₐ to Z_{c} are each independently C(R₅₆),
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
b1 to b3 are each independently an integer from 0 to 10,
Ar_{b} to Ar_{d} are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 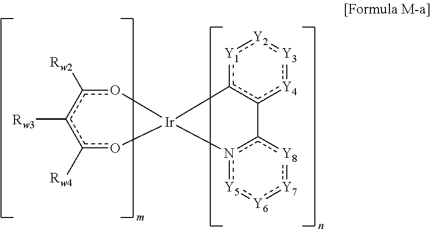
wherein in Formula M-a,
Y₁ to Y₈ are each independently C(R_{w1}) or N,
R_{w1} to R_{w4} are each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
m is 0 or 1,
n is 2 or 3, and
when m is 0, n is 3, and when m is 1, n is 2.

11. A display device comprising:
a circuit layer disposed on a base layer; and
a display element layer disposed on the circuit layer and comprising a light emitting element, wherein
the light emitting element comprises:
a first electrode;
a second electrode disposed on the first electrode; and
an emission layer disposed between the first electrode and the second electrode and comprising a first compound represented by Formula 1: 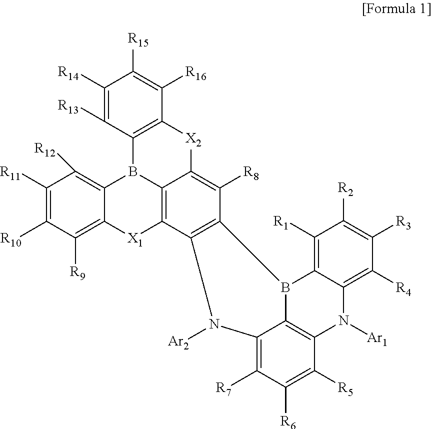
wherein in Formula 1,
X₁ and X₂ are each independently S, O, Se, Te, or N(R₁₇),
R₁ to R₁₆ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted amine group, a substituted or unsubstituted thio group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
R₁₇ is a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
Ar₁ and Ar₂ are each independently substituted or unsubstituted aryl group having 6 to 60 ring-forming carbon atoms, a substituted or unsubstituted heteroaryl group having 2 to 60 ring-forming carbon atoms, or bonded to an adjacent group to form a ring, and
at least one of Ar₁ and Ar₂ is each independently a group represented by Formula 2: 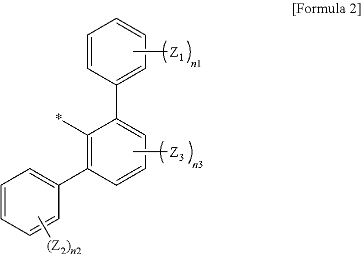
wherein in Formula 2,
Z₁ to Z₃ are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
n1 and n2 are each independently an integer from 0 to 5,
n3 is an integer from 0 to 3, and 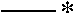 [SMILES: *C]
is a position linked to Formula 1.

12. The display device of claim 11, wherein
the light emitting element further comprises a capping layer disposed on the second electrode, and
the capping layer has a refractive index equal to or greater than about 1.6 with respect to light in a wavelength range of about 550 nm to about 660 nm.

13. The display device of claim 11, further comprising:
a light control layer disposed on the display device and comprising quantum dots, wherein
the light emitting element emits a first color light, and
the light control layer comprises:
a first light control part including a first quantum dot that converts the first color light into a second color light in a longer wavelength region than the first color light;
a second light control part including a second quantum dot that converts the second color light into a third color light in a longer wavelength region than the second color light; and
a third light control part that transmits the first color light.

14. The display device of claim 13, further comprising:
a color filter layer disposed on the light control layer, wherein
the color filter layer comprises:
a first filter that transmits the second color light;
a second filter that transmits the third color light; and
a third filter that transmits the first color light.

15. A fused polycyclic compound represented by Formula 1: 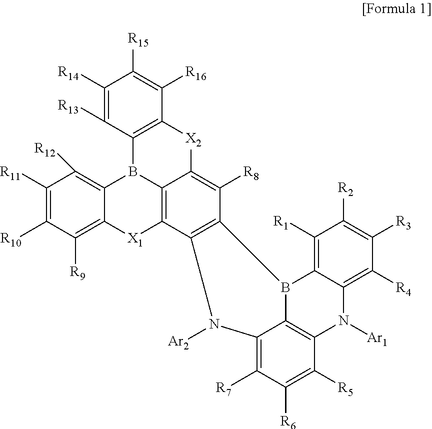
wherein in Formula 1,
X₁ and X₂ are each independently S, O, Se, Te, or N(R₁₇),
R₁ to R₁₆ are each independently a hydrogen atom, a deuterium atom, a halogen atom, a cyano group, a nitro group, a hydroxy group, a substituted or unsubstituted silyl group, a substituted or unsubstituted oxy group, a substituted or unsubstituted amine group, a substituted or unsubstituted thio group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
R₁₇ is a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
Ar₁ and Ar₂ are each independently substituted or unsubstituted aryl group having 6 to 60 ring-forming carbon atoms, a substituted or unsubstituted heteroaryl group having 2 to 60 ring-forming carbon atoms, or bonded to an adjacent group to form a ring, and
at least one of Ar₁ and Ar₂ is each independently a group represented by Formula 2: 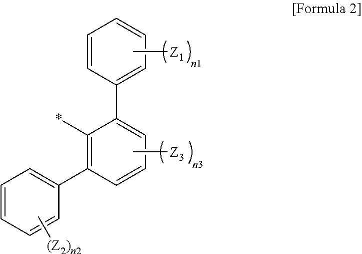
wherein in Formula 2,
Z₁ to Z₃ are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
n1 and n2 are each independently an integer from 0 to 5,
n3 is an integer from 0 to 3, and 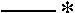 [SMILES: *C]
is a position linked to Formula 1.

16. The fused polycyclic compound of claim 15, wherein
a Stokes-shift of the fused polycyclic compound is equal to or less than about 25 nm, and
a full width at half maximum (FWHM) of the fused polycyclic compound is equal to or less than about 25 nm.

17. The fused polycyclic compound of claim 15, wherein the fused polycyclic compound is represented by Formula 3: 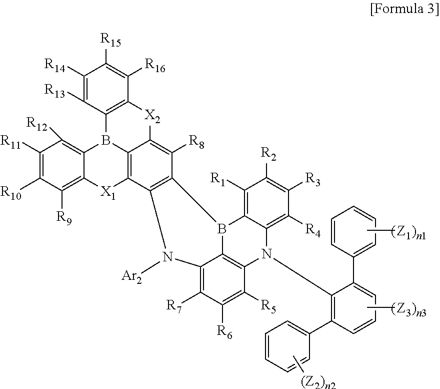
wherein in Formula 3,
X₁, X₂, R₁ to R₁₆, Ar₂, Z₁ to Z₃, and n1 to n3 are the same as defined in Formula 1 and Formula 2.

18. The fused polycyclic compound of claim 15, wherein the fused polycyclic compound is represented by Formula 5-1 or Formula 5-2: 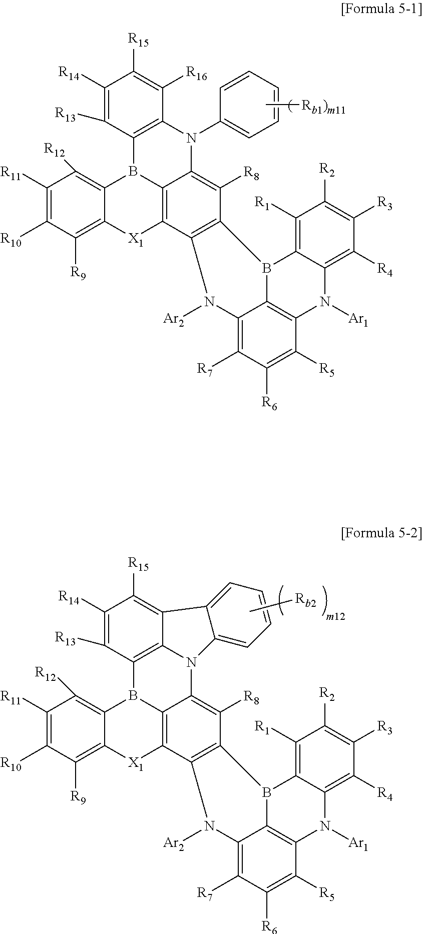
wherein in Formula 5-1 and Formula 5-2,
R_{b1} and R_{b2} are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms,
m11 is an integer from 0 to 5,
m12 is an integer from 0 to 4, and
X₁, R₁ to R₁₆, Ar₁, and Ar₂ are the same as defined in Formula 1.

19. The fused polycyclic compound of claim 15, wherein the fused polycyclic compound is represented by Formula 6-1 or Formula 6-2: 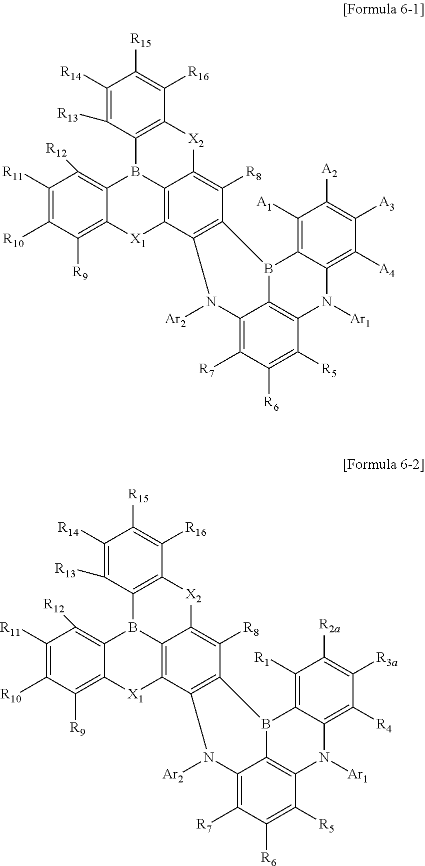
wherein, in Formula 6-1 and Formula 6-2,
X₁, X₂, R₁, R₄ to R₁₆, Ar₁, and Ar₂ are the same as defined in Formula 1,
A₁ to A₄ are each independently a hydrogen atom or a deuterium atom,
R₂ₐ and R₃ₐ are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring, and
at least one of R₂ₐ and R₃ₐ is each independently a group represented by one of Formula B-1 to Formula B-6, or R₂ₐ and R₃ₐ are positions at which the substituent represented by Formula C-1 is fused: 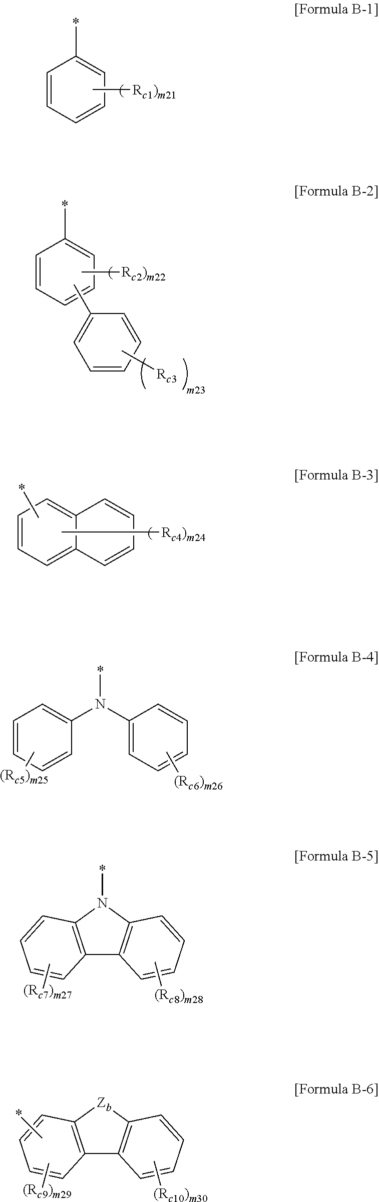
wherein in Formula B-1 to Formula B-6,
Z_{b} is O, S, Se, or N(R_{c11}),
R_{c1} to R_{c11} are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
m21, m23, m25, and m26 are each independently an integer from 0 to 5,
m22, m27, m28, and m30 are each independently an integer from 0 to 4,
m24 is an integer from 0 to 7, and
m29 is an integer from 0 to 3; and 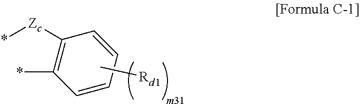
wherein in Formula C-1,
Z_{c} is O, S, or N(R_{d2}),
R_{d1} and R_{d2} are each independently a hydrogen atom, a deuterium atom, a halogen atom, a cyano group, a nitro group, a hydroxy group, a substituted or unsubstituted oxy group, a substituted or unsubstituted amine group, a substituted or unsubstituted thio group, a substituted or unsubstituted silyl group, a substituted or unsubstituted alkyl group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring,
m31 is an integer from 0 to 4, 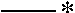 [SMILES: *C]
is a position fused at R₂ₐ and R₃ₐ in Formula 6-2.

20. The fused polycyclic compound of claim 15, wherein the fused polycyclic compound is selected from Compound Group 1:
[Compound Group 1] 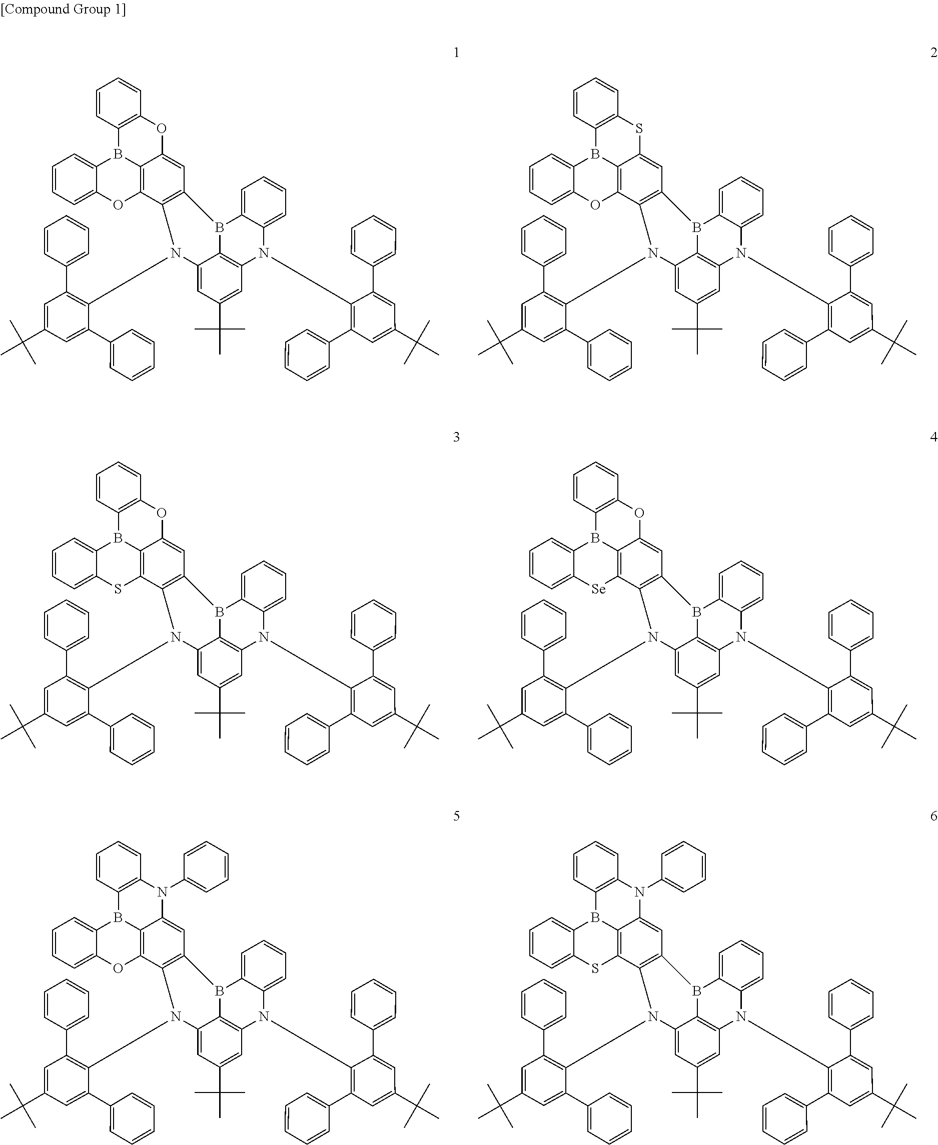 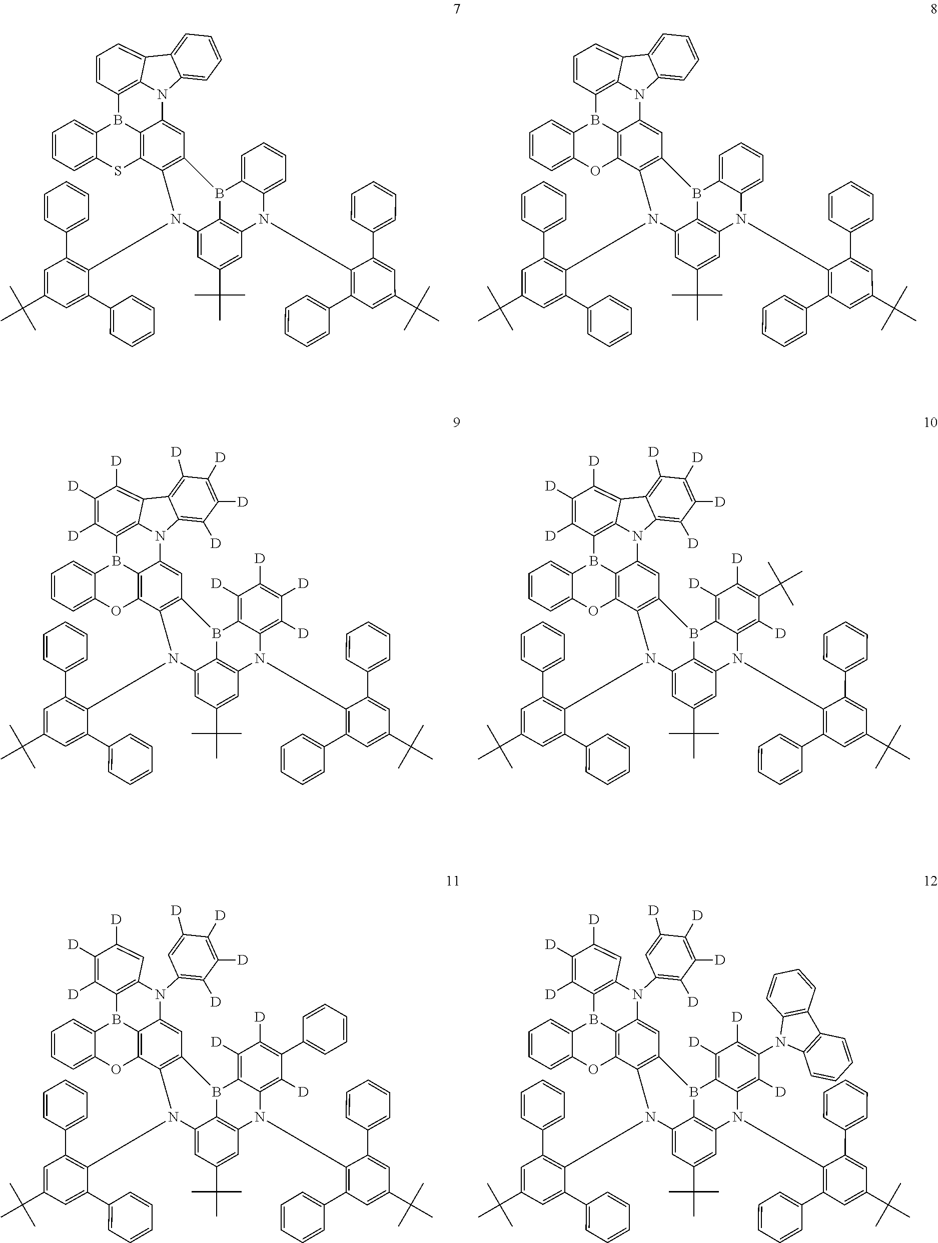 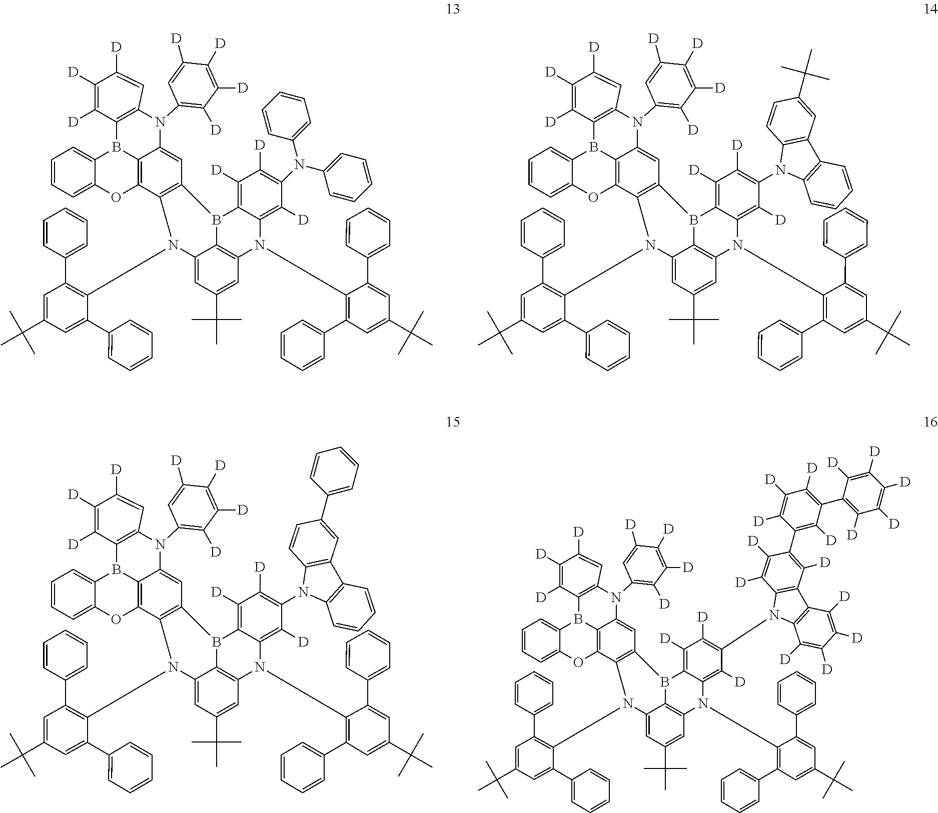 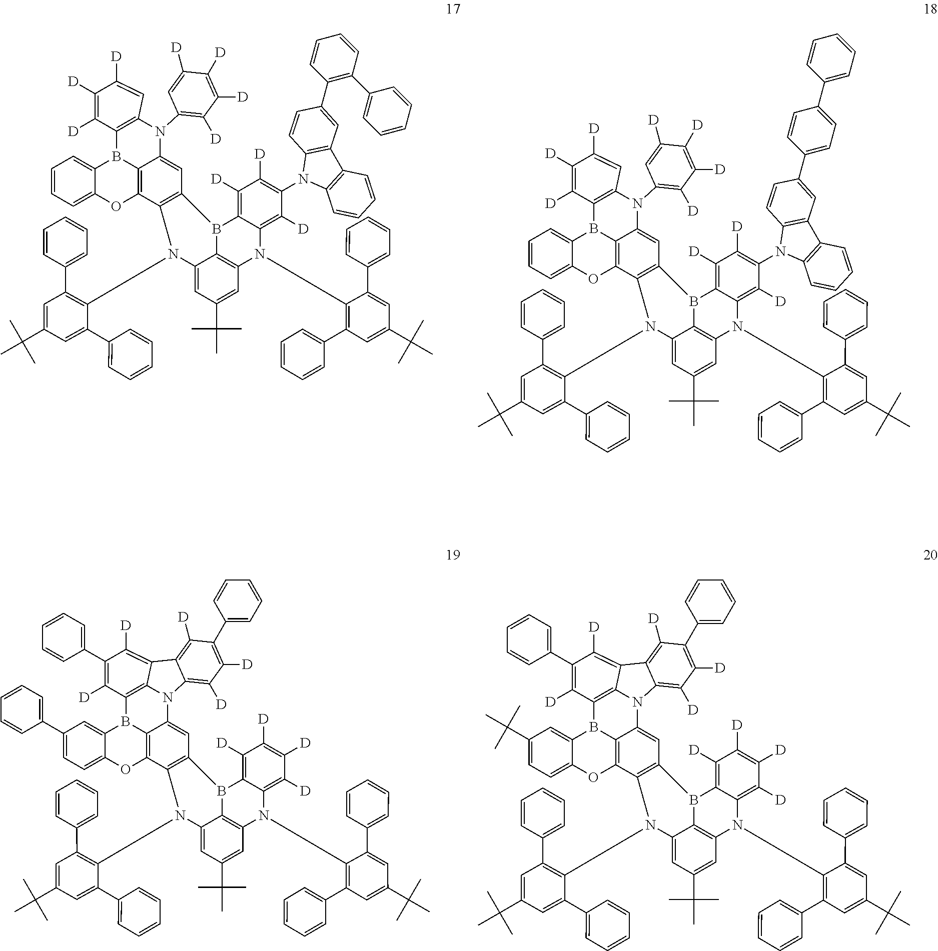 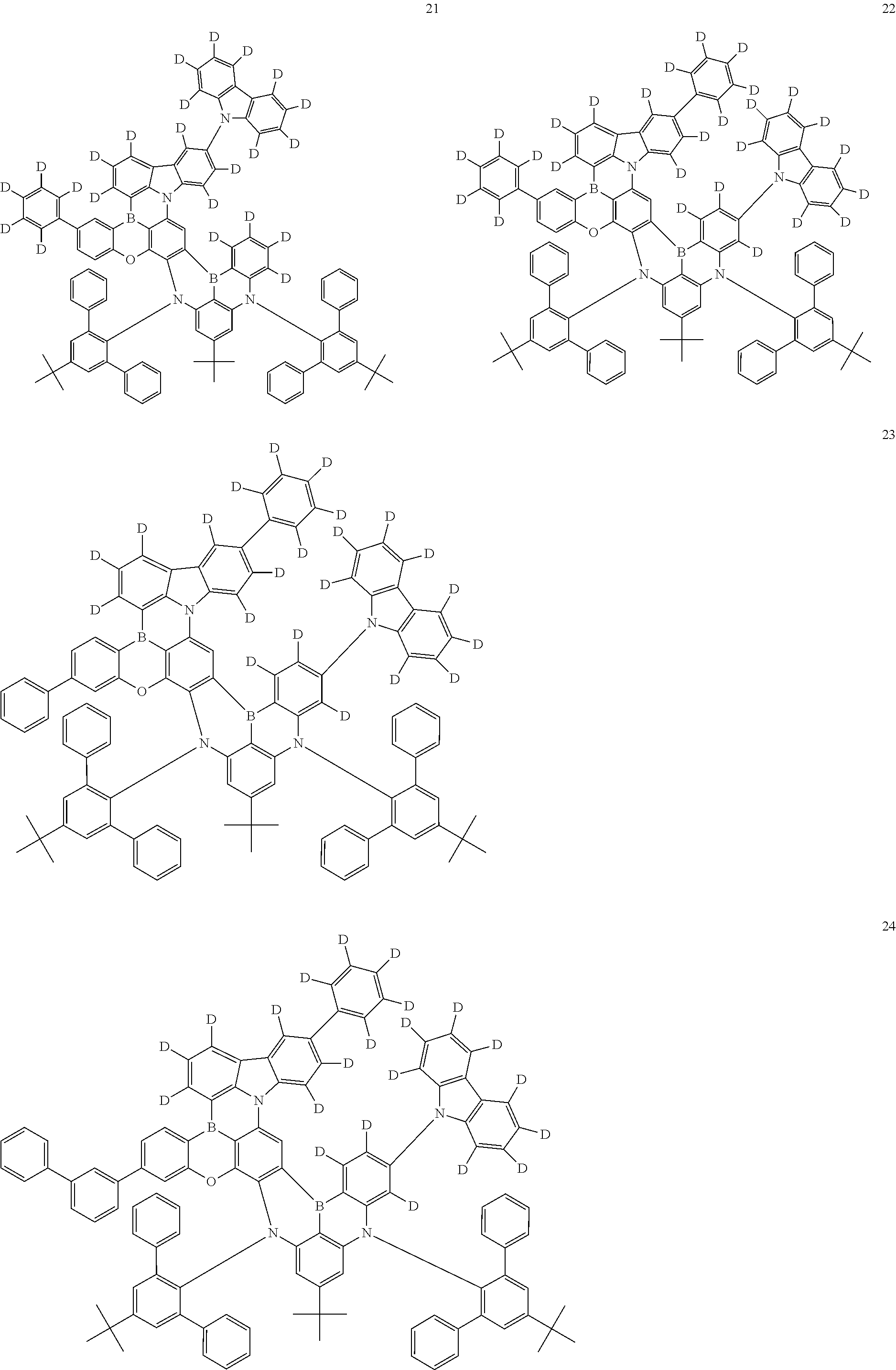 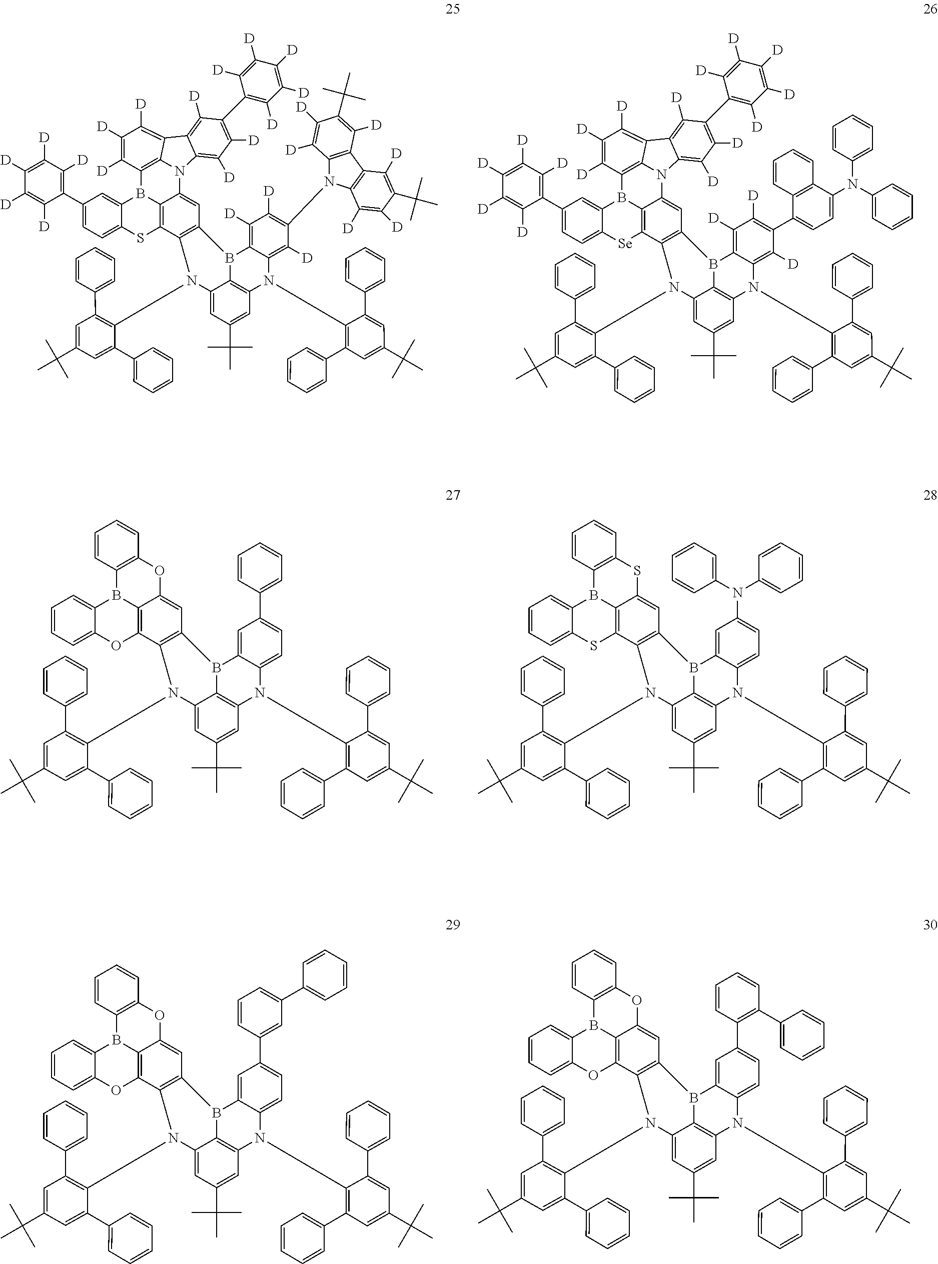 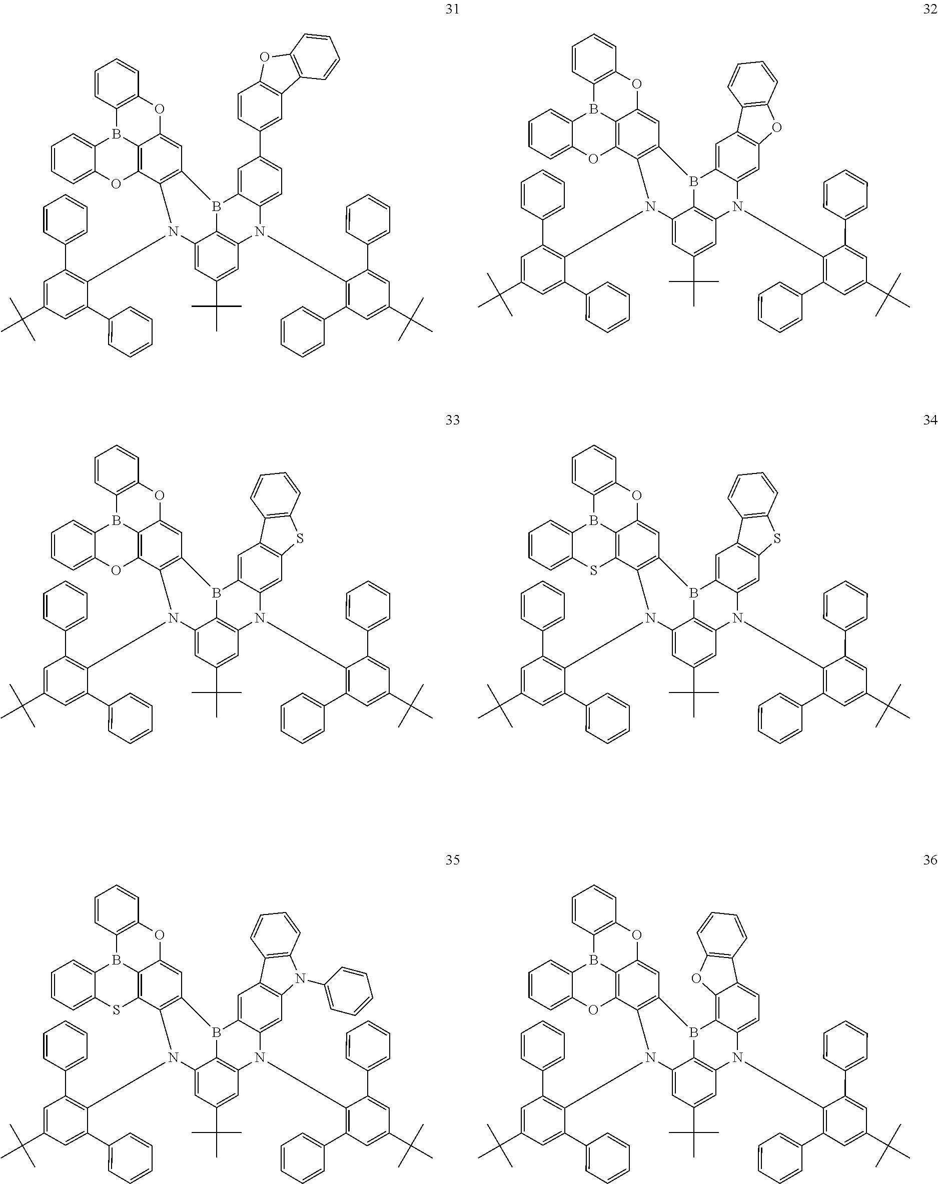 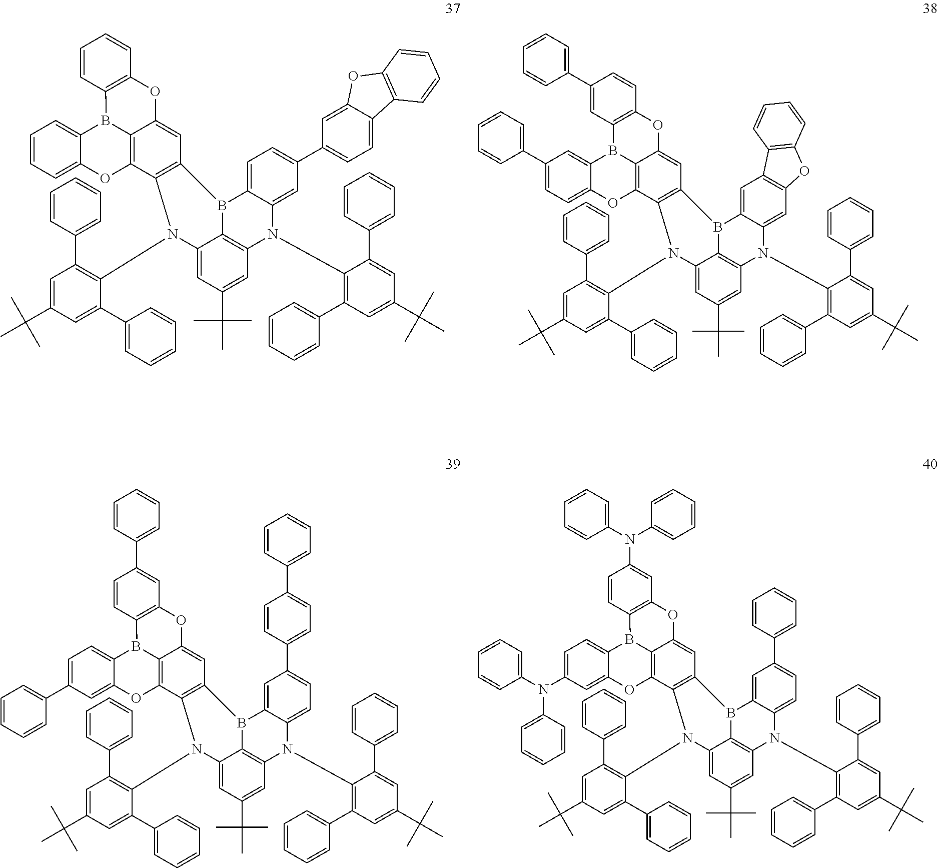 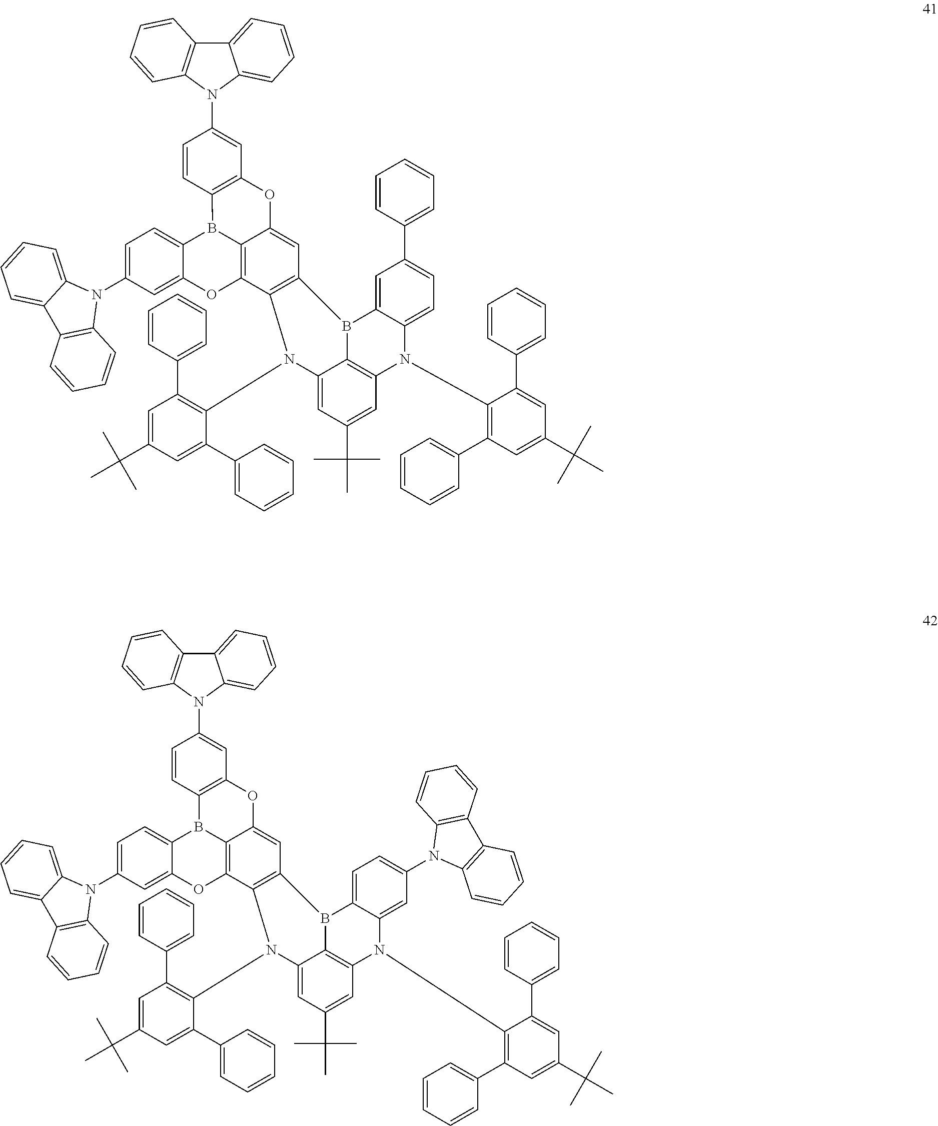 [SMILES: CC(C)(C)c1cc(-c2ccccc2)c(N2c3ccc(-c4ccccc4)cc3B3c4cc5c6c(c4N(c4c(-c7ccccc7)cc(C(C)(C)C)cc4-c4ccccc4)c4cc(C(C)(C)C)cc2c43)Oc2cc(-n3c4ccccc4c4ccccc43)ccc2B6c2ccc(-n3c4ccccc4c4ccccc43)cc2O5)c(-c2ccccc2)c1 ; CC(C)(C)c1cc(-c2ccccc2)c(N2c3cc(-n4c5ccccc5c5ccccc54)ccc3B3c4cc5c6c(c4N(c4c(-c7ccccc7)cc(C(C)(C)C)cc4-c4ccccc4)c4cc(C(C)(C)C)cc2c43)Oc2cc(-n3c4ccccc4c4ccccc43)ccc2B6c2ccc(-n3c4ccccc4c4ccccc43)cc2O5)c(-c2ccccc2)c1] 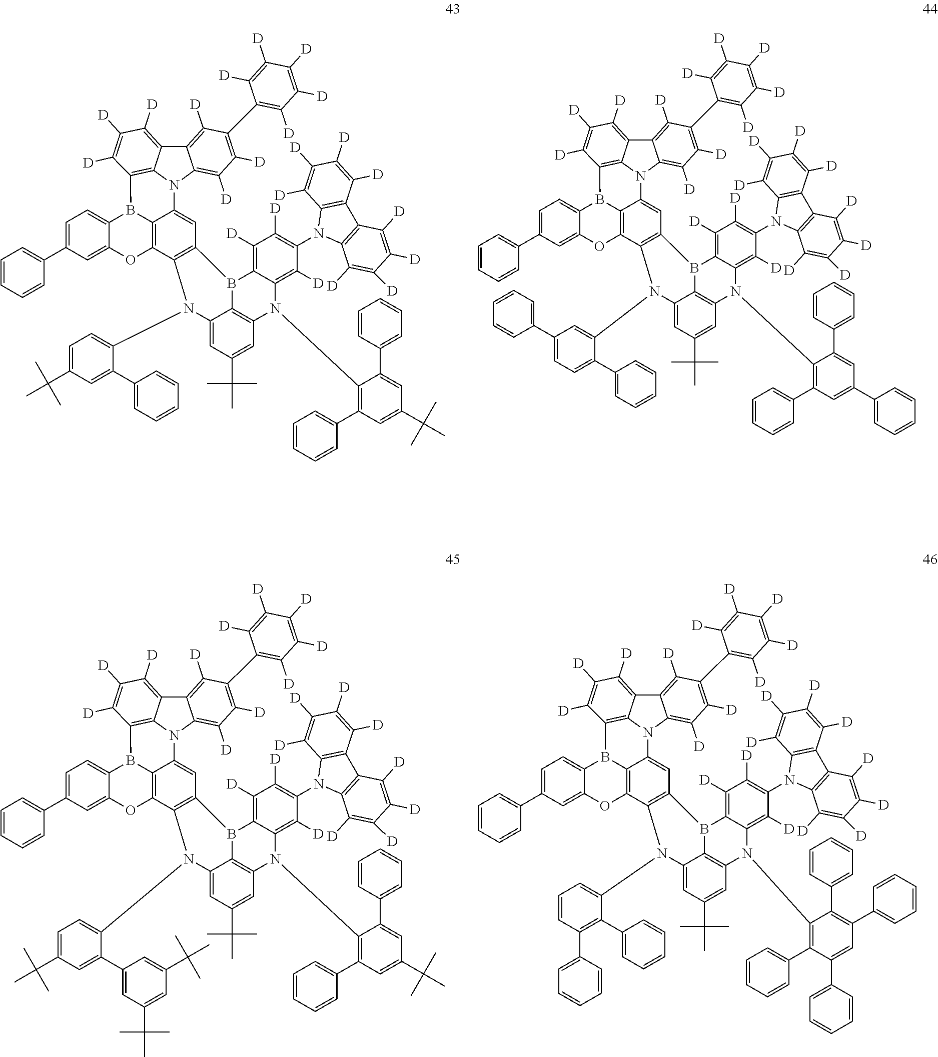 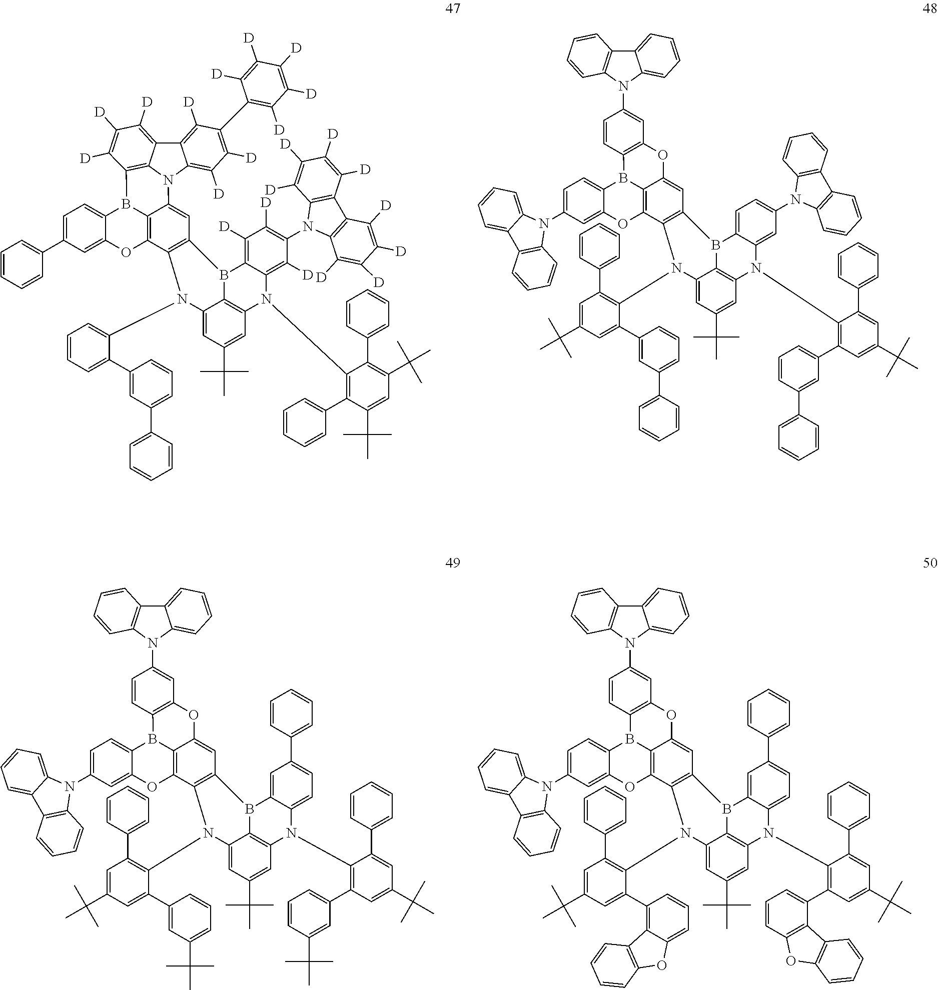 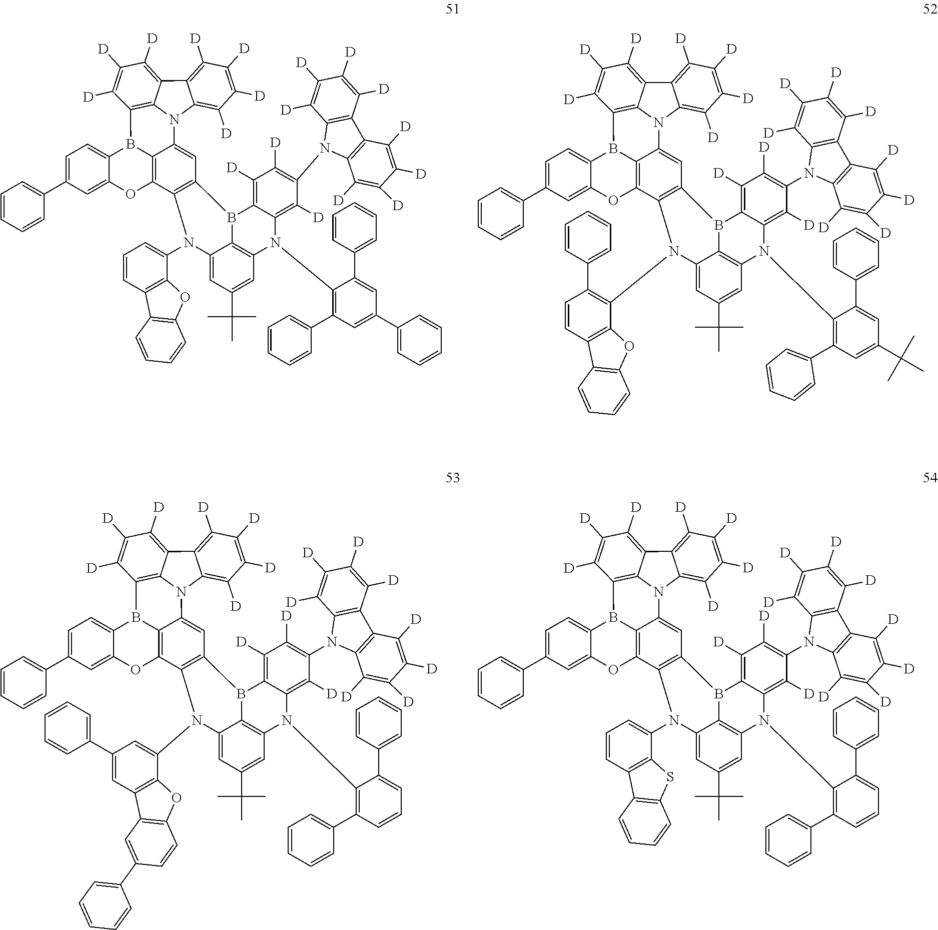 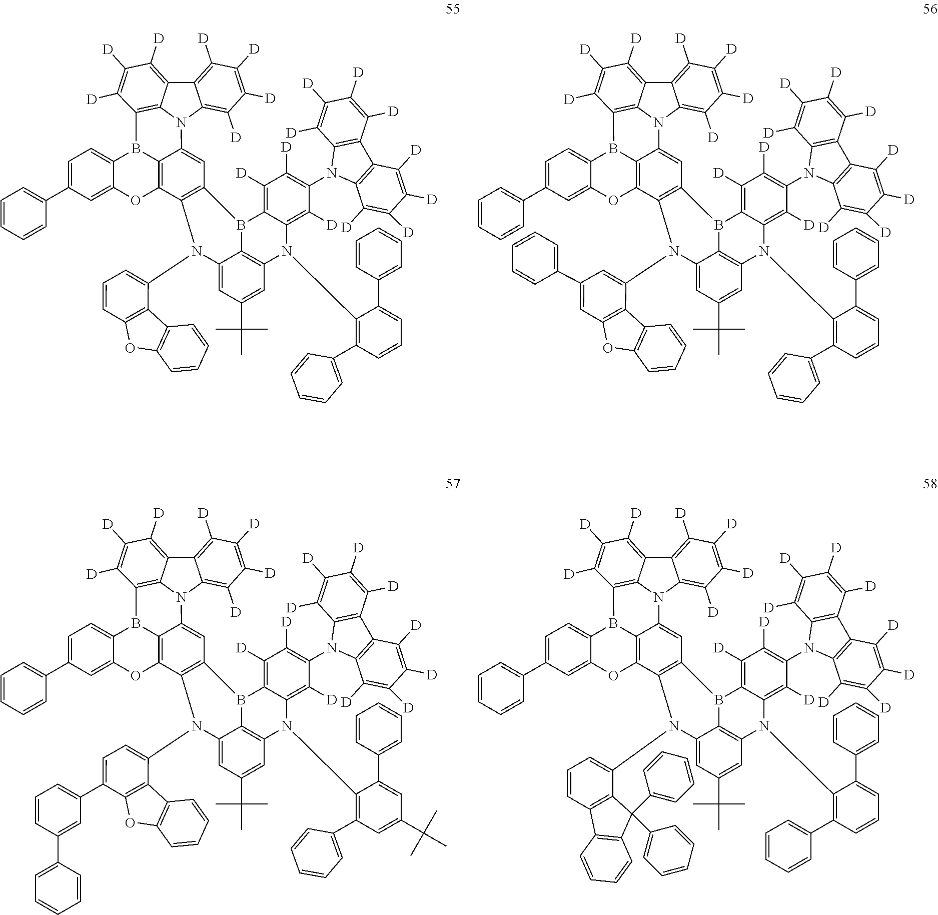 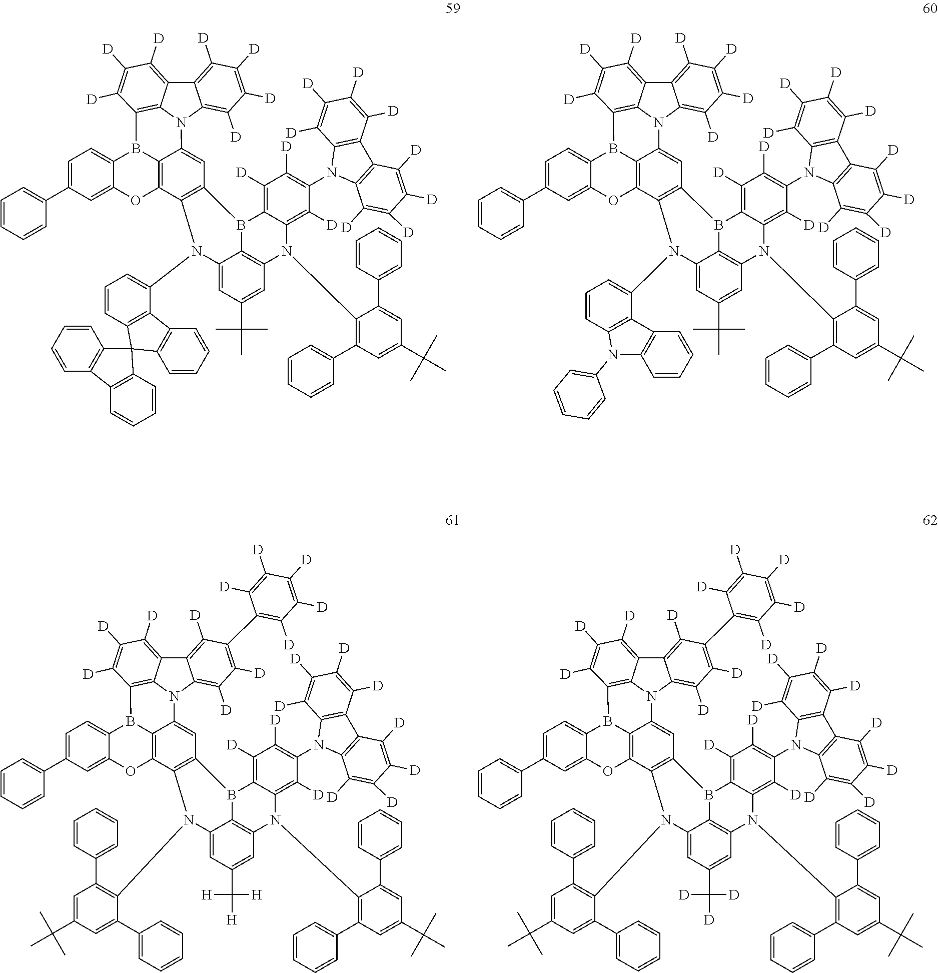 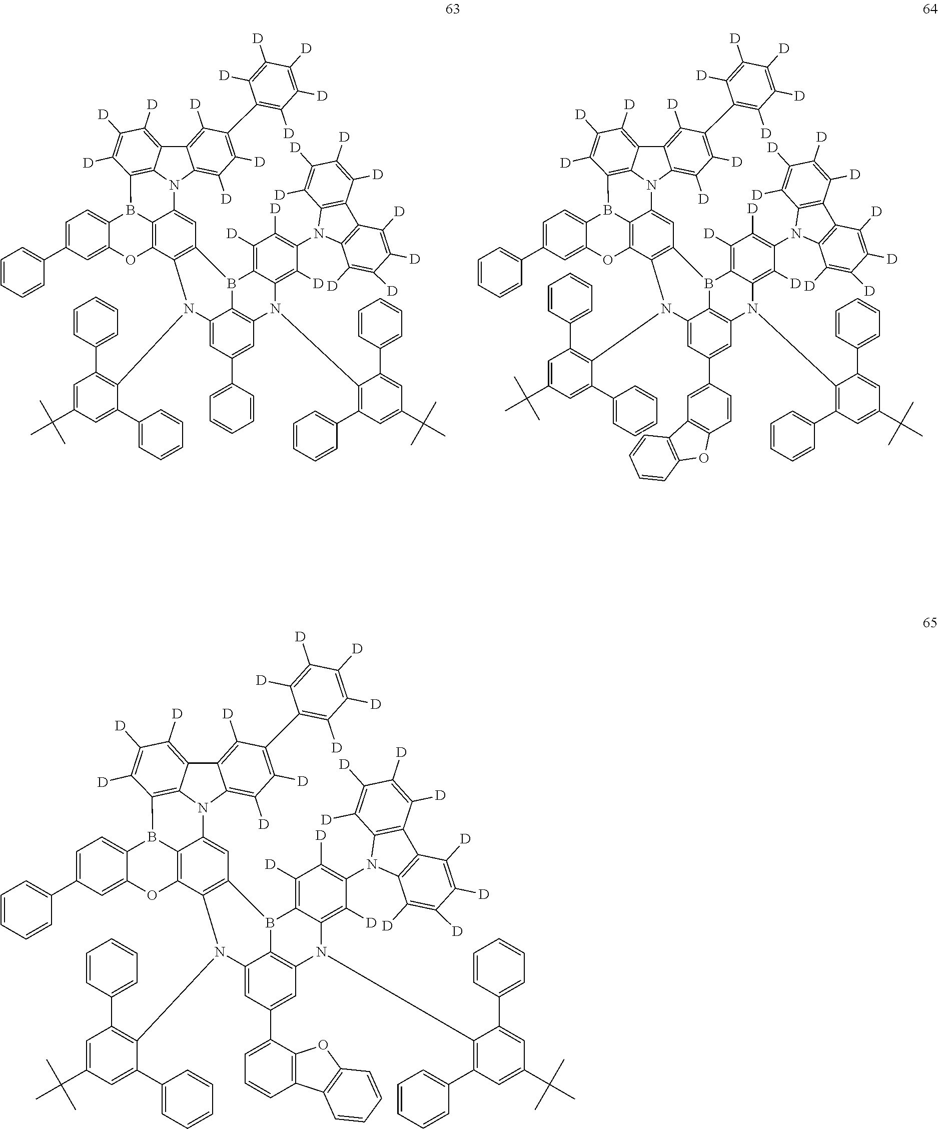 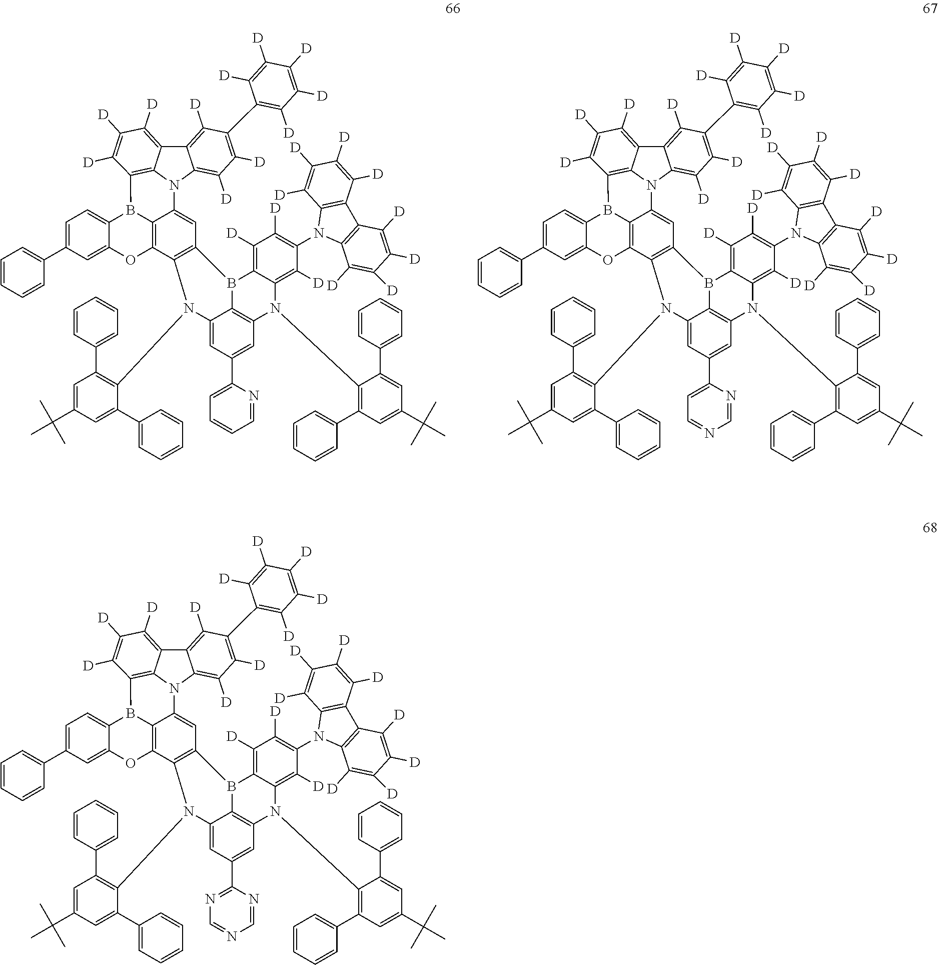 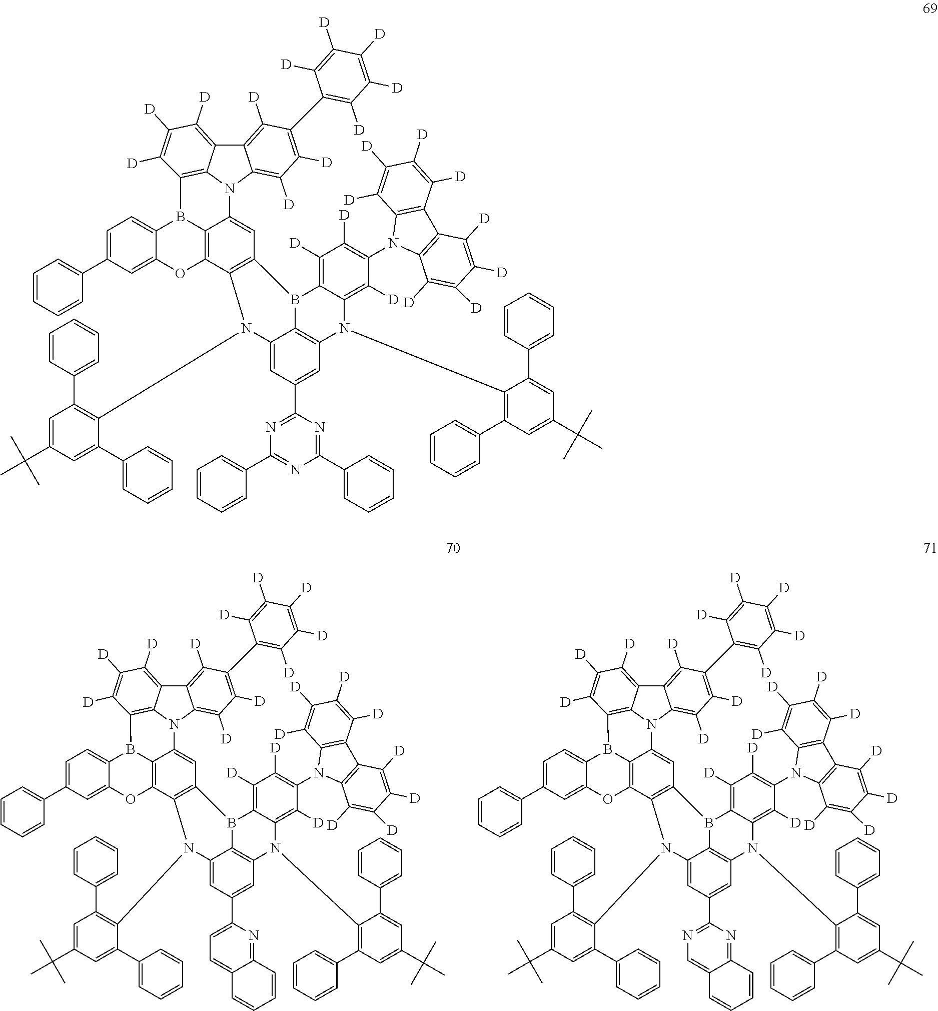 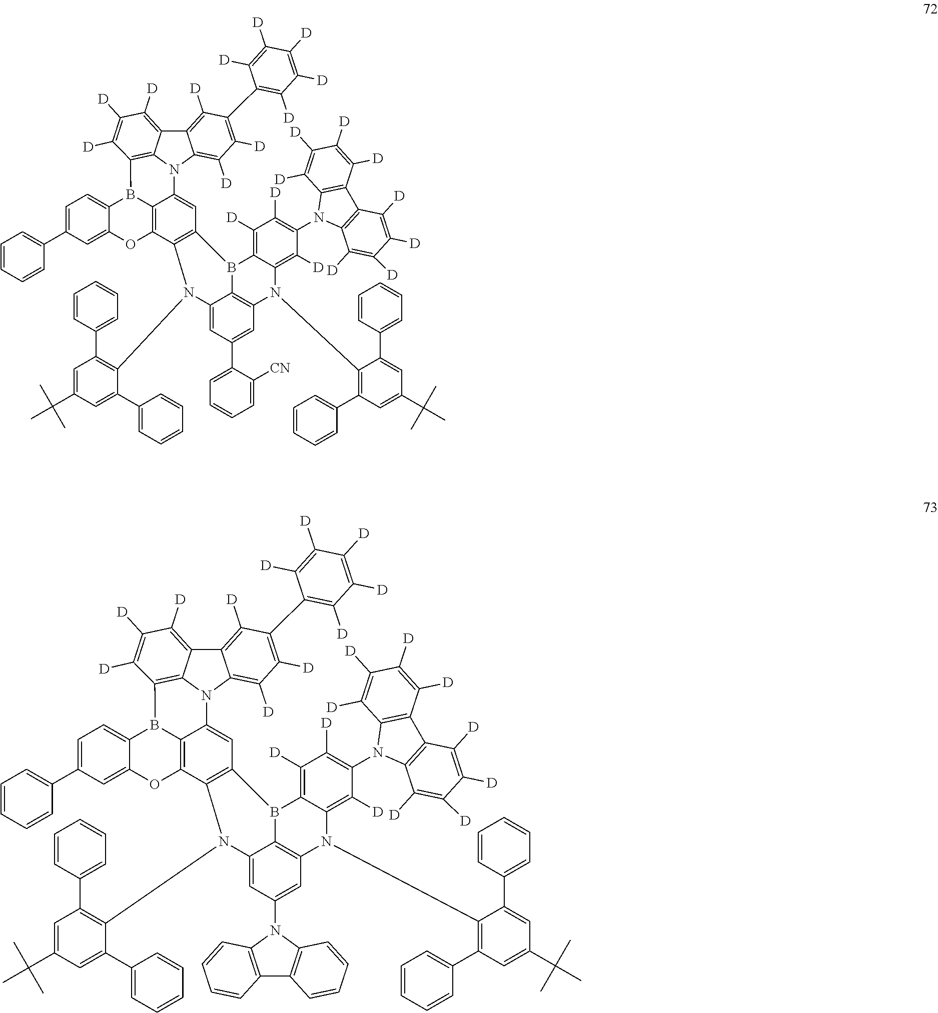 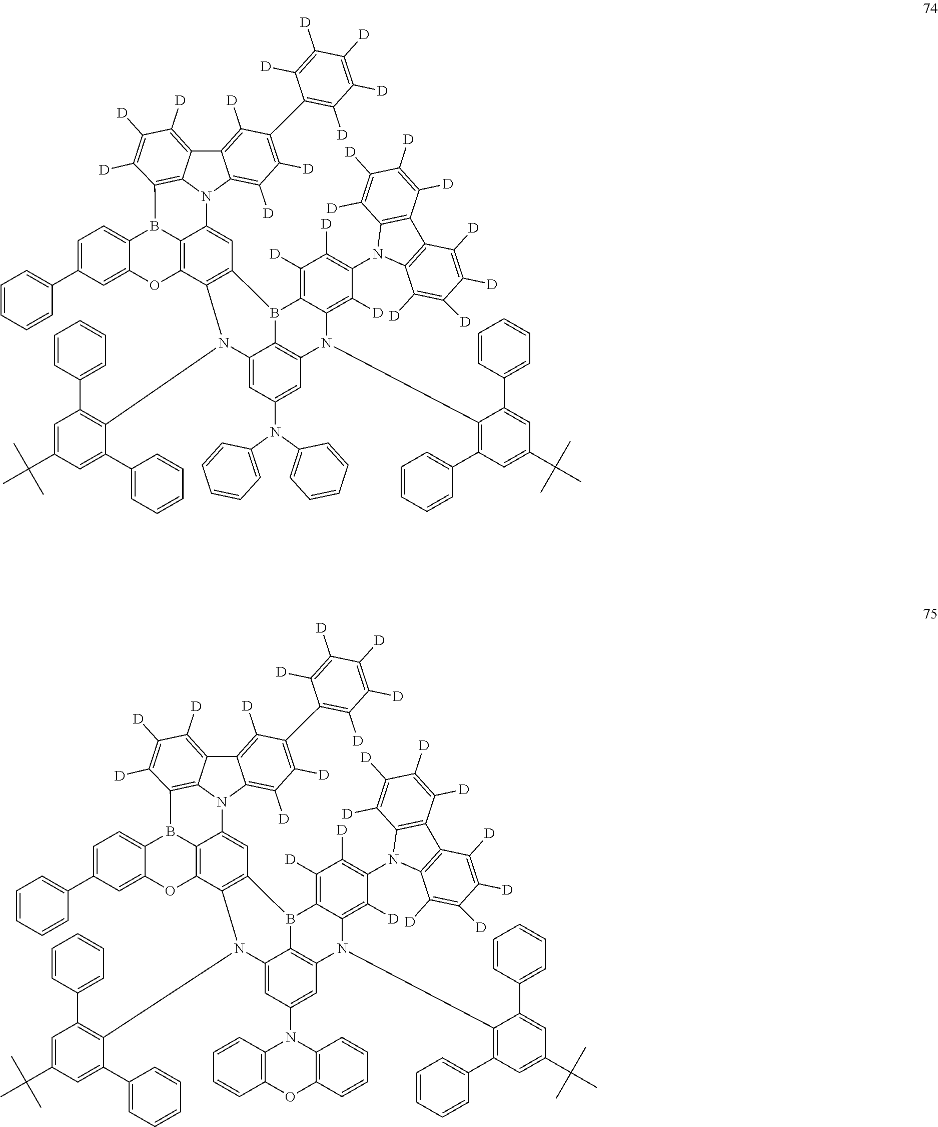 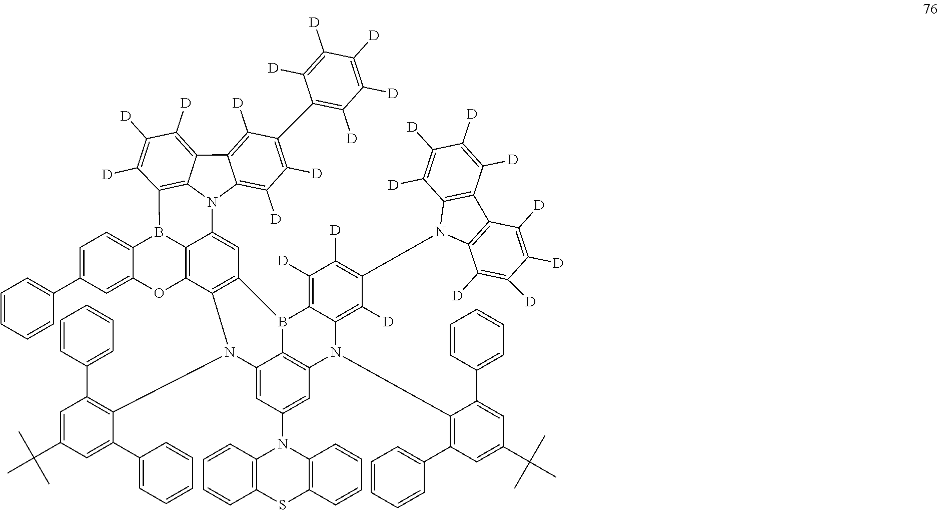 [SMILES: [2H]c1c([2H])c([2H])c(-c2c([2H])c([2H])c3c(c2[2H])c2c([2H])c([2H])c([2H])c4c2n3-c2cc3c(c5c2B4c2ccc(-c4ccccc4)cc2O5)N(c2c(-c4ccccc4)cc(C(C)(C)C)cc2-c2ccccc2)c2cc(N4c5ccccc5Sc5ccccc54)cc4c2B3c2c([2H])c([2H])c(-n3c5c([2H])c([2H])c([2H])c([2H])c5c5c([2H])c([2H])c([2H])c([2H])c53)c([2H])c2N4c2c(-c3ccccc3)cc(C(C)(C)C)cc2-c2ccccc2)c([2H])c1[2H]]
wherein in Compound Group 1,
D represents a deuterium atom.
